(19) United States
(12) Patent Application Publication
(10) Pub. No.: US 2013/0034706 A1
(43) Pub. Date: Feb. 7, 2013

(54) PATTERN FORMING METHOD, ACTINIC RAY-SENSITIVE OR RADIATION-SENSITIVE RESIN COMPOSITION, RESIST FILM, PRODUCTION METHOD OF ELECTRONIC DEVICE, AND ELECTRONIC DEVICE

(71) Applicant: Shuhei YAMAGUCHI, Haibara-gun (JP)

(72) Inventor: Shuhei YAMAGUCHI, Haibara-gun (JP)

(73) Assignee: FUJIFILM CORPORATION, Tokyo (JP)

(21) Appl. No.: 13/540,123

(22) Filed: Jul. 2, 2012

(30) Foreign Application Priority Data
Jul. 28, 2011 (JP) 2011-166023
Jun. 14, 2012 (JP) 2012-135121

(51) Int. Cl. G03F 7/027; B32B 3/10; G03F 7/20

(52) U.S. Cl. 428/195.1; 430/325; 430/281.1; 430/311

(57) ABSTRACT

The present invention relates to a pattern forming method comprising:
(1) forming a film by using an actinic ray-sensitive or radiation-sensitive resin composition containing a resin (P) of which the polarity increases by the action of an acid and thereby the solubility in a developer containing an organic solvent decreases and a compound (B) which generates an acid which is represented by the following general formula (I) by irradiation with actinic rays or radiation;
(2) exposing the film; and
(3) forming a negative-type pattern by developing with a developer which contains an organic solvent,
   the actinic ray-sensitive or radiation-sensitive resin composition and the resist film which are used in the method, a method for preparing an electronic device and the electronic device.

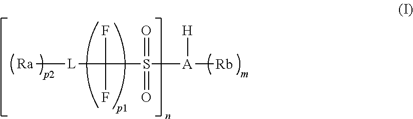

### BACKGROUND OF THE INVENTION

1. Field of the Invention

The present invention relates to a pattern forming method; an actinic ray-sensitive or radiation-sensitive resin composition and a resist film which are used in the pattern forming method; a production method of an electronic device and the electronic device. More specifically, the present invention relates to a pattern forming method that is suitably used for a production process of a semiconductor such as IC, a production process of a circuit board of a liquid crystal, a thermal head, or the like, and other lithography processes of photofabrication; an actinic ray-sensitive or radiation-sensitive resin composition and a resist film which are used for the pattern forming method; a production method of an electronic device and the electronic device.

2. Description of the Related Art

Since a resist composition for a KrF excimer laser (248 nm) has been developed, a pattern forming method using chemical amplification has been used to compensate for desensitization caused by the light absorption of the resist composition. For example, in a positive-type chemical amplification method, first, a photoacid-generating agent that is included in an exposed portion is decomposed by irradiation with light and generates an acid. Thereafter, in a process such as PEB (Post Exposure Bake), by the catalytic action of the generated acid, an alkali-insoluble group included in the resist composition is changed to an alkali-soluble group. Subsequently, development is performed using, for example, an alkaline solution. In this manner, the exposed portion is removed, and a desired pattern is obtained.

In the above method, various alkaline developers have been suggested as the alkaline developer. As an example of the alkaline developers, an aqueous alkaline developer such as 2.38% by mass of TMAH (tetramethylammonium hydroxide solution) is widely used.

In the positive-type chemical amplification method, placing a group which is acid-decomposable through a polycyclic hydrocarbon group as a spacer with respect to a polymer main chain has been attempted from the viewpoint of improving resolution, dry etching resistance, pattern formation properties and the like (for example refer to JP3390702B, JP2008-58538A, JP2010-254639A, JP2010-256873A and JP2000-122295A).

Also in the positive-type chemical amplification method, using a photoacid-generating agent which has a specific sulfonylimide structure or a sulfonylmethide structure is known from the viewpoint of improving an exposure latitude and suppressing line edge roughness (refer to JP201′-37825A).

In order to miniaturize semiconductor elements, a wavelength of an exposure light source is being shortened, and a projection lens with a high numerical aperture (high NA) is being used. Currently, an exposure machine using an ArF excimer laser having a wavelength of 193 nm as a light source has been developed. As a technique for further improving resolving power, a method of filling a liquid having a high refractive index (also referred to as a “liquid for liquid immersion” hereinafter) between a projection lens and a sample has been proposed (that is, a liquid immersion method). In addition, EUV lithography that performs exposure by using ultraviolet rays having a shorter wavelength (13.5 nm) has also been proposed.

However, in the current circumstances, it is very difficult to find an appropriate combination of a resist composition, a developer, a rinsing liquid, and the like necessary for forming a pattern that has an excellent performance overall.

In recent years, a pattern forming method using a developer containing an organic solvent has been developed (for example, refer to JP2008-292975A and JP2010-197619A). For example, in JP2008-292975A a pattern forming method which includes a process to coat on a substrate a resist composition of which solubility increases with respect to an alkaline developer and of which solubility decreases with respect to an organic solvent developer by irradiation with actinic rays or radiation, an exposure process and a development process using the organic solvent developer is disclosed. According to this method, a fine pattern with high accuracy may be stably formed.

However, further improvement is required in the pattern forming method with regard to improvement in roughness properties, uniformity in local pattern dimensions and exposure latitude and reduced developing time dependency (a degree of a change in pattern dimensions according to a change of developing time) and film thinning during development.

### SUMMARY OF THE INVENTION

An object of the present invention is to provide a pattern forming method which is excellent in roughness properties such as line width roughness, uniformity in local pattern dimensions and exposure latitude, has reduced developing time dependency and is able to suppress reduction of film thickness in a pattern portion formed by development, so-called film thinning; an actinic ray-sensitive or radiation-sensitive resin composition and a resist film used for the pattern forming method; a production method of an electronic device; and the electronic device.

The present invention is configured as follows and the problems of the present invention are solved thereby.

[1] A pattern forming method including:
(1) forming a film by using an actinic ray-sensitive or radiation-sensitive resin composition containing a resin (P) of which the polarity increases by the action of an acid and thereby the solubility in a developer containing an organic solvent decreases and a compound (B) which generates an acid which is represented by the following general formula (I) by irradiation with actinic rays or radiation;
(2) exposing the film; and
(3) forming a negative-type pattern by developing with a developer which contains an organic solvent.

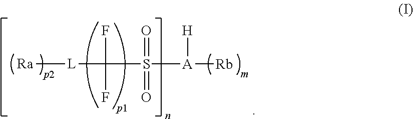

A represents a nitrogen atom or a carbon atom.
Each Ra independently represents a hydrogen atom, an alkyl group which does not have a fluorine atom as a substituent, a cycloalkyl group or an aryl group, and Rb represents an electron-attracting group, an alkyl group or an aryl group.
When A is a nitrogen atom, n represents 1 or 2 and m represents (2-n).
When A is a carbon atom, n represents an integer of 1 to 3 and m represents (3-n).
p1 represents an integer of 1 to 4 and p2 represents 1 or 2.
L represents a single bond or a (p2+1)-valent linking group. When L is a single bond, p2 represents 1.
When at least one of (i) p2 represents 2, and (ii) n represents 2 or 3, is satisfied, a plurality of Ra's may be the same as or different from each other and may be bonded to each other to form a ring.
When A is a carbon atom and m represents 2, a plurality of Rb's may be the same as or different from each other.

[2] The pattern forming method according to [1],
wherein the compound (B) is an ionic compound represented by the following general formula (II).

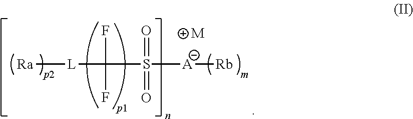

In the general formula (II), A, Ra, Rb, L, m, n, p1 and p2 have the same definition as that of the respective A, Ra, Rb, L, m, n, p1 and p2 in the general formula (I).
M⁺ represents an organic counterion.

[3] The pattern forming method according to [2],
wherein M⁺ in the above general formula (II) is a sulfonium cation or an iodonium cation.

[4] The pattern forming method according to any one of [1] to [3],
wherein in each of n groups represented by [(Ra)ₚ₂-L-(CF₂)ₚ₁—SO₂]— in the above general formula (I) or (II),
(i) p2 represents 1 and L represents a single bond or a divalent group represented by any of the following formulae (L1) to (L6), or
(ii) p2 represents 2 and L represents a trivalent formula represented by any of the following formulae (L7) to (L9).

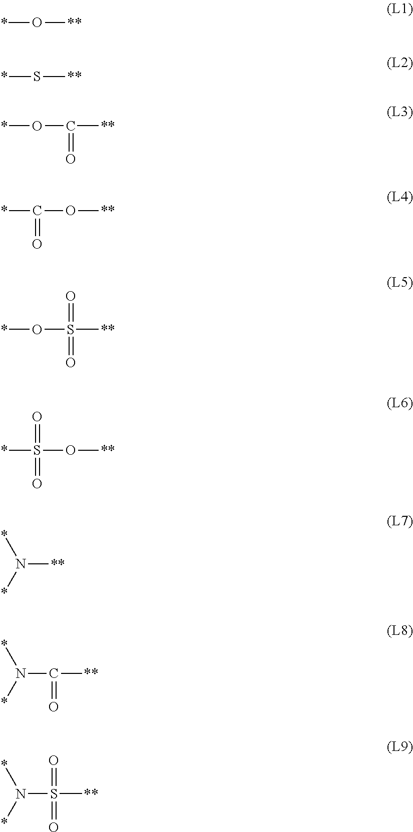

In the above formulae, * represents a bond bonding to Ra in the general formula (I) or (II) and ** represents a bond bonding to —(CF₂)ₚ₁— in the general formula (I) or (II).

[5] The pattern forming method according to any one of [1] to [4],
wherein L does not have a fluorine atom and p1 represents 1 in the above general formula (I) or (II).

[6] The pattern forming method according to any one of [1] to [5],
wherein the resin (P) has a repeating unit (a1) which is acid-decomposable and thereby generates a carboxyl group.

[7] The pattern forming method according to any one of [1] to [6],
wherein the repeating unit (a1) which generates a carboxyl group is at least one of a repeating unit represented by the following general formula (III) and a repeating unit represented by the following general formula (IV).

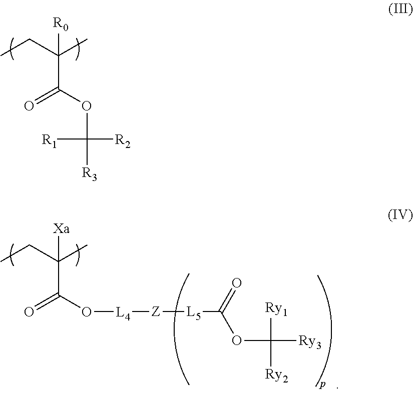

In the above general formula (III), R₀ represents a hydrogen atom, an alkyl group, a cyano group or a halogen atom.

R₁ to R₃ each independently represent a chain alkyl group.

In the above general formula (IV), Xa represents a hydrogen atom, an alkyl group, a cyano group or a halogen atom.

Ry₁ to Ry₃ each independently represent an alkyl group or a cycloalkyl group. Two of Ry₁ to Ry₃ may be bonded to each other to form a ring.

Z represents a (p+1)-valent linking group which has a polycyclic hydrocarbon structure and may have a hetero atom as a ring member.

L₄ and L₅ each independently represent a single bond or a divalent linking group.

p represents an integer of 1 to 3.

When p is 2 or 3, a plurality of L₅'s, a plurality of Ry₁'s a plurality of Ry₂'s and a plurality of Ry₃'s may be the same as or different from each other.

[8] The pattern forming method according to [6] or [7],
wherein the content of the repeating unit (a1) is 50 mol % or more, based on all the repeating units in the resin (P)

[9] The pattern forming method according to [8],
wherein the content of the repeating unit (a1) is 50 mol % or more and 65 mol % or less, based on all the repeating units in the resin (P).

[10] The pattern forming method according to any one of [1] to [9],
wherein the actinic ray-sensitive or radiation-sensitive resin composition further contains a basic compound or an ammonium salt compound (C) in which basicity decreases by irradiation with actinic rays or radiation.

[11] The pattern forming method according to any one of [1] to [10],
wherein the actinic ray-sensitive or radiation-sensitive resin composition further contains a hydrophobic resin which contains at least one of fluorine atoms and silicon atoms.

[12] The pattern forming method according to any one of [1] to [11],
wherein the developer contains at least one kind of organic solvent selected from a group consisting of a ketone-based solvent, an ester-based solvent, an alcohol-based solvent, an amide-based solvent, and an ether-based solvent.

[13] The pattern forming method according to any one of [1] to [12], further including: (4) washing with a rinsing liquid containing an organic solvent.

[14] The pattern forming method according to any one of [1] to [13],
wherein the exposing in (2) is liquid immersion exposure.

[15] An actinic ray-sensitive or radiation-sensitive resin composition including:
a resin (P) of which the polarity increases by the action of an acid and thereby the solubility in a developer containing an organic solvent decreases and
a compound (B′) which generates an acid represented by the following general formula (I-1) by irradiation with actinic rays or radiation.

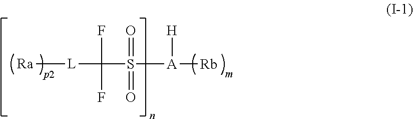

A represents a nitrogen atom or a carbon atom.

Each Ra independently represents a hydrogen atom, an alkyl group which does not have a fluorine atom as a substituent, a cycloalkyl group or an aryl group, and Rb represents an electron-attracting group, an alkyl group or an aryl group.

When A is a nitrogen atom, n represents 1 or 2 and m represents (2-n).

When A is a carbon atom, n represents an integer of 1 to 3 and m represents (3-n).

p2 represents 1 or 2.

L represents a single bond or a (p2+1)-valent linking group which does not have a fluorine atom. When L is a single bond, p2 represents 1.

When at least one of (i) p2 represents 2, and (ii) n represents 2 or 3, is satisfied, a plurality of Ra's may be the same as or different from each other and may be bonded to each other to form a ring.

When A is a carbon atom and m represents 2, a plurality of Rb's may be the same as or different from each other.

[16] An actinic ray-sensitive or radiation-sensitive resin composition including:
a resin (P′) which has a repeating unit (a1) which is acid-decomposable and thereby generates a carboxyl group and
a compound (B) which generates an acid represented by the following general formula (I) by irradiation with actinic rays or radiation,
wherein the content of the repeating unit (a1) is 50 mol % or more, based on all the repeating units in the resin (P′).

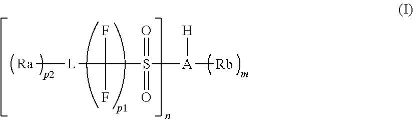

A represents a nitrogen atom or a carbon atom.

Each Ra independently represents a hydrogen atom, an alkyl group which does not have a fluorine atom as a substituent, a cycloalkyl group or an aryl group, and Rb represents an electron-attracting group, an alkyl group or an aryl group.

When A is a nitrogen atom, n represents 1 or 2 and m represents (2-n).

When A is a carbon atom, n represents an integer of 1 to 3 and m represents (3-n).

p1 represents an integer of 1 to 4 and p2 represents 1 or 2.

L represents a single bond or a (p2+1)-valent linking group. When L is a single bond, p2 represents 1.

When at least one of (i) p2 represents 2, and (ii) n represents 2 or 3, is satisfied, a plurality of Ra's may be the same as or different from each other and may be bonded to each other to form a ring.

When A is a carbon atom and m represents 2, a plurality of Rb's may be the same as or different from each other.

[17] The actinic ray-sensitive or radiation-sensitive resin composition according to [16],
wherein the content of the repeating unit (a1) is 50 mol % or more and 65 mol % or less, based on all the repeating units in the resin (P′).

[18] The actinic ray-sensitive or radiation-sensitive resin composition according to [16] or [17],
wherein the repeating unit (a1) is at least one of a repeating unit represented by the following general formula (III) and a repeating unit represented by the following general formula (IV).

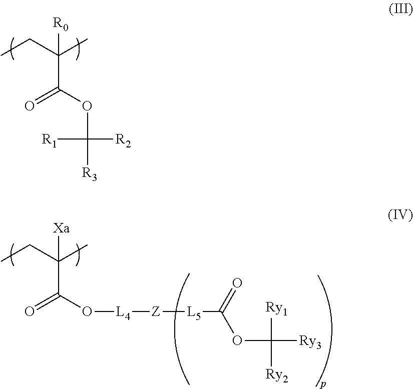

In the above general formula (III), R₀ represents a hydrogen atom, an alkyl group, a cyano group or a halogen atom.

R₁ to R₃ each independently represent a chain alkyl group.

In the above general formula (IV), Xa represents a hydrogen atom, an alkyl group, a cyano group or a halogen atom.

Ry₁ to Ry₃ each independently represent an alkyl group or a cycloalkyl group. Two of Ry₁ to Ry₃ may be bonded to each other to form a ring.

Z represents a (p+1)-valent linking group which has a polycyclic hydrocarbon structure and may have a hetero atom as a ring member.

L₄ and L₅ each independently represent a single bond or a divalent linking group.

p represents an integer of 1 to 3.

When p is 2 or 3, a plurality of L₅, a plurality of Ry₁, a plurality of Ry₂ and a plurality of Ry₃ may be the same as or different from each other.

[19] An actinic ray-sensitive or radiation-sensitive resin composition including:
a resin (P) of which the polarity increases by the action of an acid and thereby the solubility in a developer containing an organic solvent decreases,
a compound (B) which generates an acid represented by the following general formula (I) by irradiation with actinic rays or radiation and
a basic compound or an ammonium salt compound (C) in which basicity decreases by irradiation with actinic rays or radiation.

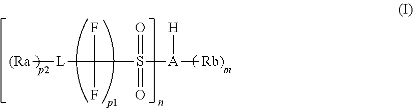

A represents a nitrogen atom or a carbon atom.

Each Ra independently represents a hydrogen atom, an alkyl group which does not have a fluorine atom as a substituent, a cycloalkyl group or an aryl group, and Rb represents an electron-attracting group, an alkyl group or an aryl group.

When A is a nitrogen atom, n represents 1 or 2 and m represents (2-n).

When A is a carbon atom, n represents an integer of 1 to 3 and m represents (3-n).

p1 represents an integer of 1 to 4 and p2 represents 1 or 2.

L represents a single bond or a (p2+1)-valent linking group. When L is a single bond, p2 represents 1.

When at least one of (i) p2 represents 2, and (ii) n represents 2 or 3, is satisfied, a plurality of Ra's may be the same as or different from each other and may be bonded to each other to form a ring.

When A is a carbon atom and m represents 2, a plurality of Rb's may be the same as or different from each other.

[20] A resist film which is formed using the actinic ray-sensitive or radiation-sensitive resin composition according to any one of [15] to [19].

[21] A manufacturing method of an electronic device, including the pattern forming method according to any one of [1] to [14].

[22] An electronic device prepared by the manufacturing method of an electronic device according to [21].

According to the present invention, it is possible to provide a pattern forming method which is excellent in roughness properties such as line width roughness, uniformity in local pattern dimension and exposure latitude, has reduced developing time dependency and is able to suppress reduction of film thickness in a pattern portion formed by development, so-called film thinning; an actinic ray-sensitive or radiation-sensitive resin composition and a resist film used for the pattern forming method; a production method of an electronic device; and the electronic device.

### BRIEF DESCRIPTION OF THE DRAWINGS

FIG. 1 is a diagram showing a ¹H-NMR chart of an acid-generating agent PAG-1.

FIG. 2 is a diagram showing a ¹⁹F-NMR chart of an acid-generating agent PAG-1.

FIG. 3 is a diagram showing a ¹H-NMR chart of an acid-generating agent PAG-14.

FIG. 4 is a diagram showing a ¹⁹F-NMR chart of an acid-generating agent PAG-14.

### DESCRIPTION OF THE PREFERRED EMBODIMENTS

Hereinafter, the embodiments of the present invention are described in detail.

Regarding the description for a group (atomic group) in the present specification, if a group (atomic group) is not described with regard to whether the group is substituted or unsubstituted, the group includes not only those not having a substituent (atomic group) but also those having a substituent (atomic group). For example, an “alkyl group” includes not only an alkyl group not having a substituent (unsubstituted alkyl group) but also an alkyl group having a substituent (substituted alkyl group). [0083] The term “active light ray” or “radioactive ray” in this specification refers to, for example, a bright line spectrum of a mercury lamp, far-ultraviolet rays represented by an excimer laser, extreme ultraviolet (EUV) rays, X-rays, an electron beam (EB) or the like. In addition, the “light” in the present invention refers to the actinic rays or the radiation.

Unless otherwise specified, the term “exposure” in this specification includes not only the exposure performed using a mercury lamp, far-ultraviolet rays represented by an excimer laser, extreme-ultraviolet rays, X-rays, EUV rays and the like, but also drawing performed using a particle beam such as an electron beam or an ion beam.

A pattern forming method of the present invention is a pattern forming method including:
(1) forming a film by using an actinic ray-sensitive or radiation-sensitive resin composition containing a resin (P) of which the polarity increases by the action of an acid and thereby the solubility in a developer containing an organic solvent decreases and a compound (B) which generates an acid which is represented by the following general formula (I) by irradiation with actinic rays or radiation;
(2) exposing the film; and
(3) forming a negative-type pattern by developing with a developer which contains an organic solvent.

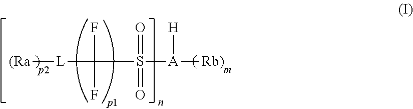

A represents a nitrogen atom or a carbon atom,
each Ra independently represents a hydrogen atom, an alkyl group which does not have a fluorine atom as a substituent, a cycloalkyl group or an aryl group, and Rb represents an electron-attracting group, an alkyl group or an aryl group,
when A is a nitrogen atom, n represents 1 or 2 and m represents (2-n),
when A is a carbon atom, n represents an integer of 1 to 3 and m represents (3-n),
p1 represents an integer of 1 to 4 and p2 represents 1 or 2,
L represents a single bond or a (p2+1)-valent linking group and when L is a single bond, p2 represents 1,
when at least one of (i) p2 represents 2, and (ii) n represents 2 or 3, is satisfied, a plurality of Ra's may be the same as or different from each other and may be bonded to each other to form a ring, and
when A is a carbon atom and m represents 2, a plurality of Rb's may be the same as or different from each other.

The reason why the pattern forming method of the present invention, which uses an acid-generating agent which generates an acid represented by the general formula (I) by irradiation with actinic rays or radiation, in forming a negative pattern by using a developer which contains an organic solvent, is excellent in roughness properties such as line width roughness, uniformity in local pattern dimensions and exposure latitude, has reduced developing time dependency and is able to suppress reduction of film thickness in a pattern portion formed by development, so-called film thinning, is unclear but is assumed to be as follows.

When development is performed using a developer which contains an organic solvent, particularly when hydrophilicity and hydrophobicity of a low molecular weight component in a resist film is greatly affected to development speed, the thickness of the pattern portion after developing and the low molecular weight component is hydrophobic, it is likely to cause problems such as film thinning.

However, in the acid-generating agent of the present invention, a sulfonyl group is directly bonded to an imide group or a methide group and a fluorinated alkylene group is bonded to the sulfonyl group. The acid-generating agent having such a structure generates a strong acid (compared to perfluoroalkane sulfonic acid as an acid generally used for a resist composition in particular) by irradiation with actinic rays or radiation. Accordingly a reaction where the polarity of the resin (P) increases due to an action of an acid may be performed with high efficiency. As a result, the solubility in a developer containing an organic solvent in an exposed portion reliably decreases and therefore film thinning in a pattern portion and developing time dependency may be suppressed.

On the other hand, an acid-generating agent with a high content ratio of fluorine atoms contained in the molecules likely causes phase separation of a resin and the acid-generating agent and localization of the acid-generating agent in the resist film since the acid-generating agent tends to have low dispersibility in the resist film. Due to this, the solubility of the resist film with respect to a developer is likely uneven in development, and roughness properties tends to be deteriorated.

However, the acid-generating agent in the present invention has a structure where a content ratio of fluorine atoms contained in the molecules may be reduced. Accordingly, it is considered that the above-described phase separation and localization in the resist film may be suppressed and roughness properties are improved.

Further, an acid represented by the above general formula (I) has a structure where a plurality of sulfonyl groups are bonded around an acid group and is large in volume compared to sulfonic acid which is generally generated in an exposed portion of a resist composition for ArF exposure. Accordingly it is considered that the volume of the acid generated in the exposed portion of the resist film increases, too much diffusion of the acid to an unexposed portion is suppressed and as a result exposure latitude is improved. In particular, when Ra is a cyclic group such as a cycloalkyl group and an aryl group, it is possible to control the volume of the acid generated in the exposed portion to increase further and to reliably improve exposure latitude.

In addition an acid represented by the general formula (I) has high acid strength. Due to this, the “reaction where the polarity of the resin (P) in the exposed portion increases due to an action of an acid” reliably accelerates and a dissolution contrast between an exposed portion and an unexposed portion with respect to the developer is very large. Therefore it is considered that uniformity in local pattern dimensions is improved.

The pattern forming method of the present invention may further include (4) washing with a rinsing liquid containing an organic solvent.

The rinsing liquid is preferably a rinsing liquid containing at least one kind of organic solvent selected from a group consisting of a hydrocarbon-based solvent, a ketone-based solvent, an ester-based solvent, an alcohol-based solvent, an amide-based solvent and an ether-based solvent.

The pattern forming method of the present invention preferably includes (5) baking after (2) exposing.

The resin (P) is also a resin of which the polarity increases due to an action of an acid and the solubility in an alkaline developer increases. Therefore the pattern forming method of the present invention may further include (6) developing with an alkaline developer.

In the pattern forming method of the present invention, (2) exposing may be performed a plurality of times.

In the pattern forming method of the present invention, (5) baking may be performed a plurality of times.

The resist film of the present invention is a film that is formed of the actinic ray-sensitive or radiation-sensitive resin composition. For example, the resist film is a film formed by coating the actinic ray-sensitive or radiation-sensitive resin composition onto a substrate.

Hereinafter, the actinic ray-sensitive or radiation-sensitive resin composition usable in the present invention will be described.

In addition, the present invention also relates to the actinic ray-sensitive or radiation-sensitive resin composition described below.

The actinic ray-sensitive or radiation-sensitive resin composition according to the present invention is used for negative-type development (development in which solubility in a developer is decreased by exposure, and the exposed portion remains as a pattern while the unexposed portion is removed). That is, the actinic ray-sensitive or radiation-sensitive resin composition according to the present invention is used as an actinic ray-sensitive or radiation-sensitive resin composition for organic solvent development, which is used for development performed using a developer that contains an organic solvent. Herein, “for organic solvent development” means that the actinic ray-sensitive or radiation-sensitive resin composition is at least provided to the developing with a developer that contains an organic solvent.

The actinic ray-sensitive or radiation-sensitive resin composition of the present invention is typically a resist composition, and preferably a negative-type resist composition (that is, a resist composition for organic solvent development) since particularly greater effects can be obtained. Moreover, the composition according to the present invention is typically a resist composition of a chemical amplification type.

[1] Resin (P) of which the Polarity Increases by the Action of an Acid and Thereby the Solubility in a Developer Containing an Organic Solvent Decreases.

Examples of the resin of which the polarity increases by the action of an acid and thereby the solubility in a developer containing an organic solvent decreases used in the actinic ray-sensitive or radiation-sensitive resin composition of the present invention include a resin (hereinafter, also referred to as an “acid-decomposable resin” or a “resin (P)”) having a group (hereinafter, also referred to as an “acid-decomposable group”) which generates a polar group by being decomposed by an action of an acid in a main chain or a side chain or both in a main chain or a side chain of the resin.

The resin (P) preferably has a repeating unit having a group which generates a polar group by being decomposed by an action of an acid.

The polar group is not particularly limited so long as the polar group is a group that is poorly-soluble or insoluble in a developer containing an organic solvent. Examples of the polar group include an acidic group (a group dissociated in 2.38% by mass of an aqueous tetramethylammonium hydroxide solution which has been used as a resist developer in the related art) such as a carboxyl group or a sulfonic acid group and an alcoholic hydroxyl group.

The alcoholic hydroxyl group is a hydroxyl group that is bonded to a hydrocarbon group, and refers to a hydroxyl group other than a hydroxyl group that is directly bonded to an aromatic ring (phenolic hydroxyl group). This alcoholic hydroxyl group does not include an aliphatic alcohol (for example, a fluorinated alcohol group (a hexafluoroisopropanol group or the like)) in which an α-position has been substituted with an electron-attracting group such as a fluorine atom as a hydroxyl group. The alcoholic hydroxyl group is preferably a hydroxyl group having a pKa of 12 or more and 20 or less.

As the acid-decomposable group, groups obtained by substituting a hydrogen atom of these groups with a group detached by an acid are preferable.

Examples of the group detached by an acid include —C(R₃₆)(R₃₇)(R₃₈), —C(R₃₆)(R₃₇)(OR₃₉) and —C(R₀₁)(R₀₂)(OR₃₉).

In the above general formulae, each of R₃₆ to R₃₉ independently represents an alkyl group, a cycloalkyl group, an aryl group, an aralkyl group, or an alkenyl group. R₃₆ and R₃₇ may be bonded to each other to form a ring.

Each of R₀₁ and R₀₂ independently represents a hydrogen atom, an alkyl group, a cycloalkyl group, an aryl group, an aralkyl group or an alkenyl group.

The alkyl group of R₃₆ to R₃₉, R₀₁ and R₀₂ is preferably an alkyl group having 1 to 8 carbon atoms, and examples thereof include a methyl group, an ethyl group, a propyl group, an n-butyl group, a sec-butyl group, a hexyl group and an octyl group, and the like.

The cycloalkyl group of R₃₆ to R₃₉, R₀₁ and R₀₂ may be monocyclic or polycyclic. The monocyclic cycloalkyl group is preferably a cycloalkyl group having 3 to 8 carbon atoms, and examples thereof include a cyclopropyl group, a cyclobutyl group, a cyclopentyl group, a cyclohexyl group, a cyclooctyl group and the like. The polycyclic cycloalkyl group is preferably a cycloalkyl group having 6 to 20 carbon atoms, and examples thereof include an adamantyl group, a norbornyl group, an isobornyl group, a camphanyl group, a dicyclopentyl group, an α-pinel group, a tricyclodecanyl group, a tetracyclododecyl group, an androstanyl group and the like. In addition, at least one carbon atom in the cycloalkyl group may be substituted with a hetero atom such as an oxygen atom.

The aryl group of R₃₆ to R₃₉, R₀₁ and R₀₂ is preferably an aryl group having 6 to 10 carbon atoms, and examples thereof include a phenyl group, a naphthyl group, an anthryl group and the like.

The aralkyl group of R₃₆ to R₃₉, R₀₁ and R₀₂ is preferably an aralkyl group having 7 to 12 carbon atoms, and examples thereof include a benzyl group, a phenethyl group, a naphthylmethyl group and the like.

The alkenyl group of R₃₆ to, R₃₉, R₀₁ and R₀₂ is preferably an alkenyl group having 2 to 8 carbon atoms, and examples thereof include a vinyl group, an allyl group, a butenyl group, a cyclohexenyl group and the like.

The ring that R₃₆ and R₃₇ form by bonding to each other is preferably a (monocyclic or polycyclic) cycloalkyl group. As the cycloalkyl group, a monocyclic cycloalkyl group such as a cyclopentyl group and a cyclohexyl group, and a polycyclic cycloalkyl group such as a norbornyl group, a tetracyclodecanyl group, a tetracyclododecanyl group and an adamantyl group are preferable. A monocyclic cycloalkyl group having 5 to 6 carbon atoms is more preferable, and a monocyclic cycloalkyl group having 5 carbon atoms is particularly preferable.

It is preferable that the resin (P) have a repeating unit (a1) which is acid decomposable and thereby generates a carboxyl group.

The repeating unit (a1) is preferably at least one of a repeating unit represented by the following formulae (III) and (IV) from the viewpoint of improving the effect of the present invention.

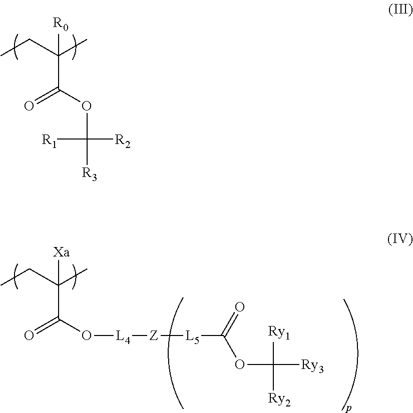

In the above general formula (III), R₀ represents a hydrogen atom, an alkyl group, a cyano group or a halogen atom. An alkyl group of R₀ may have a substituent. Examples of the substituent are a hydroxyl group and a halogen atom (preferably a fluorine atom).

The alkyl group of R₀ preferably has 1 to 4 carbon atoms. Examples thereof are a methyl group, an ethyl group, a propyl group, a hydroxymethyl group, a trifluoromethyl group or the like and a methyl group is preferable.

R₀ is preferably a hydrogen atom or a methyl group.

R₁ to R₃ each independently represent a (linear or branched) chain alkyl group. Here two or more of R₁ to R₃ do not bond to form a ring.

As an alkyl group of R₁ to R₃, groups having 1 to 4 carbon atoms such as a methyl group, an ethyl group, an n-propyl group, an isopropyl group, an n-butyl group, an isobutyl group, a t-butyl group or the like are preferable.

More preferably, R₁ to R₃ each independently represent a linear or branched alkyl group having 1 to 4 carbon atoms.

Each of the above-described groups may further have a substituent. Examples of the substituent are a halogen atom, an alkoxy group (having 1 to 4 carbon atoms), a carboxyl group, an alkoxycarbonyl group (having 2 to 6 carbon atoms), and a group having 8 or less carbon atoms are preferable.

Specific examples of the repeating units represented by the above general formula (III) are shown below, but the present invention is not limited thereto.

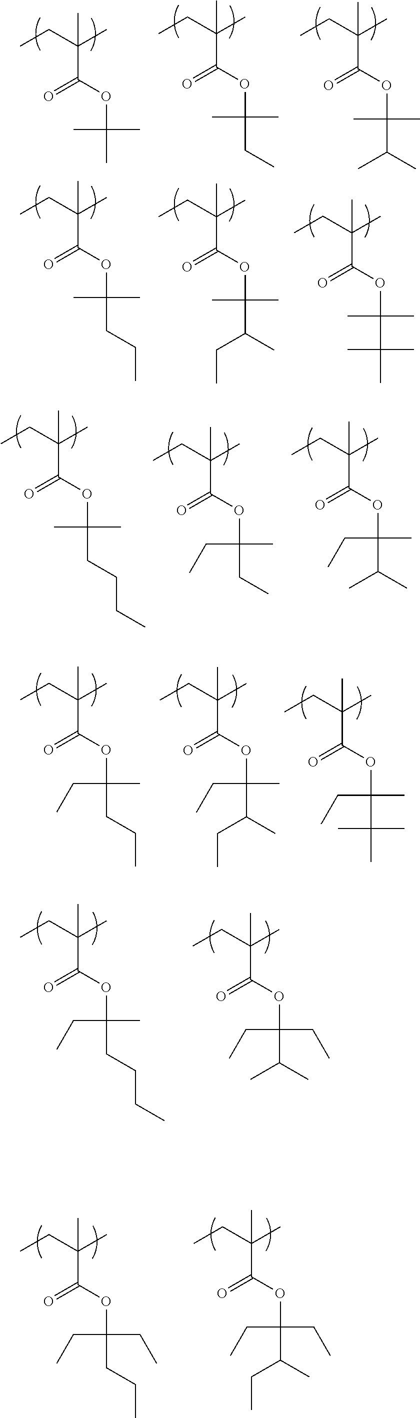

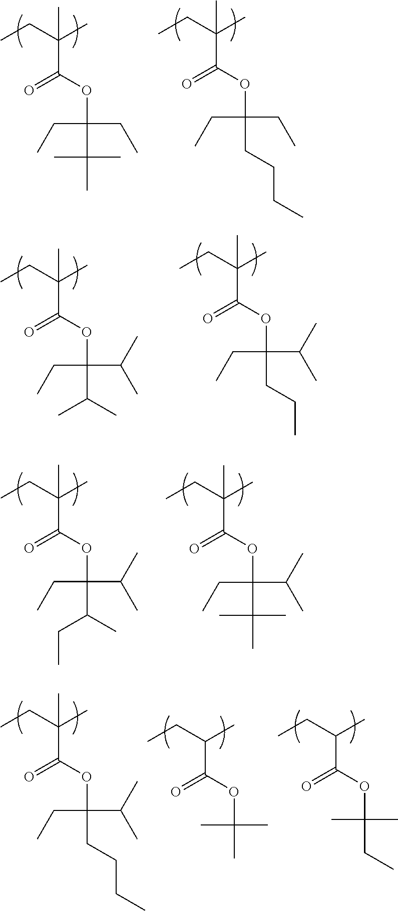

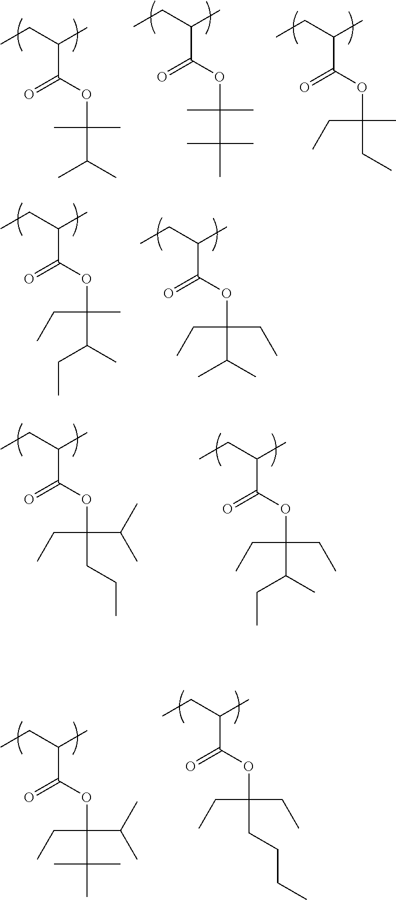

It is preferable that the repeating unit represented by the general formula (III) be a repeating unit represented by any of the following formulae (III-1), (111-2), (III-3) and (III-4). In the following specific examples, Xa₁ represents a hydrogen atom, CH₃, CF₃, or CH₂OH.

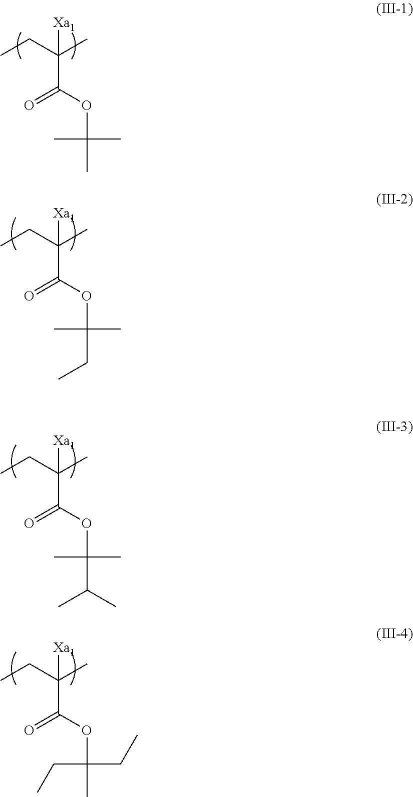

In the above general formula (IV), Xa represents a hydrogen atom, an alkyl group, a cyano group or a halogen atom,
Ry₁ to Ry₃ each independently represent an alkyl group or a cycloalkyl group,
two of Ry₁ to Ry₃ may be bonded to each other to form a ring,
Z represents a (p+1)-valent linking group which has a polycyclic hydrocarbon structure which may have a hetero atom as a ring member and as an atom group constituting the polycyclic structure, an ester bond is preferably not included (in other words, Z preferably does not include a lactone ring as a ring constituting the polycyclic structure),
L₄ and L₅ each independently represent a single bond or a divalent linking group,
p represents an integer of 1 to 3, and
when p is 2 or 3, a plurality of L₅, a plurality of Ry₁, a plurality of Ry₂ and a plurality of Ry₃ may be the same as or different from each other.

An alkyl group of Xa may have a substituent. Examples of the substituent are a hydroxyl group and a halogen atom (preferably a fluorine atom).

The alkyl group of Xa preferably has 1 to 4 carbon atoms. Examples thereof are a methyl group, an ethyl group, a propyl group, a hydroxymethyl group, a trifluoromethyl group or the like and a methyl group is preferable.

Xa is preferably a hydrogen atom or a methyl group.

The alkyl group of Ry₁ to Ry₃ may be a chainlike or branched and is preferably a methyl group, an ethyl group, an n-propyl group, an isopropyl group, an n-butyl group, an isobutyl group, a t-butyl group or the like having 1 to 4 carbon atoms.

The cycloalkyl group of Ry₁ to Ry₃ is preferably a monocyclic cycloalkyl group such as a cyclopentyl group or a cyclohexyl group, or a polycyclic cycloalkyl group such as a norbornyl group, a tetracyclodecanyl group, a tetracyclododecanyl group, or an adamantyl group.

The ring which two of Ry₁ to Ry₃ form by bonding to each other is preferably a monocyclic hydrocarbon ring such as a cyclopentan ring or a cyclohexane ring, or a polycyclic hydrocarbon ring such as a norbornane ring, a tetracyclodecane ring, a tetracyclododecane ring, or an adamantine ring. A monocyclic hydrocarbon ring having 5 to 6 carbon atoms is particularly preferable.

Each of Ry₁ to Ry₃ is preferably independently an alkyl group and more preferably a chainlike or branched alkyl group having 1 to 4 carbon atoms. In addition the chainlike or branched alkyl groups as Ry₁ to Ry₃ preferably have 5 or less carbon atoms in total.

Ry₁ to Ry₃ may further have a substituent, and examples of the substituent include an alkyl group (having 1 to 4 carbon atoms), a cycloalkyl group (having 3 to 8 carbon atoms), a halogen atom, an alkoxy group (having 1 to 4 carbon atoms), a carboxyl group, an alkoxycarbonyl group (having 2 to 6 carbon atoms), and the like. The substituent preferably has 8 or less carbon atoms. Among these, from the viewpoint of further improving the dissolution contrast between before and after acid decomposition with respect to a developer containing an organic solvent, the substituent is preferably a substituent that does not have a hetero atom such as an oxygen atom, a nitrogen atom, or a sulfur atom (for example, the substituent is preferably not an alkyl group or the like substituted with a hydroxyl group), more preferably a group that includes only hydrogen atoms and carbon atoms, and particularly preferably a linear or branched alkyl group or cycloalkyl group.

The linking group having a polycyclic hydrocarbon structure of Z includes a ring-aggregated hydrocarbon ring group and a crosslinked cyclic hydrocarbon ring group. Examples of the ring-aggregated hydrocarbon group include a group consisting of ring-aggregated hydrocarbon rings with arbitrary (p+1) hydrogen atoms removed therefrom, and examples of the crosslinked cyclic hydrocarbon ring group include a group where arbitrary (p+1) hydrogen atoms are removed from a crosslinked cyclic hydrocarbon ring.

Examples of the ring-aggregated hydrocarbon ring group include a bicyclohexane ring group, a perhydronaphthalene ring group, and the like. Examples of the crosslinked cyclic hydrocarbon ring group include bicyclic hydrocarbon ring groups such as a pinane ring group, a bornane ring group, a norpinane ring group, a norbornane ring group, and a bicyclooctane ring group (bicyclo[2.2.2]octane ring group, bicyclo[3.2.1]octane ring group, and the like); tricyclic hydrocarbon ring groups such as a homobrendane ring group, an adamantane ring group, a tricyclo[5.2.1.0^{2,6}]decane ring group, and a tricyclo[4.3.1.1^{2,5}]undecane ring group; and tetracyclic hydrocarbon ring groups such as a tetracyclo[4.4.0.1^{2,5}.1^{7,10}]dodecane ring group and a perhydro-1,4-methano-5,8-methanonaphthalene ring group. The crosslinked cyclic hydrocarbon ring group also includes a condensed ring hydrocarbon ring group, for example, a condensed ring group in which a plurality of 5 to 8-membered cycloalkane rings such as a perhydronaphthalene ring group (decalin), a perhydroanthracene ring group, a perhydrophenanthrene ring group, a perhydroacenaphthene ring group, a perhydrofluorene ring group, a perhydroindene ring group, and a perhydrophenalene ring group are condensed.

Examples of a preferable crosslinked cyclic hydrocarbon ring group include a norbornane ring group, an adamantine ring group, a bicyclooctane ring group, a tricyclo[5,2,1,0^{2,6}]decane ring group, and the like. Examples of the more preferable crosslinked cyclic hydrocarbon ring group include a norbornane ring group, and an adamantine ring group.

The linking group represented by Z and having the polycyclic hydrocarbon structure may have a substituent. Examples of the substituent which Z may have are substituents such as an alkyl group, a hydroxyl group, a cyano group, a keto group (alkylcarbonyl group and the like), acyloxy group, —COOR, —CON(R)₂, —SO₂R, —SO₃R, —SO₂N(R)₂ and the like. In the formula, R represents a hydrogen atom, an alkyl group, a cycloalkyl or an aryl group.

An alkyl group, an alkylcarbonyl group, acyloxy group, —COOR, —CON(R)₂, —SO₂R, —SO₃R, —SO₂N(R)₂ as the substituent which Z may have may further have a substituent and examples thereof are a halogen atom (preferably a fluorine atom).

A carbon atom (a carbon which contributes to forming a ring) included in the polycyclic hydrocarbon in the linking group which is represented by Z and has the polycyclic hydrocarbon structure may be a carbonyl carbon. Furthermore the polycyclic structure may have a hetero atom such as an oxygen atom, a sulfur atom and the like as a ring member as described above. However, Z as an atom group included in the polycyclic structure does not include an ester bond as described above.

Examples of the linking group represented by L₄ and L₅ are —COO—, —OCO—, —CONH—, —NHCO—, —CO—, —O—, —S—, —SO—, —SO₂—, an alkylene group (preferably having 1 to 6 carbon atoms), a cycloalkylene group (preferably having 3 to 10 carbon atoms), an alkenylene group (preferably having 2 to 6 carbon atoms), a linking group of a combination of a plurality of these or the like, and a linking group having 12 or less carbon atoms in total are preferable.

As L₄, a single bond, an alkylene group, —COO—, —OCO—, —CONH—, —NHCO—, -alkylene group-COO—, -alkylene group-OCO—, -alkylene group-CONH—, -alkylene group-NHCO—, —CO—, —O—, —SO₂— or -alkylene group-O— is preferable, and a single bond, an alkylene group, -alkylene group —COO— or -alkylene group-O— is more preferable.

As L₂, a single bond, an alkylene group, —COO—, —COO—, —CONH—, —NHCO—, —COO-alkylene group-, —OCO-alkylene group-, —CONH-alkylene group-, —NHCO-alkylene group-, —CO—, —O—, —SO₂—, —O-alkylene group- or —O-cycloalkylene group- is preferable, and a single bond, an alkylene group, —COO-alkylene group-, —O-alkylene group- or —O-cycloalkylene group- is more preferable.

In the above-described method, the bond “—” on a left end means connection to an ester bond on a side of the main chain in L₄ and to a Z in L₅. The bond “—” on a right end means connection to a Z in L₄ and to an ester bond connected to a group represented by (Ry₁)(Ry₂)(Ry₃)C— in L₅.

L₄ and L₅ may connect to a same atom constituting the polycyclic structure in Z.

p is preferably 1 or 2, and more preferably 1.

Specific examples of the repeating units represented by the following general formula (IV) will be shown below, but the present invention is not limited thereto. In the following specific examples, Xa represents a hydrogen atom, an alkyl group, a cyano group or a halogen atom.

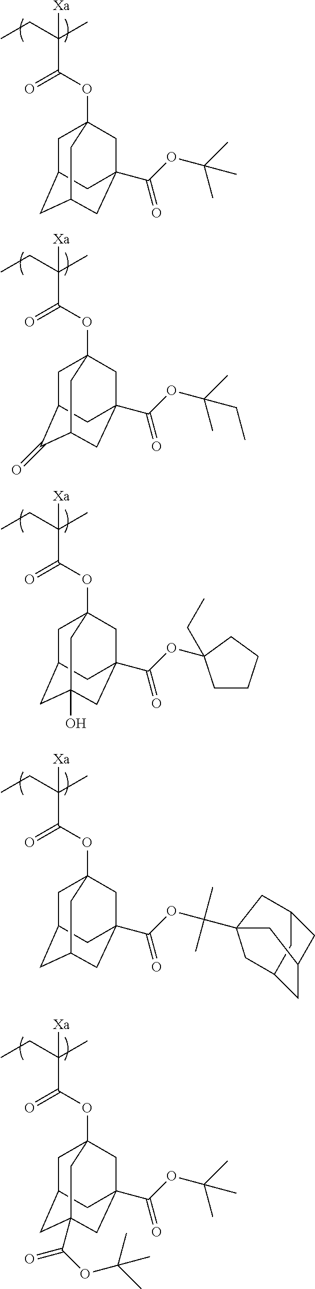

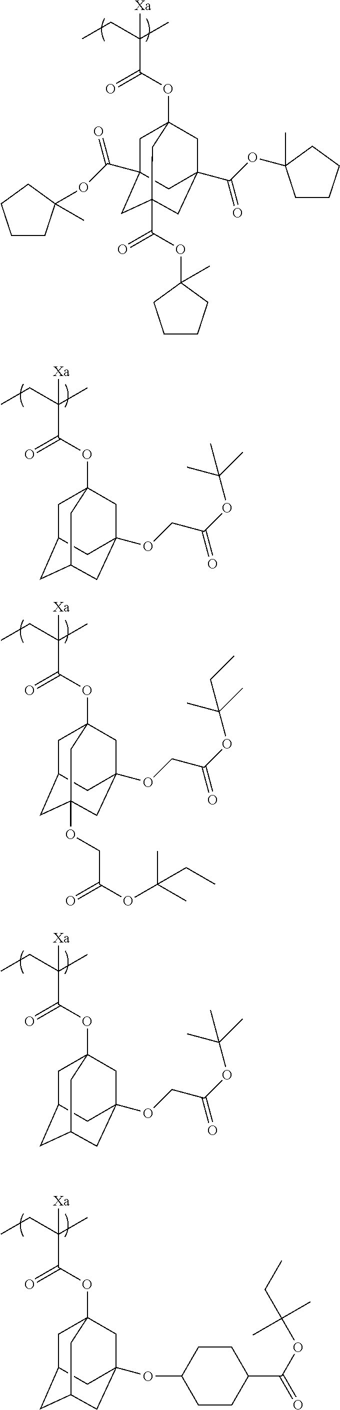

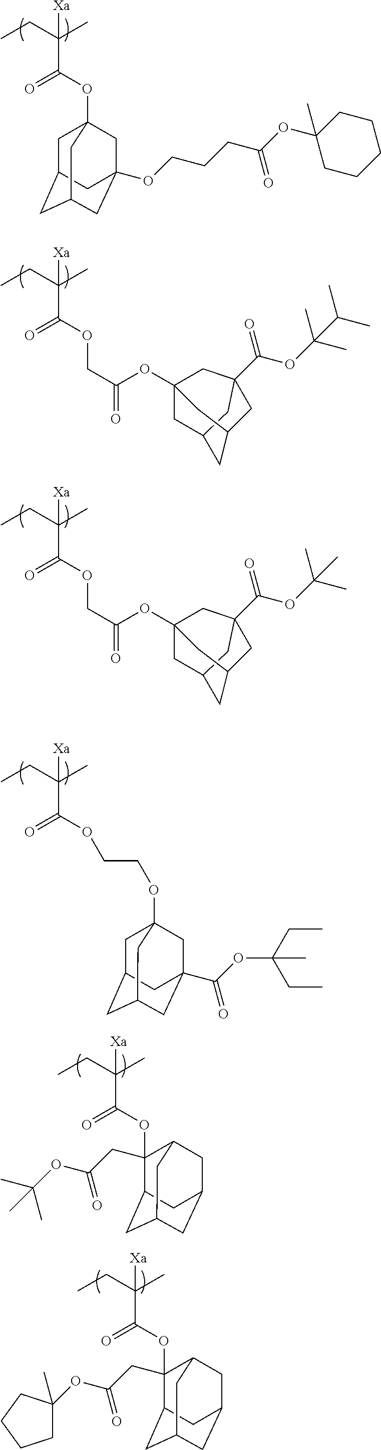

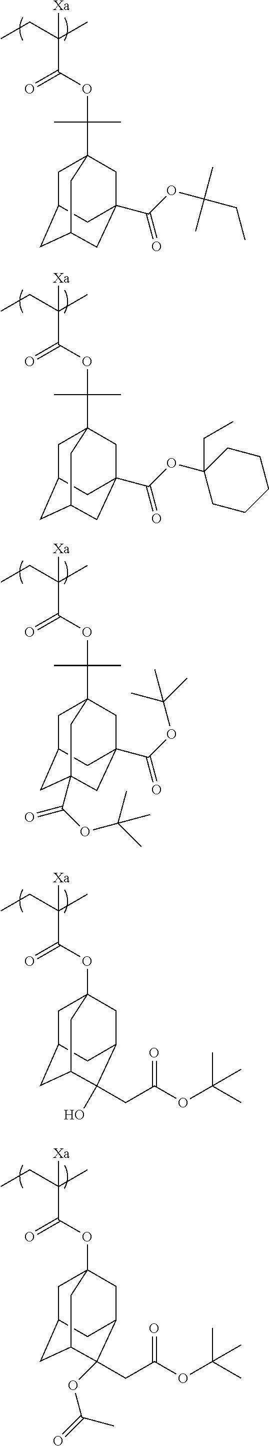

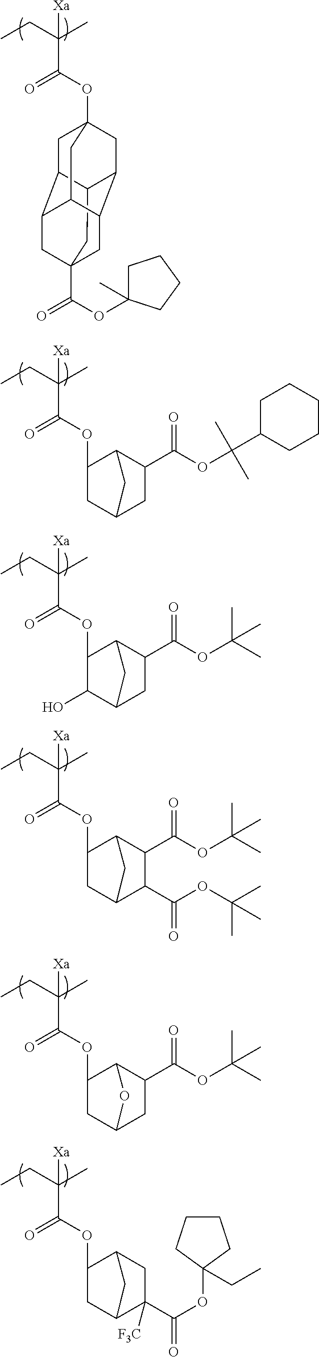

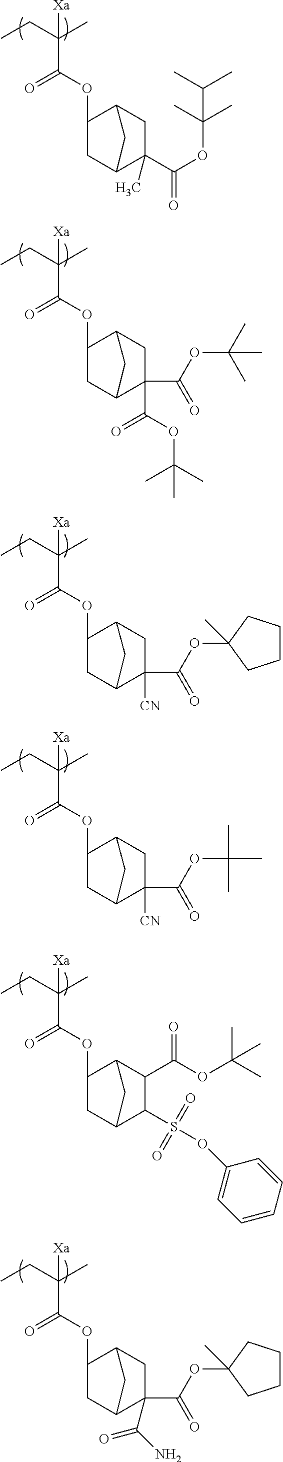

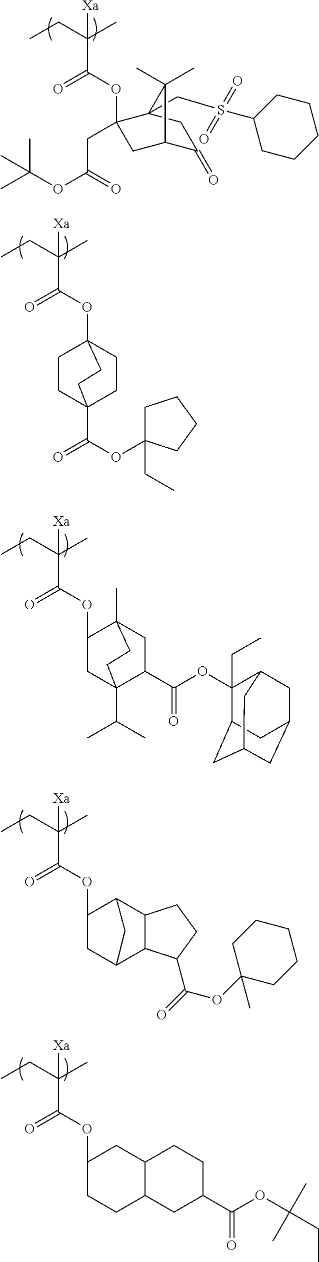

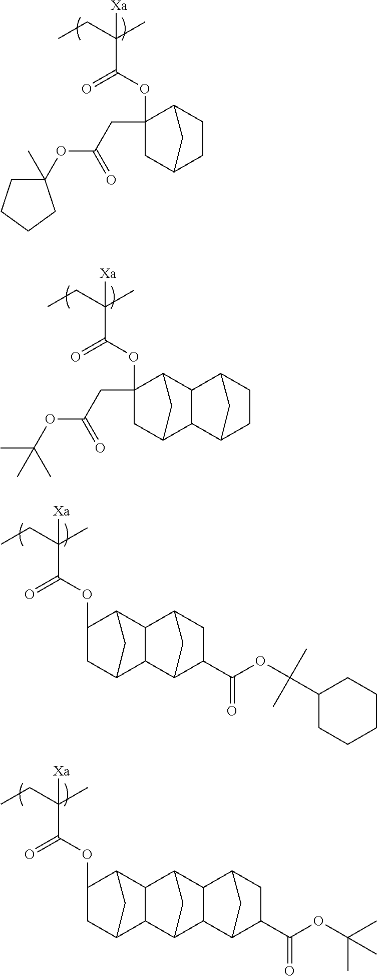

The resin (P) may have a repeating unit represented by the following general formula (AI) as the repeating unit (a1).

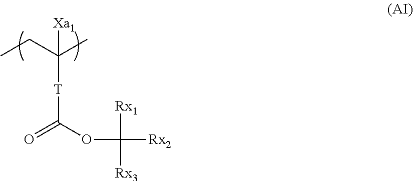

In the general formula (AI),
Xa₁ represents a hydrogen atom, a methyl group which may have a substituent, or a group represented by —CH₂—R₉, R₉ represents a hydrogen atom or a monovalent organic group. Examples of the monovalent organic group include an alkyl group having 5 or less carbon atoms and an acyl group having 5 or less carbon atoms, an alkyl group having 3 or less carbon atoms is preferable, and a methyl group is more preferable. Xa₁ preferably represents a hydrogen atom, a methyl group, a trifluoromethyl group, or a hydroxymethyl group,
T represents a single bond or a divalent linking group having no “polycyclic hydrocarbon structure which may have a hetero atom as a ring member”,
each of Rx₁ to Rx₃ independently represents a (linear or branched) alkyl group or a (monocyclic or polycyclic) cycloalkyl group,
two out of Rx₁ to Rx₃ may be bonded to form a cycloakyl group (either monocyclic or polycyclic), and
here, a case where T represents a single bond and a case where all of Rx₁ to Rx₃ represent an alkyl group and two out of Rx₁ to Rx₃ are not bonded are excluded.

Examples of the divalent linking group of T include an alkylene group, a —COO—Rt-group, a —O—Rt-group, a phenylene group and the like. In the formula, Rt represents an alkylene group or a cycloalkylene group.

T is preferably a single bond or a —COO—Rt-group. Rt is preferably an alkylene group having 1 to 5 carbon atoms, and more preferably a group, a —(CH₂)₂— group, or a —CH₂)₃— group.

The alkyl group of Rx₁ to Rx₃ is preferably a methyl group, an ethyl group, an n-propyl group, an isopropyl group, an n-butyl group, an isobutyl group, or a t-butyl group which has 1 to 4 carbon atoms.

The cycloalkyl group of Rx₁ to Rx₃ is preferably a monocyclic cycloalkyl group such as a cyclopentyl group or a cyclohexyl group, or a polycyclic cycloalkyl group such as a norbornyl group, a tetracyclodecanyl group, a tetracyclododecanyl group or an adamantyl group.

The cycloalkyl group that two out of Rx₁ to Rx₃ form by bonding to each other is preferably a monocyclic cycloalkyl group such as a cyclopentyl group and a cyclohexyl group, or a polycyclic cycloalkyl group such as a norbornyl group, a tetracyclodecanyl group, a tetracyclododecanyl group and an adamantyl group. A monocyclic cycloalkyl group having 5 to 6 carbon atoms is particularly preferable.

As a preferable embodiment, Rx₁ is a methyl group or an ethyl group, and Rx₂ and Rx₃ form the above-described cycloalkyl group by bonding to each other.

The respective groups described above may have a substituent, and examples of the substituent include an alkyl group (having 1 to 4 carbon atoms), a cycloalkyl group (having 3 to 8 carbon atoms), a halogen atom, an alkoxy group (having 1 to 4 carbon atoms), a carboxyl group, an alkoxycarbonyl group (having 2 to 6 carbon atoms), and the like. The substituent preferably has 8 or less carbon atoms. Among these, from the viewpoint of further improving the dissolution contrast with respect to a developer containing an organic solvent before and after acid decomposition, the substituent is preferably a substituent that does not have a hetero atom such as an oxygen atom, a nitrogen atom, or a sulfur atom (for example, the substituent is preferably not an alkyl group substituted with a hydroxyl group or the like), more preferably a group that includes only hydrogen atoms and carbon atoms, and particularly preferably a linear or branched alkyl group or cycloalkyl group.

Specific preferable examples of the repeating unit represented by the above general formula (AI) are shown below, but the present invention is not limited thereto.

In the specific examples, Rx and Xa₁ represent a hydrogen atom, CH₃, CF₃, or CH₂OH. Each of Rxa and Rxb represents an alkyl group having 1 to 4 carbon atoms. Z represents a substituent, and when there is a plurality of Z, the plural Z may be the same as or different from each other. p represents 0 or a positive integer. Specific and preferable examples of Z are the same as the specific and preferable examples of the substituent which each of Rx₁ to Rx₃ and the like may have.

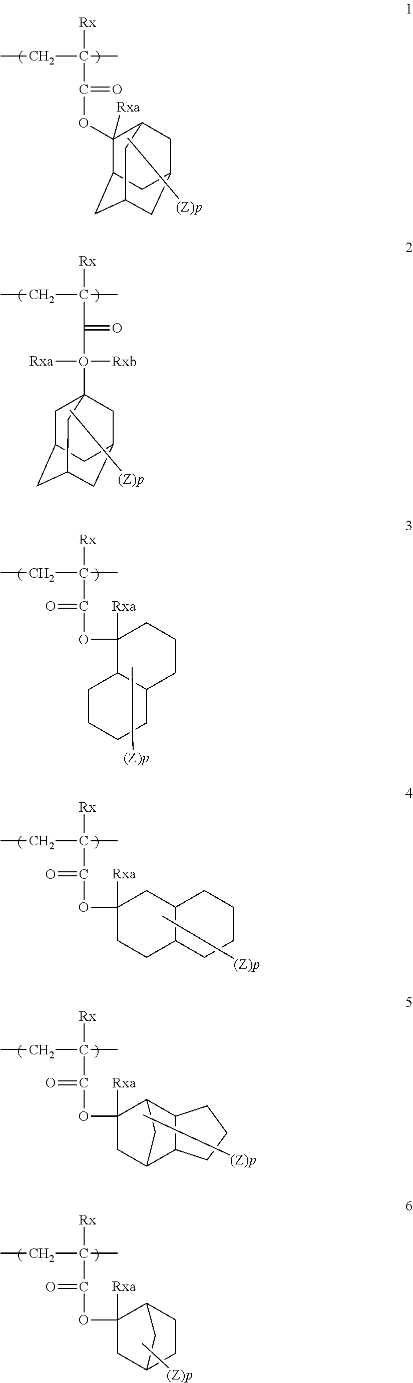

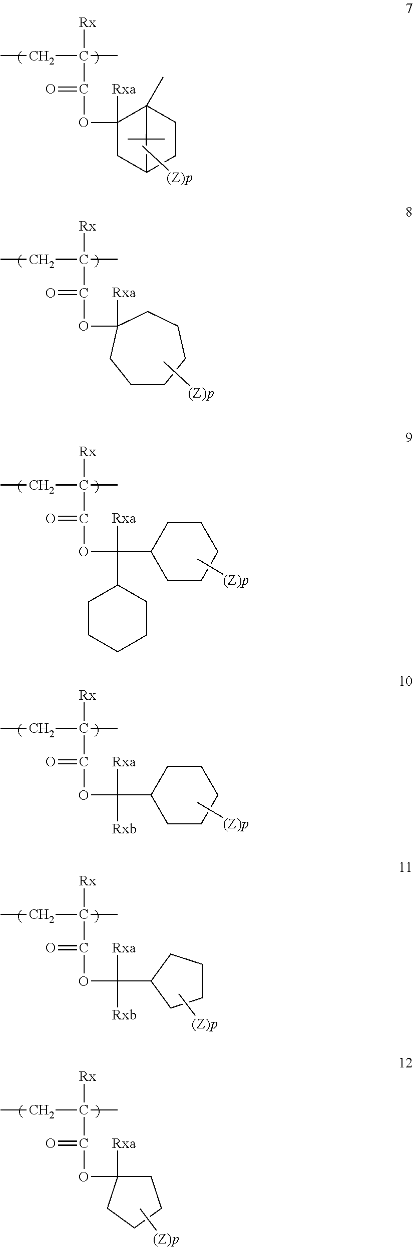

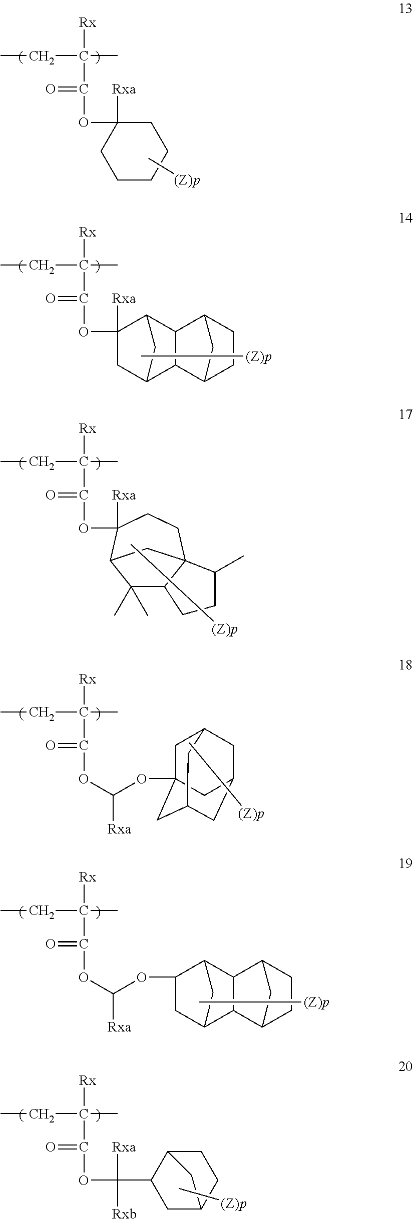

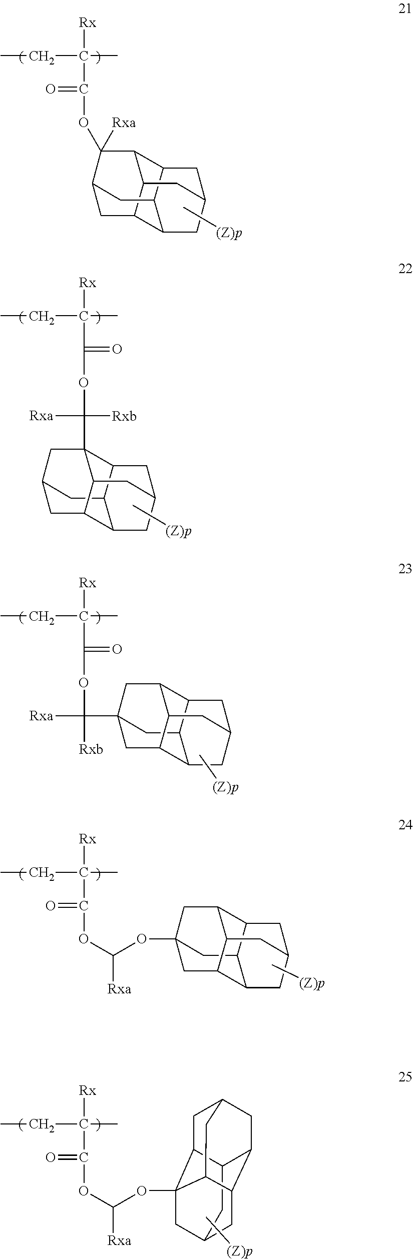

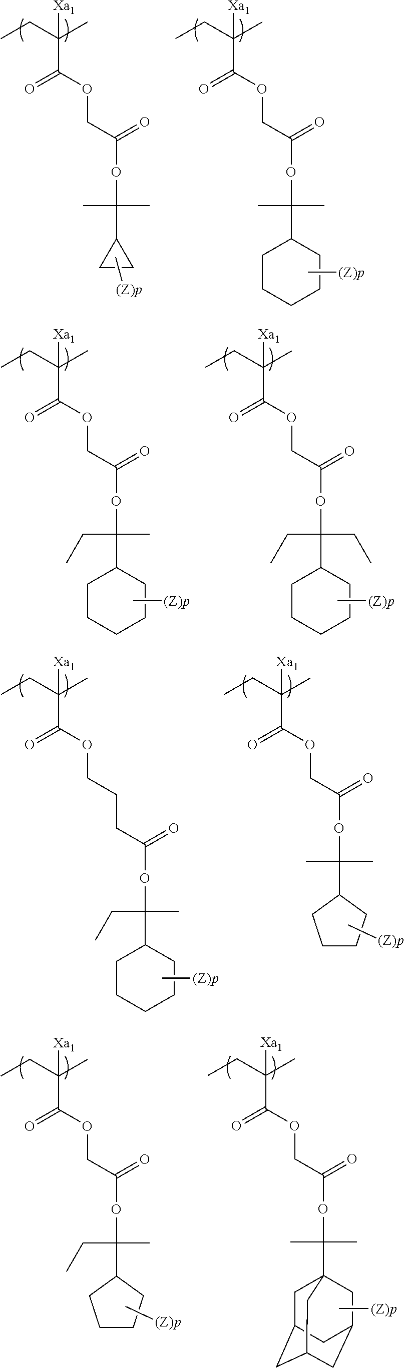

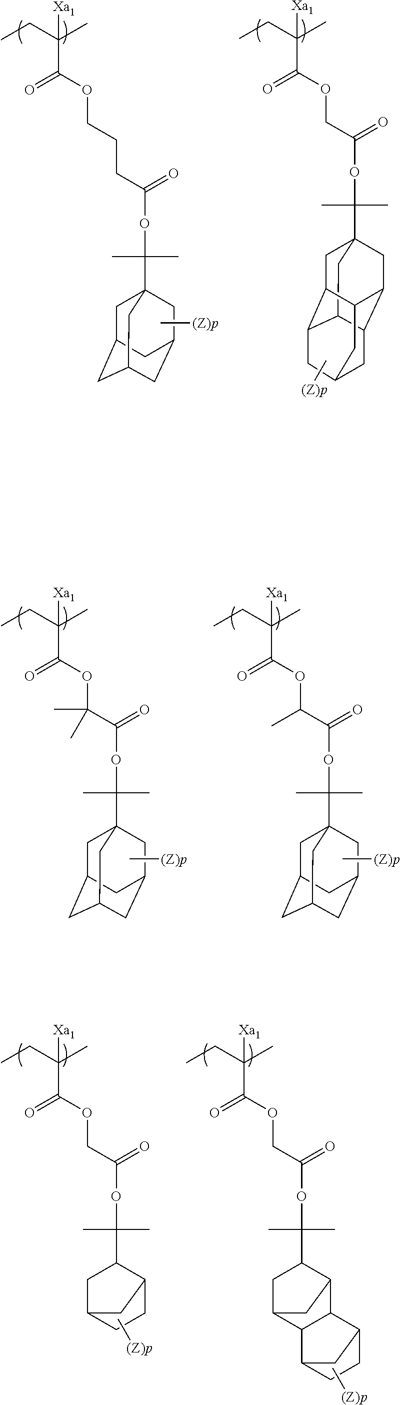

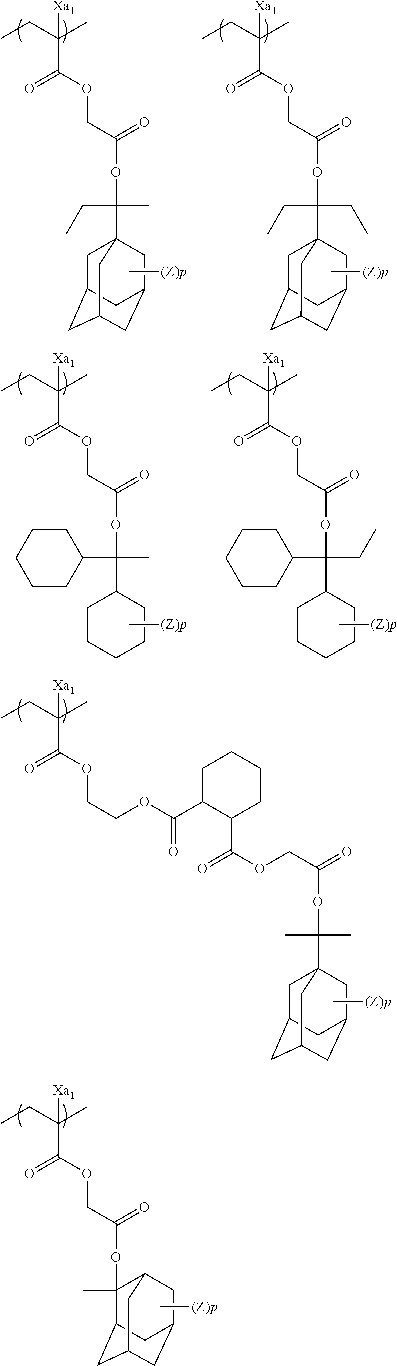

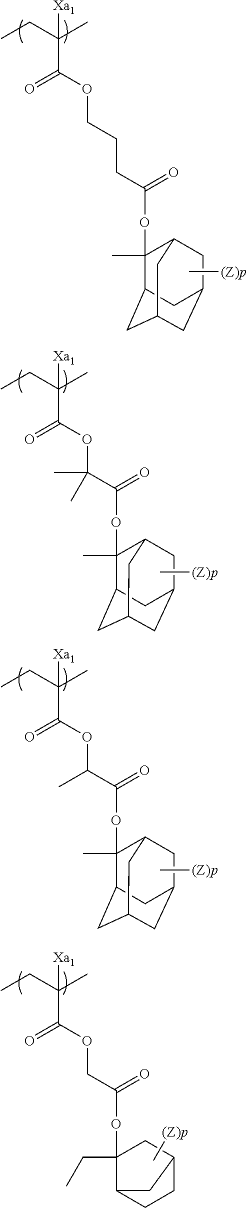

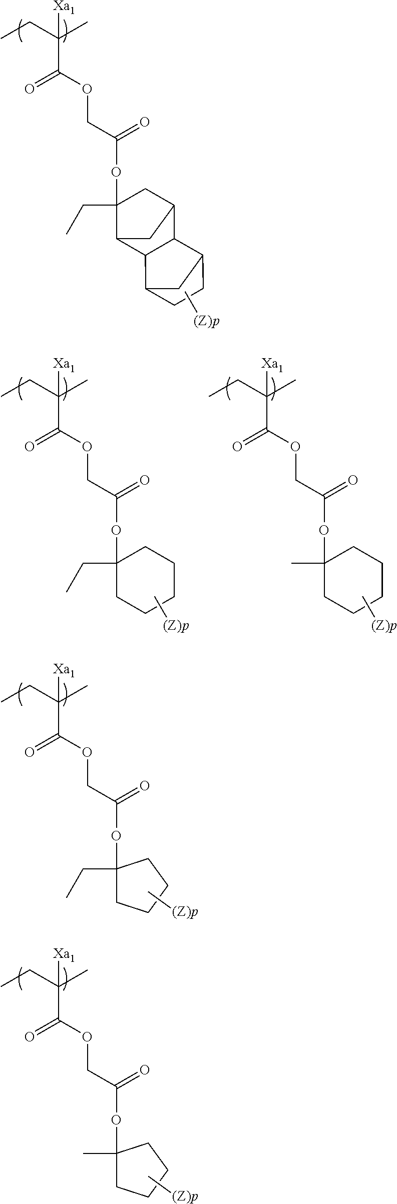

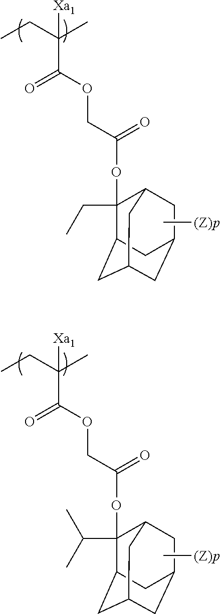

The resin (P) may have a repeating unit represented by the followings, which are acid-decomposable and generate an alcoholic hydroxyl group, as a repeating unit having a group which is acid-decomposable and generates a polar group.

In the following specific examples, Xa₁ represents a hydrogen atom, CH₃, CF₃, or CH₂OH.

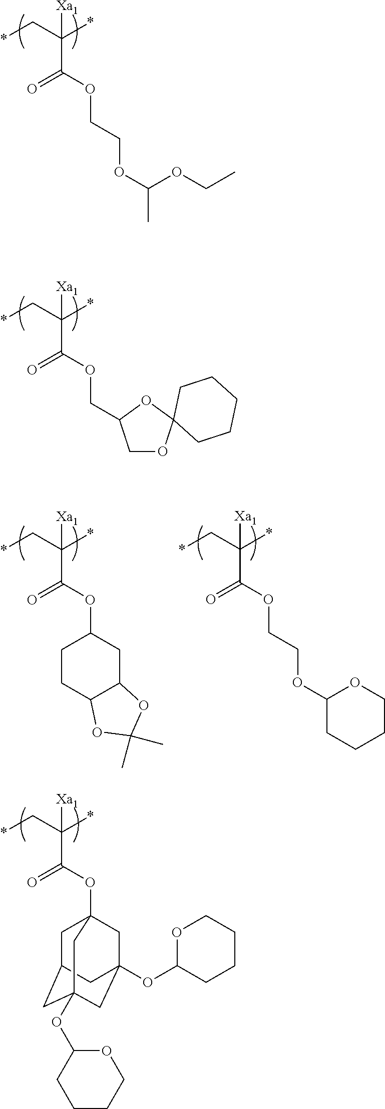

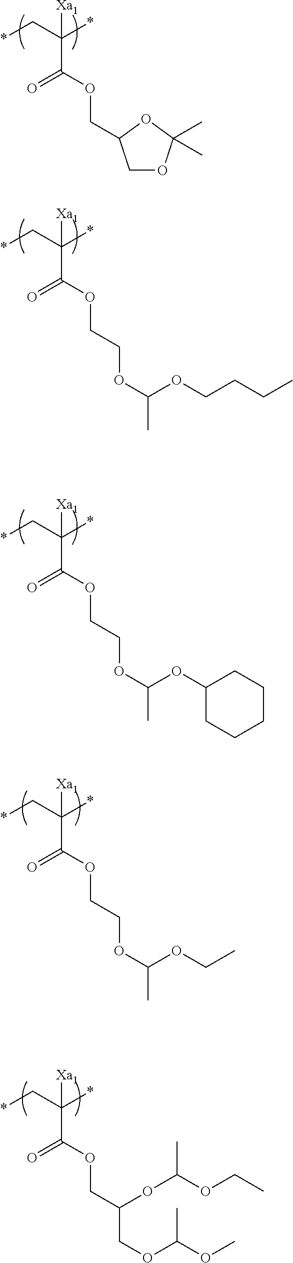

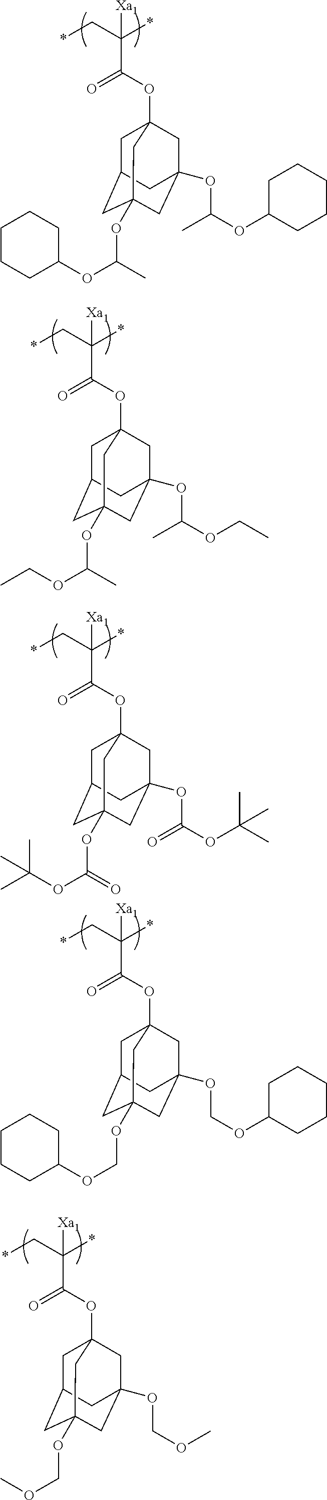

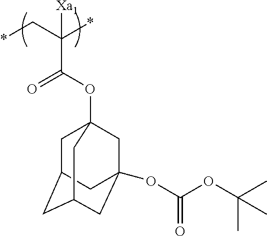

The repeating unit having an acid-decomposable group may be used alone, or 2 or more kinds thereof may be used concurrently. In a case where 2 or more kinds of repeating units having an acid-decomposable group are used concurrently, the resin (P) may have both a repeating unit represented by the above general formula (III) and a repeating unit represented by the above general formula (IV).

A content of the repeating unit (a1) which decomposes by an acid and generates a carboxyl group in the resin (P) is preferably 50 mol % or more, more preferably 50 mol % or more and 70 mol % or less, and more preferably 50 mol % or more and 65 mol % or less based on all the repeating units in the resin (P).

A total content of the repeating unit having an acid-decomposable group(s) included in the resin (P) (for example, a total of the repeating unit (a1) and “a repeating unit having the acid-decomposable group other than the repeating unit (a1)” in a form where the resin (P) has the repeating unit (a1)) is preferably 20 mol % or more and 100 mol % or less, more preferably 40 mol % or more and 80 mol % or less, and particularly preferably 50 mol % or more and 65 mol % or less based on all the repeating units in the resin.

The resin (P) may contain a repeating unit having a lactone structure.

The lactone structure is not particularly limited but is preferably a lactone structure having a 5 to 7 membered ring lactone structure and may be a lactone structure with another ring structure which is condensed forming a bicyclo structure or a spiro structure with the 5 to 7 membered lactone structure. It is more preferable that the resin (P) has a repeating unit having a lactone structure represented by any of the following general formula (LC1-1) to (LC1-17). The lactone structure may directly connect to the main chain of the resin (P). The preferable lactone structures are (LC1-1), (LC1-4), (LC1-5), (LC1-6), (LC1-13), (LC1-14) and (LC1-17) and a particularly preferable lactone structure is (LC1-4). By using such specific lactone structure, LER and development inefficiency are improved.

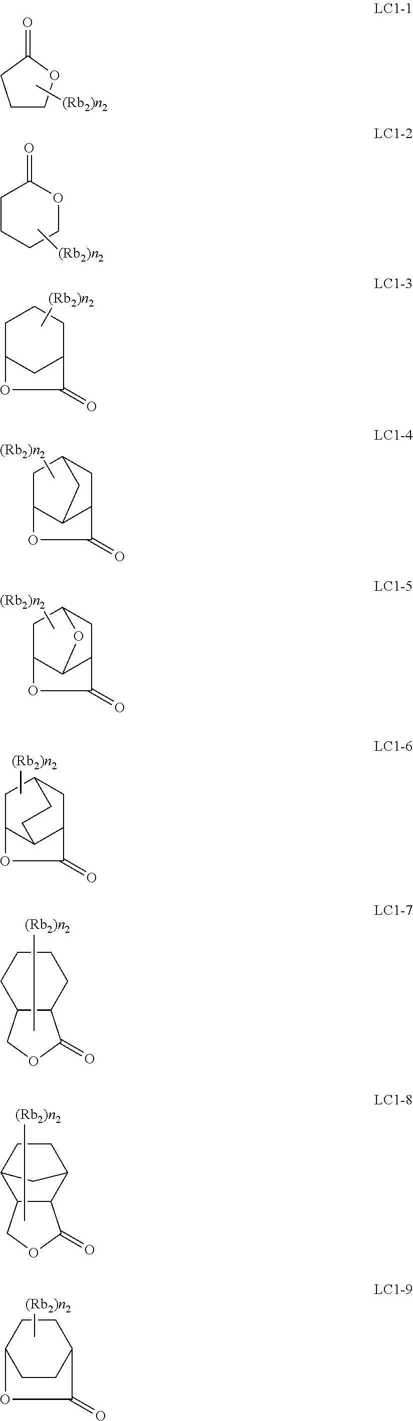

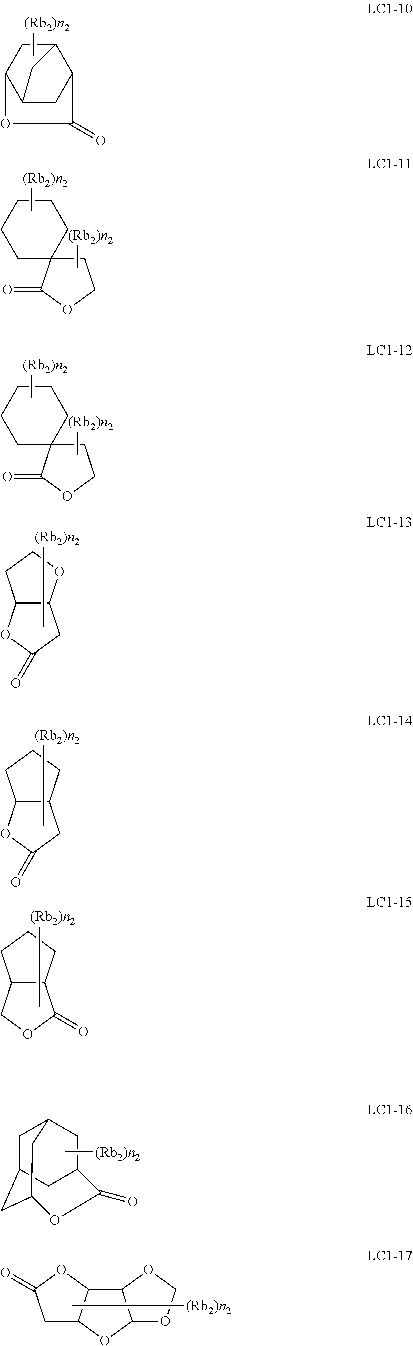

The lactone structure moiety may or may not have a substituent (Rb₂). Preferred examples of the substituent (Rb₂) include an alkyl group having 1 to 8 carbon atoms, a cycloalkyl group having 4 to 7 carbon atoms, an alkoxy group having 1 to 8 carbon atoms, an alkoxycarbonyl group having 2 to 8 carbon atoms, a carboxyl group, a halogen atom, a hydroxyl group, a cyano group, an acid-decomposable group and the like. More preferred examples are an alkyl group having 1 to 4 carbon atoms, a cyano group and an acid-decomposable group. n₂ represents an integer of 0 to 4. When n₂ represents 2 or more, the plurality of the substituents (Rb₂) may be the same as or different from each other. The plurality of the substituents (Rb₂) may bond to each other to form a ring.

As the repeating unit having a lactone structure there are generally optical isomers, and any of the optical isomer may be used. One kind of optical isomer may be used alone, or a plurality of optical isomers may be used in combination. When one kind of optical isomer is mainly used, the optical purity (ee) thereof is preferably 90% or higher, and more preferably 95% or higher.

A repeating unit having a lactone structure is preferably a repeating unit represented by the following general formula (III).

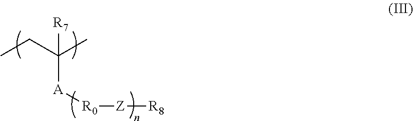

In the above general formula (III),
A represents an ester bond (a group represented by —COO—) or an amide bond (a group represented by —CONH—),
when a plurality of R₀ are present, each R₀ independently represents an alkylene group, a cycloalkylene group or a combination thereof,
   when a plurality of Z are present, each Z independently represents a single bond, an ether bond, an ester bond, an amide bond, a urethane bond,
   (a group represented by

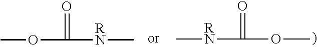

or a urea bond.
(a group represented by

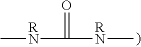

Here, each R independently represents a hydrogen atom, an alkyl group, a cycloalkyl group or an aryl group.

R₈ represents a monovalent organic group having the lactone structure.

n is a repeating number of a structure represented by —R₀—Z— and represents an integer of 0 to 5, preferably 0 or 1 and more preferably 0. When n represents 0, —R₀—Z— is not present and A and R₈ is bonded with a single bond.

R₇ represents a hydrogen atom, a halogen atom or an alkyl group.

The alkylene group or the cycloalkylene group of R₀ may have a substituent.

Z is preferably an ether bond or an ester bond and particularly preferably an ester bond.

The alkyl group of R₇ is preferably an alkyl group having 1 to 4 carbon atoms, more preferably a methyl group or an ethyl group, and particularly preferably a methyl group.

Each of the alkylene group and the cycloalkylene group of R₀ and the alkyl group of R₇ may be independently substituted. Examples of the substituents are a halogen atom such as a fluorine atom, a chlorine atom, a bromine atom and the like; a mercapto group, a hydroxyl group; an alkoxy group such as methoxy group, an ethoxy group, an isopropoxy group, a t-butoxy group, a benzyloxy group and the like; an acyloxy group such as an acetyloxy group, a propionyloxy group and the like.

R₇ is preferably a hydrogen atom, a methyl group, trifluoromethyl group or a hydroxymethyl group.

A chain alkylene group in R₀ is preferably a chain alkylene group having 1 to 10 carbon atoms and more preferably 1 to 5 carbon atoms. Examples thereof are a methylene group, an ethylene group, a propylene group and the like. A cycloalkylene group in R₀ is preferably a cycloalkylene group having 3 to 20 carbon atoms and examples thereof are a cyclohexylene group, a cyclopentylene group, a norbornylene group, an adamantylene group and the like. In order to realize an effect of the present invention, a chain alkylene group is more preferable and a methylene group is particularly preferable.

The monovalent organic group having the lactone structure represented by R₈ is not limited as long as it has a lactone structure. Specific examples thereof includes lactone structures represented by general formulae (LC1-1) to (LC1-17), and among these the structure represented by (LC1-4) is particularly preferable. Also n2 in (LC1-1) to (LC1-17) is more preferably 2 or less.

In addition, R₈ is preferably a monovalent organic group having an unsubstituted lactone structure, or a monovalent organic group having a substituted lactone structure with a methyl group, a cyano group or an alcoxycarbonyl group, and a monovalent organic group having a substituted lactone structure with a cyano group (cyanolactone).

Specific examples of the repeating unit having the lactone structure are shown below, but the present invention is not limited thereto.

In the following specific examples, R represents a hydrogen atom, an alkyl group which may have a substituent or a halogen atom, and preferably a hydrogen atom, a methyl group, a hydroxymethyl group or an acetyloxymethyl group.

(in the following formulae. Rₓ represents H, CH₃, CH₂OH or CF₃)

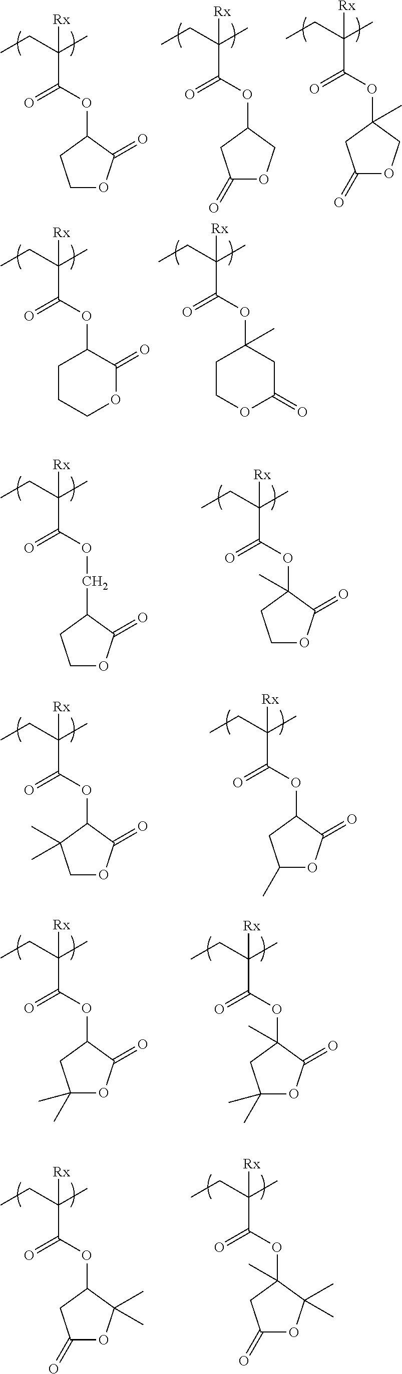

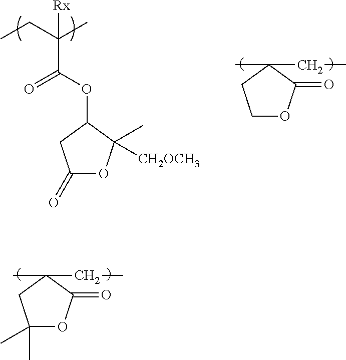

(in the following formulae, Rₓ represents H, CH₃, CH₂OH or CF₃)

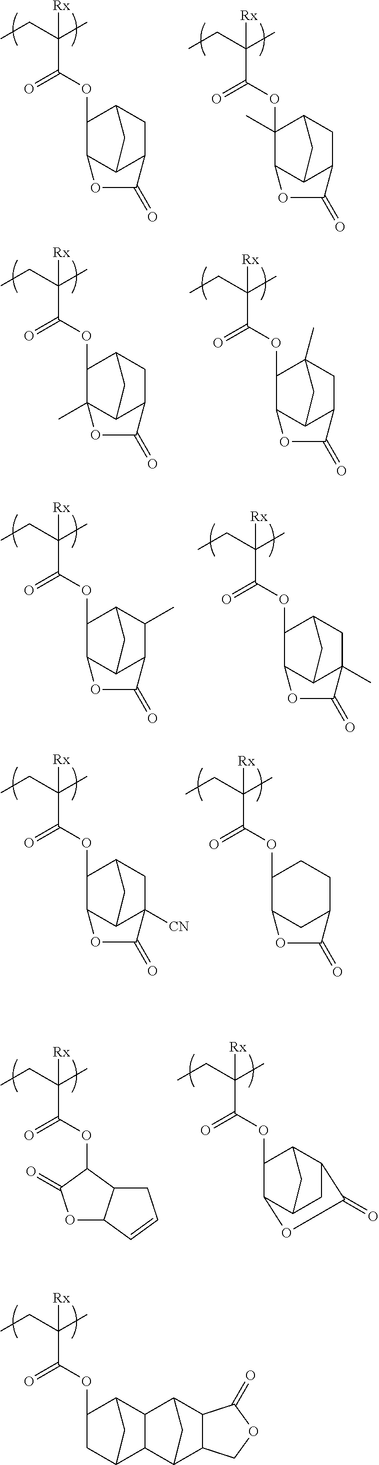

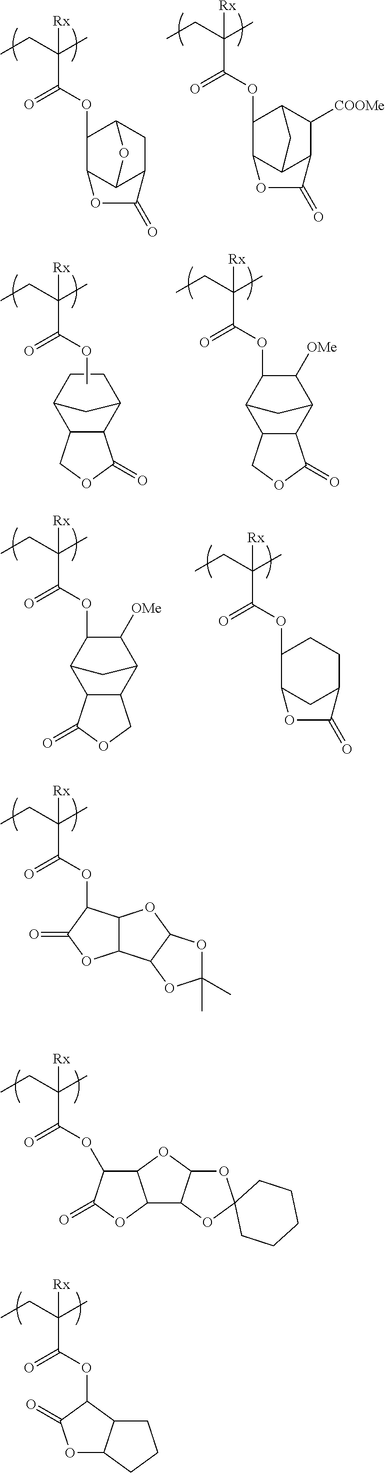

(in the following formulae, Rₓ represents H, CH₃, CH₂OH or CF₃)

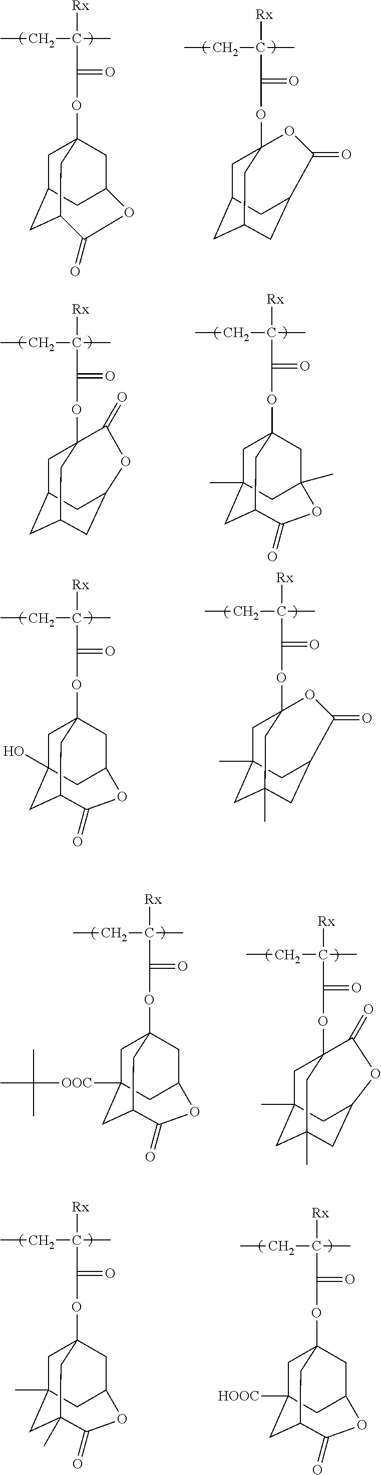

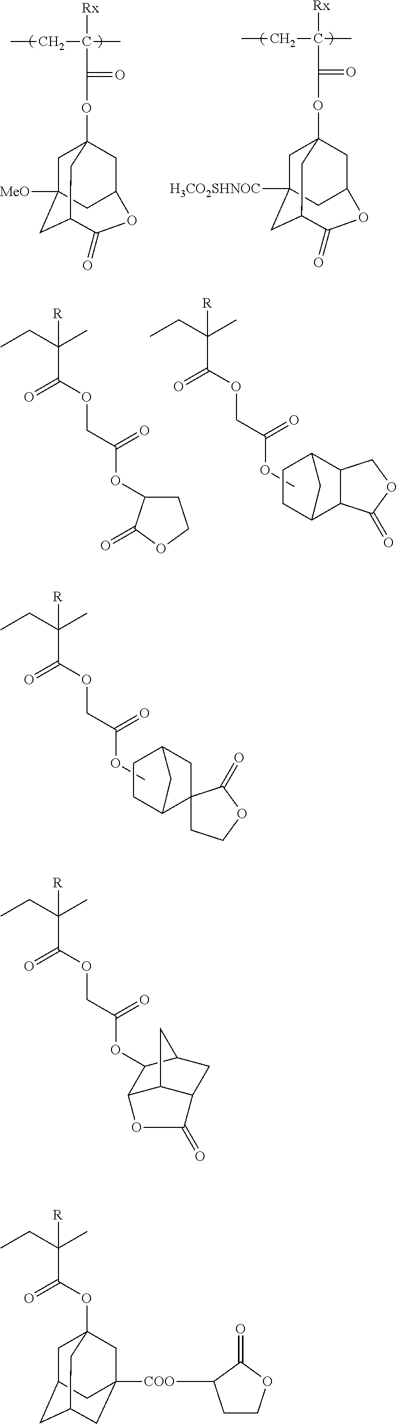

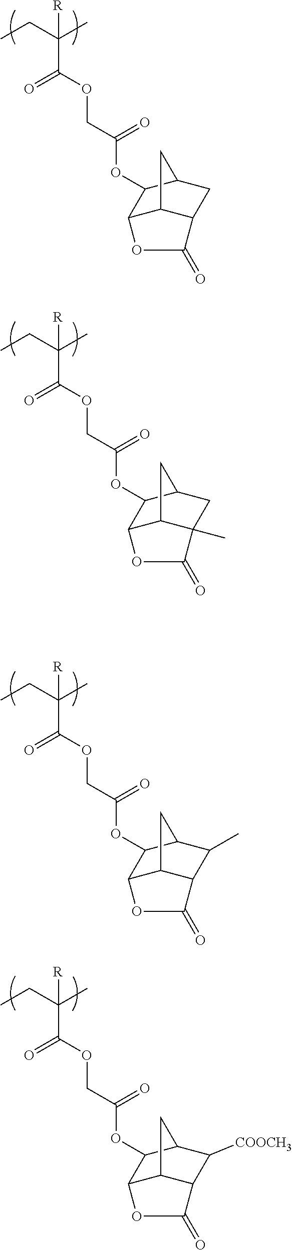

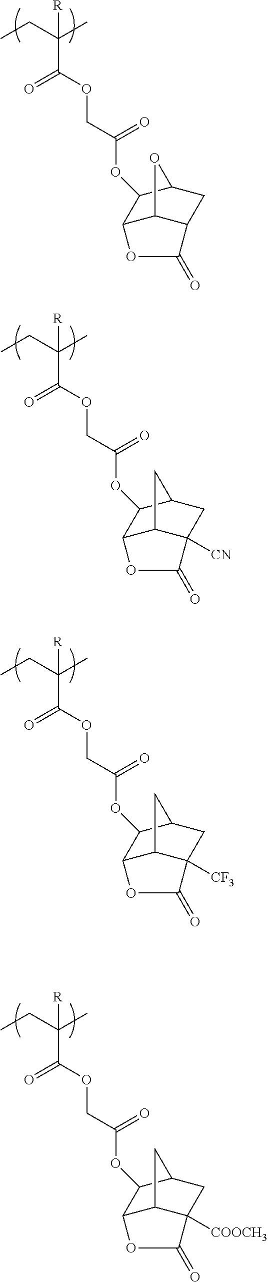

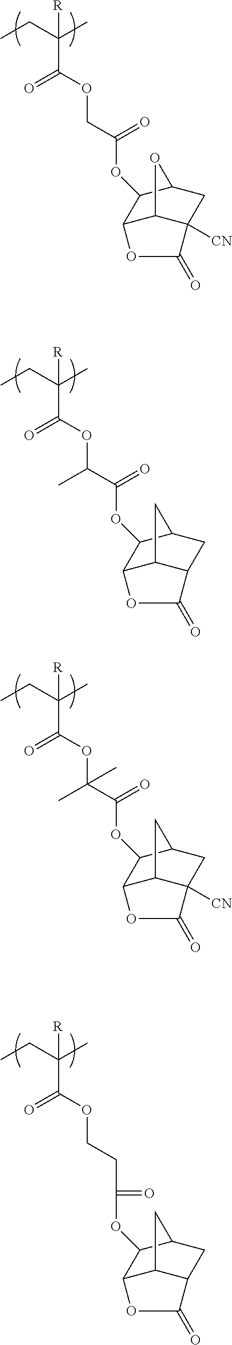

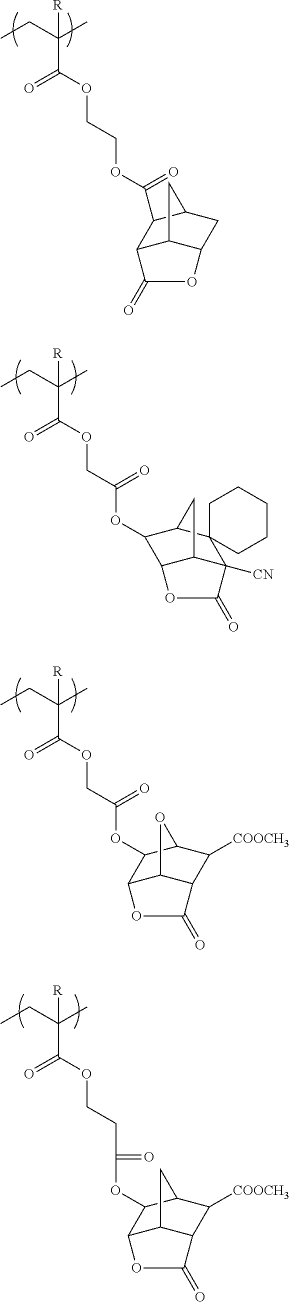

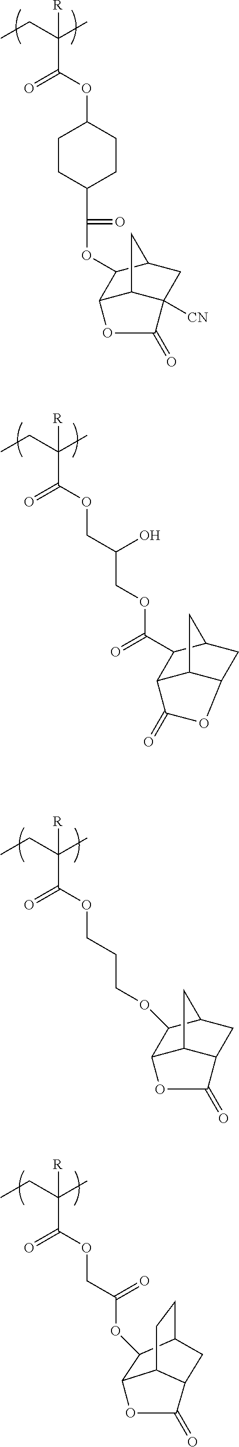

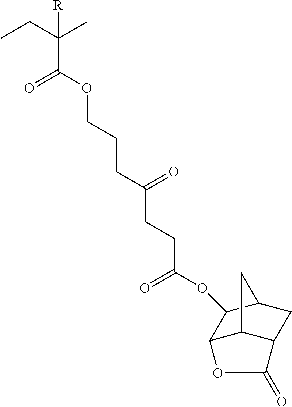

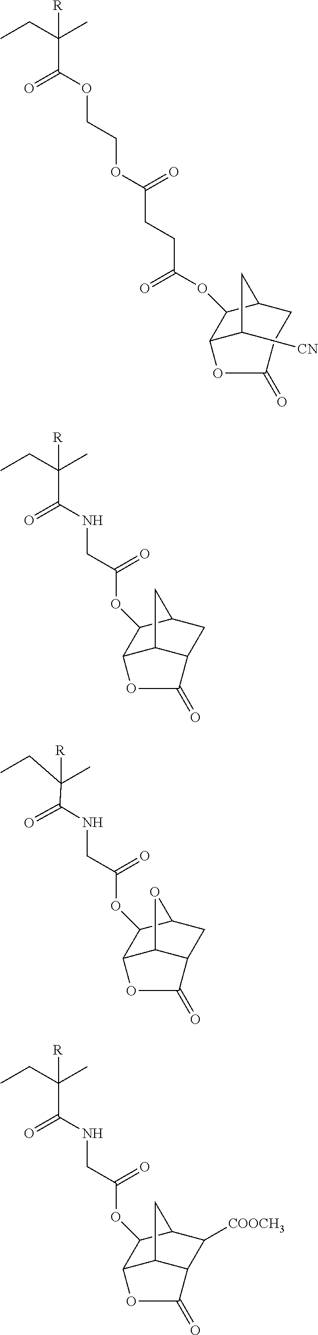

In order to enhance the effect of the present invention, 2 or more kinds of repeating units having the lactone structure may be used concurrently.

When the resin (P) contains a repeating unit having the lactone structure, the content of the repeating unit having a lactone structure is preferably 5 to 60 mol %, more preferably 5 to 55 mol %, and even more preferably 10 to 50 mol %, based on all repeating units in the resin (P).

The resin (P) preferably has a repeating unit having a hydroxy group or a cyano group other than the repeating unit represented by the general formula (III) (the repeating unit having the lactone structure). Due to this, adhesion to a substrate and affinity of a developer are improved. The repeating unit having a hydroxy group or a cyano group is preferably a repeating unit having an alicyclic hydrocarbon structure substituted with a hydroxy group or a cyano group, and preferably does not have an acid-decomposable group. The alicyclic hydrocarbon structure of the alicyclic hydrocarbon structure substituted with a hydroxy group or a cyano group is preferably an adamantyl group, a diadamantyl group or a norbornane group. Preferable examples of the alicyclic hydrocarbon structure substituted with a hydroxy group or a cyano group are the partial structures represented by the following general formulae (VIIa) to (VIId).

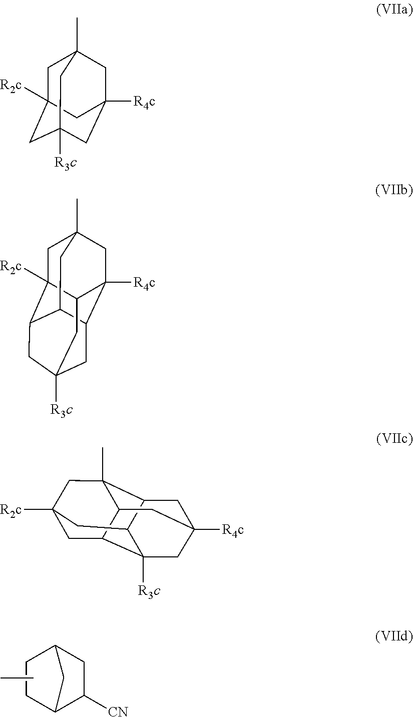

In the general formulae (VIIa) to (VIIc),
each of R₂c to R₄c independently represents a hydrogen atom, a hydroxyl group or a cyano group. Here, at least one of R₂c to R₄c represents a hydroxyl group or a cyano group. Preferably one or two out of R₂c to R₄c are hydroxyl groups and the remainders are hydrogen atoms. In the general formula (VIIa), it is more preferable that two out of R₂c to R₄c be hydroxyl groups, and the remainder be a hydrogen atom.

Examples of the repeating unit having the partial structure represented by the general formulae (VIIa) to (VIId) include repeating units represented by the following general formulae (AIIa) to (AIId).

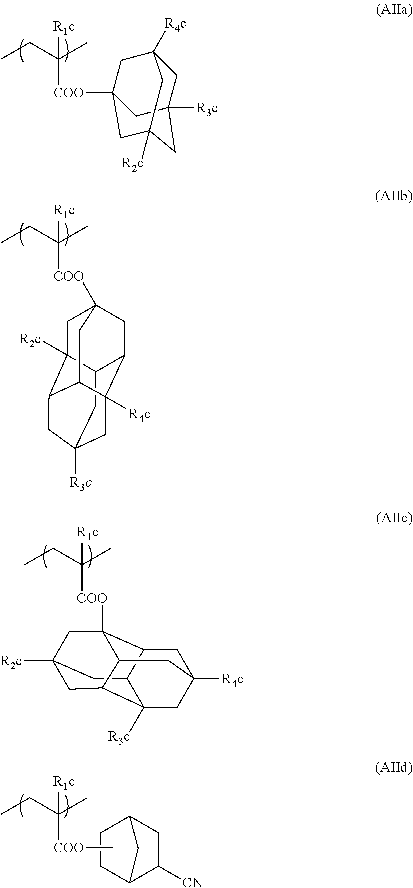

In the general formulae (AIIa) to (AIId),
R₁c represents a hydrogen atom, a methyl group, a trifluoromethyl group or a hydroxymethyl group.
R₂c to R₄c have the same definition as that of R₂c to R₄c in the general formulae (VIIa) to (VIIc).

When the resin (P) contains a repeating unit having a hydroxyl group or a cyano group, the content of the repeating unit having a hydroxyl group or a cyano group is preferably 5 mol % to 40 mol %, more preferably 5 mol % to 30 mol %, and even more preferably 10 mol % to 30 mol %, based on all repeating units in the resin (P).

Specific examples of the repeating unit having a hydroxyl group or a cyano group are shown below, but the present invention is not limited thereto.

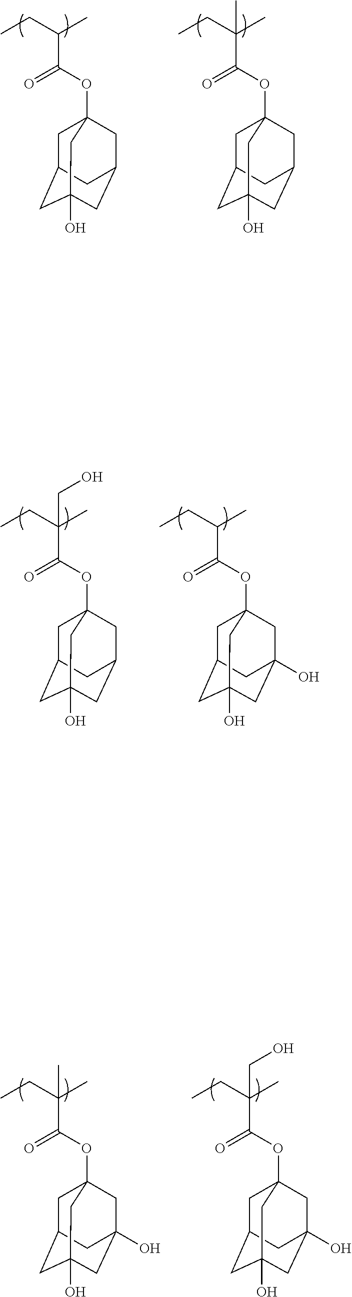

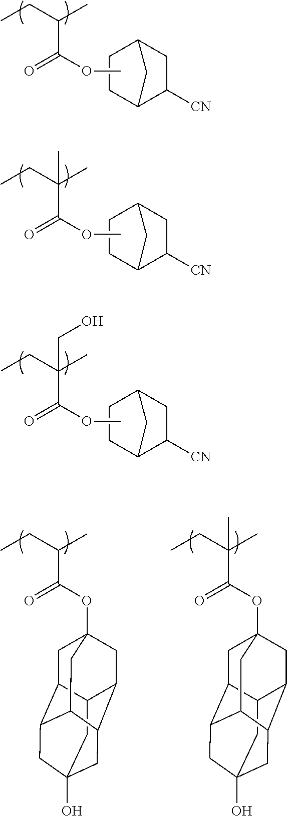

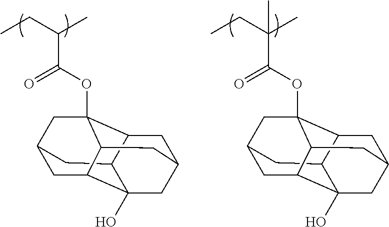

The resin (P) may include a repeating unit having an acid group. Examples of the acid group include a carboxyl group, a sulfonamide group, a sulfonylimide group, a bissulfonylamide group, and an aliphatic alcohol substituted with an electron-attracting group at the α-position (for example, hexafluoroisopropanol group), and a repeating unit having a carboxyl group is preferable. By containing a repeating unit having an acid group, the resolution increases in the usage of forming contact holes. Examples of a repeating unit having the acid group include a repeating unit in which the acid group directly bonds to the main chain of a resin, such as a repeating unit of an acrylic acid or a methacrylic acid, a repeating unit in which the acid group bonds to the main chain of a resin through a linking group, a repeating unit in which an acid group is introduced to a terminal of a polymer chain by using a polymerization initiator or a chain transfer agent having an acid group for polymerization, and any cases are preferable. The linking group may have a monocyclic or polycyclic hydrocarbon structure. In particular, a repeating unit of an acrylic acid or a methacrylic acid is preferred.

The resin (P) may or may not include the repeating unit having the acid group. When the resin (P) includes the repeating unit, the content of the repeating unit having the acid group is preferably 25 mol % or less, and more preferably 20 mol % or less based on all repeating units in the resin (P). In general, when the resin (P) includes the repeating unit having the acid group in the resin (P), the content of the repeating unit is preferably 1 mol % or more.

Specific examples of the repeating unit having the acid group is shown below, but the present invention is not limited thereto.

In the formulae, Rx represents H, CH₃, CH₂OH, or CF₃.

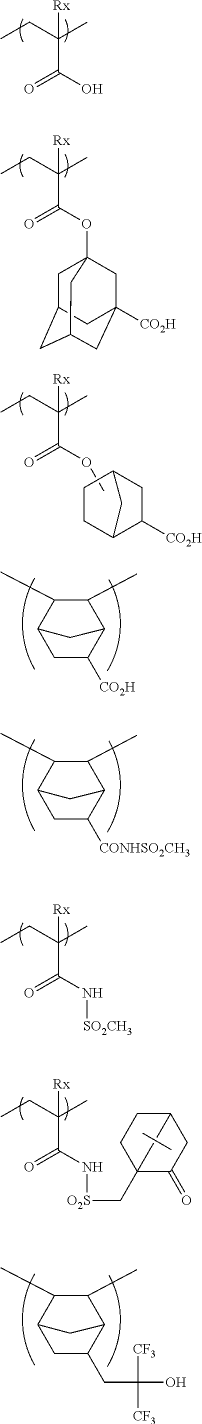

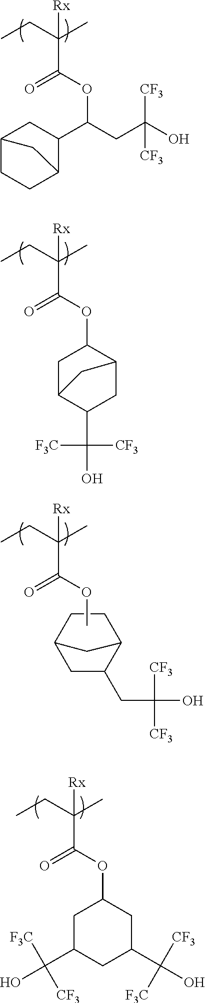

The resin (P) of the present invention may further have an alicyclic hydrocarbon structure that does not include a polar group (for example, the acid group, a hydroxyl group or a cyano group) and a repeating unit that does not exhibit acid-decomposability. Due to this, the elution of components having a low molecular weight to a liquid for liquid immersion from the resist film may be reduced during liquid immersion exposure, and the solubility of the resin may be appropriately adjusted during development performed using a developer containing an organic solvent. Examples of such a repeating unit include a repeating unit represented by the general formula (IV).

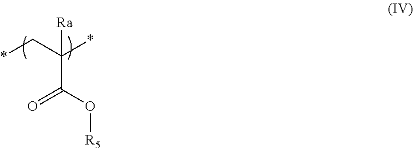

In the general formula (IV), R₅ represents a hydrocarbon group which has at least one cyclic structure and does not include a polar group.

Ra represents a hydrogen atom, an alkyl group or a —CH₂—O—Ra₂ group. In the formula, Ra₂ represents a hydrogen atom, an alkyl group, or an acyl group. Ra is preferably a hydrogen atom, a methyl group, a hydroxymethyl group or a trifluoromethyl group, and particularly preferably a hydrogen atom or a methyl group.

The cyclic structure of R₅ includes a monocyclic hydrocarbon group and a polycyclic hydrocarbon group. Examples of the monocyclic hydrocarbon group include cycloalkyl groups having 3 to 12 carbon atoms such as a cyclopentyl group, a cyclohexyl group, a cycloheptyl group and a cyclooctyl group, and a cycloalkenyl group having 3 to 12 carbon atoms such as a cyclohexenyl group. Examples of the preferable monocyclic hydrocarbon group include a monocyclic hydrocarbon group having 3 to 7 carbon atoms, and a cyclopentyl group and a cyclohexyl group are more preferable examples. [0204] The polycyclic hydrocarbon group includes a ring-aggregated hydrocarbon group and a crosslinked cyclic hydrocarbon group. Examples of the ring-aggregated hydrocarbon group include a bicyclohexyl group and a perhydronaphthalenyl group. Examples of the crosslinked cyclic hydrocarbon ring include bicyclic hydrocarbon rings such as a pinane ring, a bornane ring, a norpinane ring, a norbornane ring, and a bicyclooctane ring (bicyclo[2.2.2]octane ring, bicyclo[3.2.1]octane ring, and the like); tricyclic hydrocarbon rings such as a homobrendane ring, an adamantane ring, a tricyclo[5.2.1.0^{2,6}]decane ring, and a tricyclo[4.3.1.1^{2,5}]undecane ring; and tetracyclic hydrocarbon rings such as a tetracyclo[4.4.0.1^{2,5}.1^{7,10}]dodecane ring and a perhydro-1,4-methano-5,8-methanonaphthalene ring. The crosslinked cyclic hydrocarbon ring also includes a condensed cyclic hydrocarbon ring, for example, a condensed ring in which a plurality of 5 to 8-membered cycloalkane rings such as a perhydronaphthalene ring (decalin), a perhydroanthracene ring, a perhydrophenanthrene ring, a perhydroacenaphthene ring, a perhydrofluorene ring, a perhydroindene ring, and a perhydrophenalene ring are condensed.

Examples of a preferable crosslinked cyclic hydrocarbon ring include a norbornyl group, an adamantyl group, a bicyclooctanyl group, a tricyclo[5,2,1,0^{2,6}]decanyl group, and the like. Examples of the more preferable crosslinked cyclic hydrocarbon ring include a norbornyl group, and an adamantyl group.

These alicyclic hydrocarbon groups may have a substituent and examples of preferable substituents include a halogen atom, an alkyl group, a hydroxyl group in which a hydrogen atom has been substituted, and an amino group in which a hydrogen atom has been substituted. Examples of a preferable halogen atom include a bromine atom, a chlorine atom, and a fluorine atom, and examples of a preferable alkyl group include a methyl group, an ethyl group, a butyl group, and a t-butyl group. This alkyl group may further have a substituent, and examples of this substituent that the alkyl group may further have include a halogen atom, an alkyl group, a hydroxyl group in which a hydrogen atom has been substituted, and an amino group in which a hydrogen atom has been substituted.

Examples of the substituent of the above hydrogen atom include an alkyl group, a cycloalkyl group, an aralkyl group, a substituted methyl group, a substituted ethyl group, an alkoxycarbonyl group, and an aralkyloxycarbonyl group. Examples of a preferable alkyl group include an alkyl group having 1 to 4 carbon atoms; examples of a preferable substituted methyl group include a methoxymethyl group, a methoxythiomethyl group, a benzyloxymethyl group, a t-butoxymethyl group and a 2-methoxyethoxymethyl group; examples of a preferable substituted ethyl group include 1-ethoxyethyl and 1-methyl-1-methoxyethyl; examples of a preferable acyl group include an aliphatic acyl group having 1 to 6 carbon atoms such as a formyl group, an acetyl group, a propionyl group, a butyryl group, an isobutyryl group, a valeryl group and a pivaloyl group; and examples of the alkoxycarbonyl group include an alkoxycarbonyl group having 1 to 4 carbon atoms.

The resin (P) may or may not contain a repeating unit which has an alicyclic hydrocarbon structure not including a polar group and does not exhibit acid-decomposability. When the resin (P) contains such a repeating unit, the content of the repeating unit is preferably 1 mol % to 50 mol %, and more preferably 10 mol % to 50 mol %, based on all repeating units in the resin (P).

Specific examples of the repeating unit which has an alicyclic hydrocarbon structure not including a polar group and does not exhibit acid-decomposability will be shown below, but the present invention is not limited thereto. In the formulae, Ra represents H, CH₃, CH₂OH, or CF₃.

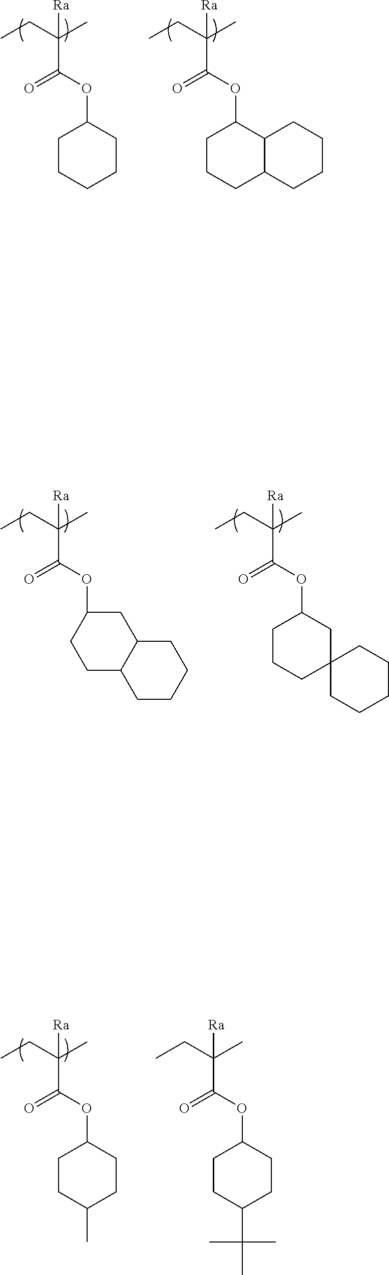

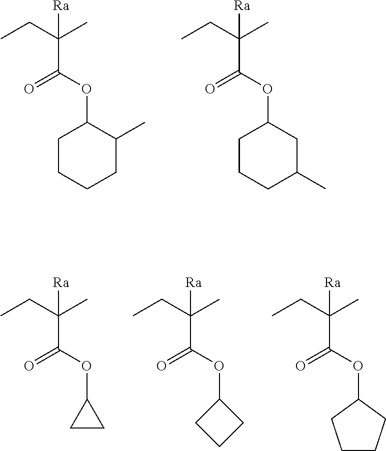

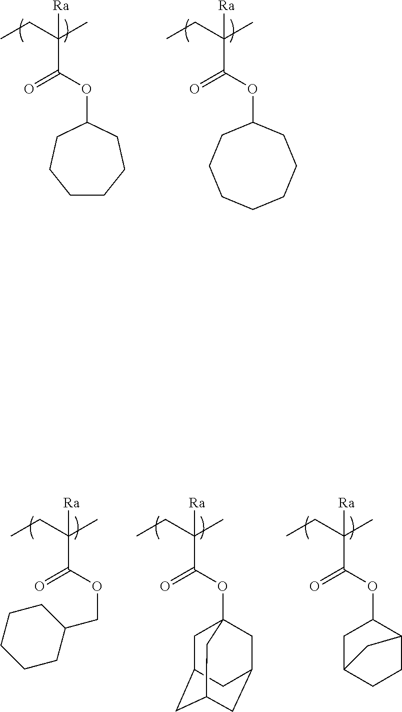

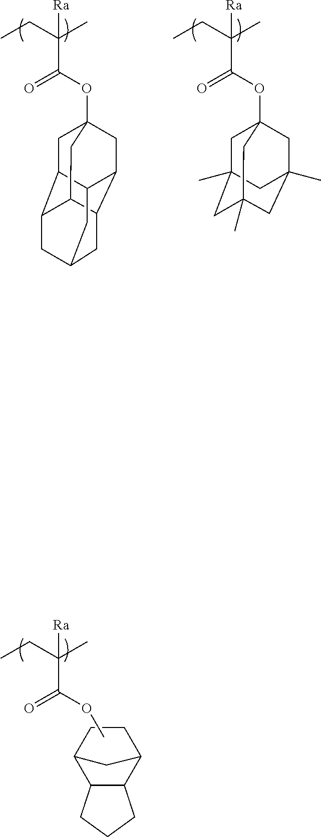

The resin (P) used for the composition of the present invention may contain various repeating structural units in addition to the repeating structural unit described above, for adjusting dry etching resistance, suitability with a standard developer, adhesion to a substrate, resist profile, and properties which are generally required for an actinic ray-sensitive or radiation-sensitive resin composition, such as resolving power, heat resistance, sensitivity and the like.

Examples of such repeating structural units include repeating structural units corresponding to the monomers described below, but the present invention is not limited thereto.

Due to this, performances required for the resin used for the composition according to the present invention, particularly,
(1) solubility in a coating solvent,
(2) film formability (glass transition point),
(3) alkali developability,
(4) film thinning (selection of a hydrophilic or hydrophobic group and an alkali-soluble group),
(5) adhesion of an unexposed portion to a substrate,
(6) dry etching resistance,
and the like can be finely adjusted.

Examples of such monomers include compounds having one addition-polymerizable unsaturated bond selected from acrylic acid esters, methacrylic acid esters, acrylamides, methacrylamides, allyl compounds, vinyl ethers, vinyl esters, and the like.

In addition, other addition-polymerizable unsaturated compounds may be copolymerized so long as these compounds are copolymerizable with the monomers corresponding to the various repeating structural units described above.

The molar ratio of the respective repeating structural units contained in the resin (P) used for the composition of the present invention is appropriately set so as to adjust the dry etching resistance, and the suitability with a standard developer of the actinic ray-sensitive or radiation-sensitive resin composition, adhesion to a substrate, resist profile and properties that are generally required for an actinic ray-sensitive or radiation-sensitive resin composition, such as resolving power, heat resistance, sensitivity and the like.

When the composition of the present invention is for ArF exposure, it is preferable that the resin (P) used for the composition of the present invention substantially do not contain an aromatic ring (specifically, the proportion of the repeating unit having an aromatic group in the resin is preferably 5 mol % or less, more preferably 3 mol % or less, and ideally 0 mol %, that is, it is desirable that the resin do not contain an aromatic group) in respect of transparency to ArF light. It is preferable that the resin (P) have a monocyclic or polycyclic alicyclic hydrocarbon structure.

When the composition of the present invention includes a resin (E) described later, it is desirable that the resin (P) do not include a fluorine atoms or a silicon atoms from a viewpoint of the compatibility between the resin (P) and the resin (E).

As the resin (P) used for the composition of the present invention, a resin in which all repeating units are constituted with a (meth)acrylate-based repeating unit is preferable. In this case, any of a resin in which all repeating units are methacrylate-based repeating units, a resin in which all repeating units are acrylate-based repeating units, and a resin in which all repeating units are methacrylate-based repeating units and acrylate-based repeating units may be used, but the content of the acrylate-based repeating units is preferably 50 mol % or less based on all repeating units.

When the composition of the present invention is irradiated with KrF excimer laser light, an electron beam, X-rays, or high energy light rays (EUV and the like) having a wavelength of 50 nm or less, the resin (P) preferably further contains a hydroxystyrene-based repeating unit. More preferably, the resin (P) contains the hydroxystyrene-based repeating unit, a hydroxystyrene-based repeating unit protected with an acid-decomposable group and an acid-decomposable repeating unit such as (meth)acrylic acid tertiary alkyl ester.

Examples of a preferable hydroxystyrene-based repeating unit having an acid-decomposable group include a repeating unit of t-butoxycarbonyloxystyrene, 1-alkoxyethoxystyrene, (meth)acrylic acid tertiary alkyl ester and the like, and a repeating unit of 2-alkyl-2-adamantyl(meth)acrylate or dialkyl (1-adamantyl)methyl(meth)acrylate is more preferable.

The resin (P) of the present invention can be synthesized by a common method (for example, radical polymerization). Examples of the general synthesis method include batch polymerization in which polymerization is performed by dissolving monomer materials and initiators in a solvent and heating the mixture; dropping polymerization in which a solution including monomer materials and initiators is added dropwise to a heated solvent for 1 to 10 hours; and the like. A preferable method is the drop polymerization. Examples of a reaction solvent include tetrahydrofuran, 1,4-dioxane, ethers such as diisopropyl ether, ketones such as methyl ethyl ketone and methyl isobutyl ketone, ester solvents such as ethyl acetate, amide solvents such as dimethylformamide and dimethylacetamide, and solvents dissolving the composition of the present invention, such as propylene glycol monomethyl ether acetate, propylene glycol monomethyl ether and cyclohexanone described later. It is preferable to perform the polymerization with the use of the same solvent as employed in the composition of the present invention. This may inhibit generation of particles during storage.

It is preferable to perform the polymerization reaction in an atmosphere of inert gas such as nitrogen or argon. As the polymerization initiator, a commercially available radical initiator (azo-based initiator, peroxide, or the like) is used to initiate the polymerization. As the radical initiator, an azo-based initiator is preferable, and an azo-based initiator having an ester group, a cyano group, or a carboxyl group is preferable. Examples of preferable initiators include azobisisobutyronitrile, azobisdimethylvaleronitrile and dimethyl 2,2′-azobis(2-methylpropionate). The initiator is added as desired or added in divided portions, and then introduced to a solvent after the reaction ends, thereby allowing collection of desired polymers by methods of collecting powder or solids. The concentration during the reaction is in the range of 5 to 50 mass %, preferably 10 to 30 mass %. The reaction temperature is generally in a range of 10° C. to 150° C., preferably 30° C. to 120° C., and more preferably 60° C. to 100° C.

After the reaction ends, the temperature is cooled to room temperature, and purification is performed. For the purification, general methods such as liquid-liquid extraction in which residual monomer or oligomer components are removed by washing with water or by appropriately combined solvents; a purification method implemented in a solution state, such as ultrafiltration in which only components having a certain level of molecular weight or less are removed by extraction; reprecipitation in which residual monomers or the like are removed by clotting a resin in a poor solvent by means of adding the resin solution dropwise to the poor solvent; and a purification method implemented in a solid state in which a filtered resin slurry is washed with a poor solvent may be used. For example, by bringing the resin into contact with a solvent (poor solvent) which poorly dissolves or does not dissolve the resin, in such an amount that the volume of the resin is 10 times or less, and preferably 10 to 5 times the reaction solution, the resin is precipitated as a solid.

As a solvent used for performing precipitation or reprecipitation from a polymer solution (solvent for precipitation or reprecipitation), any solvent may be used as long as the solvent is a poor solvent of the polymer. The solvent to be used may be appropriately selected from hydrocarbon, halogenated hydrocarbon, a nitro compound, ether, ketone; ester, carbonate, alcohols, carboxylic acid, water and a mixed solvent containing these solvents depending on the type of the polymer. Among these, as a solvent for precipitation or reprecipitation, a solvent containing at least an alcohol (particularly, methanol and the like) or water is preferable.

The amount of the solvent for precipitation or reprecipitation to be used can be appropriately selected in consideration of efficiency, yield and the like, but generally the amount is 100 to 10000 parts by mass, preferably 200 to 2000 parts by mass, and more preferably 300 to 1000 parts by mass, based on 100 parts by mass of a polymer solution.

The temperature in the precipitation or reprecipitation may be appropriately selected in consideration of efficiency, operability and the like, but the temperature is generally about 0 to 50° C., and preferably around room temperature (for example, about 20 to 35° C.). The precipitation or reprecipitation may be carried out by a well-known method such as a batch method, a continuous method, or the like and using a widely used mixing container such as a stirring tank.

The precipitated or reprecipitated polymer is generally subjected to widely used solid-liquid separation such as filtration, centrifugation, followed by drying, and then used. The filtration is performed preferably under increased pressure by using a solvent-resistant filtering medium. The drying is performed under normal pressure or reduced pressure (preferably reduced pressure) at about 30 to 100° C., and preferably about 30 to 50° C.

In addition, once the resin is precipitated and separated, the resin may be dissolved again in a solvent and brought into contact with a solvent that poorly dissolves or does not dissolve the resin. That is, a method may also be used which includes (process a) precipitating the resin by bringing the polymer into contact with a solvent that poorly dissolves or does not dissolve the polymer after the above-described radical polymerization reaction is completed, (process b) separating the resin from the solution, (process c) preparing a resin solution A by dissolving the resin again in a solvent, (process d) then precipitating a resin solid by bringing the resin solution A into contact with a solvent that poorly dissolves or does not dissolve the resin, in such an amount that the volume of the solvent is less than 10 times (preferably 5 times or less) the resin solution A, and (process e) separating the precipitated resin.

In order to inhibit the resin from aggregating after the composition is prepared, for example, a process of preparing a solution by dissolving the synthesized resin in a solvent and heating the solution at about 30 to 90° C. for about 30 minutes to 4 hours may be added as described in JP2009-037108A.

The weight average molecular weight of the resin (P) of the present invention is preferably 1,000 to 200,000, more preferably 2,000 to 20,000, even more preferably 3,000 to 18,000 and particularly preferably 3,000 to 10,000 in terms of a polystyrene-converted value measured by GPC. If the weight average molecular weight is 1,000 to 200,000, it is possible that deterioration of heat resistance and dry etching resistance is prevented and deterioration of developability and film formability which is caused by the viscosity increase is prevented.

The degree of dispersion (molecular weight distribution, Mw/Mn) is generally in a range of from 1.0 to 3.0, preferably from 1.0 to 2.6, more preferably from 1.0 to 2.0 and particularly preferably from 1.4 to 2.0. The smaller the molecular weight distribution, the better the resolution, resist form, and roughness properties and the smoother the side walls of a resist pattern. In the present specification, the weight average molecular weight (Mw) and the number average molecular weight (Mn) of the resin (P) may be calculated by using, for example, an HLC-8120 (manufactured by Tosoh Corporation) using a TSK gel Multipore HXL-M column (manufactured by Tosoh Corporation, 7.8 mm ID×30.0 cm) as a column and THF (tetrahydrofuran) as an eluent.

In the actinic ray-sensitive or radiation-sensitive resin composition of the present invention, the content of the resin (A) in the entire composition is preferably from 30 to 99 mass %, and more preferably from 60 to 95 mass % based on the total solid content.

The resin (P) may be used alone, or a plurality kinds of the resin (P) may be used concurrently.

[2] Compound (B) which Generates an Acid by Irradiation with Actinic Rays or Radiation

The actinic ray-sensitive or radiation-sensitive resin composition of the present invention includes a compound (B) which generates an acid by irradiation with actinic rays or radiation. The compound (B) is a compound which generates an acid represented by the following formula (I) by irradiation with actinic rays or radiation (hereinafter also referred to as “compound (B)”, “acid-generating agent” and the like).

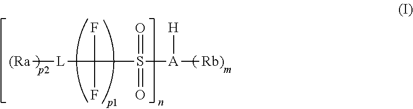

A represents a nitrogen atom or a carbon atom,
each Ra independently represents a hydrogen atom, an alkyl group which does not have a fluorine atom as a substituent, a cycloalkyl group or an aryl group, and Rb represents an electron-attracting group, an alkyl group or an aryl group,
when A is a nitrogen atom, n represents 1 or 2 and m represents (2-n),
when A is a carbon atom, n represents an integer of 1 to 3 and m represents (3-n),
p1 represents an integer of 1 to 4 and p2 represents 1 or 2,
L represents a single bond or a (p2+1)-valent linking group and when L is a single bond, p2 represents 1,
when at least one of (i) p2 represents 2, and (ii) n represents 2 or 3, is satisfied, a plurality of Ra's may be the same as or different from each other and may be bonded to each other to form a ring, in other words, when (i) is satisfied, two of Ra's may be bonded to each other to form a ring, and when (ii) is satisfied, at least one of the p2 of Ra included in one group represented by —[(Ra)ₚ₂-L-(CF₂)ₚ₁—SO₂—]- and at least one of the p2 of Ra included in another group represented by —[(Ra)ₚ₂-L-(CF₂)ₚ₁—SO₂—]- may be bonded to each other to form a ring, and
when A is a carbon atom and m represents 2, a plurality of Rb's may be the same as or different from each other.

In addition, the number of a fluorine atoms included in the acid represented by the general formula (I) is preferably 6 or less and more preferably 4 or less.

An alkyl group of Ra represents a chain alkyl group, a cycloalkyl group of Ra represents a monocyclic or polycyclic alkyl group, and an aryl group of Ra represents a monocyclic or polycyclic aryl group. Each of the above-mentioned groups may have a substituent but the alkyl group of Ra does not include a fluorine atom as a substituent. The cycloalkyl group of Ra and the aryl group of Ra each preferably do not include a fluorine atom as a substituent.

The chain alkyl group may be linear or branched and examples thereof include a methyl group, an ethyl group, a propyl group, a butyl group, a pentyl group, a hexyl group, a heptyl group, an octyl group, a dodecyl group, 2-ethylhexyl group, isopropyl group, sec-butyl group, a t-butyl group, iso-amyl group and the like.

Examples of a substituent which the chain alkyl group may have include a hydroxy group, a halogen atom other than fluorine atoms (chlorine, bromide and iodine), a nitro group, a cyano group, an amide group, a sulfonamide group, an alkoxy group such as a methoxy group, an ethoxy group, a hydroxyethoxy group, a propoxy group, a hydroxy propoxy group, a butoxy group and the like, an alkoxycarbonyl group such as a methoxycarbonyl group, an ethoxycarbonyl group and the like, an acyl group such as formyl group, an acetyl group, a benzoyl group and the like, an acyloxy group such as an acetoxy group, butyloxy group and the like, and a carboxy group.

Examples of the monocyclic alkyl group include a cyclopropyl group, a cyclobutyl group, a cyclopentyl group, a cyclohexyl group, a cyclobutyl group, a cyclooctyl group, a cyclododecanyl group, a cyclopentenyl group, a cyclohexenyl group, a cyclooctadienyl group and the like, and in particular a cyclopropyl group, a cyclopentyl group, a cyclohexyl group and a cyclooctyl group are preferred.

Examples of a substituent which the monocyclic alkyl group may have include a halogen atom (fluorine, chlorine, bromide and iodine), a nitro group, a cyano group, an amide group, a sulfonamide group, an alkyl group such as a methyl group, an ethyl group, a propyl group, n-butyl group, a sec-butyl group, a hexyl group, 2-ethylhexyl group, an octyl group and the like, an alkoxy group such as a methoxy group, an ethoxy group, a hydroxyethoxy group, a propoxy group, a hydroxypropoxy group, a butoxy group and the like, an alkoxycarbonyl group such as a methoxycarbonyl group, an ethoxycarbonyl group and the like, an acyl group such as formyl group, an acetyl group, a benzoyl group and the like, an acyloxy group such as an acetoxy group, butyloxy group and the like, and a carboxy group. The substituents preferably do not have a fluorine atom.

Examples of the polycyclic alkyl group include bicyclo[4.3.0]nonenyl, decahydronaphthalenyl, tricyclo[5.2.1.0(2,6)]decanyl, bornyl, isobornyl, norbornyl, adamantyl, noradamantyl, 1,7,7-trimethyltricyclo[2.2.1.0^{2,6}]heptanyl, 3,7,7-trimethylbicyclo[4.1.0]heptanyl and the like, and in particular norbornyl, adamantyl, noradamantyl are preferred.

Examples of the monocyclic aryl group include a phenyl group and the like, and examples of the polycyclic aryl group include a naphthyl group, anthracenyl group and the like.

Examples of a substituent which the monocyclic or polycyclic aryl group may have include a hydroxy group, a halogen atom (fluorine, chlorine, bromide and iodine), a nitro group, a cyano group, an amide group, a sulfonamide group, an alkyl group such as a methyl group, an ethyl group, a propyl group, n-butyl group, a sec-butyl group, a hexyl group, 2-ethylhexyl group, an octyl group and the like, an alkoxy group such as a methoxy group, an ethoxy group, a hydroxyethoxy group, a propoxy group, a hydroxy propoxy group a butoxy group and the like, an alkoxycarbonyl group such as a methoxycarbonyl group, an ethoxy carbonyl group and the like, an acyl group such as formyl group, an acetyl group, a benzoyl group and the like, an acyloxy group such as an acetoxy group, butyloxy group and the like, and a carboxy group. The substituent preferably does not include a fluorine atom.

In the formula, Rb represents an electron-attracting group, an alkyl group, or an aryl group.

Examples of electron-attracting group of Rb include a carboxyl group (*—COOH), an ester group (*—COORc), a sulfone group (*—SO₂Rc), a sulfonic acid group (*—SO₃H), a sulfonic acid ester group (*—SO₂—O—Rc), a sulfonamide group (*—SO₂N(Rc)₂), a nitro group (*—NO₂), a cyano group (*—CN) and the like. R_{c} represents an alkyl group or a cycloalkyl group.

Examples of the alkyl group as Rb and the aryl group as Rb are respectively the same ones as those described for the alkyl group as Ra and the aryl group as Ra, and may respectively further have a substituent. Examples of such an additional substituent include a hydroxyl group, a halogen atom (fluorine, chlorine, bromine, iodine), a nitro group, a cyano group, an amide group, a sulfonamide group, an alkyl group such as a methyl group, an ethyl group, a propyl group, a n-butyl group, a sec-butyl group, a hexyl group, 2-ethylhexyl group, an octyl group and the like, an alkoxy group such as a methoxy group, an ethoxy group, a hydroxyethoxy group, a propoxy group, a hydroxypropoxy group, a butoxy group and the like, an alkoxycarbonyl group such as a methoxycarbonyl group, an ethoxycarbonyl group and the like, an acyl group such as a formyl group, an acetyl group, a benzoyl group, a carbonyl group of a carbon forming a ring and the like, an acyloxy group such as an acetoxy group, butylyloxy group and the like, and a carboxy group from the viewpoint of acid strength.

Examples of the alkyl group as Rc and the cycloalkyl group as Rc are respectively the same ones as those described for the alkyl group as Ra and the cycloalkyl group as Ra, and may respectively further have a substituent. Examples of such an additional substituent are the same ones as those explained for the substituent of Rb.

The electron-attracting group of Rb is preferably a sulfone group (*—SO₂Rc), a sulfonic acid ester group (*—SO₂—O—Rc), a sulfonamide group (*—SO₂N(Rc)₂), a nitro group (*—NO₂) or a cyano group (*—CN), and is more preferably include a sulfone group (*—SO₂Rc) or cyano group (*—CN).

In the present invention, it is preferable that at least one of the following (I) and (II) be satisfied from the viewpoint of improving exposure latitude in particular:
(I) in each n groups represented by [(Ra)ₚ₂-L-(CF₂)ₚ₁—SO₂]—, at least one of p2 of Ra is a cycloalkyl group or an aryl group.
(II) at least one of (i) p2 represents 2 and (ii) n represents 2 or 3 are satisfied and also a plural of Ra bonds to form a ring.

Examples of the (p2+1)-valent linking group represented by L when p2 is 1, which is a divalent linking group, include —COO—, —COO—, —CO—, —O—, —S—, —SO—, —SO₂—, an alkylene group, a cycloalkylene group, a alkenylene group, a group of a combination of 2 or more of these, and the like. The alkylene, the cycloalkylene and the alkenylene group may further have a substituent and examples thereof are the same ones as those described for a substituent which the chain alkyl group as Ra may have. Here the substituent preferably does not include a fluorine atom. In other words, L preferably does not have a fluorine atom.

Examples of the (p2+1)-valent linking group represented by L when p2 is 2, which is a trivalent linking group, include a group consisting of the above-described divalent linking group from which one arbitrary hydrogen atom is removed.

In each of n groups represented by [(Ra)ₚ₂-L-(CF₂)ₚ₁—SO₂]— in the above general formula (I) or (II), it is preferable if (i) p2 represents 1 and also L represents a single bond or a divalent group represented by any of the following formulae (L1) to (L6), or if (ii) p2 represents 2 and L represents a trivalent formula represented by any of the following formulae (L7) to (L9).

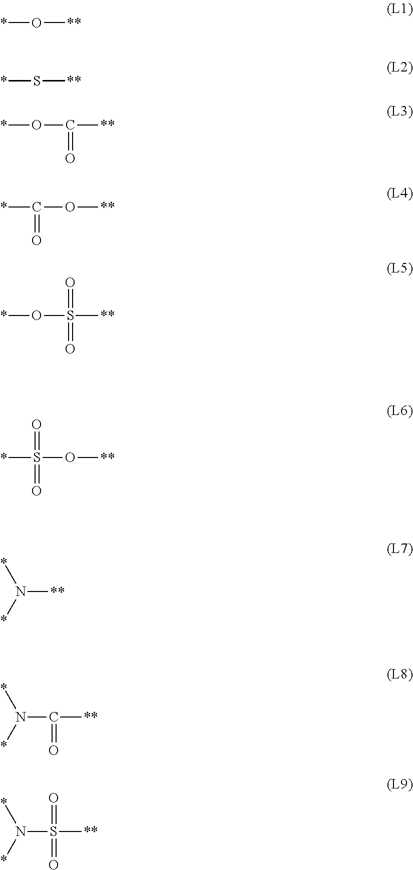

In the above formulae, * represents the bond bonding to Ra in the general formula (I) or (II), and ** represents a bond bonding to —(CF₂)ₚ₁— in the general formula (I) or (II).

p1 is preferably 1 or 2, more preferably 1, and particularly preferably 1 at the same time as L being a group represented by the above formula (L5) or (L9). In these embodiments, L preferably does not have a fluorine atom.

In a case that p2 represents 2 and two of Ra included in a same group represented by [(Ra)₂-L-(CF₂)ₚ₁—SO₂]— bond to each other to form a ring, L is preferably a linking group having a nitrogen atom represented by a group the above formula (L6) or (L7) and the like. The ring formed by the two of Ra by bonding to each other preferably have a cyclic amine structure having a nitrogen atom in the ring. Examples of the cyclic amine structure include an aziridine structure, an azetidine structure, a pyrrolidine structure, a piperidine structure, a hexamethyleneimine structure, a heptamethyleneimine structure, a piperazine structure, a decahydroquinoline structure, an 8-azabicyclo[3.2.1]octane structure, an indole structure, an oxazolidine structure, a thiazolidine structure, a 2-azanorbornane structure, a 7-azanorbornane structure, a morpholine structure, a thiamorpholine structure and the like, and the structures may have a substituent. Examples of the substituent include a hydroxy group, a halogen atom (fluorine, chlorine, bromide and iodine), a nitro group, a cyano group, an amide group, a sulfonamide group, an alkyl group such as a methyl group, an ethyl group, a propyl group, n-butyl group, a sec-butyl group, a hexyl group, 2-ethylhexyl group, an octyl group and the like, an alkoxy group such as a methoxy group, an ethoxy group, a hydroxyethoxy group, a propoxy group, a hydroxypropoxy group a butoxy group and the like, an alkoxycarbonyl group such as a methoxycarbonyl group, an ethoxycarbonyl group and the like, an acyl group such as formyl group, an acetyl group, a benzoyl group, a carbonyl group of a carbon forming a ring and the like, an acyloxy group such as an acetoxy group, butyloxy group and the like, and a carboxy group. The substituent preferably does not include a fluorine atom.

Specific examples of the acid represented by the general formula (I) which the compound (B) generates by irradiation with actinic rays or radiation are shown below, but the present invention is not limited thereto.

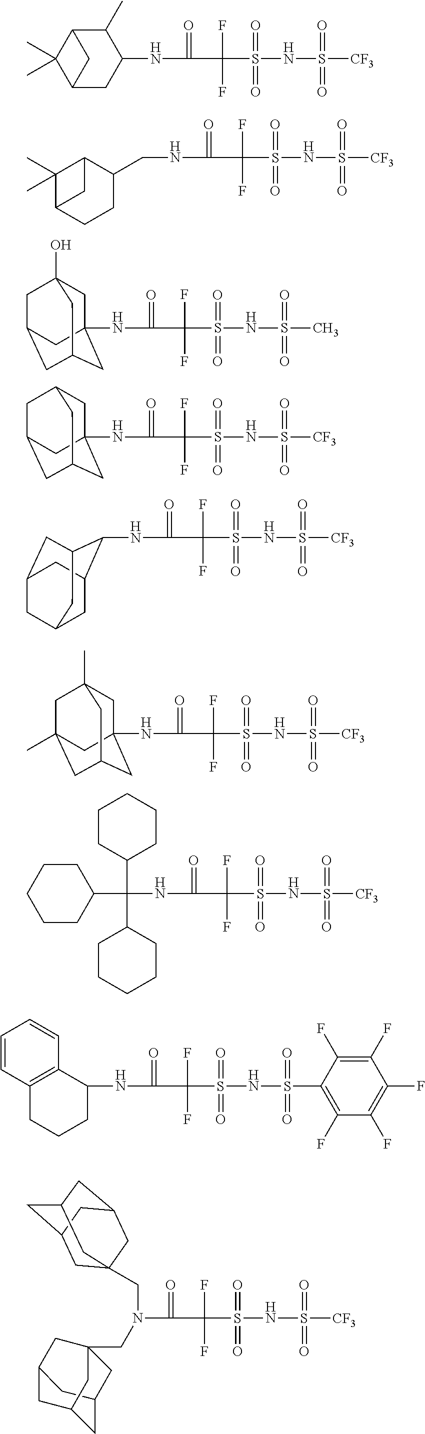

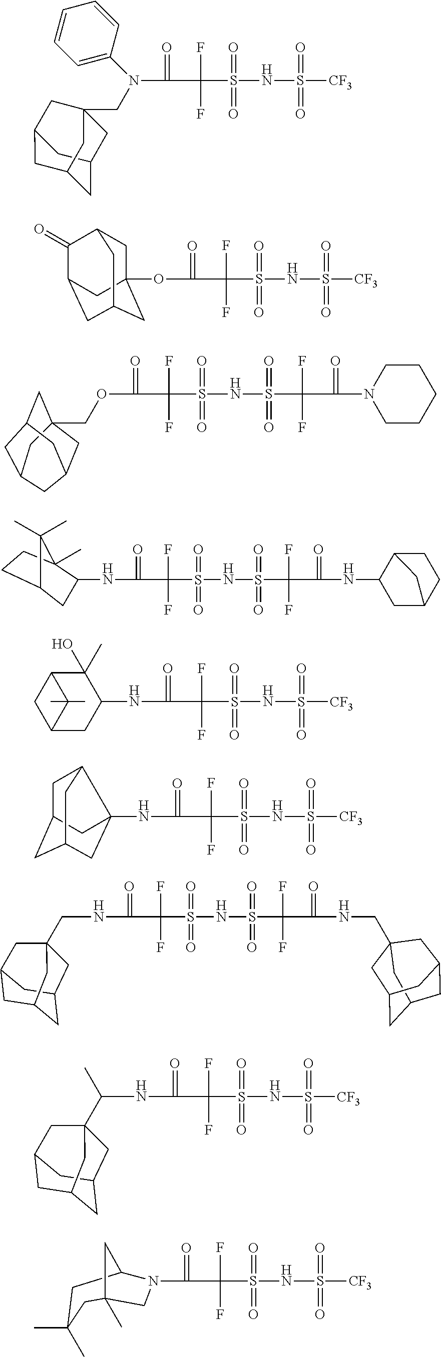

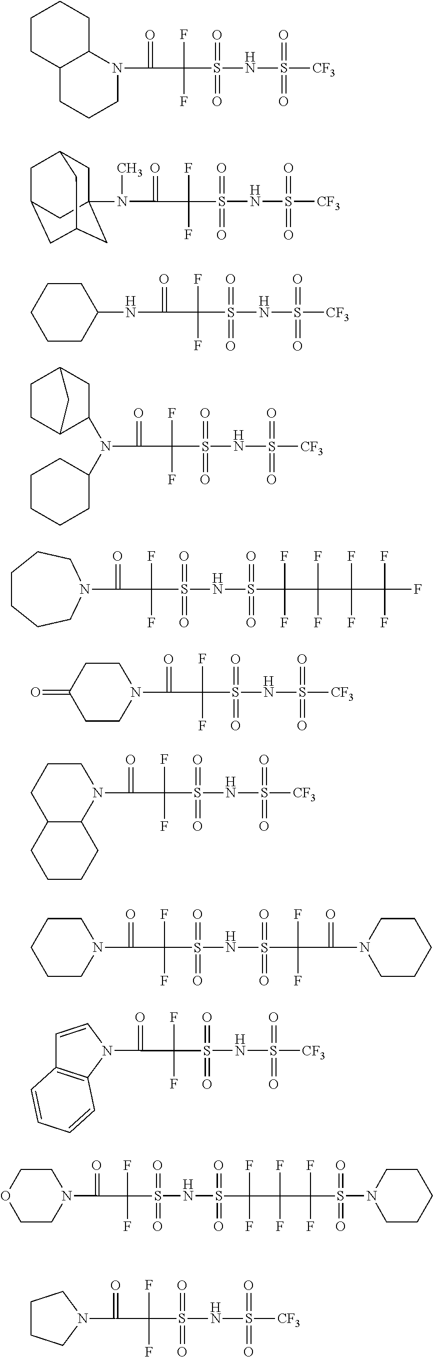

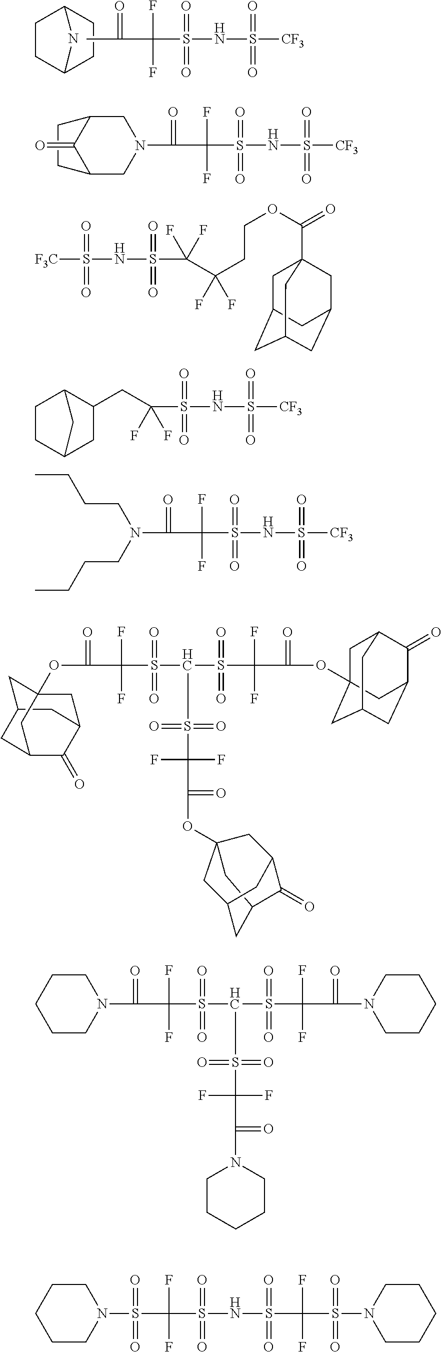

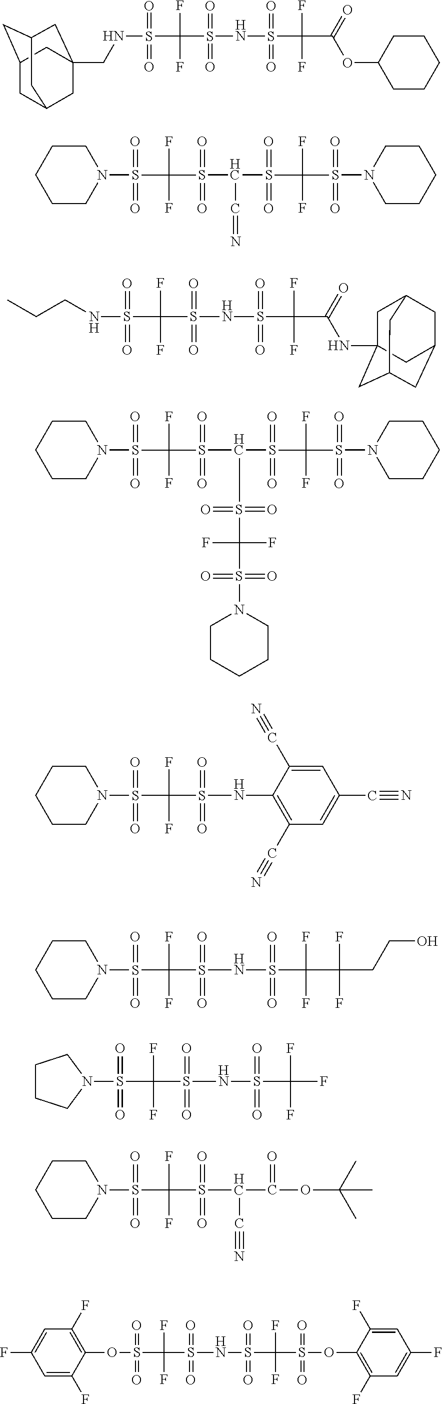

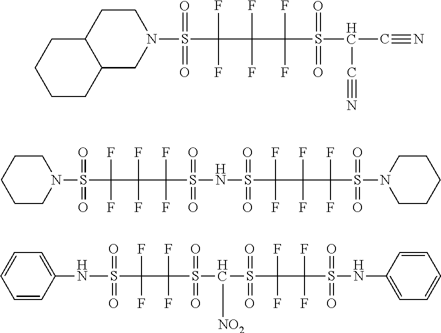

The compound (B) is preferably an ionic compound represented by the following general formula (II).

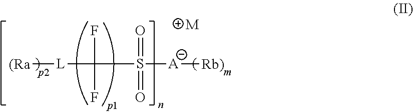

In the general formula (II), A, Ra, Rb, L, m, n, p1 and p2 have the same definition as that of the respective A, Ra, Rb, L, m, n, p1 and p2 in the general formula (I),
M⁺ represents an organic counterion, and
the organic counterion represented by M⁺ is preferably a sulfonium cation or an iodonium cation, and a sulfonium cation is particularly preferable.

An example of the compound represented by the general formula (II) includes a compound represented by the following general formula (ZI) or (ZII).

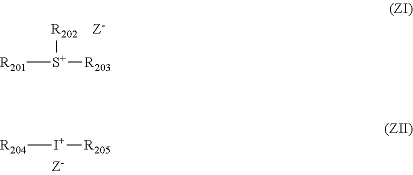

In the above general formula (ZI),
each of R₂₀₁, R₂₀₂, and R₂₀₃ independently represents an organic group.

The organic group represented by R₂₀₁, R₂₀₂, and R₂₀₃ generally has 1 to 30 carbon atoms and preferably has 1 to 20 carbon atoms.

In addition, two out of R₂₀₁ to R₂₀₃ may form a ring structure by bonding to each other, and the ring may contain an oxygen atom, a sulfur atom, an ester bond, an amide bond or a carbonyl group in the ring. Examples of the group that two out of R₂₀₁ to R₂₀₃ form by bonding to each other include an alkylene group (for example, a butylene group or a pentylene group).

Z⁻ represents an anionic structure of an acid represented by the general formula (I) (in other words an anion of the compound represented by the general formula (II)).

Examples of the organic group represented by R₂₀₁, R₂₀₂, and R₂₀₃ include groups corresponding to compounds (ZI-1), (ZI-2), (ZI-3) and (ZI-4) described later.

In addition, the organic group may be a compound having a plurality of the structures represented by the general formula (ZI). For example, the organic group may be a compound having a structure in which at least one of R₂₀₁ to R₂₀₃ of the compound represented by the general formula (ZI) bonds to at least one of R₂₀₁ to R₂₀₃ of another compound represented by the general formula (ZI).

Examples of a more preferable (ZI) component may include the compounds (ZI-1) to (ZI-4) described later.

The compound (ZI-1) is an aryl sulfonium compound in which at least one of R₂₀₁ to R₂₀₃ of the above general formula (ZI) is an aryl group, that is, a compound having aryl sulfonium as a cation.

In the aryl sulfonium compound, all of R₂₀₁ to R₂₀₃ may be aryl groups; alternatively, a portion of R₂₀₁ to R₂₀₃ may be an aryl group, and the remaining groups may be an alkyl group or a cycloalkyl group.

Examples of the aryl sulfonium compound include a triaryl sulfonium compound, a diaryl alkyl sulfonium group, an aryl dialkyl sulfonium compound, a diaryl cycloalkyl sulfonium compound, and an aryl dicycloalkyl sulfonium compound.

As the aryl group of the aryl sulfonium compound, a phenyl group and a naphthyl group are preferable, and a phenyl group is more preferable. The aryl group may be an aryl group having a heterocyclic structure containing an oxygen atom, a nitrogen atom, a sulfur atom, and the like. Examples of the heterocyclic structure include a pyrrole residue, a furan residue, a thiophene residue, an indole residue, a benzofuran residue and a benzothiophene residue. When the aryl sulfonium compound has two or more aryl groups, the two or more aryl groups may be the same as or different from each other.

The alkyl group or cycloalkyl group which the aryl sulfonium compound optionally has as necessary is preferably a linear or branched alkyl group having 1 to 15 carbon atoms and a cycloalkyl group having 3 to 15 carbon atoms, and examples thereof include a methyl group, an ethyl group, a propyl group, an n-butyl group, a sec-butyl group, a t-butyl group, a cyclopropyl group, a cyclobutyl group and a cyclohexyl group.

The aryl group, alkyl group, and cycloalkyl group of R₂₀₁ to R₂₀₃ may have an alkyl group (having 1 to 15 carbon atoms, for example), a cycloalkyl group (having 3 to 15 carbon atoms, for example), an aryl group (having 6 to 14 carbon atoms, for example), an alkoxy group (having 1 to 15 carbon atoms, for example), a halogen atom, a hydroxyl group, or a phenylthio group as a substituent. The substituent is preferably a linear or branched alkyl group having 1 to 12 carbon atoms, a cycloalkyl group having 3 to 12 carbon atoms, a linear, branched or cyclic alkoxy group having 1 to 12 carbon atoms, and more preferably an alkyl group having 1 to 4 carbon atoms or an alkoxy group having 1 to 4 carbon atoms. The substituent may be substituted with at least one out of three of R₂₀₁ to R₂₀₃, or may be substituted with all of three. When R₂₀₁ to R₂₀₃ are aryl groups, the substituent is preferably substituted at a p-position of the aryl group.

Next, the compound (ZI-2) is described.

The compound (ZI-2) is a compound in which each of R₂₀₁ to R₂₀₃ in the formula (ZI) independently represents an organic group not having an aromatic ring. The aromatic ring herein also includes an aromatic ring containing a hetero atom.

The organic group not containing an aromatic ring represented by R₂₀₁ to R₂₀₃ has generally 1 to 30 carbon atoms, and preferably 1 to 20 carbon atoms

Each of R₂₀₁ to R₂₀₃ is independently preferably an alkyl group, a cycloalkyl group, an allyl group or a vinyl group preferably, and more preferably a linear or branched 2-oxoalkyl group, a 2-oxocycloalkyl group or an alkoxycarbonyl methyl group, and particularly preferably a linear or branched 2-oxoalkyl group.

Preferable examples of the alkyl group and cycloalkyl group of R₂₀₁ to R₂₀₃ include a linear or branched alkyl group (for example, a methyl group, an ethyl group, a propyl group, a butyl group, or a pentyl group) having 1 to 10 carbon atoms and a cycloalkyl group (a cyclopentyl group, a cyclohexyl group, or a norbornyl group) having 3 to 10 carbon atoms. More preferable examples of the alkyl group include a 2-oxoalkyl group and an alkoxycarbonyl methyl group. More preferable examples of the cycloalkyl group include a 2-oxocycloalkyl group.

The 2-oxoalkyl group may be linear or branched, and more preferable examples thereof include a group having >C═O in the second position of the above alkyl group.

Preferable examples of the 2-oxocycloalkyl group include a group having >C═O in the second position of the above cycloalkyl group.

Preferable examples of the alkoxy group in the alkoxycarbonyl methyl group include an alkoxy group having 1 to 5 carbon atoms (a methoxy group, an ethoxy group, a propoxy group, a butoxy group or a pentoxy group).

R₂₀, to R₂₀₃ may be further substituted with a halogen atom, an alkoxy group (having 1 to 5 carbon atoms, for example), a hydroxyl group, a cyano group, or a nitro group.

Next, the compound (ZI-3) is described.

The compound (ZI-3) is a compound represented by the following general formula (ZI-3), which is a compound having a phenacyl sulfonium salt structure.

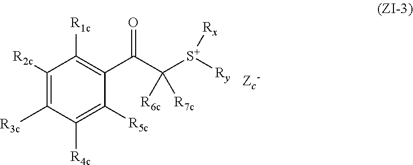

In the general formula (ZI-3),
each of R_{1c} to R_{5c} independently represents a hydrogen atom, an alkyl group, a cycloalkyl group, an aryl group, an alkoxy group, an aryloxy group, an alkoxycarbonyl group, an alkylcarbonyloxy group, a cycloalkylcarbonyloxy group, a halogen atom, a hydroxyl group, a nitro group, an alkylthio group or an arylthio group,
each of R_{6c} and R_{7c} independently represents a hydrogen atom, an alkyl group, a cycloalkyl group, a halogen atom, a cyano group or an aryl group, and
each of Rₓ and R_{y} independently represents an alkyl group, a cycloalkyl group, a 2-oxoalkyl group, a 2-oxocycloalkyl group, an alkoxycarbonyl alkyl group, an aryl group or a vinyl group.

Any two or more out of R_{1c} to R_{5c}, R_{5c} and R_{6c}, R_{c} and R_{7c}, R_{5c} and Rₓ, and Rₓ and R_{y} may form a ring structure by bonding to each other respectively, and this ring structure may include an oxygen atom, a sulfur atom, a ketone group, an ester bond, or an amide bond.

Examples of the ring structure include an aromatic or non-aromatic hydrocarbon ring, an aromatic or non-aromatic hetero ring, and a polycyclic condensed ring formed of a combination of two or more of these rings. Examples of the ring structure include a 3- to 10-membered ring, and the ring structure is preferably a 4- to 8-membered ring and more preferably a 5- to 6-membered ring.

Examples of the group that any two or more out of R_{1c} to R_{5c}, R_{6c} and R_{7c}, and Rₓ and R_{y} form by bonding to each other include a butylene group and a pentylene group.

The group that R_{5c} and R_{6c}, and R_{5c} and Rₓ form by bonding to each other is preferably a single bond or an alkylene group, and examples of the alkylene group include a methylene group and an ethylene group.

Z_{c}⁻ represents an anionic structure of an acid represented by the general formula (I) (in other words an anion of the compound represented by the general formula (II).

The alkyl group of R_{1c} and R_{7c} may be linear or branched. Examples of the alkyl group includes an alkyl group having 1 to 20 carbon atoms and preferably include a linear or branched alkyl group having 1 to 12 carbon atoms (for example, a methyl group, an ethyl group, a linear or branched propyl group, a linear or branched butyl group, or a linear or branched pentyl group). Examples of the cycloalkyl group include a cycloalkyl group (for example, a cyclopentyl group or a cyclohexyl group) having 3 to 10 carbon atoms.

The aryl group represented by R_{1c} and R_{7c} preferably has 5 to 15 carbon atoms, and examples thereof include a phenyl group and a naphthyl group.

The alkoxy group represented by R_{1c} to R_{5c} may be linear, branched or cyclic. Examples of the alkoxy group include an alkoxy group having 1 to 10 carbon atoms, and preferably include a linear or branched alkoxy group having 1 to 5 carbon atoms (for example, a methoxy group, an ethoxy group, a linear or branched propoxy group, a linear or branched butoxy group, or a linear or branched pentoxy group) and a cyclic alkoxy group having 3 to 10 carbon atoms (for example, a cyclopentyloxy group or a cyclohexyloxy group).

Specific examples of the alkoxy group in the alkoxycarbonyl group represented by R_{1c} to R_{5c} are the same as the above specific examples of the alkoxy group represented by R_{1c} to R_{5c}.

Specific examples of the alkyl group in the alkylcarbonyloxy group and the alkylthio group represented by R_{1c} to R_{5c} are the same as the above specific examples of the alkyl group represented by R_{1c} to R_{5c}.

Specific examples of the cycloalkyl group in the cycloalkyl carbonyloxy group represented by R_{1c} to R_{5c} are the same as the above specific examples of the cycloalkyl group represented by R_{1c} to R_{5c}.

Specific examples of the aryl group in the aryloxy group and the arylthio group represented by R_{1c} to R_{5c} are the same as the above specific examples of the aryl group represented by R_{1c} to R_{5c}.

Any one of R_{1c} to R_{5c} is preferably a linear or branched alkyl group, a cycloalkyl group, or a linear, branched or cyclic alkoxy group. More preferably, the sum of the number of the carbon atoms of R_{1c} to R_{5c} is 2 to 15. In this structure, solvent solubility is further improved, and the generation of particles during storage is inhibited.

Examples of the ring structure that any two out of R_{1c} to R_{5c} may form by bonding to each other preferably include a 5- or 6-membered ring, and particularly preferably include a 6-membered ring (for example, a phenyl ring).

Examples of the ring structure that R_{5c} and R_{6c} may form by bonding to each other include a 4- or more membered ring (particularly preferably a 5- to 6-membered ring) that is formed in a manner in which R_{5c} and R_{6c} constitute a single bond or an alkylene group (a methylene group, an ethylene group, or the like) by bonding to each other, and this single bond or alkylene group forms the 4- or more membered ring together with a carbonyl carbon atom and a carbon atom in the general formula (I).

As an embodiment of R_{6c} and R_{7c}, a case where both the R_{6c} and R_{7c} are alkyl groups is preferable. Particularly, a case where each of R_{6c} and R_{7c} is a linear or branched alkyl group having 1 to 4 carbon atoms is preferable, and particularly, a case where both R6c and R7c are methyl groups is preferable.

When R6c and R7c form a ring by bonding to each other, the group that R_{6c} and R_{7c} form by bonding to each other is preferably an alkylene group having 2 to 10 carbon atoms, and examples thereof include an ethylene group, a propylene group, a butylene group, a pentylene group and a hexylene group. The ring which R_{6c} and R_{7c} form by bonding to each other may include a hetero atom such as oxygen atoms and the like in the ring.

Examples of the alkyl group and the cycloalkyl group represented by Rₓ and R_{y} include the same alkyl group and cycloalkyl group as those in R_{1c} to R_{7c}.

Examples of the 2-oxoalkyl group and the 2-oxocycloalkyl group represented by Rₓ and R_{y} include the group having >C═O in the second position of the alkyl group and the cycloalkyl group represented by R_{1c} to R_{7c}.

Examples of the alkoxy group in the alkoxycarbonyl alkyl group represented by Rₓ and R_{y} include the same alkoxy group as those in R_{1c} to R_{5c}. Examples of the alkyl group include an alkyl group having 1 to 12 carbon atoms, and preferably include a linear alkyl group having 1 to 5 carbon atoms (for example, a methyl group or an ethyl group).

The aryl group represented by Rₓ and R_{y} is not particularly limited, but is preferably an unsubstituted aryl group or an aryl group substituted with a monocyclic or polycyclic cycloalkyl group (preferably a cycloalkyl group having 3 to 10 carbon atoms).

The vinyl group represented by Rₓ and R_{y} is not particularly limited, but is preferably an unsubstituted vinyl group or a vinyl group substituted with a monocyclic or polycyclic cycloalkyl group (preferably a cycloalkyl group having 3 to 10 carbon atoms).

Examples of the ring structure that R_{5c} and Rₓ may form by bonding to each other include a 5- or more membered ring (particularly preferably a 5-membered ring) which is formed in a manner in which R_{5c} and Rₓ constitute a single bond or an alkylene group (a methylene group, an ethylene group, or the like) by bonding to each other, and this single bond or alkylene group forms the 5- or more membered ring together with a sulfur atom and a carbonyl carbon atom in the general formula (I).

Examples of the ring structure that Rₓ and R_{y} may form by bonding to each other include a 5- or 6-membered ring, and particularly preferably include a 5-membered ring (that is, a tetrahydrothiophene ring) that the divalent Rₓ and R_{y} (for example, a methylene group, an ethylene group, a propylene group, or the like) form together with a sulfur atom in the general formula (ZI-3).

Rₓ and R_{y} are an alkyl group or a cycloalkyl group having preferably 4 or more carbon atoms, more preferably 6 or more carbon atoms, and even more preferably 8 or more carbon atoms.

R_{1c} to R_{7c}, Rₓ and R_{y} may further have a substituent, and examples of the substituent include a halogen atom (for example, a fluorine atom), an hydroxyl group, a carboxyl group, a cyano group, a nitro group, an alkyl group, a cycloalkyl group, an aryl group, an alkoxy group, an aryloxy group, an acyl group, an arylcarbonyl group, an alkoxyalkyl group, an aryloxyalkyl group, an alkoxycarbonyl group, an aryloxycarbonyl group, an alkoxycarbonyloxy group, an aryloxycarbonyloxy group and the like.

Examples of the alkyl group may have include a linear or a branched alkyl group having 1 to 12 carbon atoms such as a methyl group, an ethyl group, a n-propyl group, an i-propyl group, an n-butyl group, a 2-methylpropyl group, a 1-methylpropyl group, a t-butyl group and the like.

Examples of the cycloalkyl group include a cycloalkyl group having 3 to 10 carbon atoms such as a cyclopentyl group, a cyclohexyl group and the like.

Examples of the aryl group include an aryl group having 6 to 15 carbons such as a phenyl group or a naphthyl group and the like.

Examples of the alkoxy group include a linear, branched or cyclic alkoxy group having 1 to 20 carbon atoms, such as a methoxy group, an ethoxy group, an n-propoxy group, an i-propoxy group, an n-butoxy group, a 2-methylpropoxy group, a 1-methylpropoxy group, a t-butoxy group, a cyclopentyloxy group, and a cyclohexyloxy group.

Examples of the aryloxy group include an aryloxy group having 6 to 10 carbon atoms such as a phenyloxy group, a naphthyloxy group and the like.

Examples of the acyl group include a linear or branched acyl group having 2 to 12 carbon atoms such as an acetyl group, a propanoyl group, an n-butanoyl group, an i-butanoyl, n-heptanoyl group, a 2-methylbutanoyl group, 1-methylbutanoyl group, t-heptanoyl group and the like.

An examples of the arylcarbonyl group include an aryloxy group having 6 to 10 carbon atoms such as a phenylcarbonyl group, a naphthylcarbonyl group and the like.

Examples of the alkoxyalkyl group include a linear, branched or cyclic alkoxyalkyl group having 2 to 21 carbon atoms, such as a methoxymethyl group, an ethoxymethyl group, a 1-methoxyethyl group, a 2-methoxyethyl group, a 1-ethoxyethyl group and a 2-ethoxyethyl group.

Examples of the aryloxyalkyl group include an aryloxy group having 7 to 12 carbon atoms such as a phenyloxymethyl group, a phenyloxyethyl group, a naphthyloxymethyl group, a naphthyloxyethyl group and the like.

Examples of the alkoxycarbonyl group include a linear, branched or cyclic alkoxycarbonyl group having 2 to 21 carbon atoms, such as a methoxycarbonyl group, an ethoxycarbonyl group, an n-propoxycarbonyl group, an i-propoxycarbonyl group, an n-butoxycarbonyl group, a 2-methylpropoxycarbonyl group, a 1-methylpropoxycarbonyl group, a t-butoxycarbonyl group, a cyclopentyloxycarbonyl group and a cyclohexyloxycarbonyl group.

Examples of the aryloxycarbonyl include an aryloxycarbonyl group having 7 to 11 carbon atoms such as a phenyloxycarbonyl group, a naphthyloxycarbonyl group and the like.

Examples of the alkoxycarbonyloxy group include a linear, branched or cyclic alkoxycarbonyloxy group having 2 to 21 carbon atoms, such as a methoxycarbonyloxy group, an ethoxycarbonyloxy group, an n-propoxycarbonyloxy group, an i-propoxycarbonyloxy group, an n-butoxycarbonyloxy group, a t-butoxycarbonyloxy group, a cyclopentyloxycarbonyloxy group and a cyclohexyloxycarbonyloxy group.

Examples of the aryloxycarbonyloxy group include an aryloxycarbonyloxy group having 7 to 11 carbon atoms such as a phenyloxycarbonyloxy group, a naphthyloxycarbonyloxy group and the like.

In the general formula (ZI-3), it is more preferable that each of R_{1c}, R_{2c}, R_{4c} and R_{5c} independently represent a hydrogen atom, and that R_{3c} represent a group other than a hydrogen atom, that is, an alkyl group, a cycloalkyl group, an aryl group, an alkoxy group, an aryloxy group, an alkoxycarbonyl group, an alkylcarbonyloxy group, a cycloalkylcarbonyloxy group, a halogen atom, a hydroxyl group, a nitro group, an alkylthio group, or an arylthio group.

Specific examples of a cation of the compound represented by the general formula (ZI-2) or (ZI-3) in the present invention include the following.

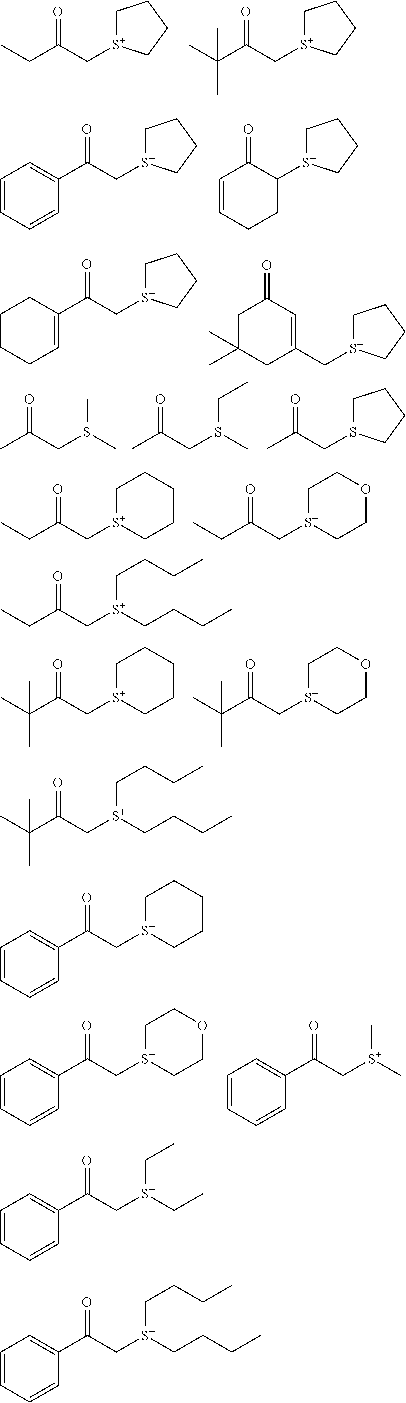

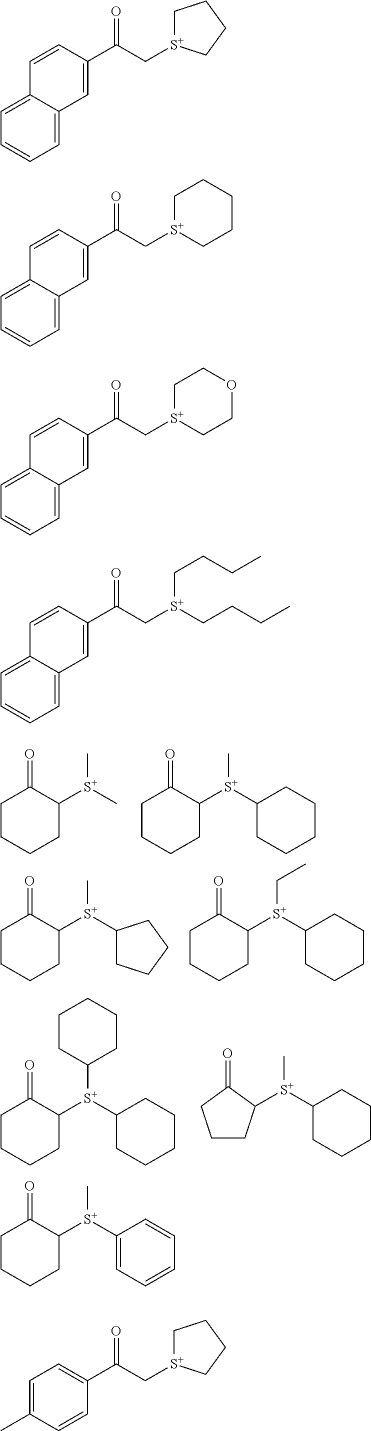

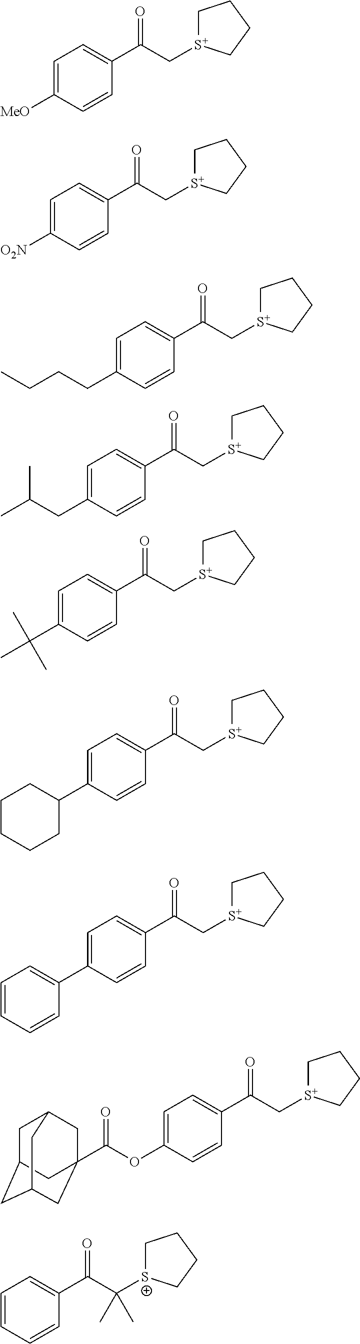

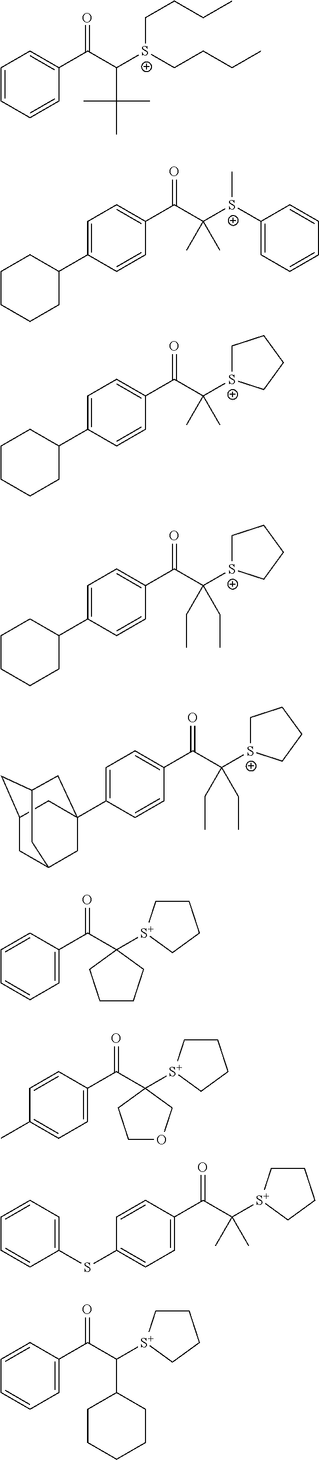

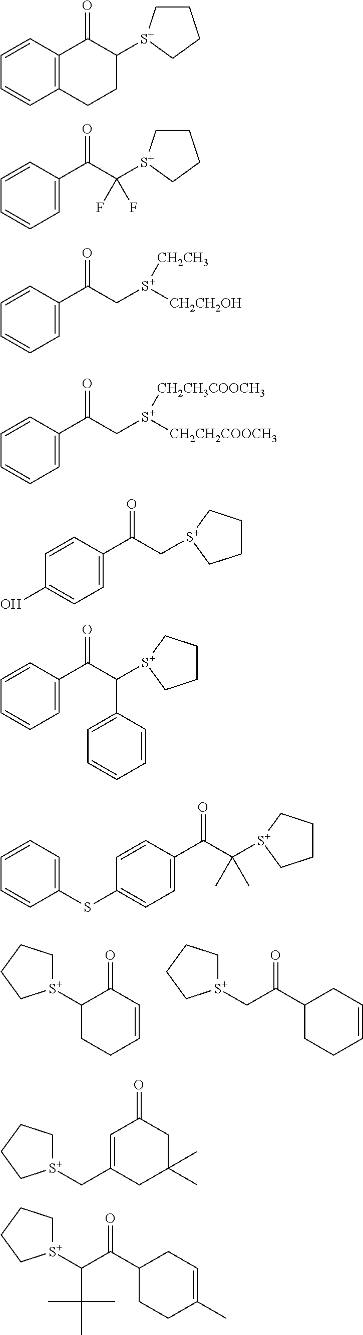

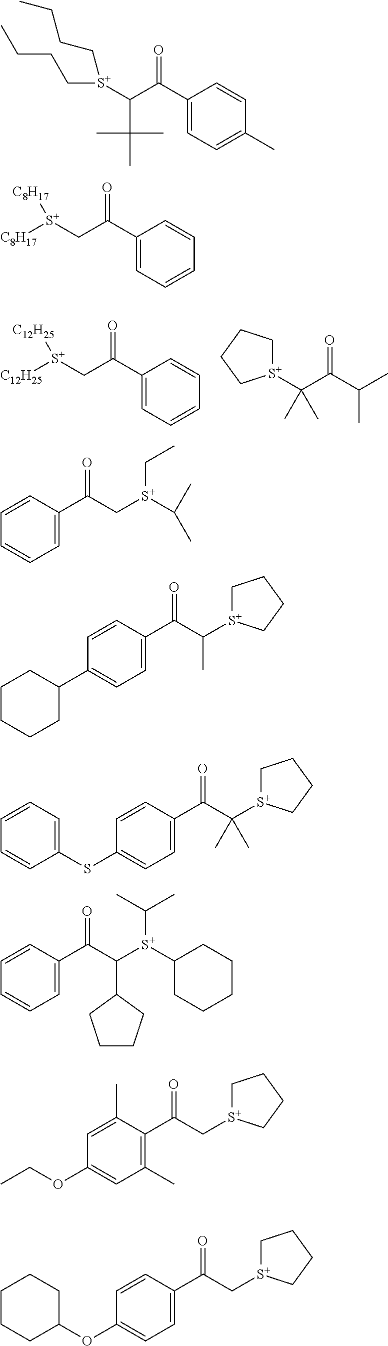

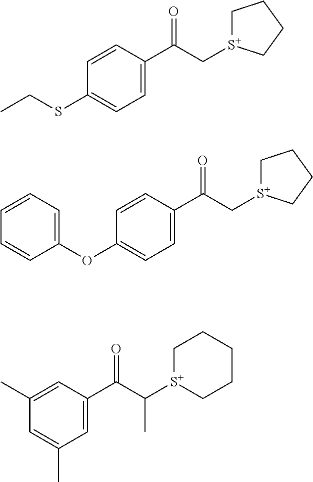

Next, the compound (ZI-4) is described.

The compound (ZI-4) is represented by the following general formula (ZI-4).

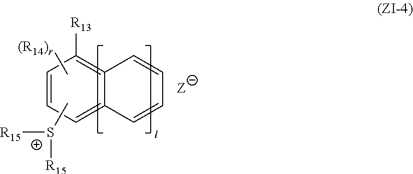

In general formula (ZI-4),
R₁₃ represents a hydrogen atom, a fluorine atom, a hydroxyl group, an alkyl group, a cycloalkyl group, an alkoxy group, an alkoxycarbonyl group or a group having a cycloalkyl group. These groups may have a substituent,
when there is a plurality of R₁₄, each R₁₄ independently represents a hydroxyl group, an alkyl group, a cycloalkyl group, an alkoxy group, an alkoxycarbonyl group, an alkylcarbonyl group, an alkylsulfonyl group, a cycloalkylsulfonyl group or a group having a cycloalkyl group and these groups may have a substituent,
each R₁₅ independently represents an alkyl group, a cycloalkyl group or a naphthyl group and two R₁₅ may form a ring by bonding to each other. These groups may have a substituent,
l represents an integer of 0 to 2,
r represents an integer of 0 to 8, and
Z⁻ represents an anionic structure of an acid represented by the general formula (I) (in other words an anion of the compound represented by the general formula (II).

In the general formula (Z-14), the alkyl group of R₁₃, R₁₄ and R₁₅ is preferably a linear or branched alkyl group having 1 to 10 carbon atoms, and a methyl group, an ethyl group, an n-butyl group, a t-butyl group and the like are preferable.

Examples of the cycloalkyl group of R₁₃, R₁₄, and R₁₅ include a monocyclic or polycyclic cycloalkyl group (preferably a cycloalkyl group having 3 to 20 carbon atoms), and particularly, cyclopropyl, cyclopentyl, cyclohexyl, cycloheptyl and cyclooctyl are preferable.

Examples of the alkoxy group of R₁₃ and R₁₄ include linear or branched alkoxy groups having 1 to 10 carbon atoms, and a methoxy group, an ethoxy group, an n-propoxy group, an n-butoxy group and the like are preferable.

The alkoxycarbonyl group of R₁₃ and R₁₄ is linear or branched, and preferably has 2 to carbon atoms, and a methoxycarbonyl group, an ethoxycarbonyl group, an n-butoxycarbonyl group, and the like are preferable.

Examples of the cycloalkyl group- of R₁₃ and R₁₄ include monocyclic or polycyclic cycloalkyl groups (preferably a cycloalkyl group having 3 to 20 carbon atoms) such as a monocyclic or polycyclic cycloalkyloxy group and an alkoxy group having a monocyclic or polycyclic cycloalkyl group. These groups may further have a substituent.

The monocyclic or polycyclic cycloalkyloxy group of R₁₃ and R₁₄ preferably has 7 or more carbon atoms in total, and more preferably has 7 to 15 carbon atoms in total, and preferably have a monocyclic cycloalkyl group. Examples of the monocyclic cycloalkyloxy group having 7 or more carbon atoms in total include a cycloalkyloxy group such as a cyclopropyloxy group, a cyclobutyloxy group, a cyclopentyloxy group, a cyclohexyloxy group, a cycloheptyloxy group, a cyclooctyloxy group, a cyclododecanyloxy group or the like which arbitrarily has a substituent including an alkyl group such as a methyl group, an ethyl group, a propyl group, a butyl group, a pentyl group, a hexyl group, a heptyl group, an octyl group, a dodecyl group, a 2-ethylhexyl group, an isopropyl group, a sec-butyl group, a t-butyl group or an iso-amyl group; a hydroxyl group; a halogen atom (fluorine, chlorine, bromine or iodine); a nitro group; a cyano group; an amide group; a sulfonamide group; an alkoxy group such as a methoxy group, an ethoxy group, a hydroxyethoxy group, a propoxy group, a hydroxypropoxy group, a butoxy group or the like; an alkoxycarbonyl group such as a methoxycarbonyl group, an ethoxycarbonyl group, or the like; an acyl group such as a formyl group, an acetyl group, a benzoyl group or the like; an acyloxy group such as an acetoxy group, a butyryloxy group or the like; a carboxy group or the like. The total number of the carbon atoms of the monocyclic or polycyclic cycloalkyloxy group is 7 or more including an arbitrary substituent on the cycloalkyl group.

Examples of the polycyclic cycloalkyloxy group having 7 or more carbon atoms in total include a norbornyloxy group, a tricyclodecanyloxy group, a tetracyclodecanyloxy group, an adamantyloxy group and the like.

The alkoxy group of R₁₃ and R₁₄, which has a monocyclic or polycyclic cycloalkyl group, preferably has 7 or more carbon atoms in total, more preferably has 7 to 15 carbon atoms in total, and is preferably an alkoxy group having a monocyclic cycloalkyl group. The alkoxy group which has 7 or more carbon atoms in total and has a monocyclic cycloalkyl group is a group which is obtained by substituting a monocyclic cycloalkyl group which may have the substituent described above with an alkoxy group such as methoxy, ethoxy, propoxy, butoxy, pentyloxy, hexyloxy, heptoxy, octyloxy, dodecyloxy, 2-ethylhexyloxy, isopropoxy, sec-butoxy, t-butoxy, or iso-amyloxy. There are 7 or more carbon atoms in the alkoxy group in total including the substituent. Examples of the alkoxy group include a cyclohexyl methoxy group, a cyclopentyl ethoxy group, a cyclohexyl ethoxy group and the like, and among these a cyclohexyl methoxy group is preferable.

Examples of the alkoxy group having a polycyclic cycloalkyl group which has 7 or more carbon atoms in total include a norbornyl methoxy group, a norbornyl ethoxy group, a tricyclodecanyl methoxy group, a tricyclodecanyl ethoxy group, a tetracyclodecanyl methoxy group, a tetracyclodecanyl ethoxy group, an adamantyl methoxy group, an adamantyl ethoxy group and the like, and a norbornyl methoxy group, a norbornyl ethoxy group, and the like are preferable.

Examples of the alkyl group of the alkylcarbonyl group of R₁₄ include the same specific examples as the alkyl group represented by R₁₃ to R₁₅ described above.

The alkylsulfonyl group and cycloalkylsulfonyl group of R₁₄ are preferably linear, branched, or cyclic, and preferably have 1 to 10 carbon atoms. As the alkylsulfonyl group and cycloalkylsulfonyl group, for example, a methanesulfonyl group, an ethanesulfonyl group, an n-propanesulfonyl group, an n-butanesulfonyl group, a cyclopentanesulfonyl group, a cyclohexanesulfonyl group and the like are preferable.

Examples of the substituent that the respective groups described above may have include a halogen atom (for example, a fluorine atom), a hydroxyl group, a carboxyl group, a cyano group, a nitro group, an alkoxy group, an alkoxyalkyl group, an alkoxycarbonyl group, an alkoxycarbonyloxy group and the like.

Examples of the alkoxy group include linear, branched, or cyclic alkoxy groups having 1 to 20 carbon atoms, such as a methoxy group, an ethoxy group, an n-propoxy group, an i-propoxy group, an n-butoxy group, a 2-methylpropoxy group, a 1-methylpropoxy group, a t-butoxy group, a cyclopentyloxy group, and a cyclohexyloxy group.

Examples of the alkoxyalkyl group include linear, branched, or cyclic alkoxyalkyl groups having 2 to 21 carbon atoms, such as a methoxymethyl group, an ethoxymethyl group, a 1-methoxyethyl group, a 2-methoxyethyl group, a 1-ethoxyethyl group, and a 2-ethoxyethyl group.

Examples of the alkoxycarbonyl group include linear, branched, or cyclic alkoxycarbonyl groups having 2 to 21 carbon atoms, such as a methoxycarbonyl group, an ethoxycarbonyl group, an n-propoxycarbonyl group, an i-propoxycarbonyl group, an n-butoxycarbonyl group, a 2-methylpropoxycarbonyl group, a 1-methylpropoxycarbonyl group, a t-butoxycarbonyl group, a cyclopentyloxycarbonyl group and a cyclohexyloxycarbonyl group.

Examples of the alkoxycarbonyloxy group include linear, branched; or cyclic alkoxycarbonyloxy groups having 2 to 21 carbon atoms, such as a methoxycarbonyloxy group, an ethoxycarbonyloxy group, an n-propoxycarbonyloxy group, an i-propoxycarbonyloxy group, an n-butoxycarbonyloxy group, a t-butoxycarbonyloxy group, a cyclopentyloxycarbonyloxy group and a cyclohexyloxycarbonyloxy group.

The ring structure that two R₁₅'s may form by bonding to each other is preferably a 5- or 6-membered ring which two divalent R₁₅ forms with a sulfur atom in the general formula (ZI-4), and particularly preferably a 5-membered ring (that is, a tetrahydrothiophene ring) together with a sulfur atom in the general formula (ZI-4). The ring structure may be condensed with an aryl group or a cycloalkyl group. The divalent R₁₅ may have a substituent, and examples of the substituent include a hydroxyl group, a carboxyl group, a cyano group, a nitro group, an alkyl group, a cycloalkyl group, an alkoxy group, an alkoxyalkyl group, an alkoxycarbonyl group, an alkoxycarbonyloxy group and the like. There may be a plurality of substituents for the ring structure, and these substituents may form a ring (an aromatic or non-aromatic hydrocarbon ring, an aromatic or non-aromatic hetero ring, and a polycyclic condensed ring formed of a combination of two or more of these rings) by bonding to each other.

R₁₅ in the general formula (ZI-4) is preferably a methyl group, an ethyl group, a naphthyl group, a divalent group in which two R₁₅'s bond to each other and form a tetrahydrothiophene ring structure together with a sulfur atom, and the like.

The substituent that R₁₃ and R₁₄ may have is preferably a hydroxyl group, an alkoxy group, an alkoxycarbonyl group, or a halogen atom (particularly, a fluorine atom).

is preferably 0 or 1, and more preferably 1.

r is preferably 0 to 2.

Specific examples of the cation of the composition represented by the general formula (ZI-4) in the present invention are shown below.

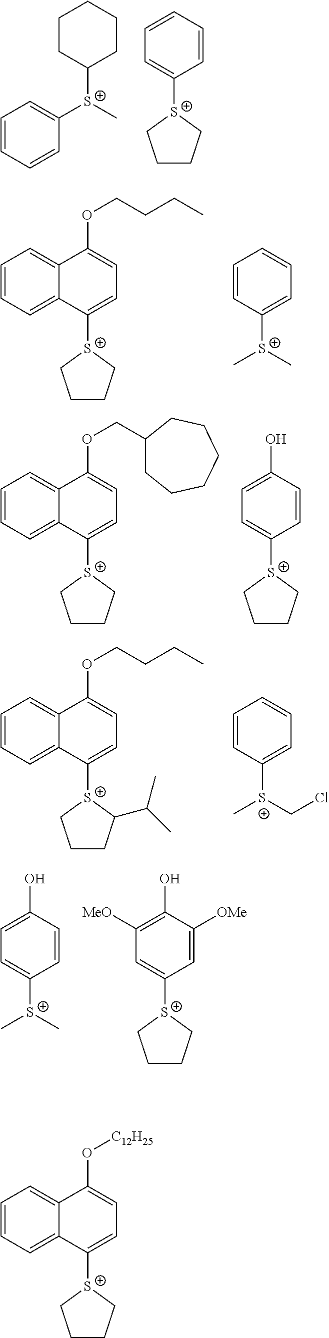

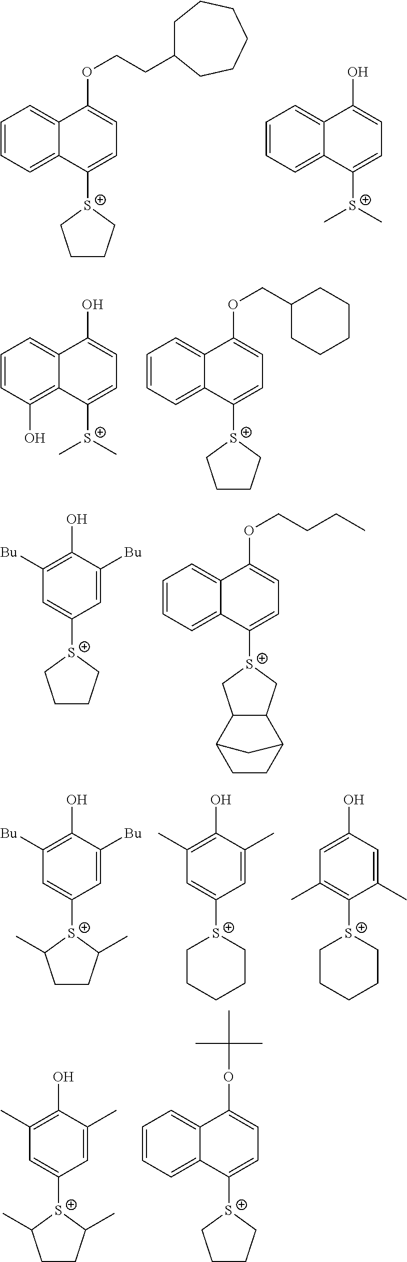

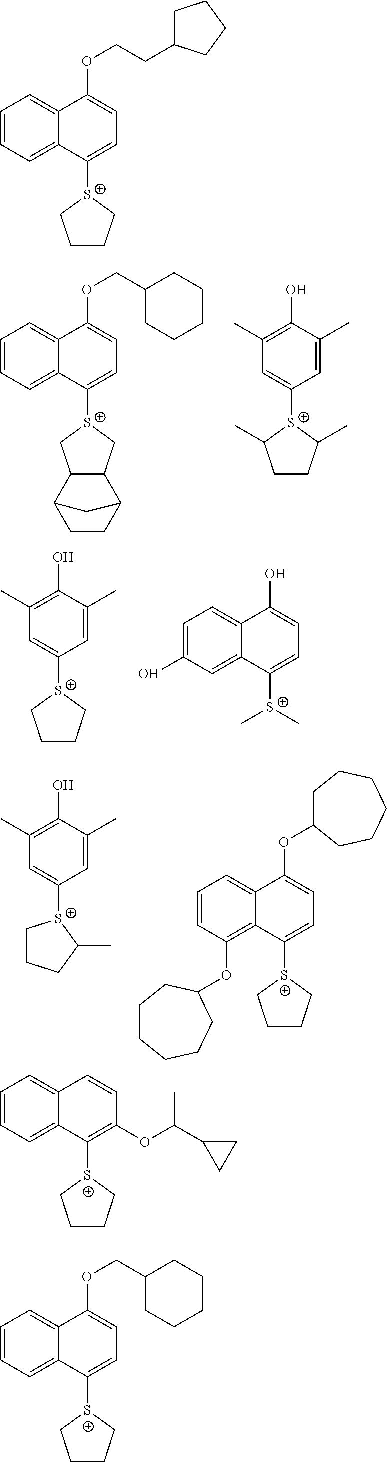

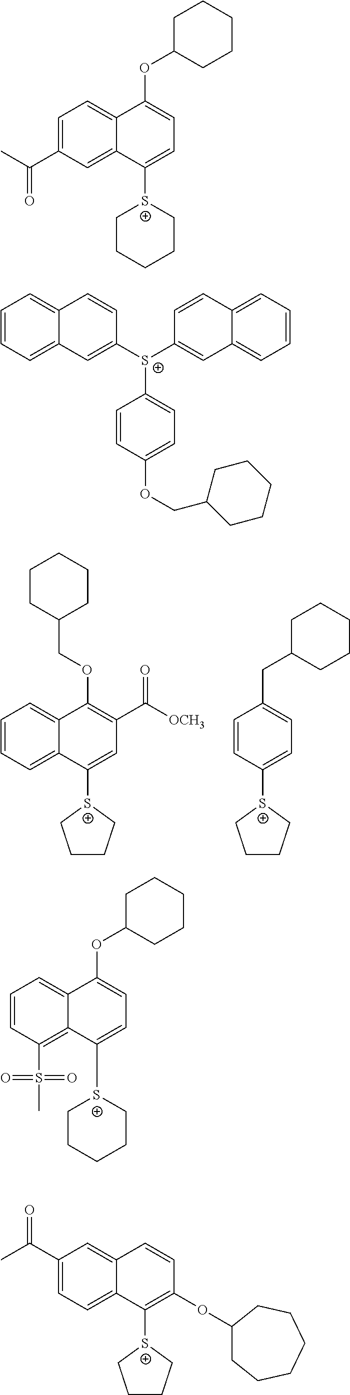

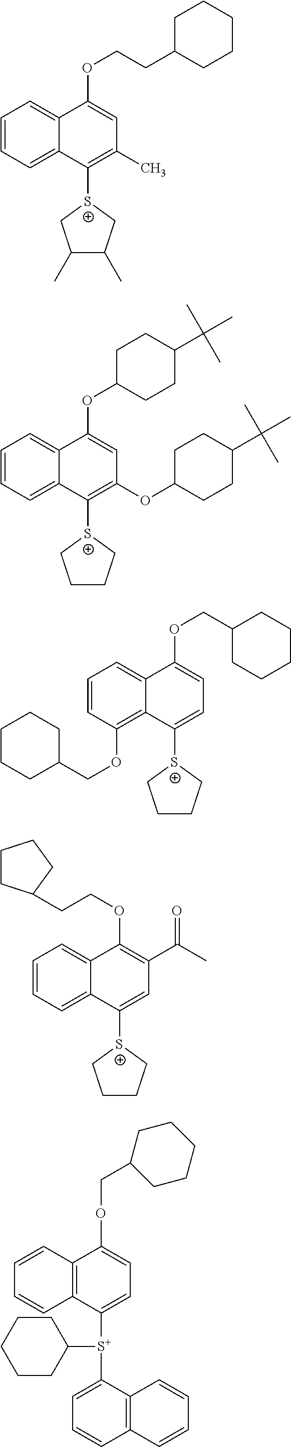

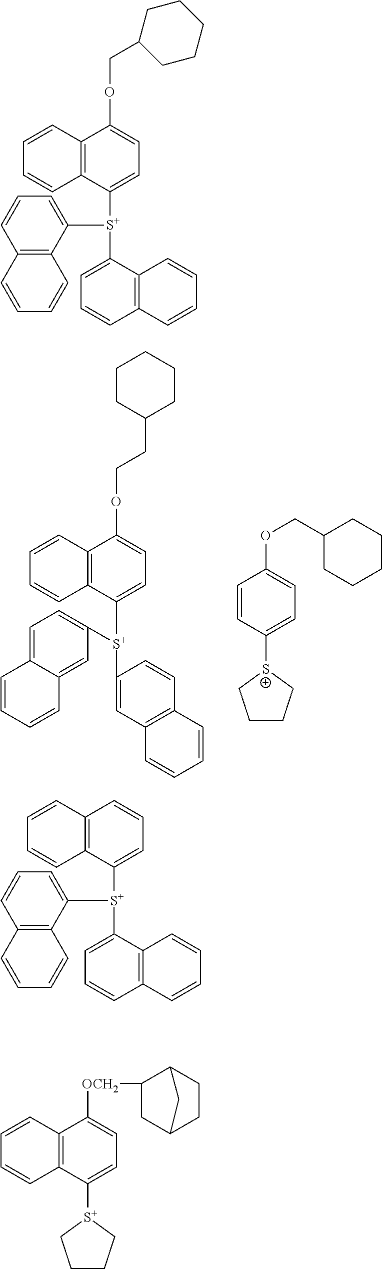

Next, the general formula (ZII) are described.

Each of R₂₀₄ and R₂₀₅ in the general formula (ZII) independently represents an aryl group, an alkyl group or a cycloalkyl group.

The aryl group of R₂₀₄ and R₂₀₅ is preferably a phenyl group or a naphthyl group, and more preferably a phenyl group. The aryl group of R₂₀₄ and R₂₀₅ may be an aryl group having a heterocyclic structure that includes an oxygen atom, a nitrogen atom, a sulfur atom or the like. Examples of the skeleton of the aryl group having a heterocyclic structure include pyrrole, furan, thiophene, indole, benzofuran, benzothiophene and the like.

Preferable examples of the alkyl group and cycloalkyl group of R₂₀₄ and R₂₀₅ include a linear or branched alkyl group having 1 to 10 carbon atoms (for example, a methyl group, an ethyl group, a propyl group, a butyl group and a pentyl group) and a cycloalkyl group having 3 to 10 carbon atoms (for example, a cyclopentyl group, a cyclohexyl group, or a norbornyl group).

The aryl group, alkyl group, and cycloalkyl group of R₂₀₄ and R₂₀₅ may have a substituent. Examples of the substituent which the aryl group, alkyl group, and cycloalkyl group of R₂₀₄ and R₂₀₅ may have include an alkyl group (having 1 to 15 carbon atoms, for example), a cycloalkyl group (having 3 to 15 carbon atoms, for example), an aryl group (having 6 to 15 carbon atoms, for example), an alkoxy group (having 1 to 15 carbon atoms, for example), a halogen atom, a hydroxyl group, a phenylthio group and the like.

Z⁻ represents an anionic structure of an acid represented by the general formula (I) (in other words an anion represented by the general formula (II).

Specific examples of the cation in the compound represented by the general formula (ZII) are shown.

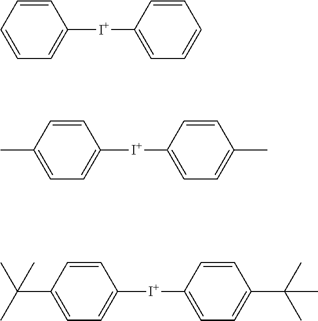

Specific examples of the compound (B) is shown below but the present invention is not limited thereto.

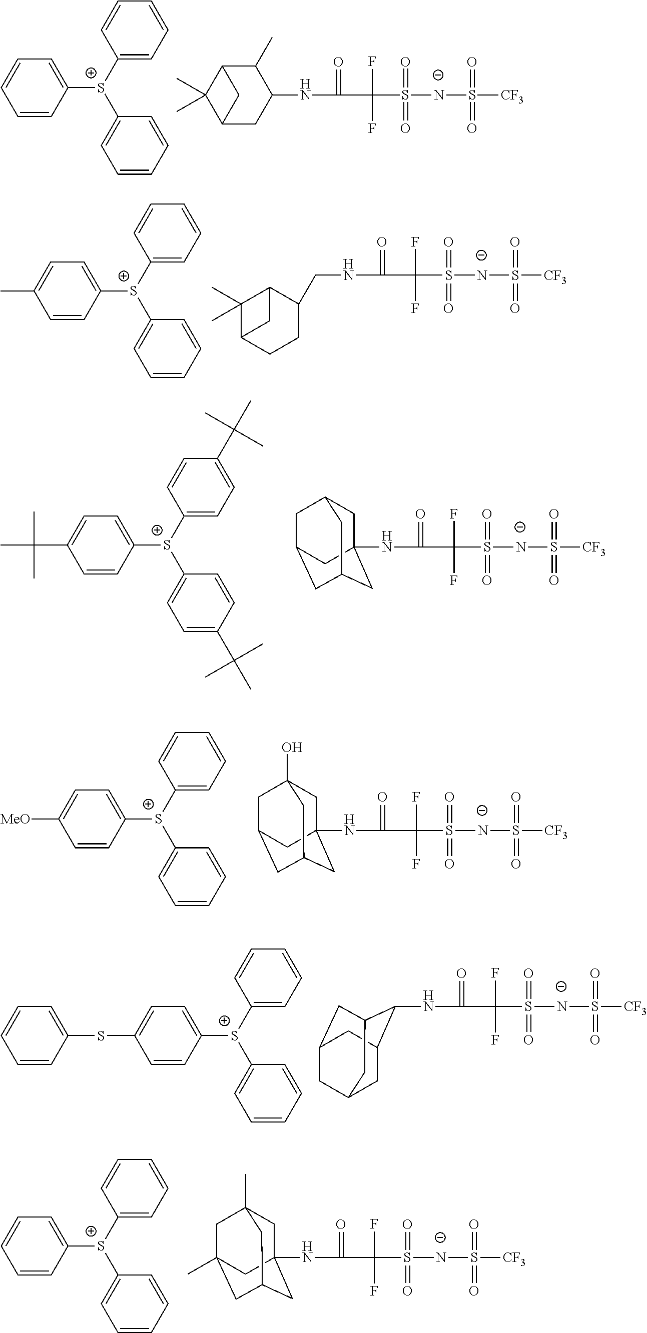

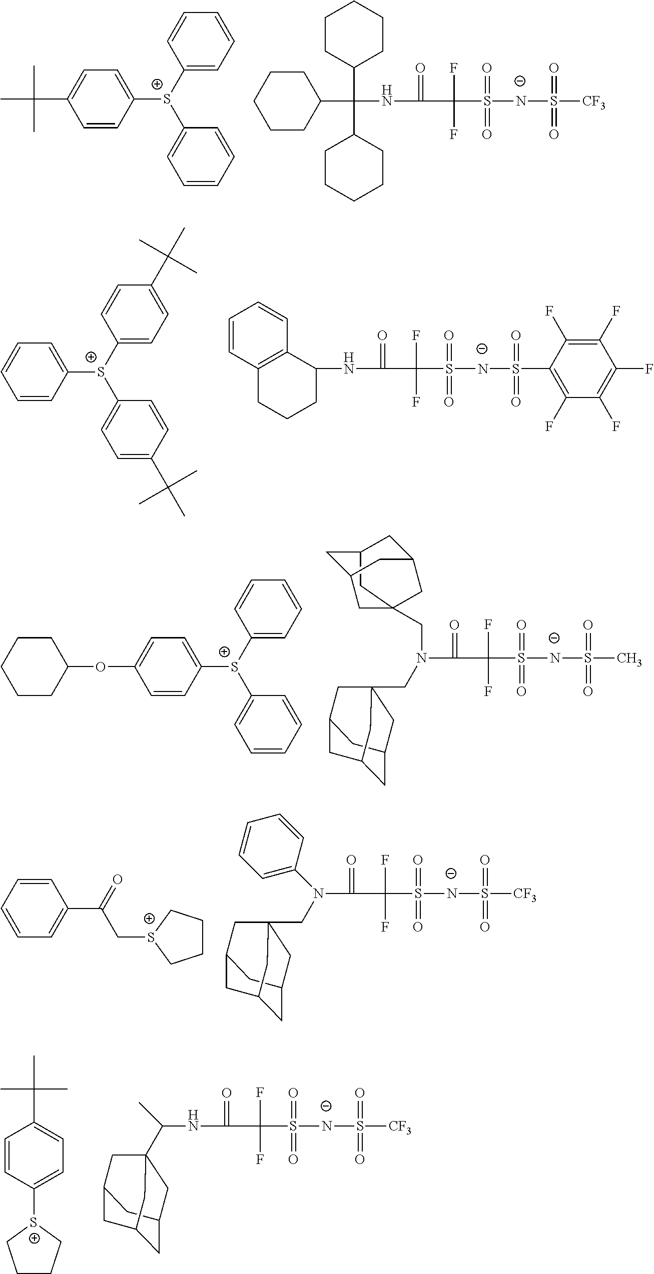

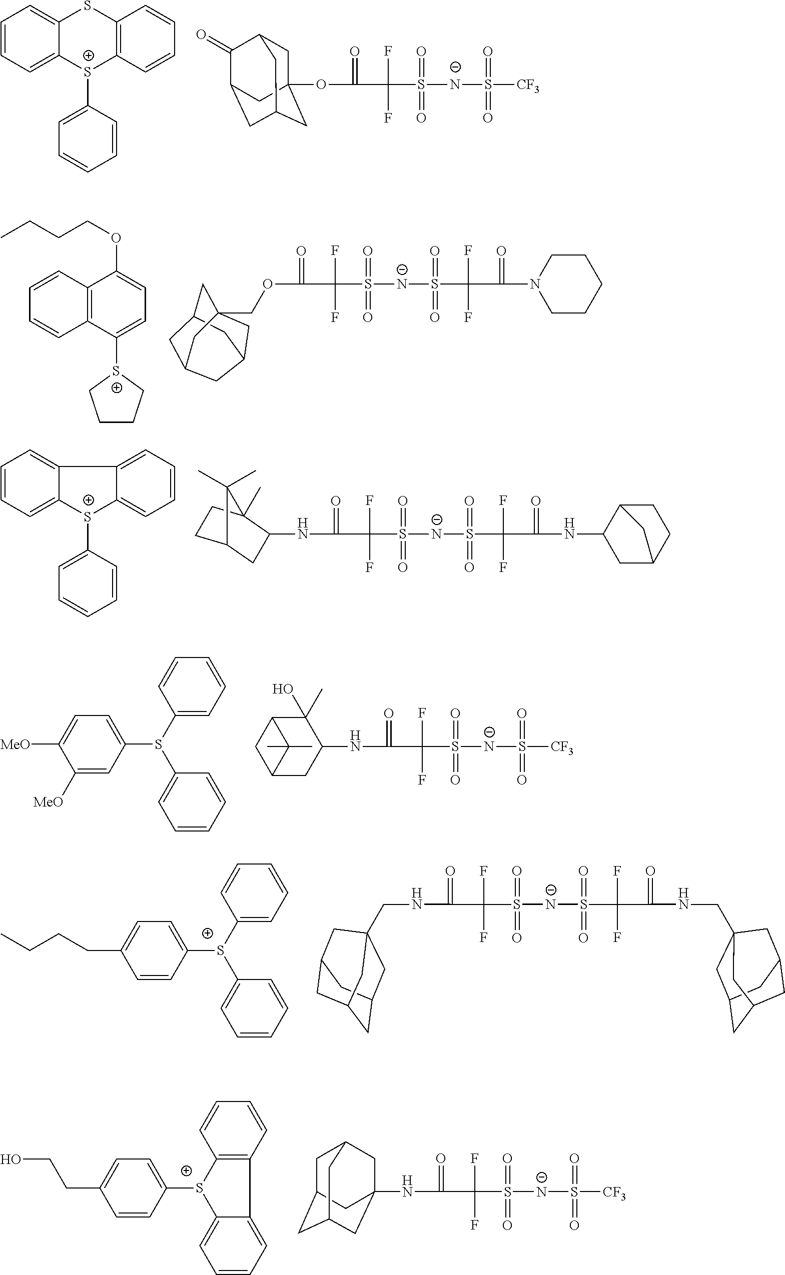

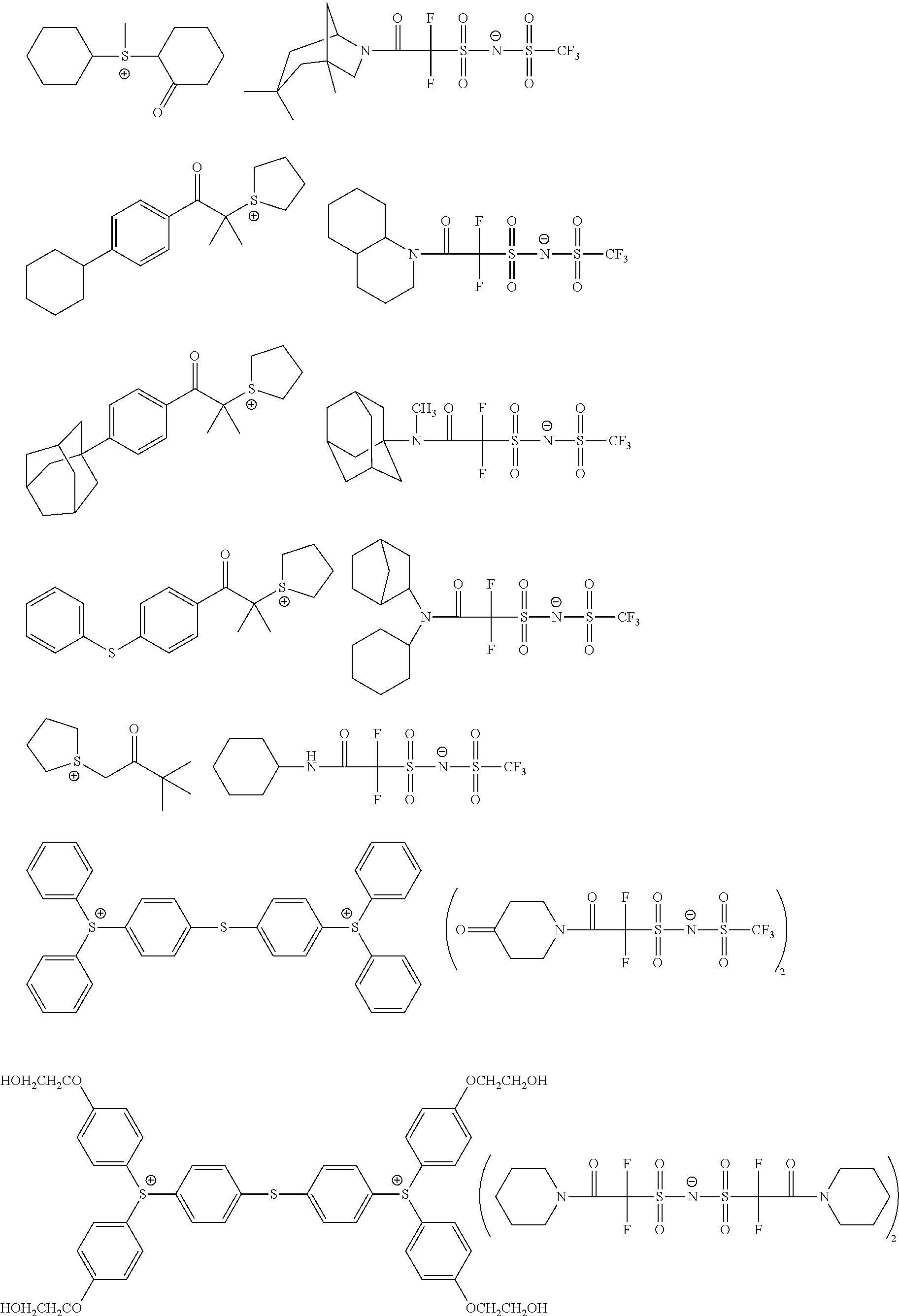

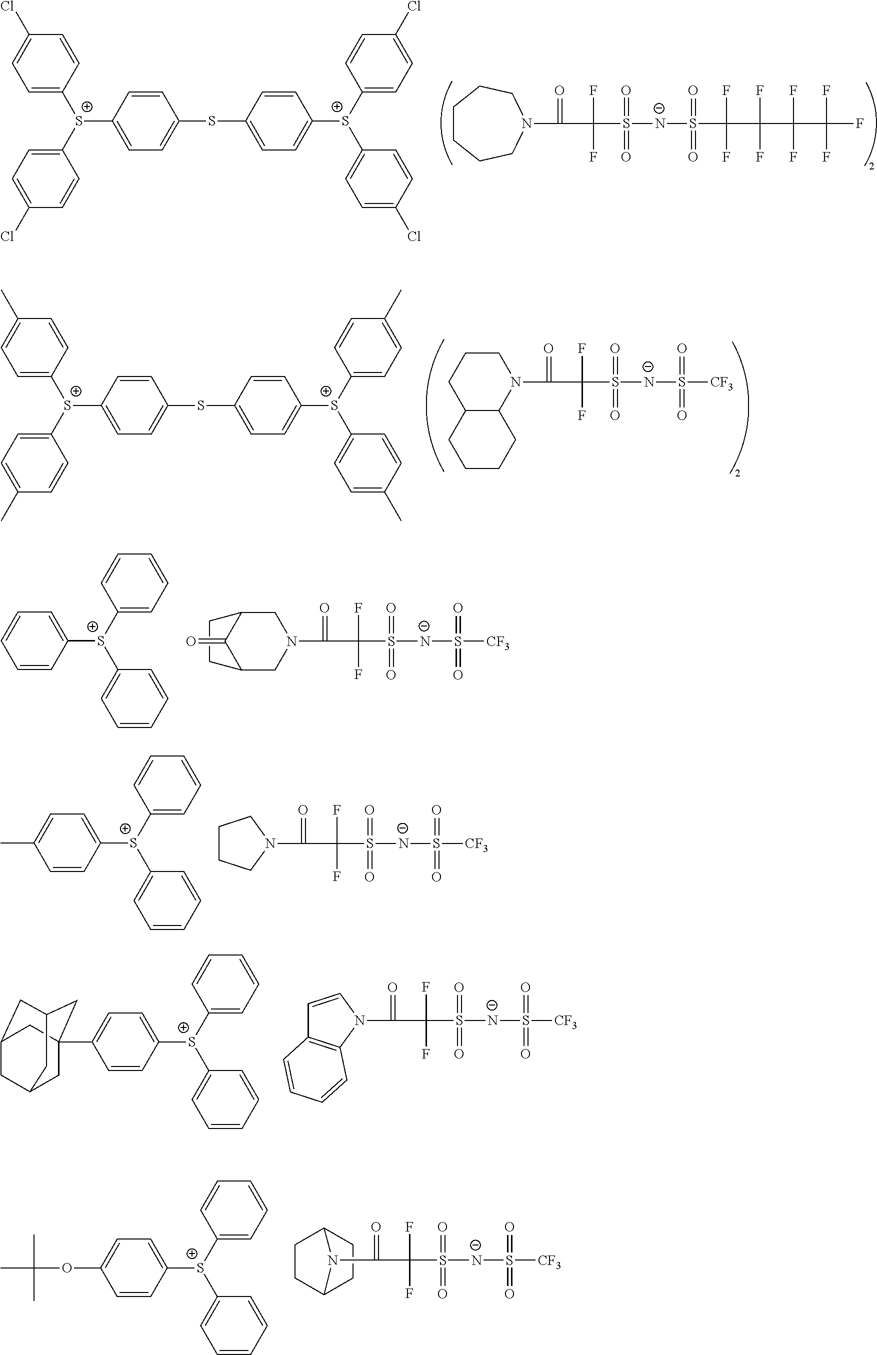

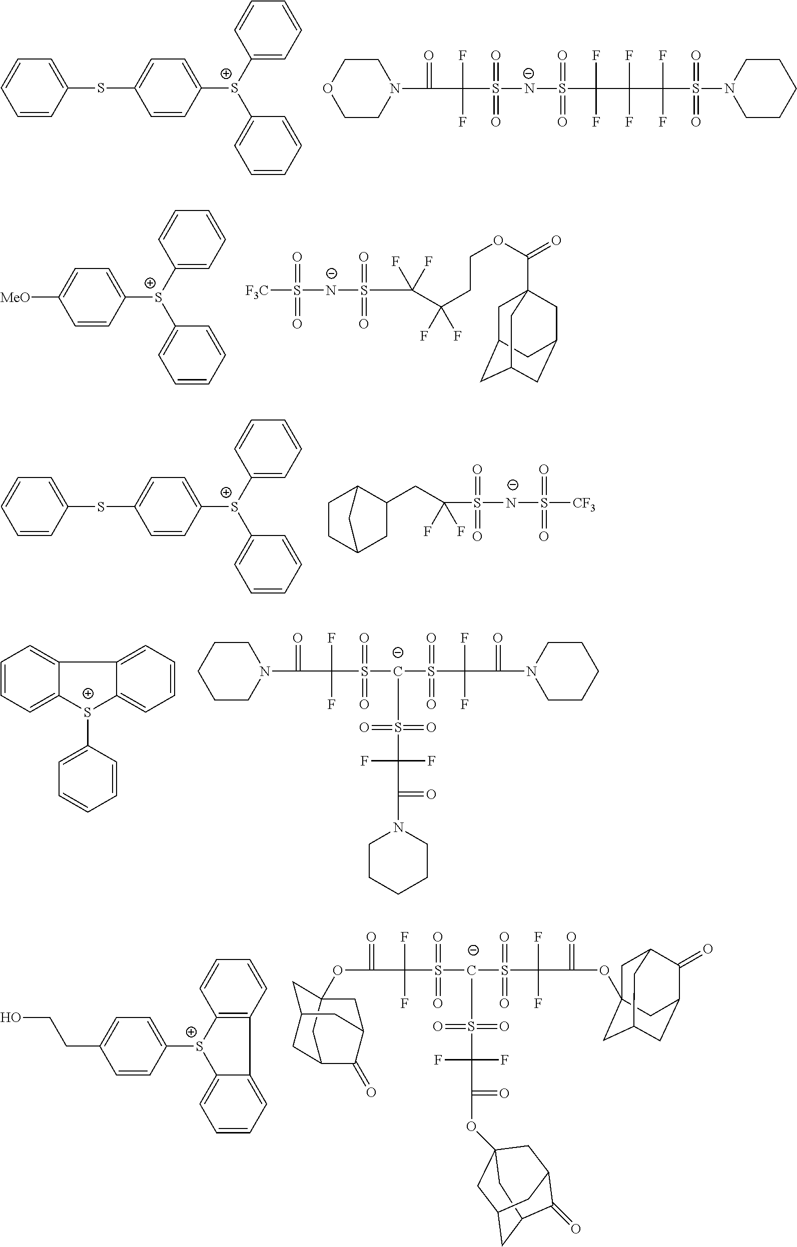

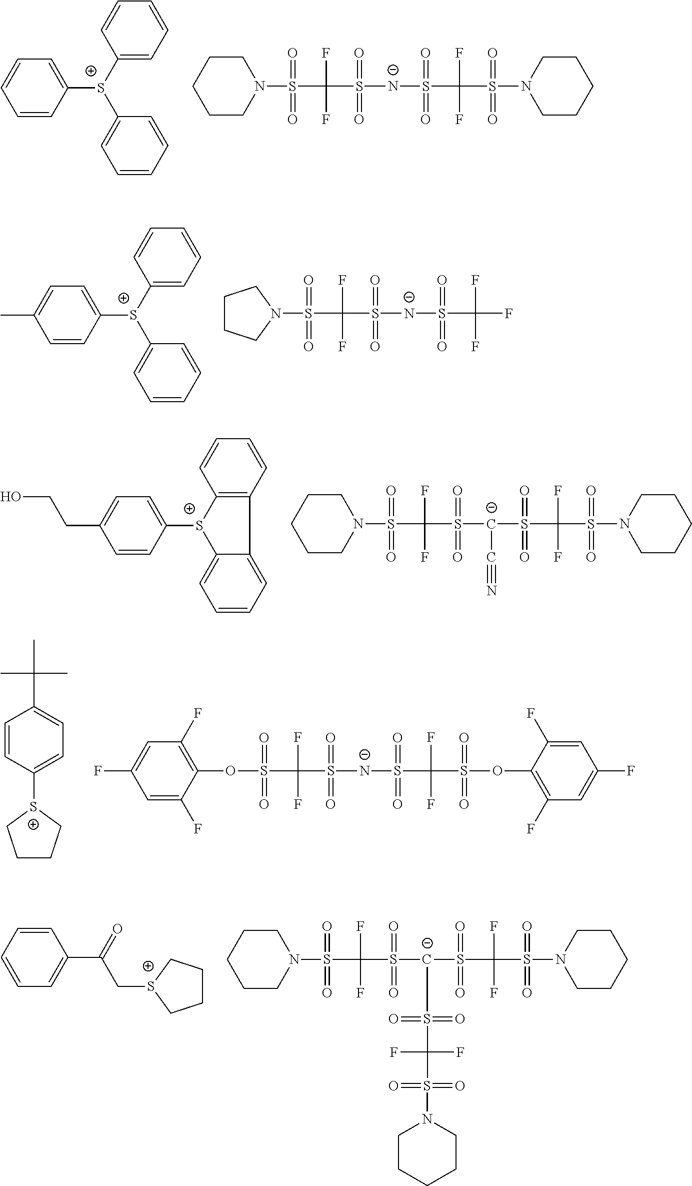

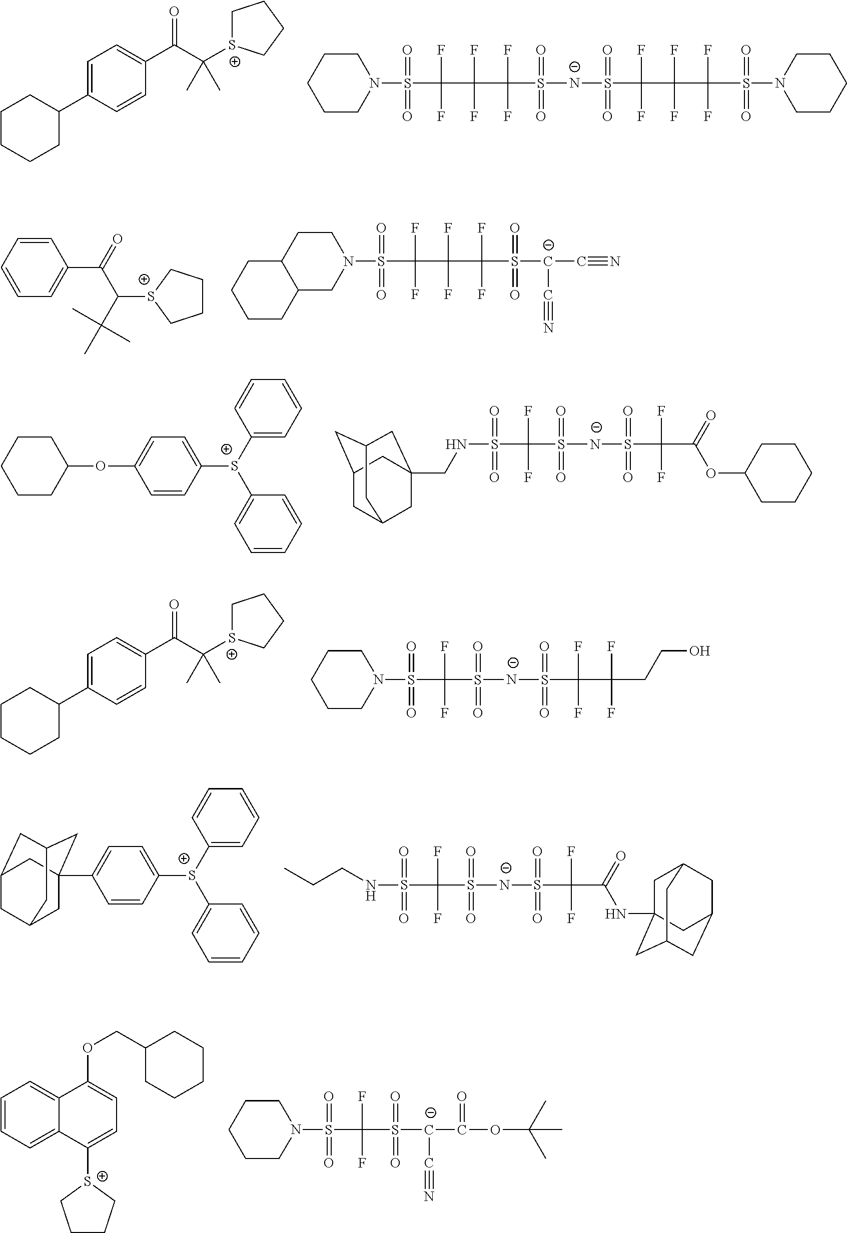

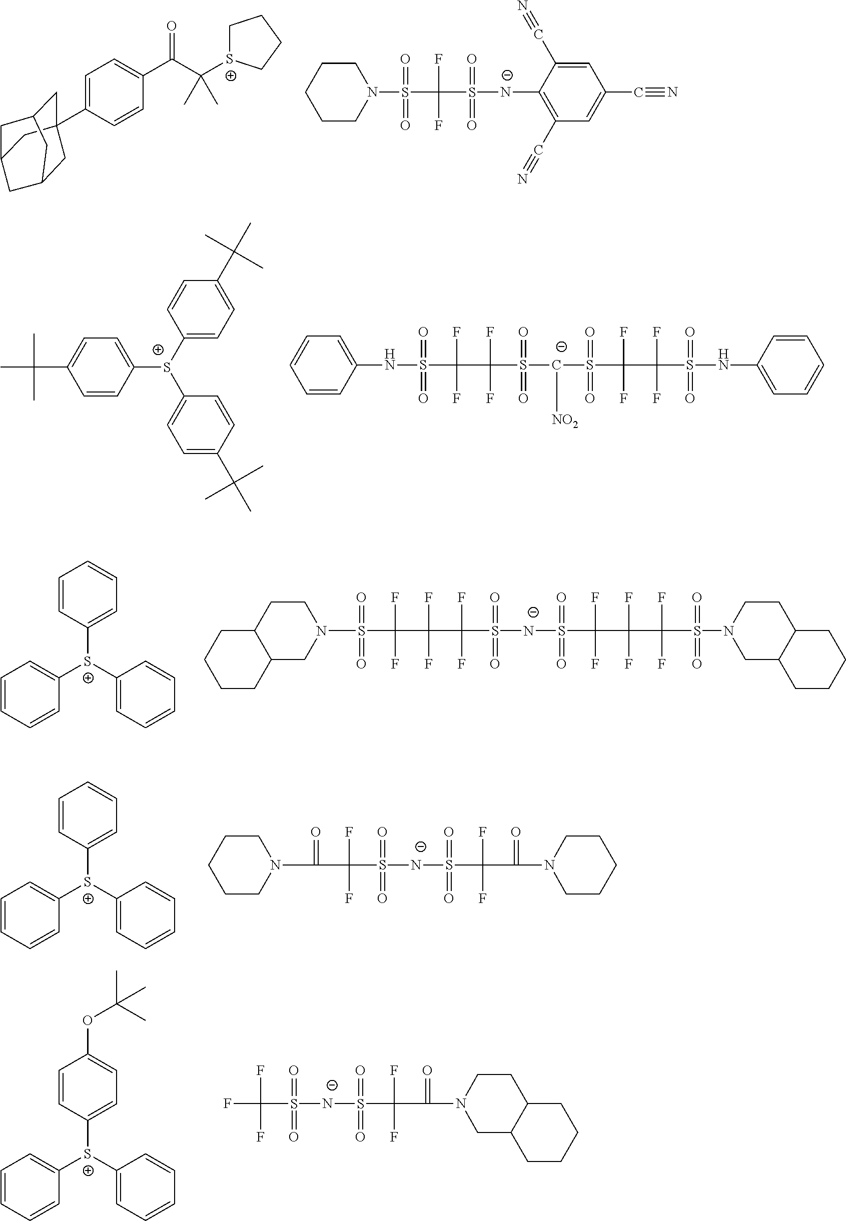

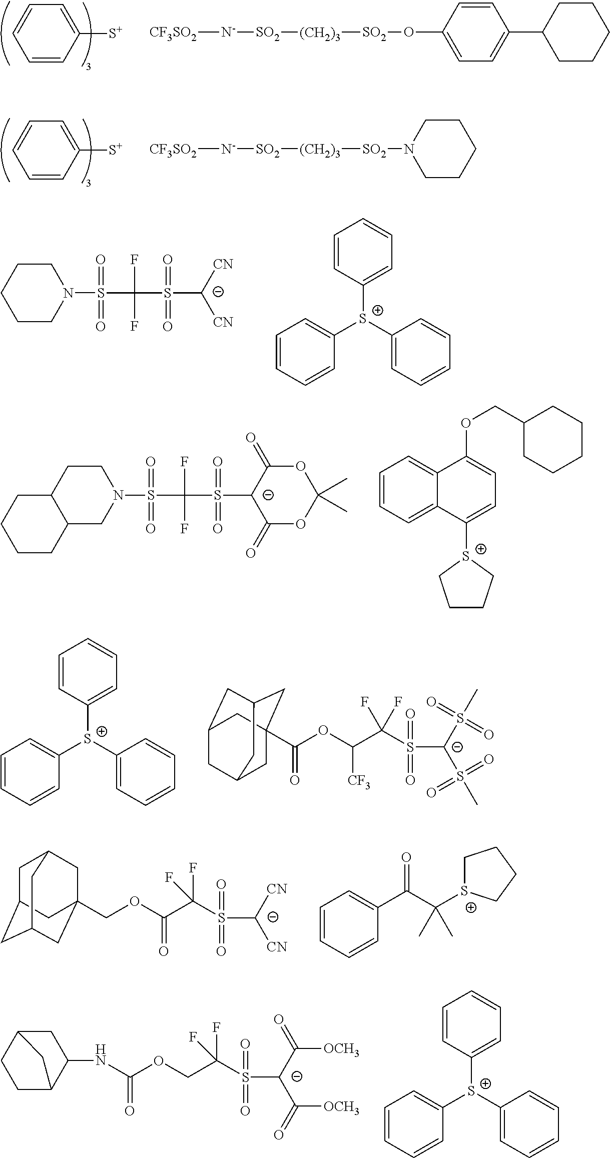

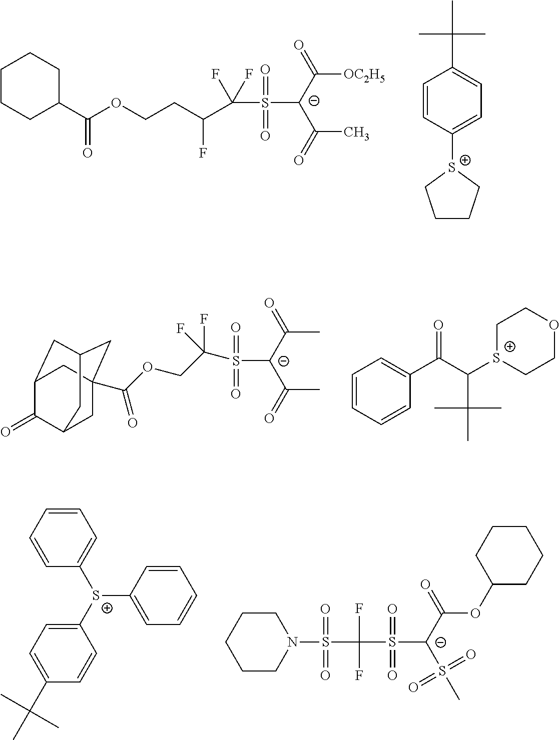 [SMILES: CCOC(=O)[C-](C(C)=O)S(=O)(=O)C(F)(F)C(F)CCOC(=O)C1CCCCC1 ; CC(C)(C)c1ccc([S+]2CCCC2)cc1 ; CC(=O)[C-](C(C)=O)S(=O)(=O)C(F)(F)COC(=O)C12CC3CC(C1)C(=O)C(C3)C2 ; CC(C)(C)C(C(=O)c1ccccc1)[S+]1CCOCC1 ; CC(C)(C)c1ccc([S+](c2ccccc2)c2ccccc2)cc1 ; CS(=O)(=O)[C-](C(=O)OC1CCCCC1)S(=O)(=O)C(F)(F)S(=O)(=O)N1CCCCC1]

The acid-generating agent can be synthesized based on well-known methods, for example, the method disclosed in JP2007-161707A.

The compound (B) may be used alone or in combination of two or more kinds thereof.

The content of the compound (B) in the resist composition is preferably 0.1 to 25% by mass, more preferably 1 to 20% by mass, even more preferably 3 to 19% by mass, and particularly more preferably 5 to 18% by mass, based on the total solid contents of the resist composition.

The compound (B) may be used in a combination with an acid-generating agent (hereinafter, also referred to as a compound (B′)) other than the compound (B).

Examples of the compound (B′) which may be used in a combination with the compound (B) include the acid-generating agent described in the paragraph 0150 in US2008/0248425A.

In addition, as the compound (B′) which may be used concurrently, a photocationic polymerization initiator, a photoradical polymerization initiator, a decolorizer of pigments, an optical discoloring agent, or a well-known compound which is used for a microresist or the like and generates an acid by irradiation with actinic rays or radiation and a mixture thereof can be appropriately selected and used.

Furthermore, a diazonium salt, a phosphonium salt, a sulfonium salt, an iodonium salt, an imidosulfonate, an oxime sulfonate, a diazodisulfone, a disulfone, and o-nitrobenzyl sulfonate may be used concurrently. A compound introduced by these groups or compounds which generate an acid by irradiation with actinic rays or radiation, to a main chain or a side chain of a polymer may be used. Examples thereof are compounds descried in U.S. Pat. No. 3,849,137A, DE3914407A, JP1988-26653A (JP-S63-26653A), JP1980-164824A (JP-S55-164824A), JP1987-69263A (JP-S62-69263A), JP1988-146038A (JP-S63-146038A), JP1988-163452A (JP-S63-163452A), JP1987-153853A (JP-S62-153853A), JP1988-146029A (JP-S63-146029A) and the like.

In addition, a compound which is described in U.S. Pat. No. 3,779,778A, EP126712B and the like, which generates an acid by irradiation with light may be used. Preferable examples of the compounds as the compound (B′) include a compound represented by the following general formulae (ZI′), (ZII′) and (ZIII′).

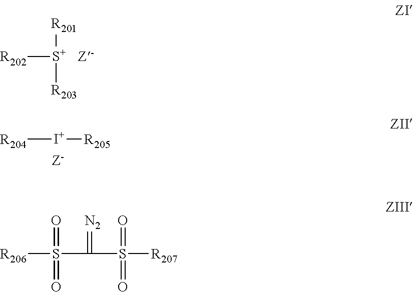

In the general formula (ZI′),
each of R₂₀₁, R₂₀₂, and R₂₀₃ has the same definition as the ones in the general formula (ZI), and
Z′⁻ represents a non-nucleophilic anion having a structure other than the anionic structure of the acid represented by the above general formula (I).

Examples of the non-nucleophilic anion represented by include a sulfonic acid anion, a carboxylic acid anion and the like.

The non-nucleophilic anion is an anion with a very low ability of causing a nucleophilic reaction, which is an anion that may inhibit temporal decomposition caused by an intra-molecular nucleophilic reaction. Due to this, the temporal stability of the resist composition is improved.

Examples of the sulfonic acid anion include an aliphatic sulfonic acid anion, an aromatic sulfonic acid anion, a camphorsulfonic acid anion and the like.

Examples of the carboxylic acid anion include an aliphatic carboxylic acid anion, an aromatic carboxylic acid anion, an aralkyl carboxylic acid anion and the like.

The aliphatic moiety in the aliphatic sulfonic acid anion may be an alkyl group or a cycloalkyl group, and is preferably an alkyl group having 1 to 30 carbon atoms and a cycloalkyl group having 3 to 30 carbon atoms. Examples thereof include a methyl group, an ethyl group, a propyl group, an isopropyl group, an n-butyl group, an isobutyl group, a sec-butyl group, a pentyl group, a neopentyl group, a hexyl group, a heptyl group, an octyl group, a nonyl group, a decyl group, an undecyl group, a dodecyl group, a tridecyl group, a tetradecyl group, a pentadecyl group, a hexadecyl group, a heptadecyl group, an octadecyl group, a nonadecyl group, an eicosyl group, a cyclopropyl group, a cyclopentyl group, a cyclohexyl group, an adamantyl group, a norbornyl group, a bornyl group and the like.

As the aromatic group in the aromatic sulfonic acid anion, an aryl group having 6 to 14 carbon atoms is preferable. Examples thereof include a phenyl group, a tolyl group, a naphthyl group, and the like.

The alkyl group, cycloalkyl group and aryl group in the aliphatic sulfonic acid anion and aromatic sulfonic acid anion may have a substituent. Examples of the substituent of the alkyl group, cycloalkyl group, and aryl group in the aliphatic sulfonic acid anion and aromatic sulfonic acid anion include a nitro group, a halogen atom (a fluorine atom, a chlorine atom, a bromine atom or an iodine atom), a carboxyl group, a hydroxyl group, an amino group, a cyano group, an alkoxy group (preferably having 1 to 15 carbon atoms), a cycloalkyl group (preferably having 3 to 15 carbon atoms), an aryl group (preferably having 6 to 14 carbon atoms), an alkoxycarbonyl group (preferably having 2 to 7 carbon atoms), an acyl group (preferably having 2 to 12 carbon atoms), an alkoxycarbonyloxy group (preferably having 2 to 7 carbon atoms), an alkylthio group (preferably having 1 to 15 carbon atoms), an alkylsulfonyl group (preferably having 1 to 15 carbon atoms), an alkyliminosulfonyl group (preferably having 2 to 15 carbon atoms), an aryloxysulfonyl group (preferably having 6 to 20 carbon atoms), an alkylaryloxy sulfonyl group (preferably having 7 to 20 carbon atoms), a cycloalkylaryloxy sulfonyl group (preferably having 10 to 20 carbon atoms), an alkyloxy alkyloxy group (preferably having 5 to 20 carbon atoms), a cycloalkylalkyloxy alkyloxy group (preferably having 8 to 20 carbon atoms) and the like. Regarding the aryl group and the ring structure of the respective groups, an alkyl group (preferably having 1 to 15 carbon atoms) may be further exemplified as a substituent.

Examples of the aliphatic moiety in the aliphatic carboxylic acid anion include the same alkyl group and cycloalkyl group of the examples of the aliphatic group in the aliphatic sulfonic acid anion.

Examples of the aromatic group in the aromatic carboxylic acid anion are the same aryl group of the aromatic group in the aromatic sulfonic acid anion.

The aralkyl group in the aralkylcarboxylic acid anion is preferably an aralkyl group having 7 to 12 carbon atoms, and examples thereof include a benzyl group, a phenethyl group, a naphthyl methyl group, a naphthyl ethyl group, a naphthyl butyl group and the like.

The alkyl group, cycloalkyl group, aryl group and aralkyl group in the aliphatic carboxylic acid anion, aromatic carboxylic acid anion and aralkyl carboxylic acid anion may have a substituent. Examples of the substituent of the alkyl group, cycloalkyl group, aryl group and aralkyl group in the aliphatic carboxylic acid anion, aromatic carboxylic acid anion and aralkyl carboxylic acid anion include the same halogen atom, alkyl group, cycloalkyl group, alkoxy group, alkylthio group and the like as those in the aromatic sulfonic acid anion.

As other non-nucleophilic anions, fluorophosphates, fluoroborates, fluoroantimonates, and the like can be exemplified.

As the non-nucleophilic anion of Z⁻, an aliphatic sulfonic acid anion in which an α-position of the sulfonic acid has been substituted with a fluorine atom and an aromatic sulfonic acid anion substituted with a fluorine atom or a group having a fluorine atom are preferable. The non-nucleophilic anion is more preferably a perfluoroaliphatic sulfonic acid anion having 4 to 8 carbon atoms or a benzenesulfonic acid anion having a fluorine atom, and even more preferably a nonafluorobutanesulfonic acid anion, a perfluorooctanesulfonic acid anion, a pentafluorobenzenesulfonic acid anion, or a 3,5-bis(trifluoromethyl)benzenesulfonic acid anion.

In addition, a compound having a plurality of the structures represented by the general formula (ZI′) may be used. For example, a compound having a structure in which at least one of R₂₀₁ to R₂₀₃ of the compound represented by the general formula (ZI′) bonds to at least one of R₂₀₁ to R₂₀₃ of another compound represented by the general formula (ZI′) may be used.

As more preferable (ZI′) components, the compounds (ZI-1′), (ZI-2′) and (ZI-3′) explained below can be exemplified.

The compound (ZI-1′) is an aryl sulfonium compound where at least one of R₂₀₁ to R₂₀₃ of the above general formula (ZI′) is an aryl group, that is, a compound having aryl sulfonium as a cation. R₂₀₁ to R₂₀₃ in the compound (ZI-1′) are the same as R₂₀₁ to R₂₀₃ in the above-mentioned compound (ZI-1).

Next, the compound (ZI-2′) is described.

The compound (ZI-2′) is a compound where each of R₂₀₁ to R₂₀₃ in Formula (ZI′) independently represents an organic group not having an aromatic ring. R₂₀₁ to R₂₀₃ in the compound (ZI-2′) are the same as R₂₀₁ to R₂₀₃ in the above-mentioned compound (ZI-2).

The compound (ZI-3′) is a compound represented by the following general formula (ZI-3′), which is a compound having a phenacyl sulfonium salt structure.

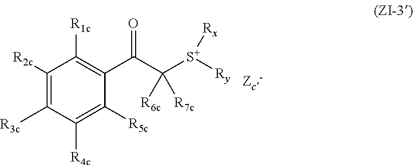

In the general formula (ZI-3′),
each of R_{1c} to R_{7c}, Rₓ and R_{y} has the same definition as the ones in the general formula (ZI-3).

Zc′⁻ represents a non-nucleophilic anion, and examples thereof include the same examples of the non-nucleophilic anion of Z′⁻ in the general formula (ZI′).

In the general formulae (ZII′) and (ZIII′),
each of R₂₀₄ to R₂₀₇ independently represents an aryl group, an alkyl group or a cycloalkyl group.

Examples of the aryl group of R₂₀₄ to R₂₀₇ include the same as the examples of the aryl group of R₂₀₄ and R₂₀₅ in the above general formula (ZII).

Examples of the alkyl group and the cycloalkyl group of R₂₀₄ to R₂₀₇ include the same as the examples of the alkyl group and the cycloalkyl group of R₂₀₄ and R₂₀₅ in the above general formula (ZII).

Z′⁻ represents a non-nucleophilic anion having a structure other than the anionic structure of the acid represented by the above general formula (I), and examples thereof include the same examples of the non-nucleophilic anion of Z′⁻ in the general formula (ZI′)

Further examples of the compound (B′) include compounds represented by the following general formulae (ZIV′), (ZV′) and (ZVI′).

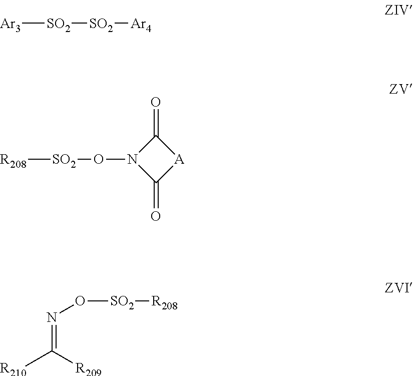

In the general formulae (ZIV′) to (ZVI′),
each of Ar₃ and Ar₄ independently represents an aryl group.

Each of R₂₀₈, R₂₀₉, and R₂₁₀ independently represents an alkyl group, a cycloalkyl group or an aryl group.

A represents an alkylene group, an alkenylene group, or an arylene group. [0399] Specific examples of the aryl group of Ar₃, Ar₄, R₂₀₈, R₂₀₉ and R₂₁₀ include the same ones as the specific examples of the aryl group represented by R₂₀₁, R₂₀₂ and R₂₀₃ in the general formula (ZI-1′).

Specific examples of the alkyl group and the cycloalkyl group of R₂₀₈, R₂₀₉ and R₂₁₀ include the same ones as the specific examples of the alkyl group and the cycloalkyl group represented by R₂₀₁, R₂₀₂ and R₂₀₃ in the general formula (ZI-2′).

Examples of the alkylene group of A include an alkylene group (for example, a methylene group, an ethylene group, a propylene group, an isopropylene group, a butylene group, an isobutylene group and the like) having 1 to 12 carbon atoms. Examples of the alkenylene group of A include an alkenylene group having 2 to 12 carbon atoms (for example, an ethynylene group, a propenylene group, a butenylene group and the like). Examples of the arylene group of A include an arylene group (for example, a phenylene group, a tolylene group, a naphthylene group and the like) having 6 to 10 carbon atoms.

Among the examples of the compound (B′), compounds represented by the general formulae (ZI′) to (ZIII′) are preferable.

The compound (B′) is preferably a compound which has one sulfonic acid group or an imide group and generates an acid; more preferably a compound which generates monovalent perfluoroalkane sulfonic acid, a compound which generates an aromatic sulfonic acid substituted with a monovalent fluorine atom or with a group containing a fluorine atom, or a compound generating an imidic acid substituted with a monovalent fluorine atom or with a group containing a fluorine atom; and even more preferably a sulfonium salt of a fluorine-substituted alkanesulfonic acid, a fluorine-substituted benzenesulfonic acid, a fluorine-substituted imidic acid, or a fluorine-substituted methidic acid. The usable acid-generating agent is particularly preferably a fluorine-substituted alkanesulfonic acid, a fluorine-substituted benzenesulfonic acid, or a fluorine-substituted imidic acid which generate an acid with pKa=−1 or less, and thereby sensitivity is increased.

Among the examples of the compound (B′), particularly preferable examples are shown below.

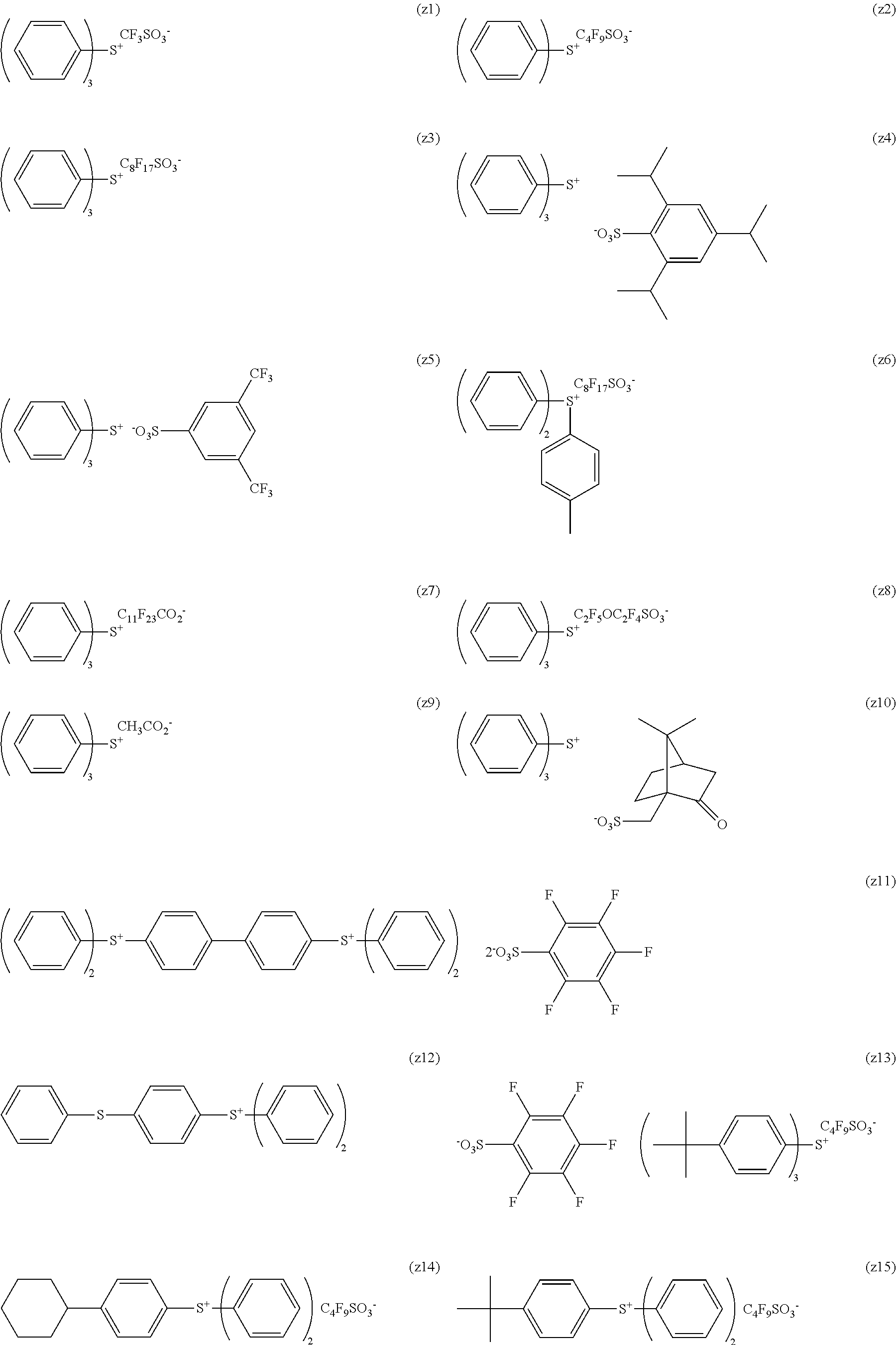

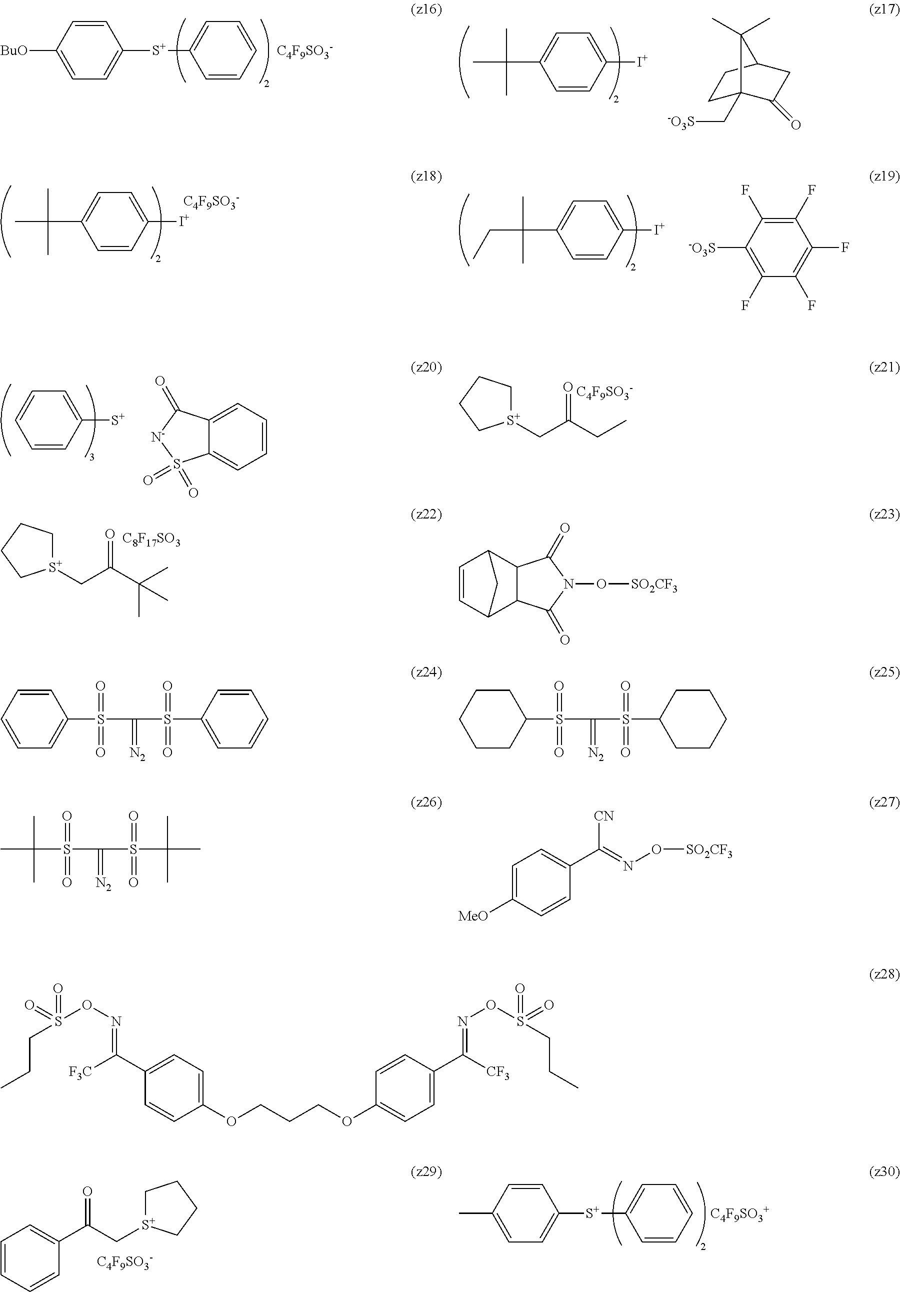

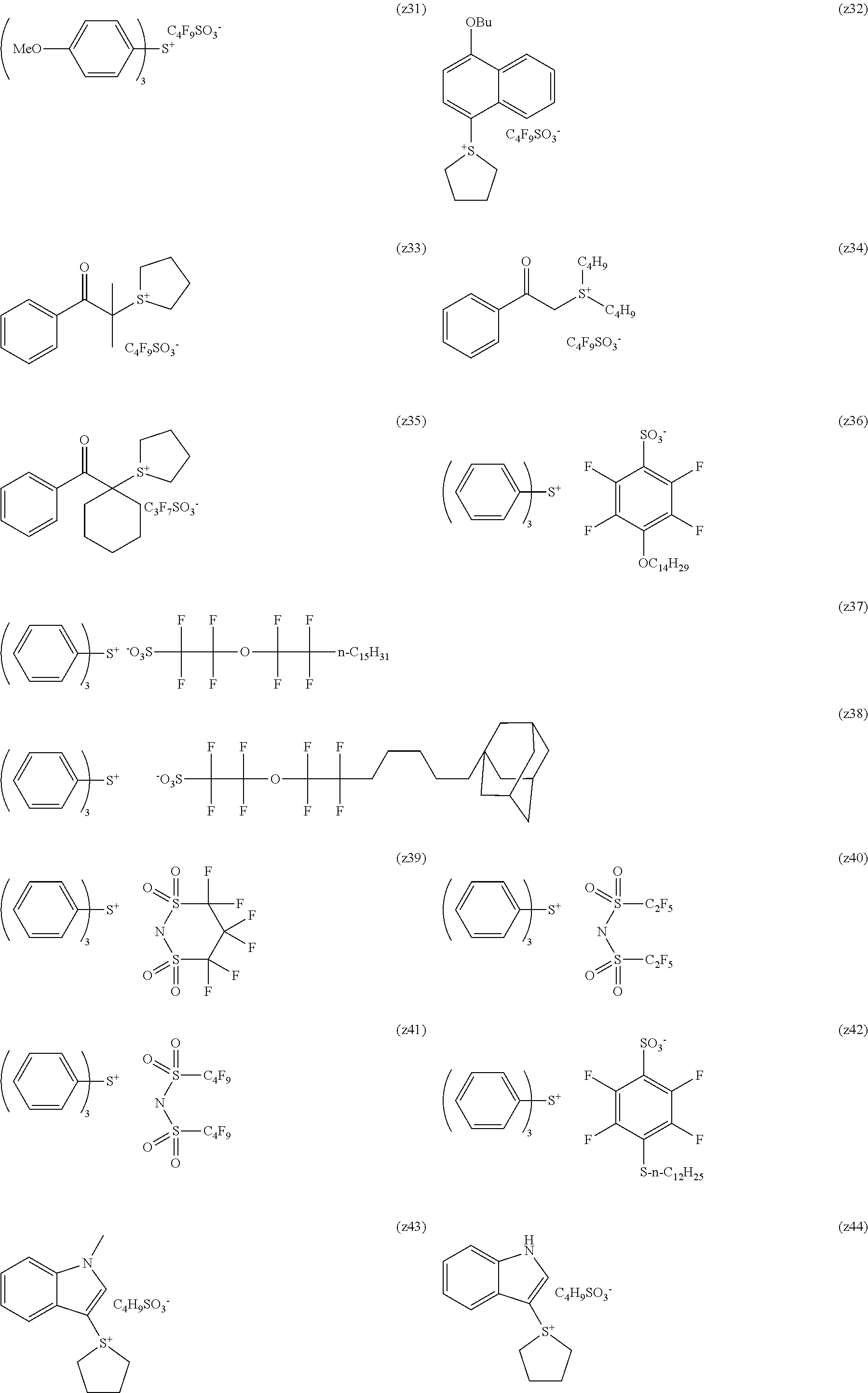

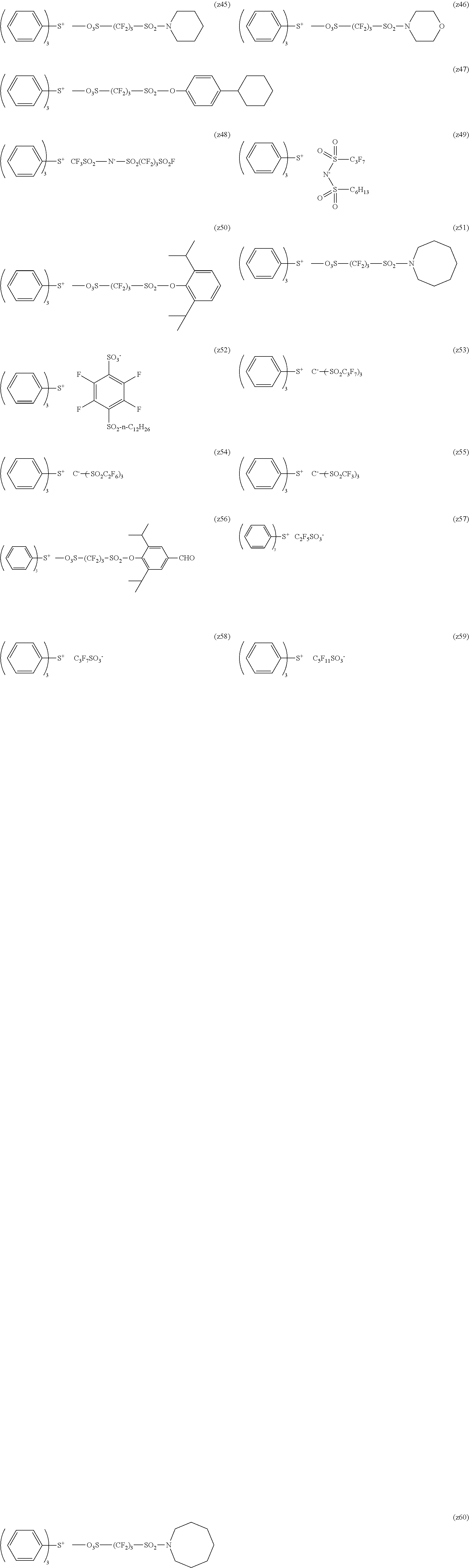

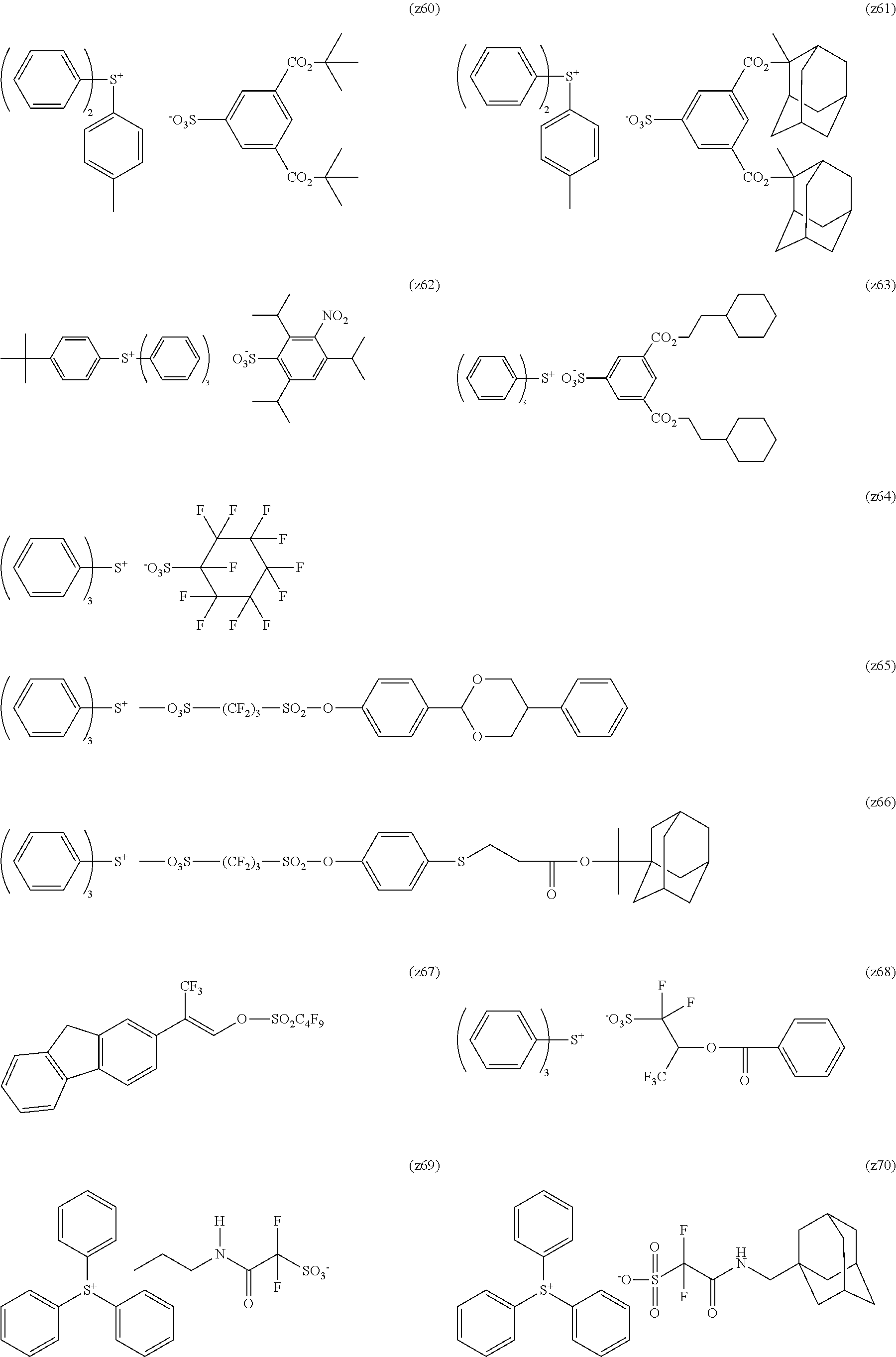

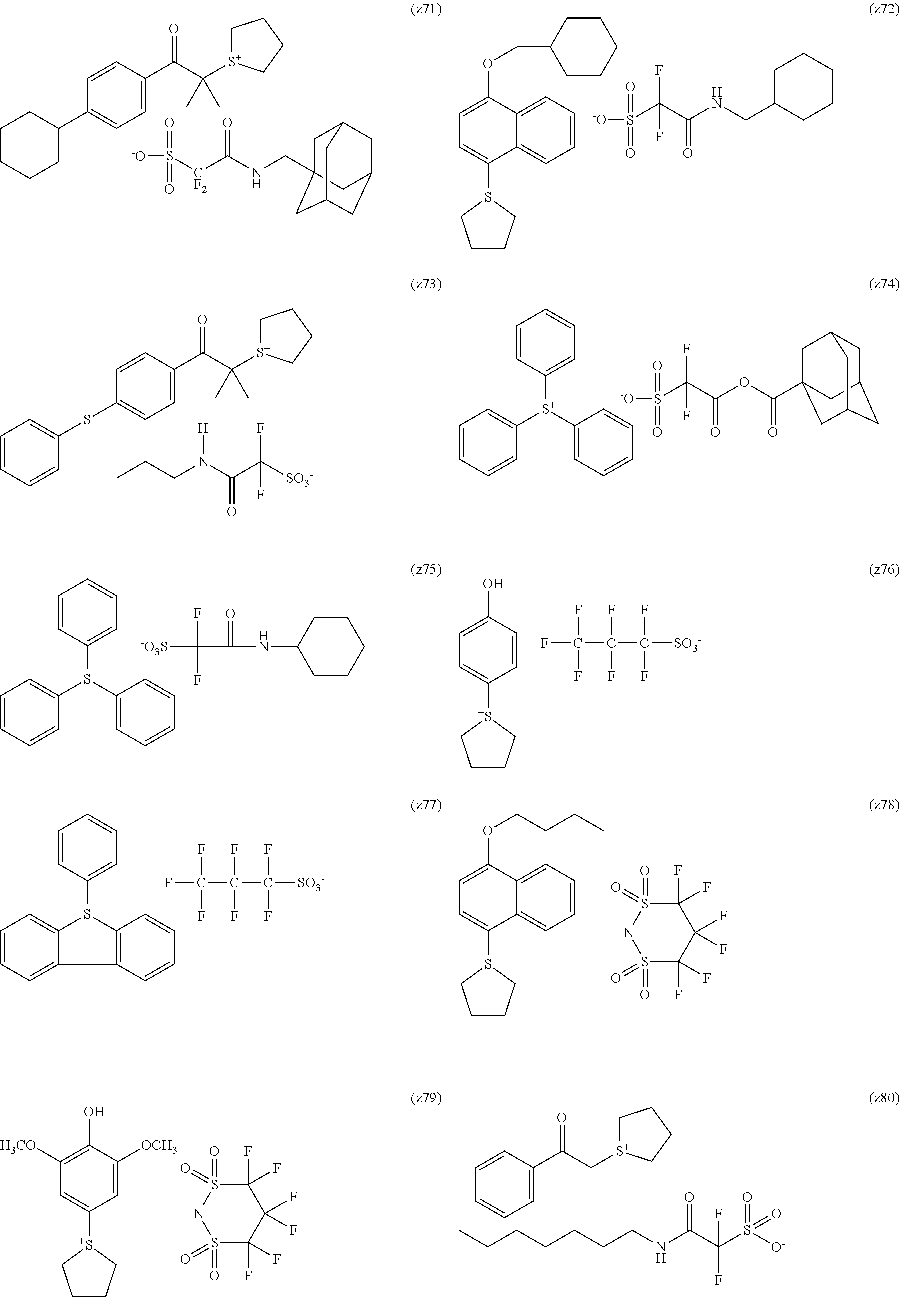

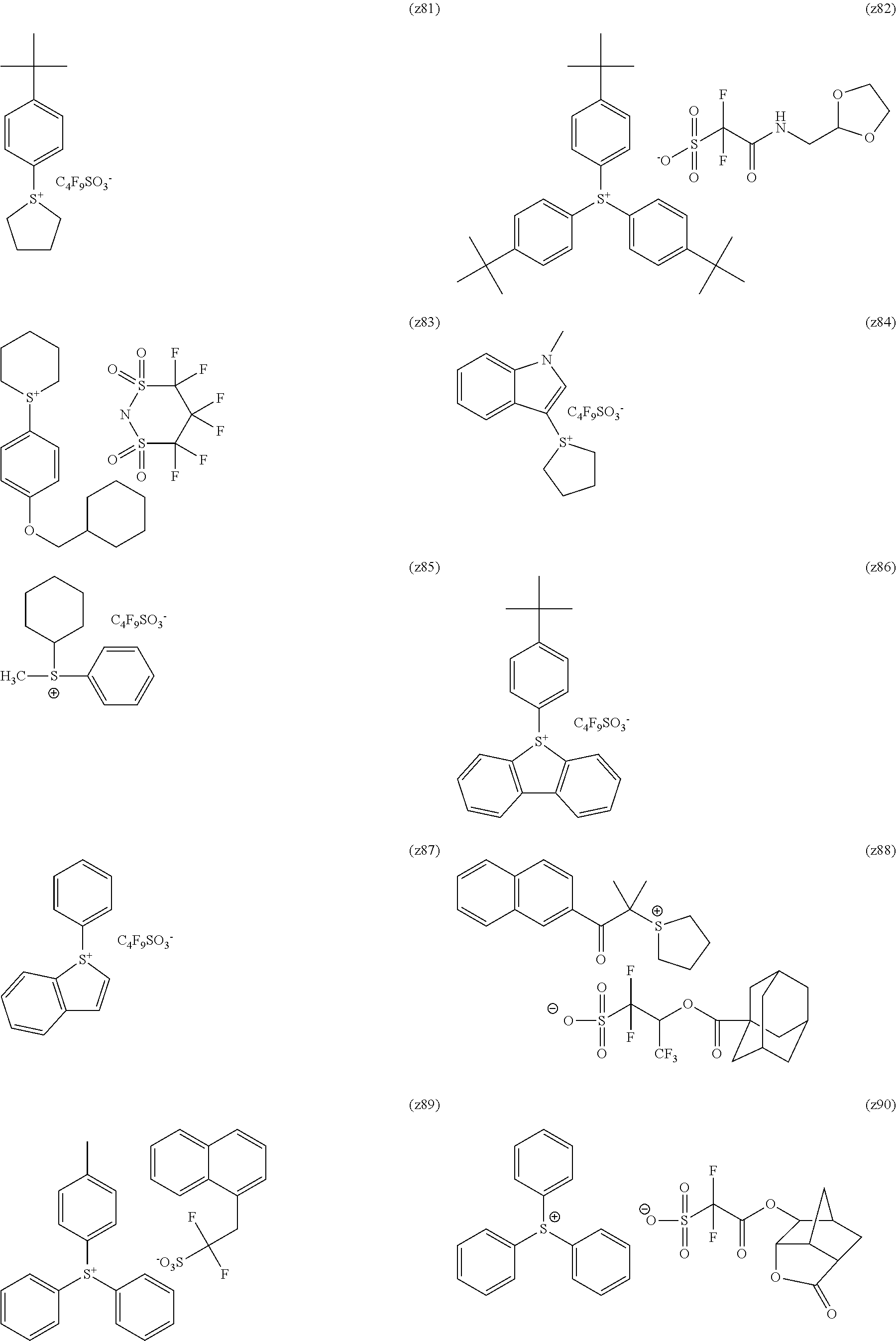

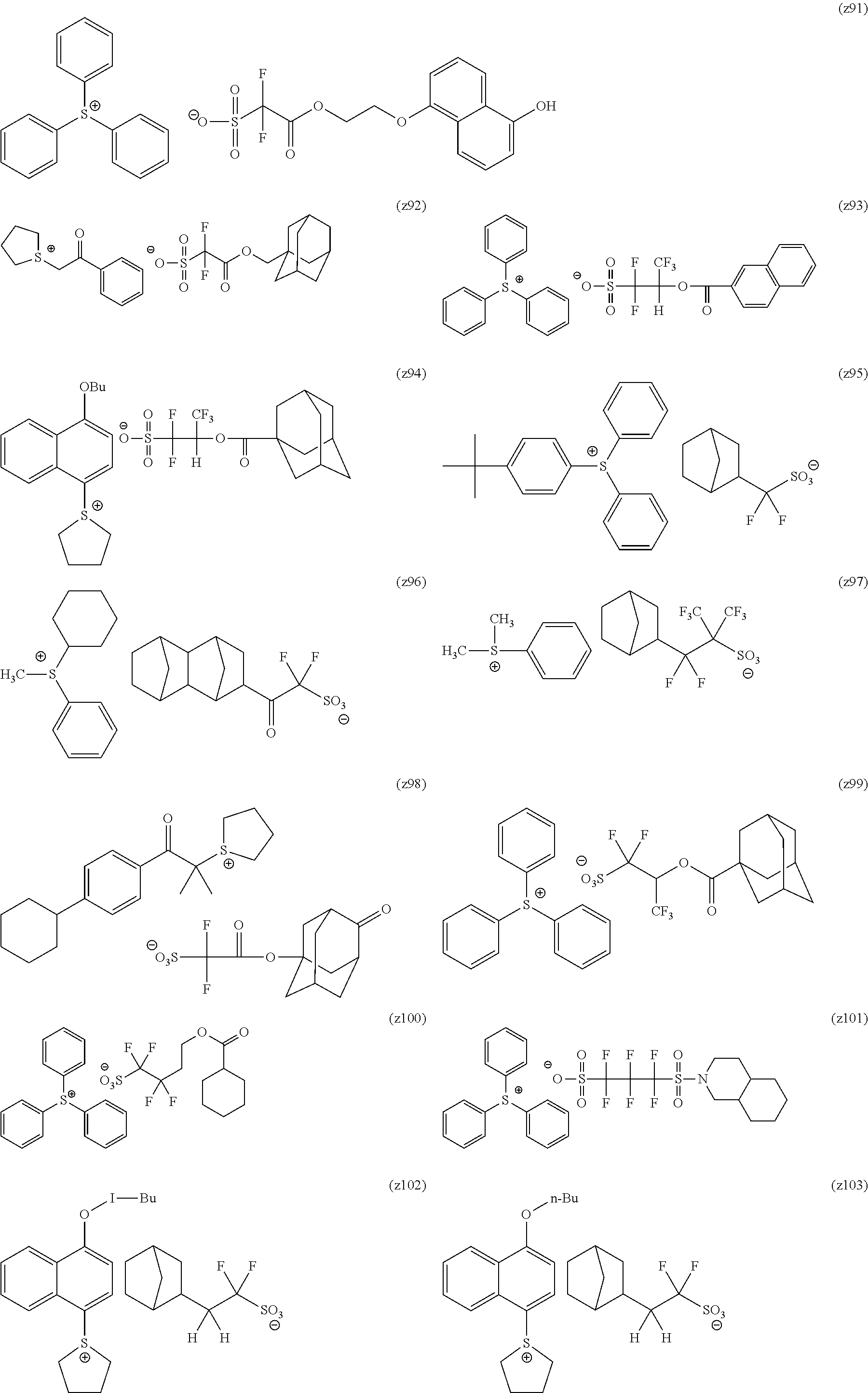

The total content of the acid-generating agent (in a case where an acid-generating agent other than the compound (B) is used concurrently, the amount of the acid-generating agent is included) is preferably 0.1 to 27% by mass, more preferably 0.5 to 23% by mass, even more preferably 1 to 22% by mass, and particularly more preferably 3 to 20% by mass, based on the total solid contents of the resist composition.

The molar ratio (compound (B)/compound (B′)) of the usage amount of the acid-generating agent, in a case where the compound (B) and the compound (B′) are used concurrently, is generally 99/1 to 20/80, preferably 99/1 to 40/60 and more preferably 99/1 to 50/50.

[3-1] Basic Compound or Ammonium Salt Compound (C) in which Basicity Decreases by Irradiation with Actinic Rays or Radiation

The actinic ray-sensitive or radiation-sensitive resin composition of the present invention preferably contains a basic compound or an ammonium salt compound in which basicity decreases by irradiation with actinic rays or radiation (hereinafter also referred to as a basic compound (C)).

The compound (C) is preferably a compound (C-1) having a basic functional group or an ammonium group, and a group which generates an acidic functional group by irradiation with actinic rays or radiation. That is, the compound (C) is preferably a basic compound having a basic functional group and a group which generates an acidic functional group by irradiation with actinic rays or radiation, or an ammonium salt compound having an ammonium group and a group which generates an acidic functional group by irradiation with actinic rays or radiation.

Examples of the compound (C) or (C-1) as a compound which is generated by decomposition by irradiation with actinic rays or radiation, and of which basicity was decreased, include a compound represented by the following general formula (PA-I), (PA-II) or (PA-III), and the compound represented by the general formula (PA-II) or (PA-III) is particularly preferable from the viewpoint of attaining excellent effects to a high degree in all of LWR (Line Width Roughness), uniformity in local pattern dimension, and DOF (Depth Of Focus).

First, the compound represented by the general formula (PA-I) will be described.

Q-A₁-(X)ₙ—B—R (PA-I)

In the general formula (PA-I),
A₁ represents a single bond or a divalent linking group,
Q represents —SO₃H— or —CO₂H and corresponds to an acidic functional group which is generated by irradiation with actinic rays or radiation,
X represents —SO₂— or —CO—,
n represents 0 or 1,
B represents a single bond, an oxygen atom or —N(Rx)—,
Rx represents a hydrogen atom or a monovalent organic group, and
R represents a monovalent organic group containing a basic functional group or a monovalent organic group containing an ammonium group.

The divalent linking group of A₁ is preferably a divalent linking group having 2 to 12 carbon atoms, and examples thereof include an alkylene group, a phenylene group and the like. More preferable examples thereof include an alkylene group having at least one fluorine atom and preferably having 2 to 6 carbon atoms and more preferably having 2 to 4 carbon atoms. An oxygen atom, a sulfur atom or the like may be included in the alkylene chain. The alkylene group is particularly preferably an alkylene group where 30 to 100% of the number of hydrogen atoms are substituted with fluorine atoms, and it is more preferable that a carbon atom bonded at Q position have a fluorine atom. Further, a perfluoroalkylene group is preferable, and a perfluoroethylene group, a perfluoropropylene group and a perfluorobutylene group are more preferable.

The monovalent organic group of Rx preferably has 4 to 30 carbons and examples thereof include an alkyl group, a cycloalkyl group, an aryl group, an aralkyl group, an alkenyl group and the like.

The alkyl group of Rx may have a substituent, preferably is a linear or branched alkyl group having 1 to 20 carbon atoms, and may have an oxygen atom, a sulfur atom or a nitrogen atom in the alkyl chain.

Examples of the alkyl group having a substituent particularly include a group in which a linear or branched alkyl group is substituted with a cycloalkyl group (for example, an adamantylmethyl group, an adamantylethyl group, a cyclohexylethyl group, a camphor residue and the like).

The cycloalkyl group of Rx may have a substituent, preferably is a cycloalkyl group having 3 to 20 carbon atoms, and may have an oxygen atom in the ring.

The aryl group of Rx may have a substituent and preferably is an aryl group having 6 to 14 carbon atoms.

The aralkyl group of Rx may have a substituent and preferably is an aralkyl group having 7 to 20 carbon atoms.

The alkenyl group of Rx may have a substituent and preferably is a group where the aralkyl group mentioned as Rx, for example, has a double bond in an arbitrary position.

Preferable examples of a structure of the basic functional group include a structure of crown ether, primary to tertiary amines or a nitrogen-containing heterocycle (pyridine, imidazole, pyrazine or the like).

Preferable examples of a structure of the ammonium group include a structure of primary, secondary or tertiary ammoniums, pyridinium, imidazolinium, pyrazinium or the like.

Here, the basic functional group is preferably a functional group having a nitrogen atom, and a structure having primary, secondary or tertiary amino groups or a heterocyclic structure containing nitrogen is more preferable. In these structures, it is preferable that all the atoms near the nitrogen atom in the structure be a carbon atom or a hydrogen atom from the viewpoint of increasing basicity. In addition, the electron-attracting functional group (a carbonyl group, a sulfonyl group, a cyano group, a halogen atom or the like) does not directly connected to a nitrogen atom from the viewpoint of increasing basicity.

The monovalent organic group (R group) having such a structure preferably has 4 to 30 carbon atoms. Examples thereof include an alkyl group, a cycloalkyl group, an aryl group, an aralkyl group, an alkenyl group and the like, and each of the groups may have a substituent.

Each of an alkyl group, a cycloalkyl group, an aryl group, an aralkyl group, all aralkyl group and an alkenyl group of R including a basic functional group or an ammonium group, are the same as the alkyl group, the cycloalkyl group, the aryl group, the aralkyl group, the aralkyl group and the alkenyl group as Rx.

Examples of the substituent which each of the above-mentioned groups may have include a halogen atom, a hydroxyl group, a nitro group, a cyano group, a carboxy group, a carbonyl group, a cycloalkyl group (preferably having 3 to 10 carbon atoms), an aryl group (preferably having 6 to 14 carbon atoms), an alkoxy group (preferably having 1 to 10 carbon atoms), an acyl group (preferably having 2 to 20 carbon atoms), an acyloxy group (preferably having 2 to 10 carbon atoms), an alkoxycarbonyl group (preferably 2 to 20 carbon atoms), an aminoacyl group (preferably 2 to 20 carbon atoms) and the like. Regarding a cyclic structure of the aryl group and the cycloalkyl group, the substituent may be an alkyl group (preferably having 1 to 20 carbon atoms). Regarding the aminoacyl group, the substituent may be 1 or 2 further alkyl groups (preferably having 1 to 20 carbon atoms).

When B is —N(Rx)—, R and Rx may be bonded to each other to form a ring. By forming a ring structure, stability is improved and stability during storage of a composition using such B is also improved. The number of the carbon atoms forming the ring is preferably 4 to 20, a monocyclic type and a polycyclic type may be used, and an oxygen atom, a sulfur atom or a nitrogen atom may be included in the ring.

Examples of the monocyclic structure include a 4- to 8-membered ring including a nitrogen atom. Examples of the polycyclic structure include a structure consisting of a combination of 2 or more of monocyclic structure. The monocyclic structure and the polycyclic structure may have a substituent, and examples thereof include a halogen atom, a hydroxyl group, a cyano group, a carboxy group, a carbonyl group, a cycloalkyl group (preferably having 3 to 10 carbon atoms), an aryl group (preferably having 6 to 14 carbon atoms), an alkoxy group (preferably having 1 to 10 carbon atoms), an acyl group (preferably having 2 to 15 carbon atoms), an acyloxy group (preferably having 2 to 15 carbon atoms), an alkoxycarbonyl group (preferably having 2 to 15 carbon atoms), an aminoacyl group (preferably having 2 to 20 carbon atoms). Regarding the cyclic structure of the aryl group and the cycloalkyl group, the substituent may be a further alkyl group (preferably having 1 to 15 carbon atoms). Regarding the aminoacyl group, the substituent may be 1 or 2 alkyl groups (preferably having 1 to 15 carbon atoms).

Among compounds represented by the general formula (PA-I), a compound with a sulfonic acid at Q position may be synthesized using a general sulfonamide reaction. For example, a method where one of the sulfonylharide portion of a vinyl sulfonylharide compound is selectively reacted with an amine compound, then a sulfonamide bond is formed, and another sulfonylharide portion is hydrolyzed, or a method where a cyclic sulfonic acid anhydride is reacted with an amine compound to open the ring.

Next, the compound represented by the general formula (PA-II) is described.

Q₁-X₁—NH—X₂-Q₂ (PA-II)

In the general formula (PA-II),
Q₁ and Q₂ each independently represent a monovalent organic group, provided that any one of Q₁ and Q₂ contains a basic functional group, and Q₁ and Q₂ may be bonded to each other to form a ring and the ring formed may contain a basic functional group,
X₁ and X₂ each independently represent —CO— or —SO₂—, and
—NH— corresponds to an acidic functional group which is generated by irradiation with actinic rays or radiation.

The monovalent organic group as Q₁ or Q₂ in the general formula (PA-II) preferably has 1 to 40 carbon atoms, and examples thereof include an alkyl group, a cycloalkyl group, an aryl group, an aralkyl group, an alkenyl group and the like.

The alkyl group of Q₁ or Q₂ may have a substituent, is preferably a linear or branched alkyl group having 1 to 30 carbon atoms, and an oxygen atom, a sulfur atom or a nitrogen atom may be included in the alkyl chain.

The cycloalkyl group of Q₁ or Q₂ may have a substituent, is preferably a cycloalkyl group having 3 to 20 carbon atoms, and an oxygen atom or a nitrogen atom may be included in the ring.

The aryl group of Q₁ or Q₂ may have a substituent and is preferably an aryl group having 6 to 14 carbon atoms.

The aralkyl group of Q₁ or Q₂ may have a substituent and is preferably an aralkyl group having 7 to 20 carbon atoms.

The alkenyl group of Q₁ or Q₂ may have a substituent and is preferably a group where the above-mentioned alkyl group has a double bond in an arbitrary position.

Examples of the substituent which each of the above-mentioned group may have include a halogen atom, a hydroxyl group, a nitro group, a cyano group, a carboxy group, a carbonyl group, a cycloalkyl group (preferably having 3 to 10 carbon atoms), an aryl group (preferably having 6 to 14 carbon atoms), an alkoxy group (preferably having 1 to 10 carbon atoms), an acyl group (preferably having 2 to 20 carbon atoms), an acyloxy group (preferably having 2 to 10 carbon atoms), an alkoxycarbonyl group (preferably having 2 to 20 carbon atoms), an aminoacyl group (preferably having 2 to 10 carbon atoms). Regarding the ring structure in the aryl group and the cycloalkyl group, the substituent may be a further alkyl group (preferably having 1 to 10 carbon atoms). Regarding the aminoacyl group, the substituent may be a further alkyl group (preferably having 1 to 10 carbon atoms). Examples of the alkyl group having a substituent include a perfluoroalkyl group such as a perfluoromethyl group, a perfluoroethyl group, a perfluoropropyl group, a perfluorobutyl group and the like.

Examples of a preferable partial structure of the basic functional group which at least one of Q₁ and Q₂ has include the same ones explained as the basic functional group which R of the general formula (PA-I) has.

Examples of the structure where the ring formed by Q₁ and Q₂ bonding together and the ring has the basic functional group, include a structure where the organic groups of Q₁ and Q₂ are further bonded with an alkylene group, an oxy group, an imino group or the like.

In the general formula (PA-II), at least one of X₁ and X₂ is preferably —SO₂—.

Next, the compound represented by the general formula (PA-III) will be described.

Q₁-X₁—NH—X₂-A₂-(X₃)ₘ—B-Q₃ (PA-III)

In the general formula (PA-III),
Q₁ and Q₃ each independently represent a monovalent organic group, provided that any one of Q₁ and Q₃ contains a basic functional group, and Q₁ and Q₃ may be bonded to each other to form a ring and the ring formed may contain a basic functional group,
X₁, X₂, and X₃ each independently represent —CO— or —SO₂—,
A₂ represents a divalent linking group,
B represents a single bond, an oxygen atom, or —N(Qx)-,
Qx represents a hydrogen atom or a monovalent organic group,
when B is —N(Qx)-, Q₃ and Qx may be bonded to each other to form a ring,
m represents 0 or 1, and
—NH— corresponds to an acidic functional group which is generated by irradiation with actinic rays or radiation.

Q₁ has the same definition as that of the Q₁ in the general formula (PA-II).

Examples of the organic group of Q₃ include the same as the examples of the organic group of Q₁ and Q₂ in the general formula (PA-II).

Examples of the structure where Q₁ and Q₃ are bonded to form a ring and the formed ring has the basic functional group, include a structure where organic groups of Q₁ and Q₃ are further bonded with an alkylene group, an oxy group, an imino group or the like.

The divalent linking group of A₂ is preferably a divalent linking group having a fluorine atom and 1 to 8 carbon atoms, and examples thereof include an alkylene group having a fluorine atom and 1 to 8 carbon atoms, a phenylene group having a fluorine atom and the like. More preferable examples thereof include an alkylene group having a fluorine atom and preferably having 2 to 6 carbon atoms and more preferably having 2 to 4 carbon atoms. A bonding group such as an oxygen atom, a sulfur atom or the like may be included in the alkylene chain. The alkylene group is preferably an alkylene group where 30 to 100% of the number of hydrogen atoms are substituted with fluorine atoms, is more preferably a perfluoroalkylene group, and is particularly preferably a perfluoroalkylene group having 2 to 4 carbon atoms.

The monovalent organic group of Qx is preferably an organic group having 4 to 30 carbon atoms, and examples thereof include an alkyl group, a cycloalkyl group, an aryl group, an aralkyl group, an alkenyl group and the like. The examples of the alkyl group, the cycloalkyl group, the aryl group, the aralkyl group, the alkenyl group include the same as the examples of Rx in the above formula (PA-I).

In the general formula (PA-III), X₁, X₂ and X₃ are preferably —SO₂—.

The compound (C) is preferably a sulfonium salt compound of the compound represented by the general formula (PA-I), (PA-II) or (PA-III) and an iodonium salt compound of the compound represented by the general formula (PA-I), (PA-II) or (PA-III), and is more preferably a compound represented by the following general formula (PA1) or (PA2).

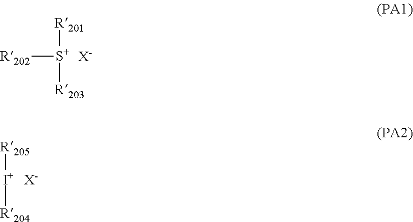

In the general formula (PA1),
each of R′₂₀₁, R′₂₀₂ and R′₂₀₃ independently represents an organic group, and are specifically the same as R₂₀₁, R₂₀₂ and R₂₀₃ in the formula ZI of the component (B), and
X⁻ represents a sulfonate anion or a carboxylic acid anion where a hydrogen atom at a —SO₃H position or a —COOH position of the compound represented by the general formula (PA-I) is removed, or an anion where a hydrogen atom is removed from a —NH— position of the compound represented by the general formula (PA-II) or (PA-III).

In the above general formula (PA2),
each of R′₂₀₄ and R′₂₀₅ independently represents an aryl group, an alkyl group or a cycloalkyl group, and are specifically the same as R₂₀₄ and R₂₀₅ in the formula ZII of the component (B), and
X⁻ represents a sulfonate anion or a carboxylic acid anion where a hydrogen atom at a —SO₃H position or a —COOH position of the compound represented by the general formula (PA-I) is removed, or an anion where a hydrogen atom is removed from a —NH— position of the compound represented by the general formula (PA-II) or (PA-III).

The compound (C) decomposes by irradiation with actinic rays or radiation and generates the compound represented by the general formula (PA-I), (PA-II) or (PA-III).

The compound represented by the general formula (PA-I) is a compound of which basicity is reduced or eliminated compared to the compound (C) or a compound changed from being basic to being acidic, by having a basic functional group or an ammonium group together with a sulfonic acid group or a carboxylic acid group.

The compound represented by the general formula (PA-II) or (PA-III) is a compound of which basicity is reduced or eliminated compared to the compound (C) or a compound changed from being basic to being acidic, by having a basic functional group together with an organic sulfonylimino group or an organic carbonylimino group.

In the present invention, reduction of basicity by irradiation with actinic rays or radiation means reduction of acceptor performance to a proton (an acid generated by irradiation with actinic rays or radiation) of the compound (C) by irradiation with actinic rays or radiation. The reduction of acceptor performance means reduction of an equilibrium constant in a chemical equilibrium when equilibrium reaction is performed which generates a non-covalently bonded complex, which is a proton adduct, from a compound having a basic functional group and a proton, or in which exchange of a counter cation of a compound having an ammonium group with a proton is performed.

In this manner, it is considered that through the compound (C) of which basicity is reduced by irradiation with actinic rays or radiation being included in the resist film, it is possible to suppress an unintended reaction of an acid diffused from an exposed portion and the resin (P) in an unexposed portion, accordingly acceptor performance of the compound (C) is sufficiently exhibited, and in an exposed portion acceptor performance of the compound (C) is reduced and therefore an intended reaction of the acid and the resin (P) occurs more reliably. Due to an effect of such mechanisms, it is considered that a pattern with excellent LWR (Line Width Roughness), uniformity in local pattern dimension, and DOF (Depth Of Focus) and pattern shapes may be obtained.

Here, it is possible to measure basicity by pH measurement and to calculate with commercially available software.

Specific examples of the compound (C) which generates the compound represented by the general formula (PA-I) by irradiation with actinic rays or radiation are shown below, but the present invention is not limited thereto.

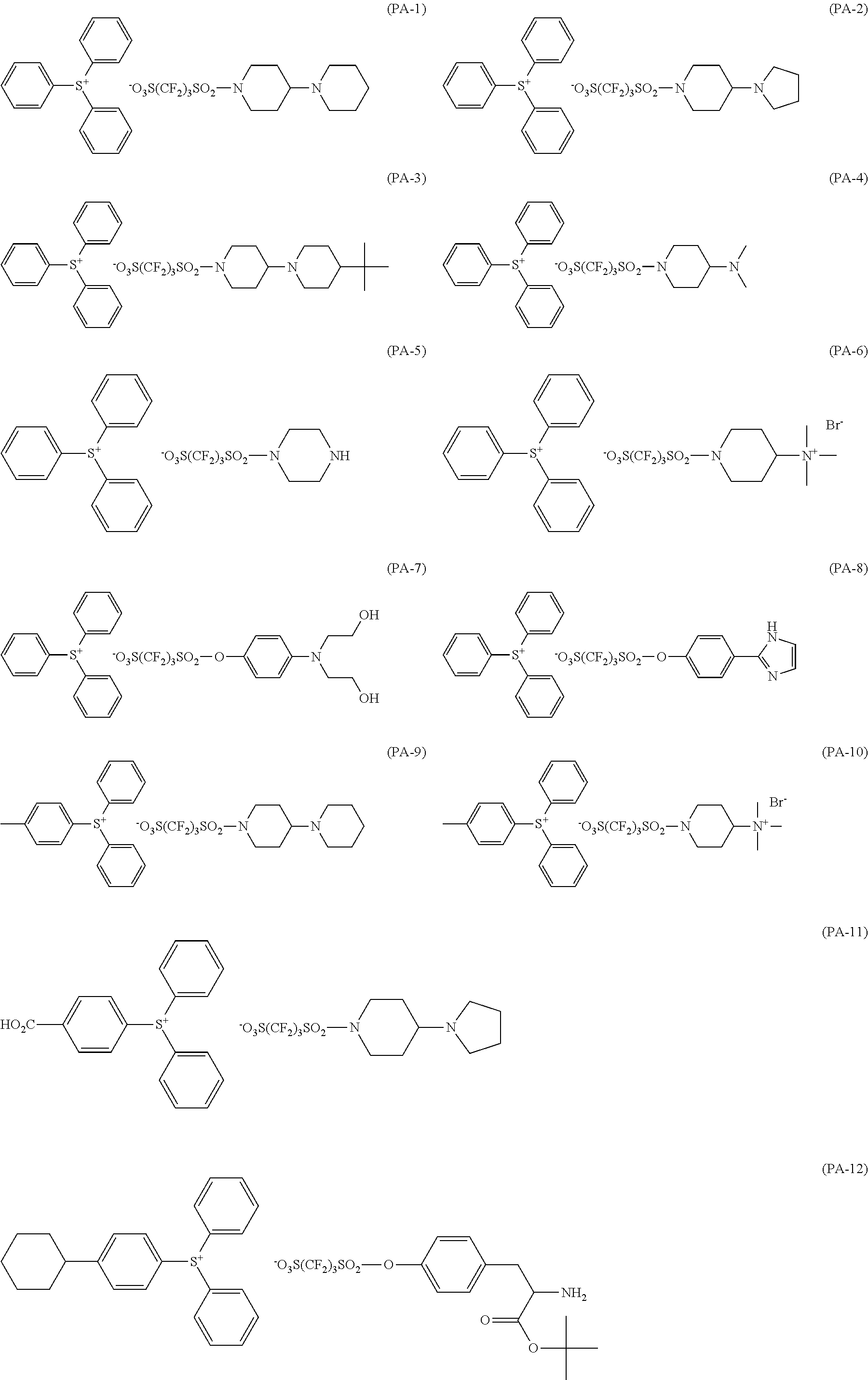

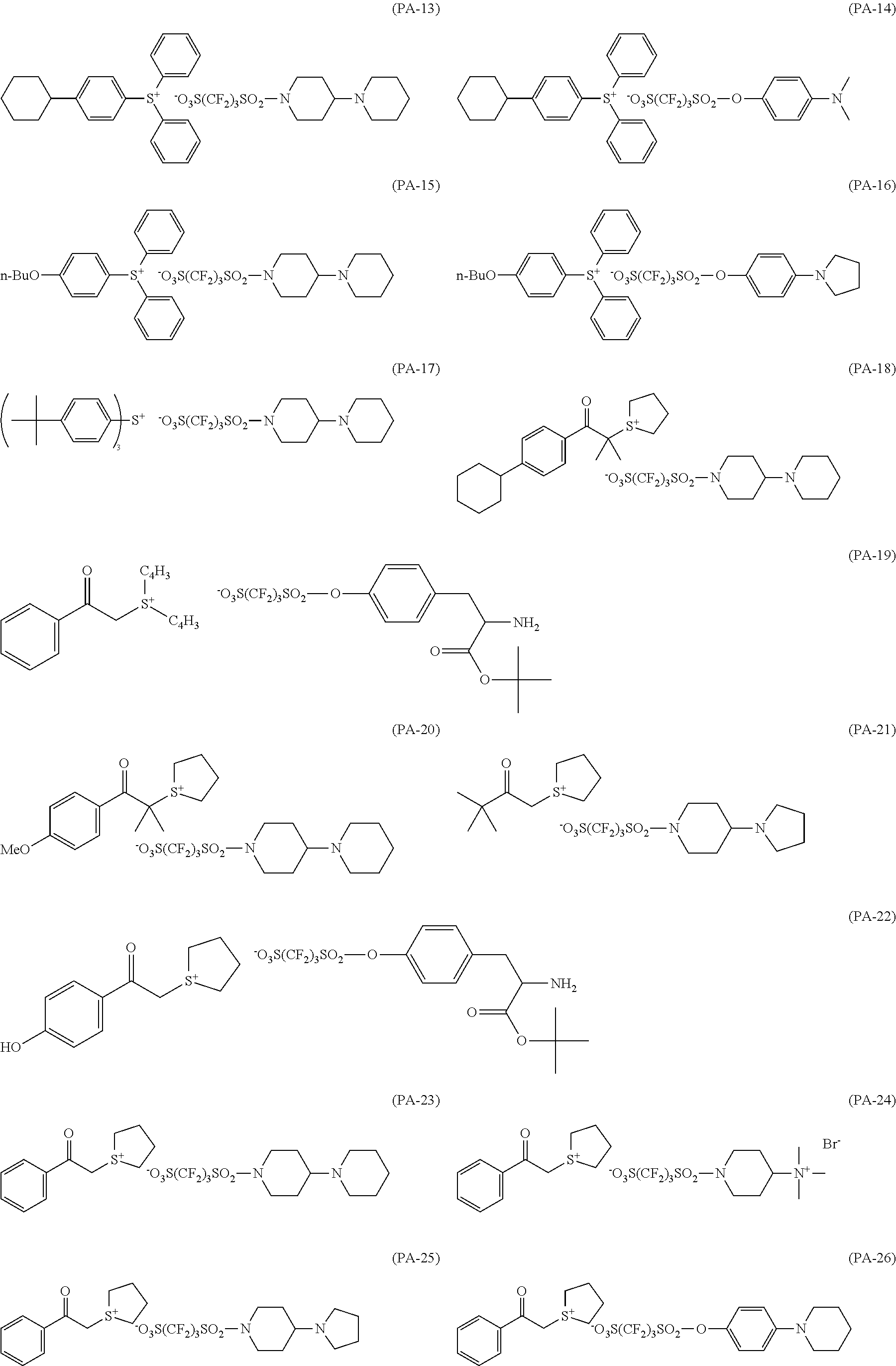

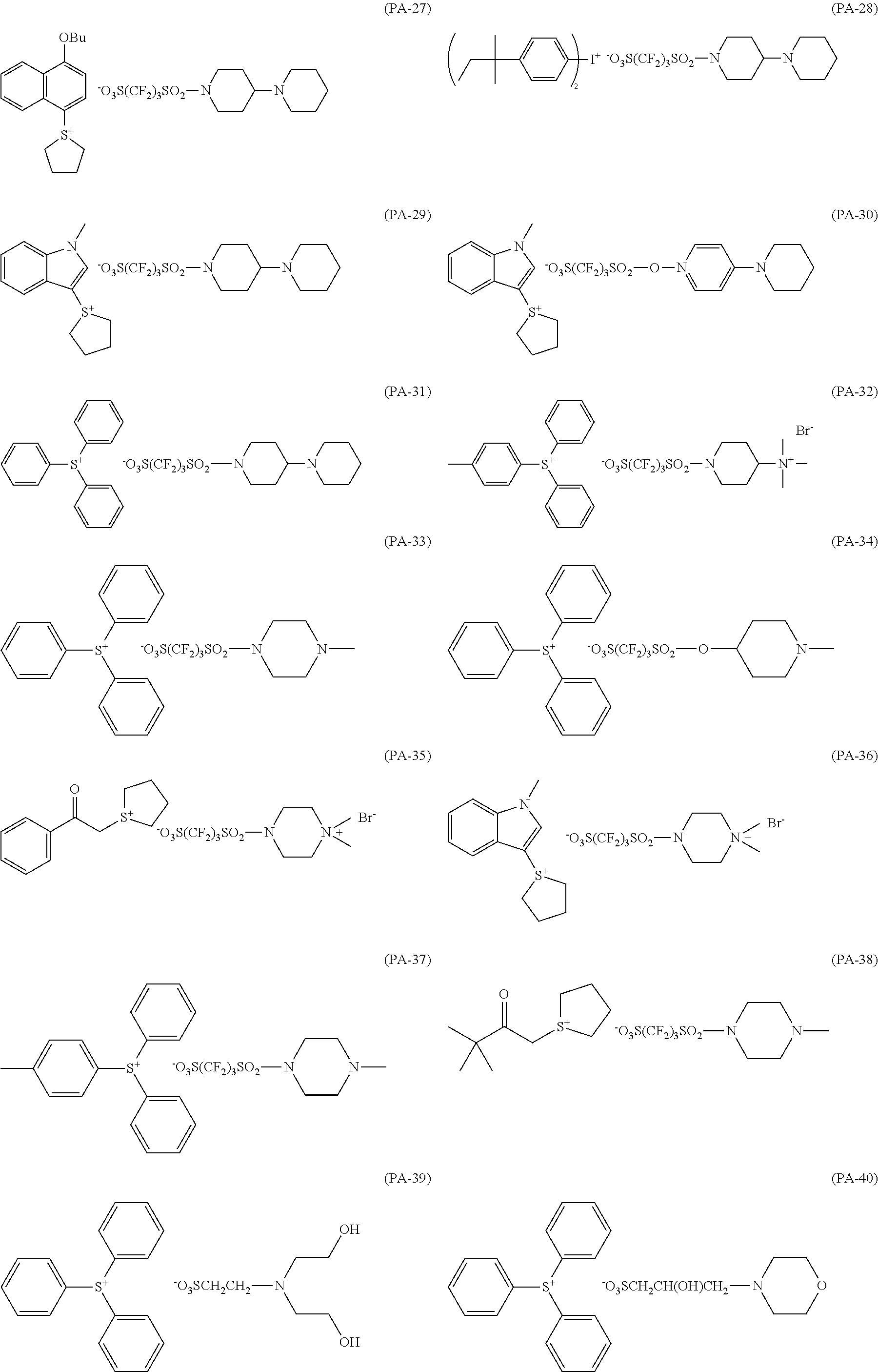

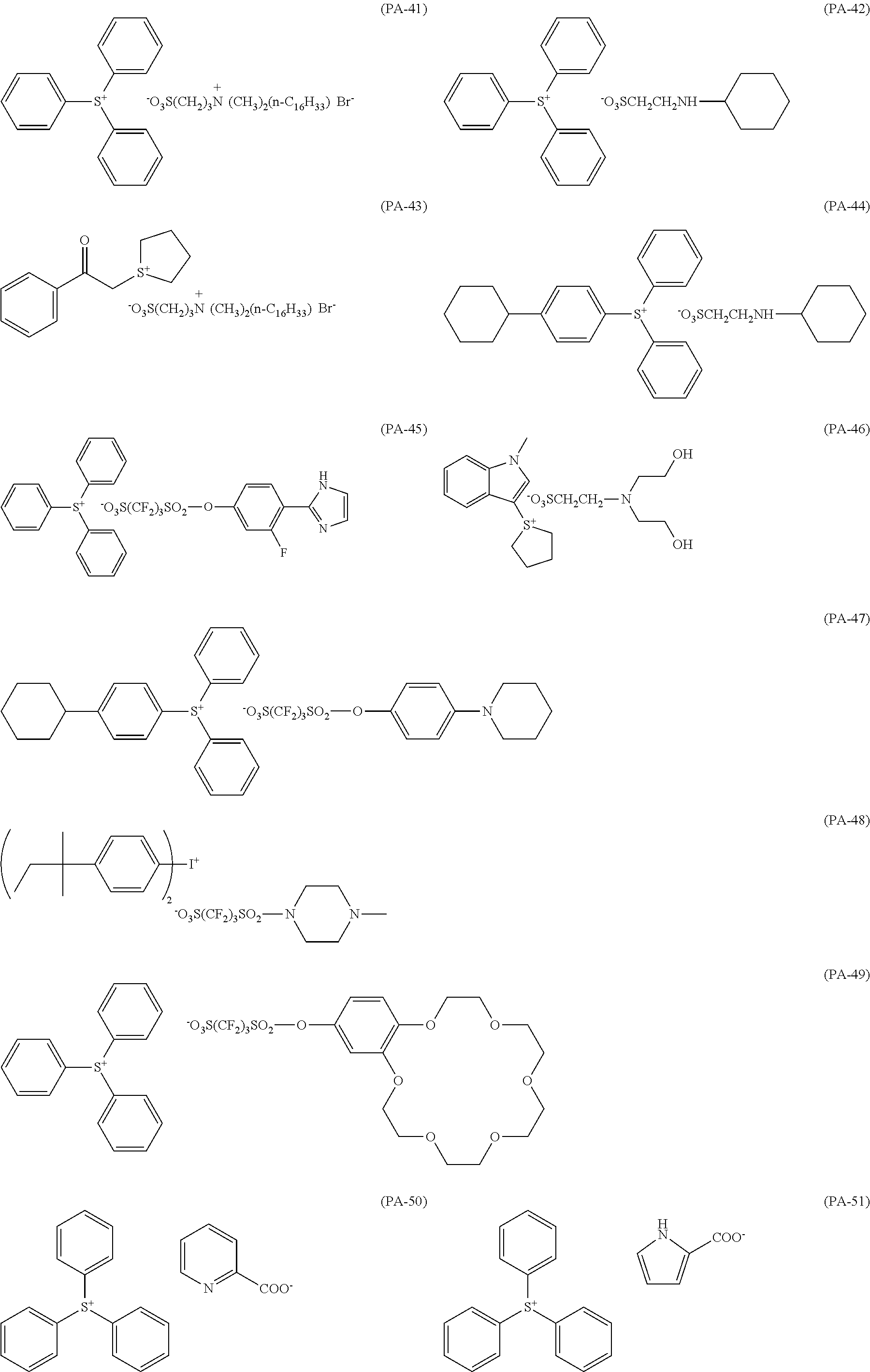

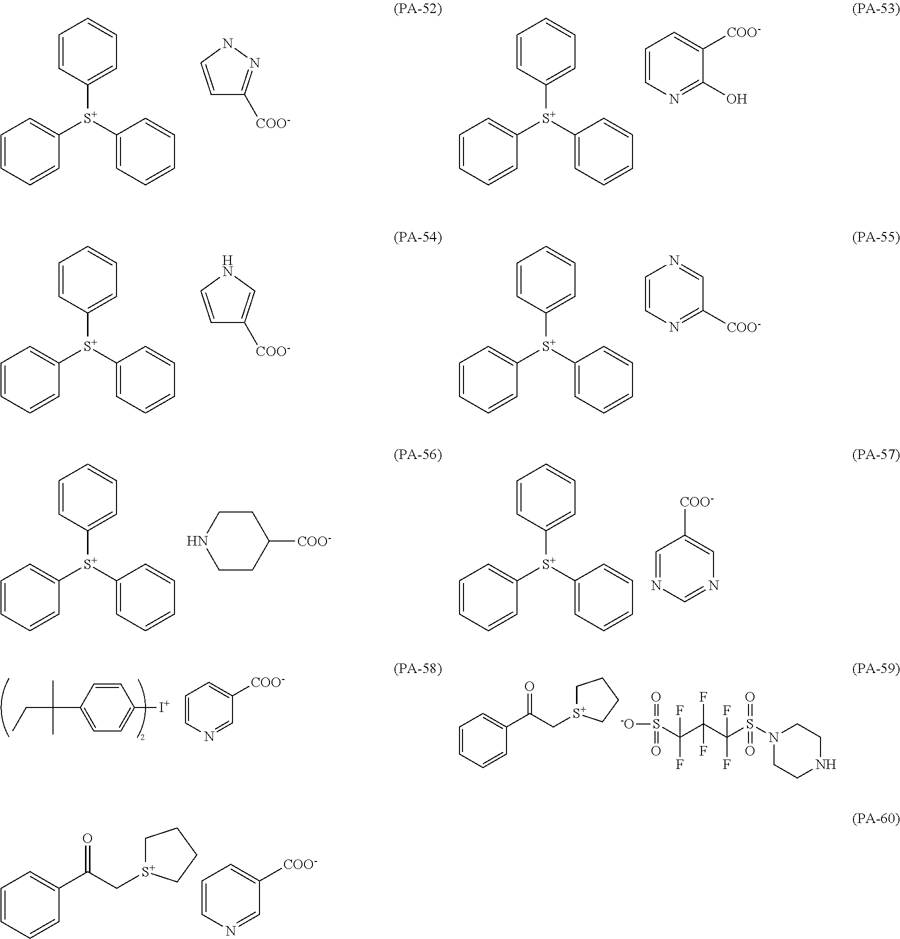

These compounds can be easily synthesized from the compound represented by the general formula (PA-I) or a lithium, sodium or potassium salt thereof, and a hydroxide, a bromide, a chloride, or the like of iodonium or sulfonium and the like through the salt exchange method described in JP1999-501909A (JP-H11-501909A) or JP2003-246786A. Alternatively, the compounds can be synthesized according to the synthesis method described in JP 1995-333851A (JP-H07-333851A).

Specific examples of the compound (C) which generates a compound represented by the general formula (PA-II) or (PA-III) by irradiation with actinic rays or radiation are shown below, but the present invention is not limited thereto.

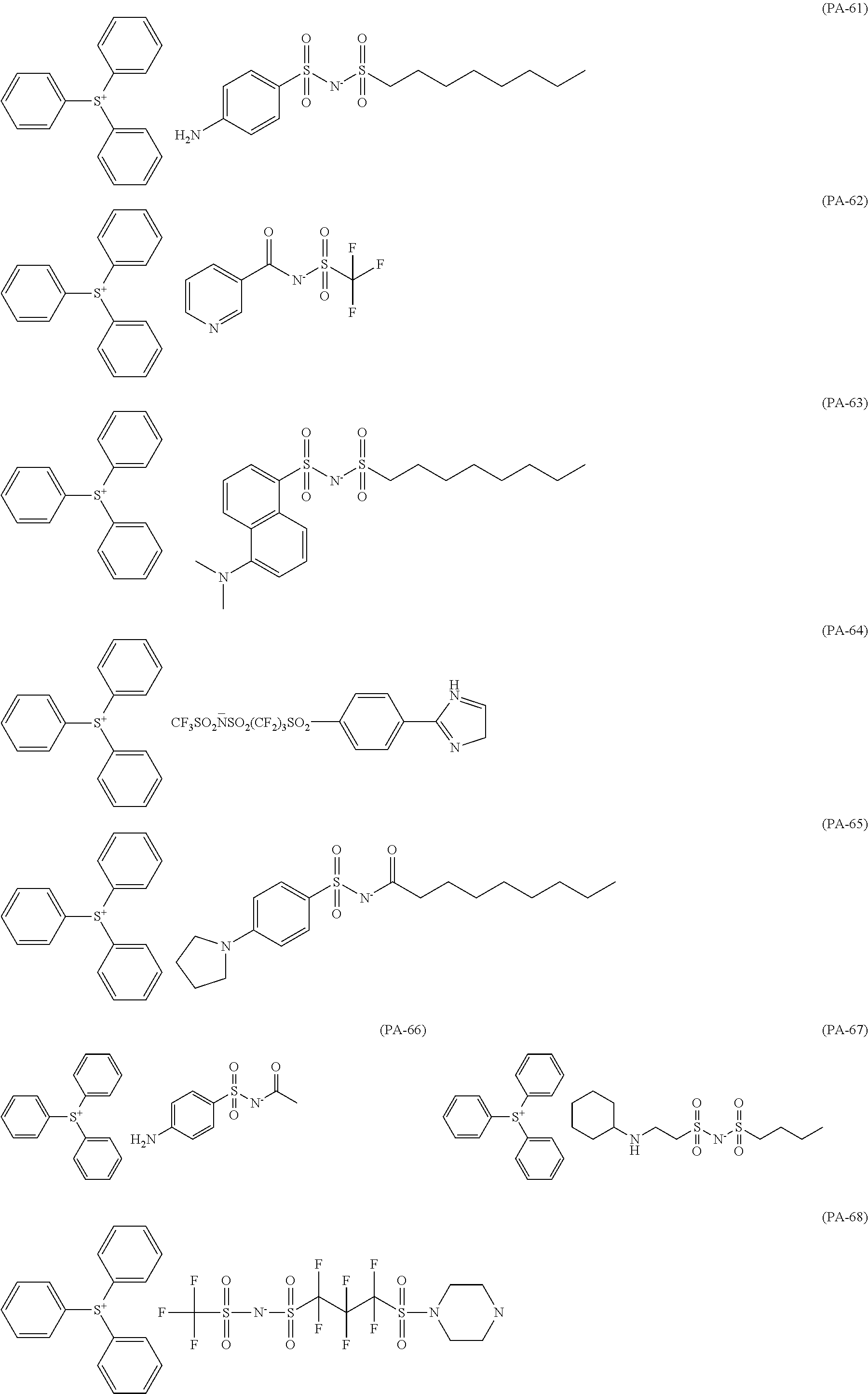

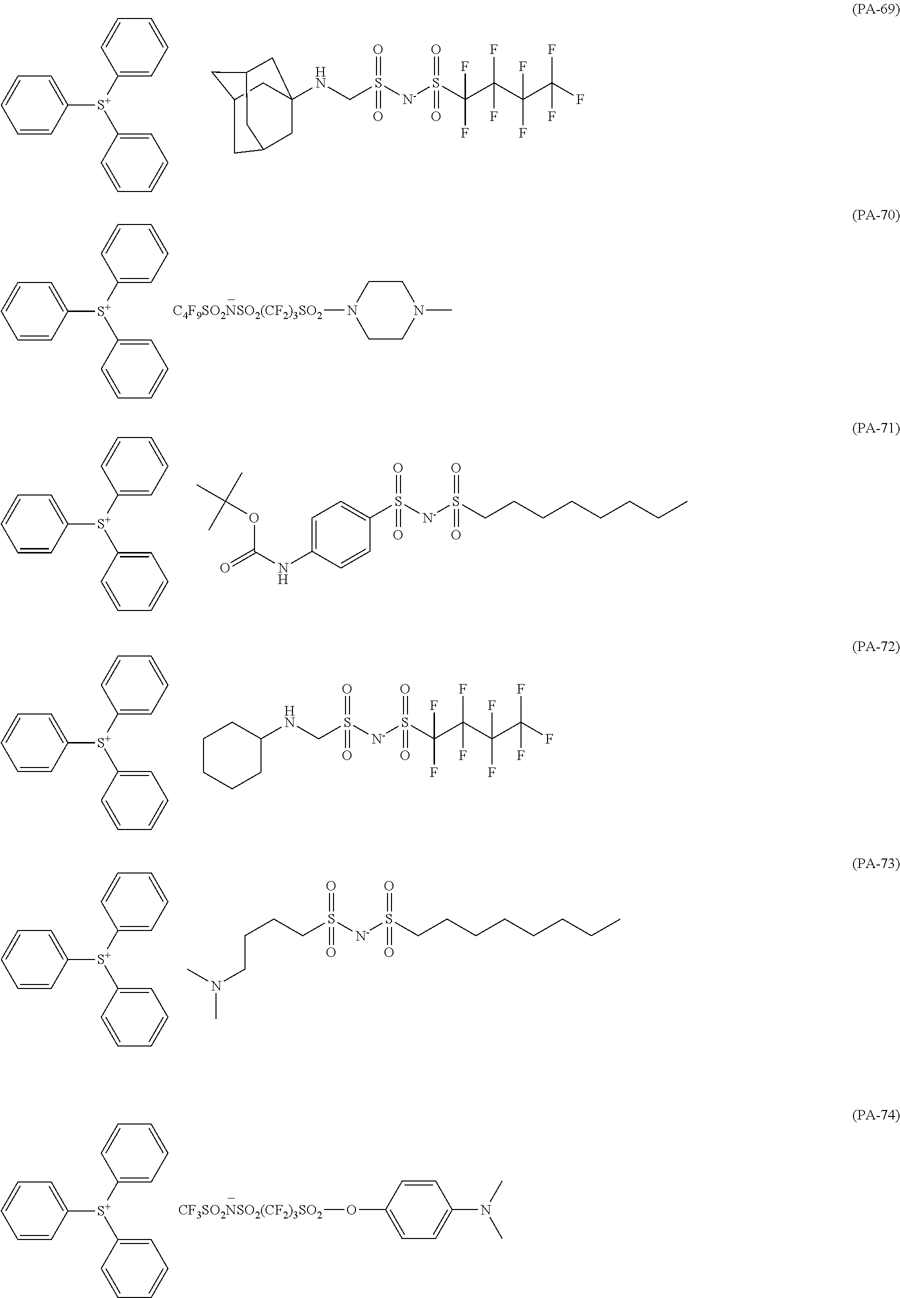

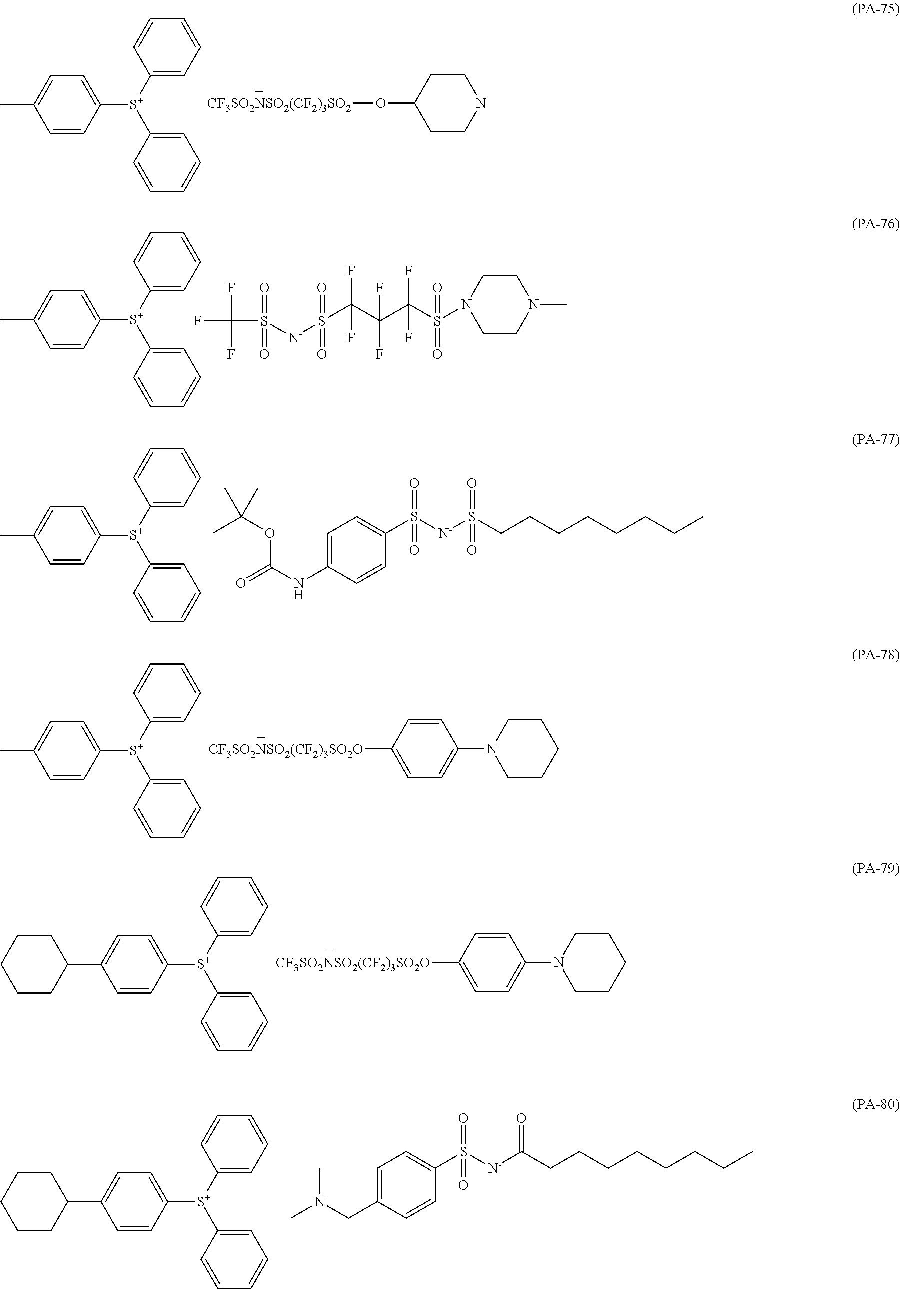

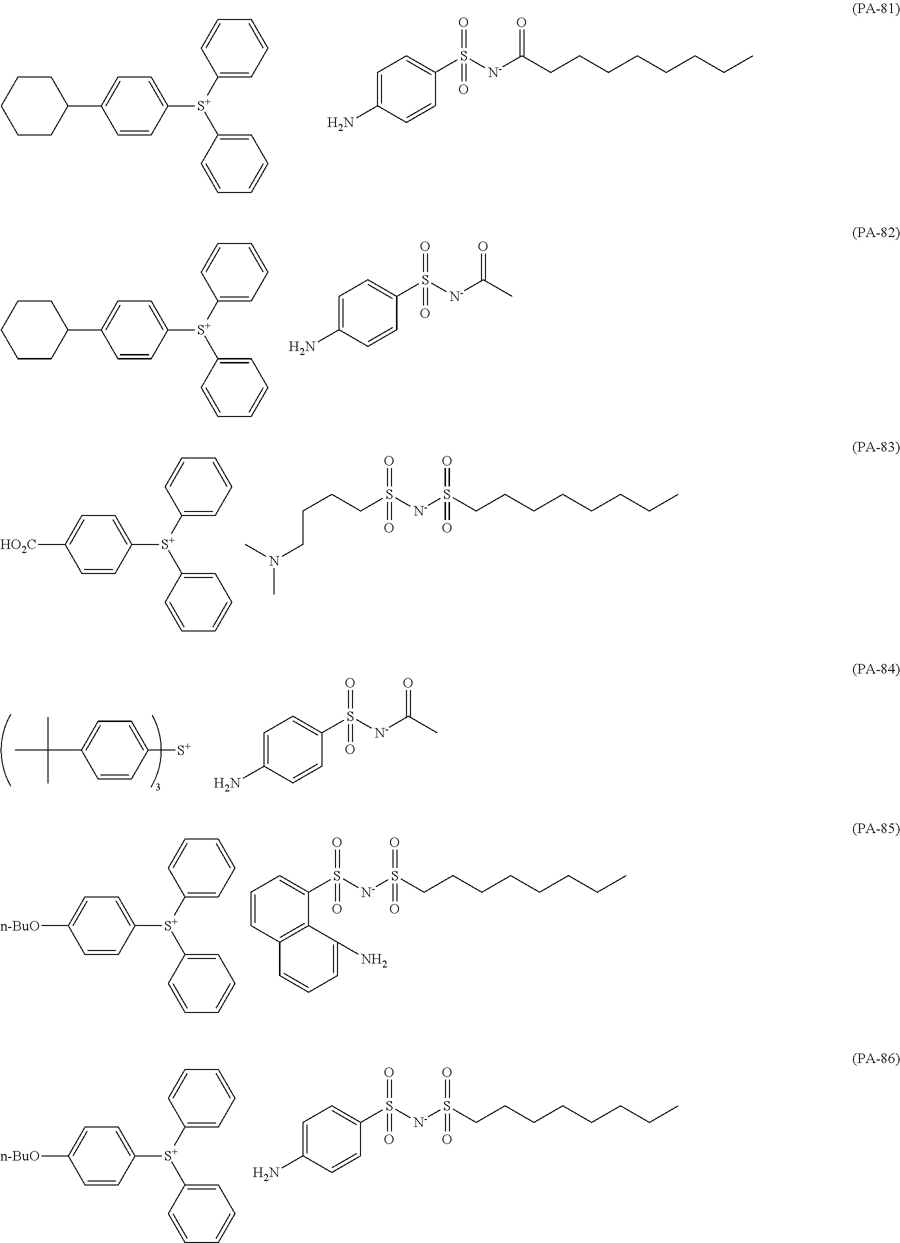

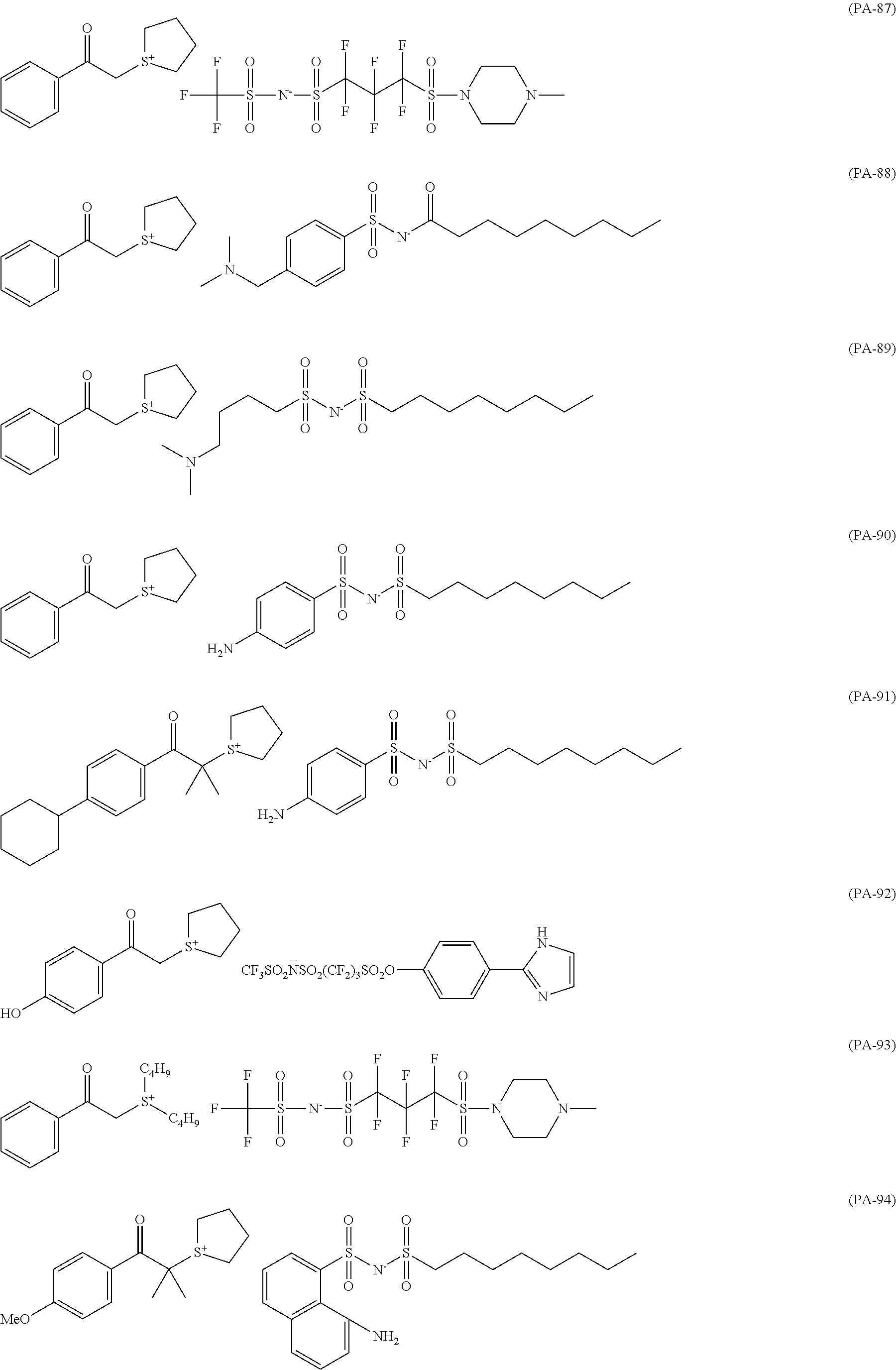

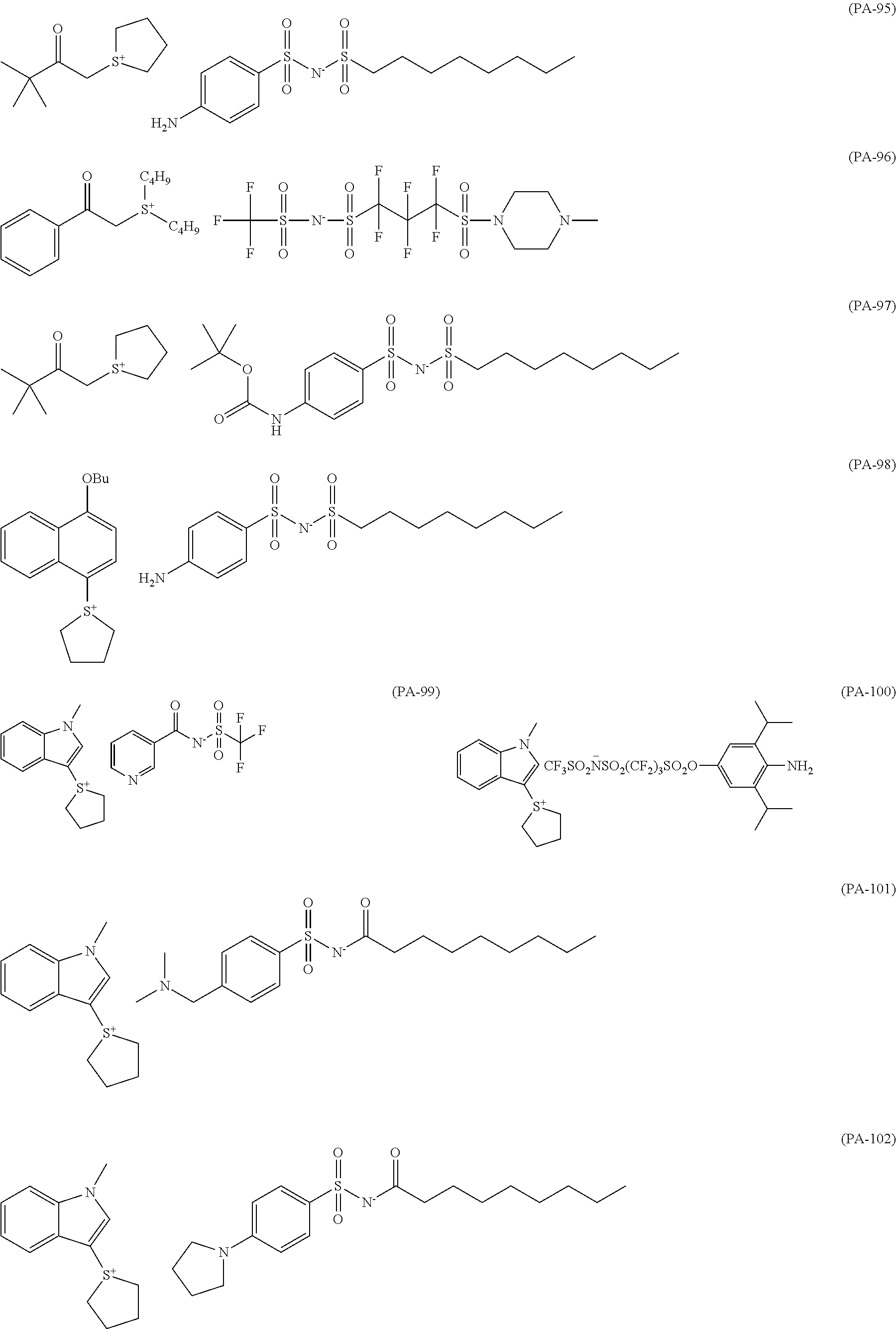

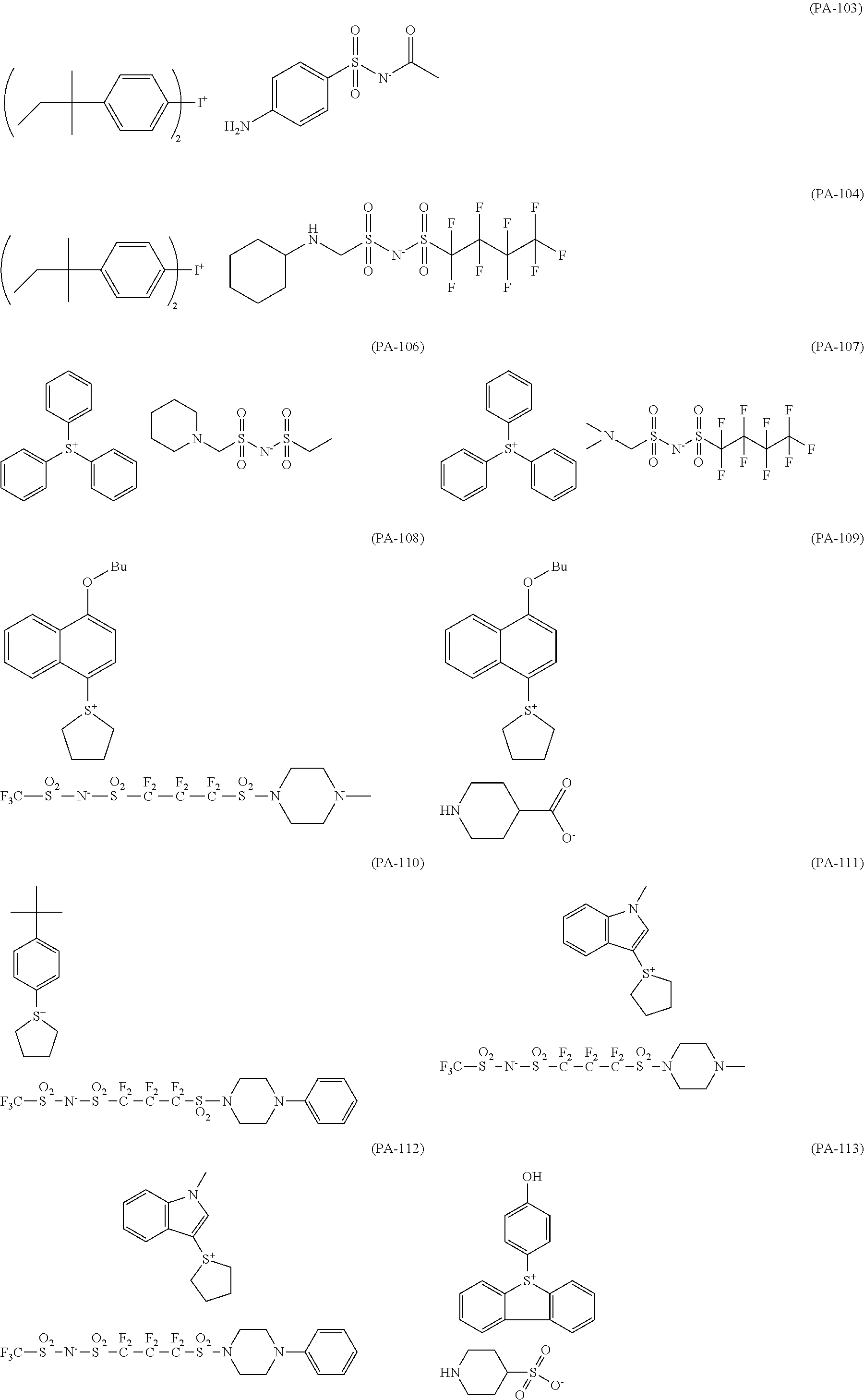

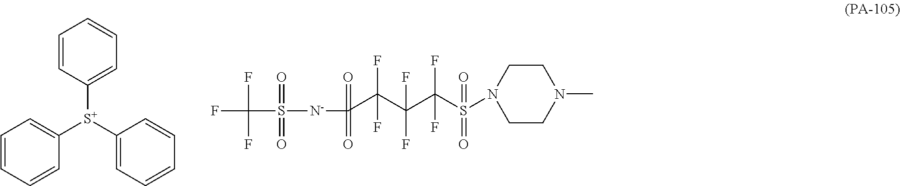

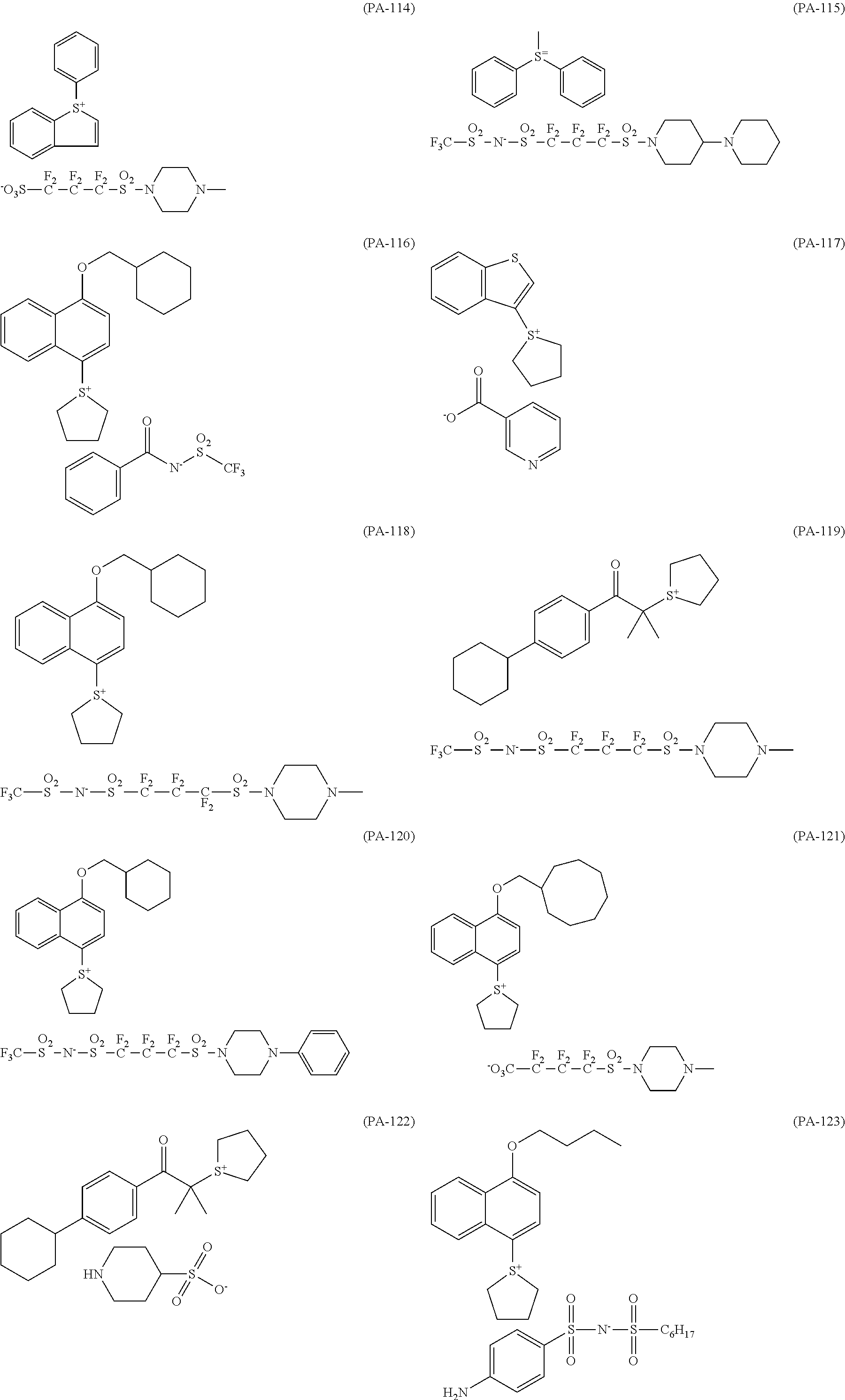

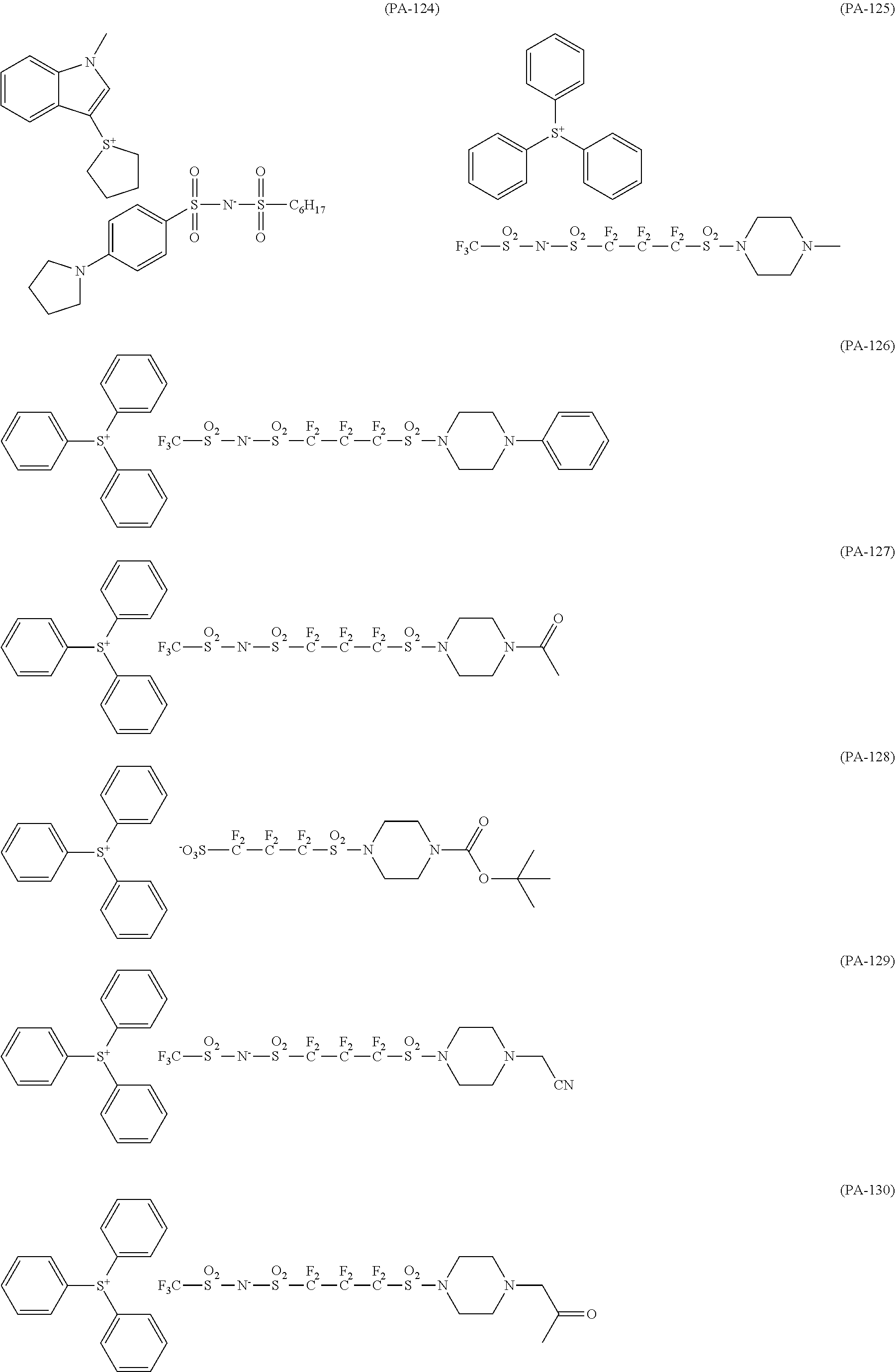

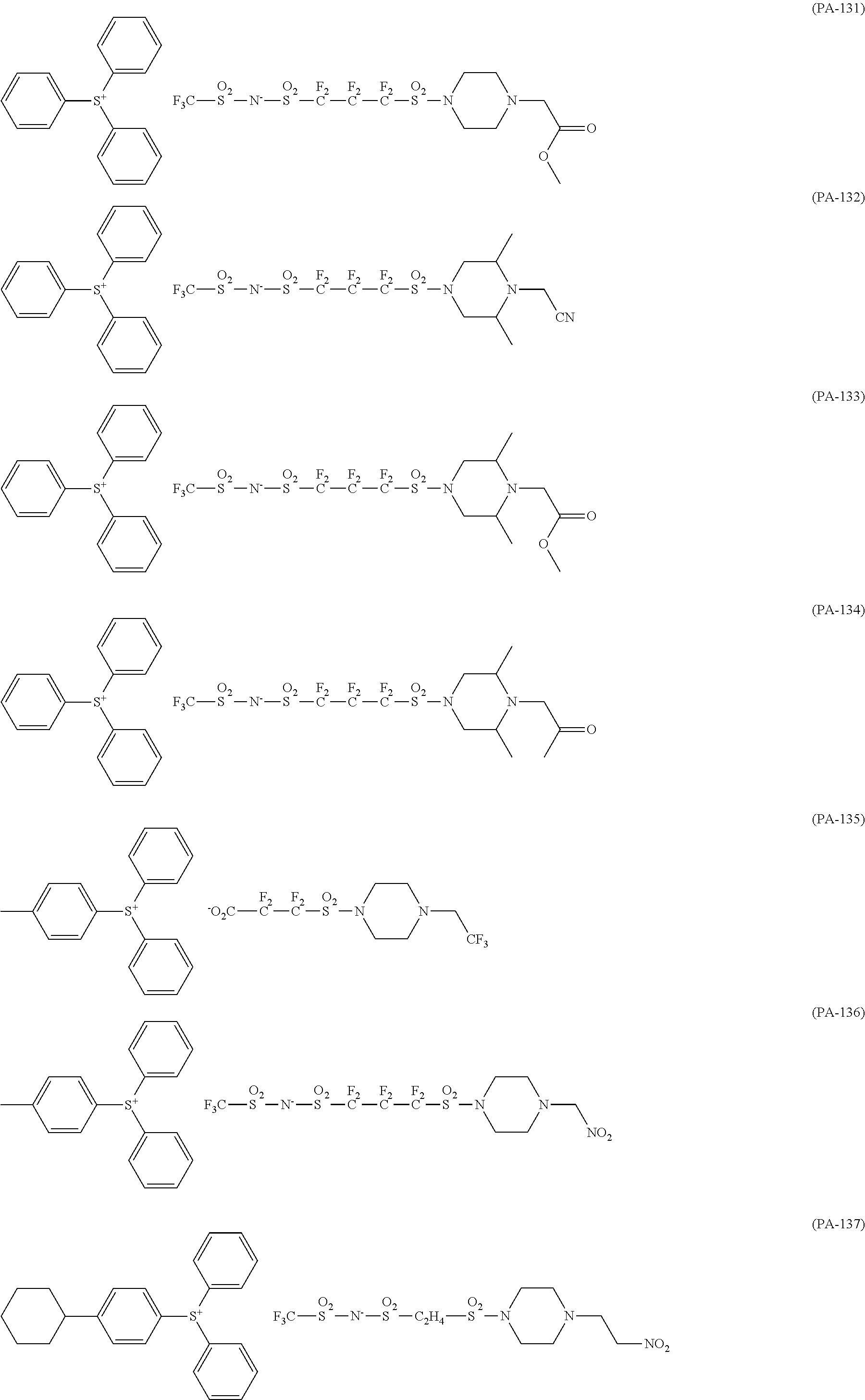

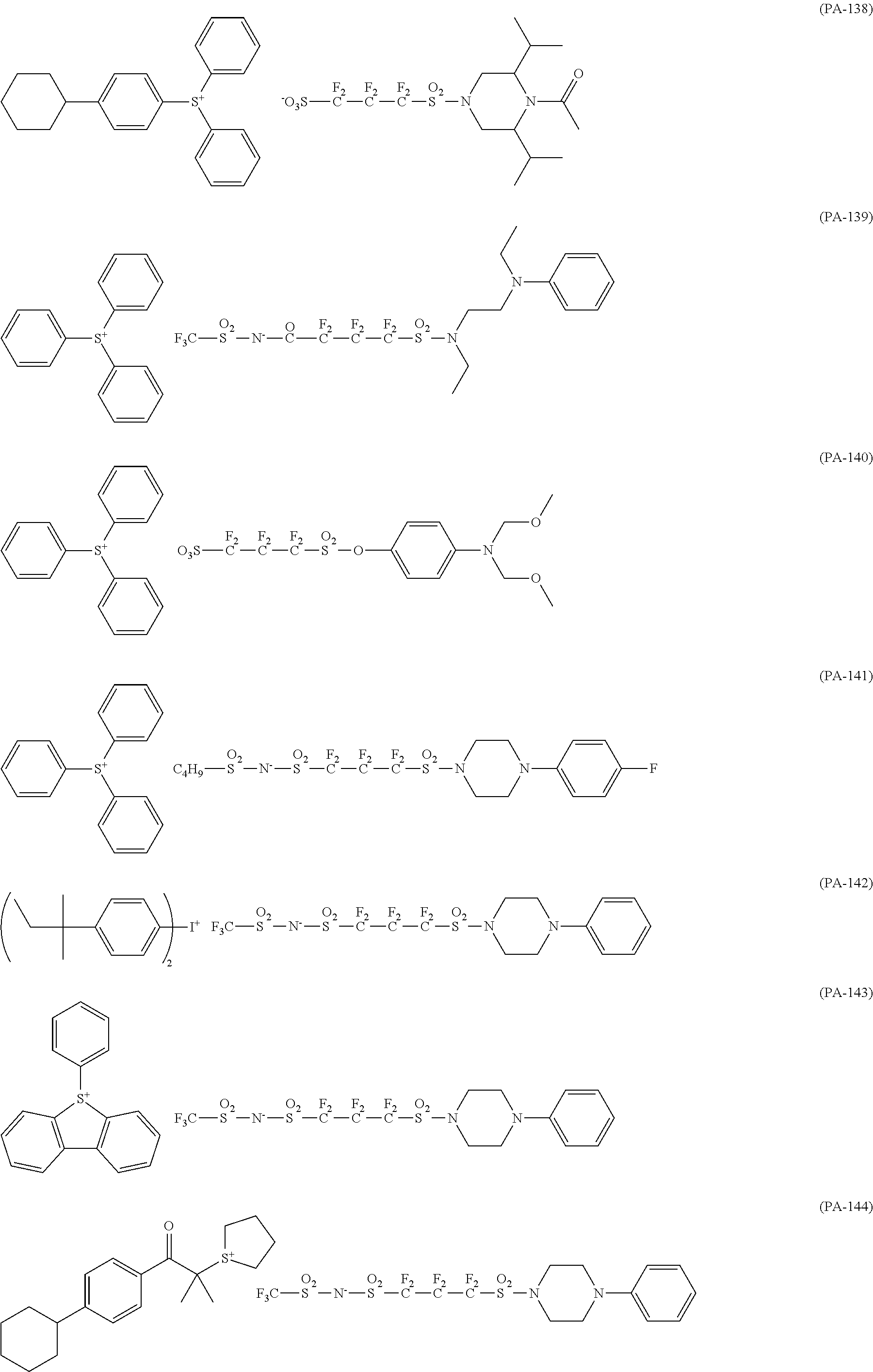

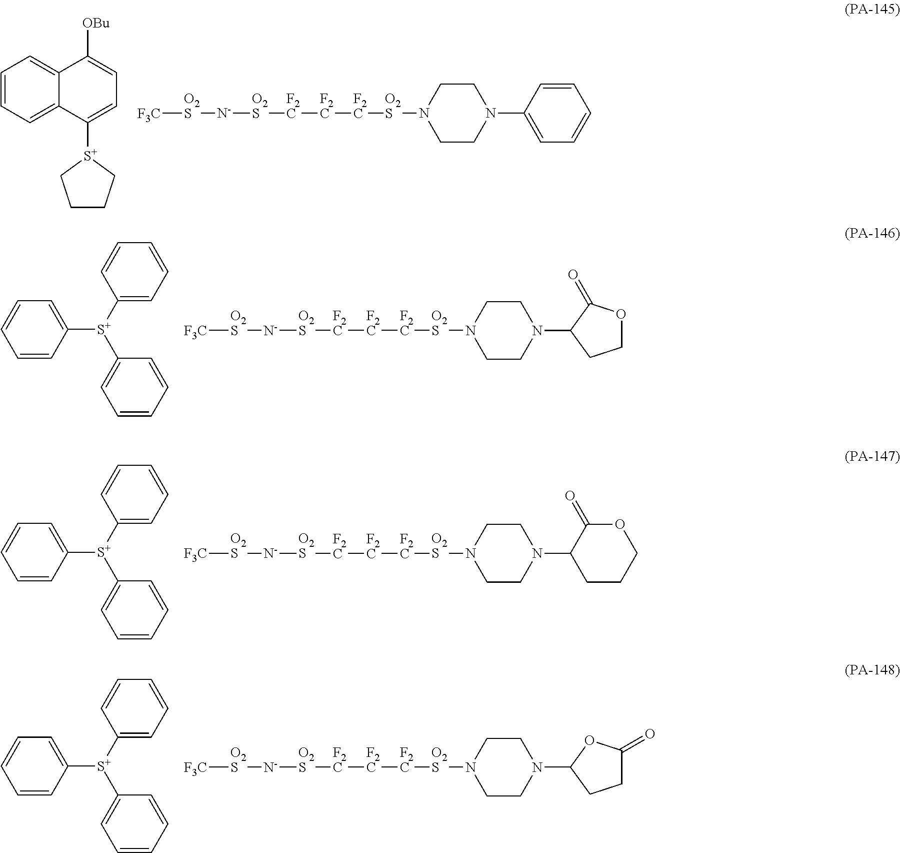

These compounds can be easily synthesized using a general sulfonic esterification reaction or a sulfonamide forming reaction. For example, the compounds can be obtained by a method where a bissulfonyl halide compound is reacted in such a manner that one of the sulfonyl halide moieties is selectively reacted with an amine, an alcohol, or the like including a partial structure represented by the general formula (PA-II) or (PA-III) to form a sulfonamide bond or a sulfonic ester bond, and thereafter the other sulfonyl halide moiety is hydrolyzed; or by a method in which a cyclic sulfonic anhydride is subjected to ring cleavage with an amine or alcohol including a partial structure represented by the general formula (PA-II). The amine or alcohol including a partial structure represented by the general formula (PA-II) or (PA-III) can be synthesized by reacting an amine or alcohol with an anhydride such as (R′O₂C)₂O and (R′SO₂)₂O, or an acid chloride compound such as R′O₂CCl and R′SO₂Cl (wherein R′ represents a methyl group, an n-octyl group, a trifluoromethyl group, or the like) under basic conditions. In particular the compounds can be synthesized according to the synthesis method described in JP2006-330098A.

The molecular weight of the compound (C) is preferably from 500 to 1000.

The actinic ray-sensitive or radiation-sensitive resin composition of the present invention may or may not include the compound (C). When the compound (C) is included, the content thereof is generally 0.1 to 20% by mass, and preferably 0.1 to 10% by mass, based on the solid content of the actinic ray-sensitive or radiation-sensitive resin composition.

[3-2] Basic Compound (C′)

The actinic ray-sensitive or radiation-sensitive resin composition of the present invention may include a basic compound (C′) in order to reduce a change in performance over time from exposing to baking.

Preferable examples of the basic compound include a compound represented by the following formulae (A) to (E).

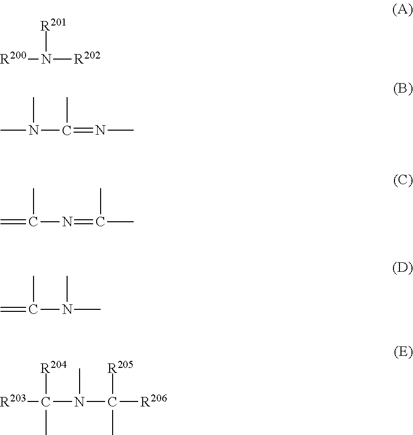

In the general formulae (A) and (E),
R²⁰⁰, R²⁰¹, and R²⁰² may be the same as or different from each other, and represent a hydrogen atom, an alkyl group (preferably having 1 to 20 carbon atoms), a cycloalkyl group (preferably having 3 to 20 carbon atoms), or an aryl group (having 6 to 20 carbon atoms). Herein, R²⁰¹ and R²⁰² may form a ring by bonding to each other. R²⁰³, R²⁰⁴, R²⁰⁵ and R²⁰⁶ may be the same as or different from each other, and represent an alkyl group having 1 to 20 carbon atoms.

Regarding the alkyl group, as the alkyl group having a substituent, an aminoalkyl group having 1 to 20 carbon atoms, a hydroxyalkyl group having 1 to 20 carbon atoms and a cyanoalkyl group having 1 to 20 carbon atoms are preferable.

These alkyl groups in the general formulae (A) and (E) are preferably unsubstituted.

Preferable examples of the compound include guanidine, aminopyrrolidine, pyrazole, pyrazoline, piperazine, aminomorpholine, aminoalkyl morpholine, piperidine and the like. More preferable examples of the compound include a compound having an imidazole structure, a diazabicyclo structure, an onium hydroxide structure, an onium carboxylate structure, a trialkylamine structure, an aniline structure, or a pyridine structure, an alkylamine derivative having a hydroxyl group and/or an ether bond, an aniline derivative having a hydroxyl group and/or an ether bond, and the like.

Examples of the compound having an imidazole structure include imidazole, 2,4,5-triphenylimidazole, benzimidazole and the like. Examples of the compound having a diazabicyclo structure include 1,4-diazabicyclo[2,2,2]octane, 1,5-diazabicyclo[4,3,0]nona-5-ene, 1,8-diazabicyclo[5,4,0]undeca-7-ene and the like. Examples of the compound having an onium hydroxide structure include triaryl sulfonium hydroxide, phenacyl sulfonium hydroxide, sulfonium hydroxide having a 2-oxoalkyl group, and specifically, triphenyl sulfonium hydroxide, tris(t-butylphenyl)sulfonium hydroxide, bis(t-butylphenyl)iodonium hydroxide, phenacyl thiophenium hydroxide, 2-oxopropyl thiophenium hydroxide and the like. The compound having an onium carboxylate structure is a compound having an onium hydroxide structure, wherein the anion portion thereof has been carboxylated. Examples thereof include acetate, adamantane-1-carboxylate, perfluoroalkyl carboxylate and the like. Examples of the compound having a trialkylamine structure include tri(n-butyl)amine, tri(n-octyl)amine and the like. Examples of the compound having an aniline structure include 2,6-diisopropylaniline, N,N-dimethylaniline, N,N-dibutylaniline, N,N-dihexylaniline, and the like. Examples of the alkylamine derivative having a hydroxyl group and/or an ether bond include ethanolamine, diethanolamine, triethanolamine, tris(methoxyethoxyethyl)amine, and the like. Examples of the aniline derivative having a hydroxyl group and/or an ether bond include N,N-bis(hydroxyethyl)aniline and the like.

Preferable examples of the basic compound further include an amine compound having a phenoxy group, an ammonium salt compound having a phenoxy group, an amine compound having a sulfonic acid ester group and an ammonium salt compound having a sulfonic acid ester group.

It is preferable that at least one alkyl group bond to a nitrogen atom in the amine compound having a phenoxy group, the ammonium salt compound having a phenoxy group, the amine compound having a sulfonic acid ester group, and the ammonium salt compound having a sulfonic acid ester group. It is also preferable that these compounds have an oxygen atom in the alkyl chain described above, and that an oxyalkylene group be formed in the compounds. The number of the oxyalkylene groups is one or more in a molecule, preferably 3 to 9 and more preferably 4 to 6. The oxyalkylene group preferably has a structure of —CH(CH₃)CH₂O— or —CH₂CH₂CH₂O—.

Specific examples of the amine compound having a phenoxy group, the ammonium salt compound having a phenoxy group, the amine compound having a sulfonic acid ester group, and the ammonium salt compound having a sulfonic acid ester group include compounds (C1-1) to (C3-3) exemplified in 0066 of the specification of US2007/0224539A, but the present invention is not limited thereto.

As a kind of the basic compound, a nitrogen-containing organic compound having a group removed by the action of an acid can be used. Examples of such a compound include a compound represented by the following general formula (F). In addition, in the compound represented by the following general formula (F), the group to be removed by the action of an acid is removed, whereby the basicity is effectively exhibited in a system.

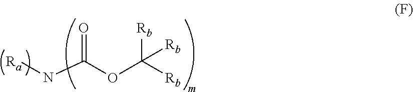

In the general formula (F), Rₐ independently represents a hydrogen atom, an alkyl group, a cycloalkyl group, an aryl group or an aralkyl group. When n=2, two Rₐ's may be the same as or different from each other, and the two Rₐ's may form a divalent heterocyclic hydrocarbon group (preferably having 20 or less carbon atoms) or a derivative thereof by bonding to each other.

R_{b} independently represents a hydrogen atom, an alkyl group, a cycloalkyl group, an aryl group or an aralkyl group. Here, in —C(R_{b})(R_{b})(R_{b}), when one or more R_{b}'s are hydrogen atoms, at least one of the remaining R_{b}'s is a cyclopropyl group or a 1-alkoxyalkyl group.

At least two R_{b}'s may form an alicyclic hydrocarbon group, an aromatic hydrocarbon group, a heterocyclic hydrocarbon group, or a derivative thereof by bonding to each other.

In represents an integer of 0 to 2, m represents an integer of 1 to 3, and n+m=3.

In the general formula (F), the alkyl group, cycloalkyl group, aryl group and aralkyl group represented by Rₐ and R_{b} may be substituted with a functional group such as a hydroxyl group, a cyano group, an amino group, a pyrrolidino group, a piperidino group, a morpholino group, an oxo group or with an alkoxy group or a halogen atom.

Examples of the alkyl group, cycloalkyl group, aryl group or aralkyl group (these alkyl group, cycloalkyl group, aryl group, and aralkyl group may be substituted with the functional group, alkoxy group, or halogen atom described above) of the R include

a group derived from a linear or branched alkane such as methane, ethane, propane, butane, pentane, hexane, heptane, octane, nonane, decane, undecane and dodecane; a group obtained by substituting these alkane-derived groups with one or more kinds or one or more cycloalkyl groups such as a cyclobutyl group, a cyclopentyl group and a cyclohexyl group;

a group derived from cycloalkane such as cyclobutane, cyclopentane, cyclohexane, cycloheptane, cyclooctane, norbornane, adamantane or noradamantane; a group obtained by substituting these cycloalkane-derived groups with one or more kinds or one or more linear or branched alkyl groups such as a methyl group, an ethyl group, an n-propyl group, an i-propyl group, an n-butyl group, a 2-methylpropyl group, a 1-methylpropyl group and a t-butyl group;

a group derived from aromatic compounds such as benzene, naphthalene and anthracene; a group obtained by substituting these aromatic compound-derived groups with one or more kinds or one or more linear or branched alkyl groups such as a methyl group, an ethyl group, an n-propyl group, an i-propyl group, an n-butyl group, a 2-methylpropyl group, a 1-methylpropyl group and a t-butyl group;

a group derived from heterocyclic compounds such as pyrrolidine, piperidine, morpholine, tetrahydrofuran, tetrahydropyran, indole, indoline, quinoline, perhydroquinoline, indazole and benzimidazole; a group obtained by substituting these heterocyclic compound-derived groups with one or more kinds or one or more of groups derived from a linear or branched alkyl group or a group derived from aromatic compounds; a group obtained by substituting a group derived from a linear or branched alkane and a group derived from cycloalkane with one or more kinds or one or more groups derived from aromatic compounds such as a phenyl group, a naphthyl group and an anthracenyl group; or a group obtained by substituting the above-described substituents with a functional group such as a hydroxyl group, a cyano group, an amino group, a pyrrolidino group, a piperidino group, a morpholino group and an oxo group.

Examples of the divalent heterocyclic hydrocarbon group (preferably having 1 to 20 carbon atoms) which the Rₐ form by bonding to each other or the derivative thereof include a group obtained by substituting a group derived from heterocyclic compounds such as pyrrolidine, piperidine, morpholine, 1,4,5,6-tetrahydropyrimidine, 1,2,3,4-tetrahydroquinoline, 1,2,3,6-tetrahydropyridine, homopiperazine, 4-azabenzimidazole, benzotriazole, 5-azabenzotriazole, 1H-1,2,3-triazole, 1,4,7-triazacyclononane, tetrazole, 7-azaindole, indazole, benzimidazole, imidazo[1,2-a]pyridine, (1S,4S)-(+)-2,5-diazabicyclo[2.2.1]heptane, 1,5,7-triazabicyclo[4.4.0]dec-5-ene, indole, indoline, 1,2,3,4-tetrahydroquinoxaline, perhydroquinoline and 1,5,9-triazacyclododecane, and a group derived from these heterocyclic compounds with one or more kinds or one or more groups derived from a linear or branched alkane, a group derived from a cycloalkane, a group derived from aromatic compounds, a group derived from heterocyclic compounds, and a functional group such as a hydroxyl group, a cyano group, an amino group, a pyrrolidino group, a piperidino group, a morpholino group and an oxo group.

Specific examples of the compound represented by the general formula (F) are shown below.

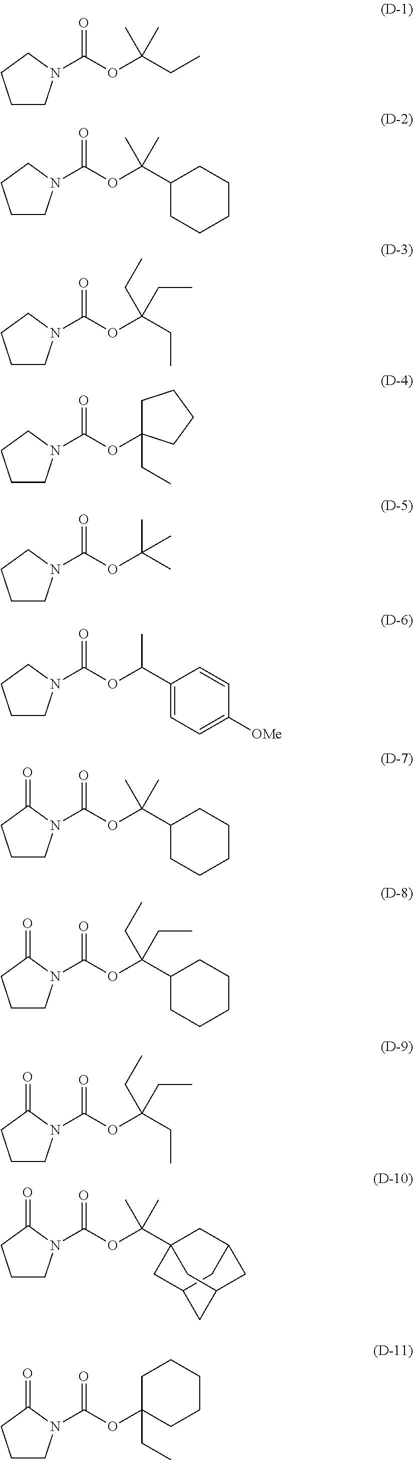

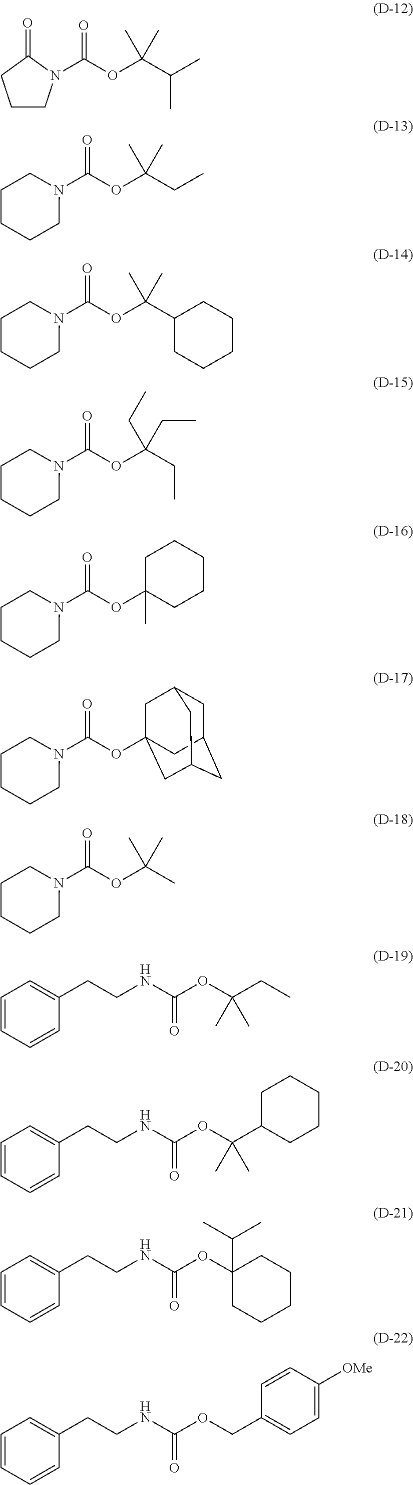

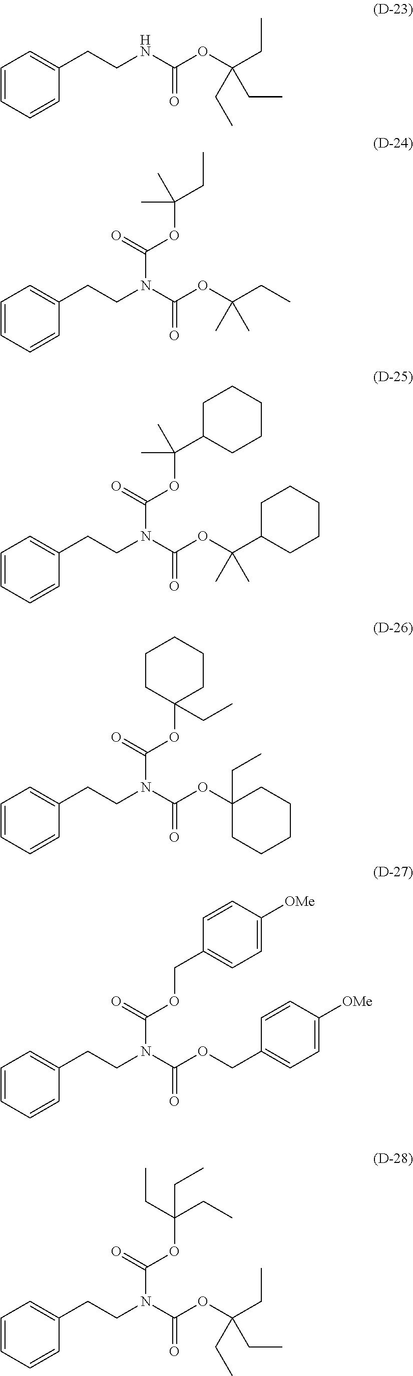

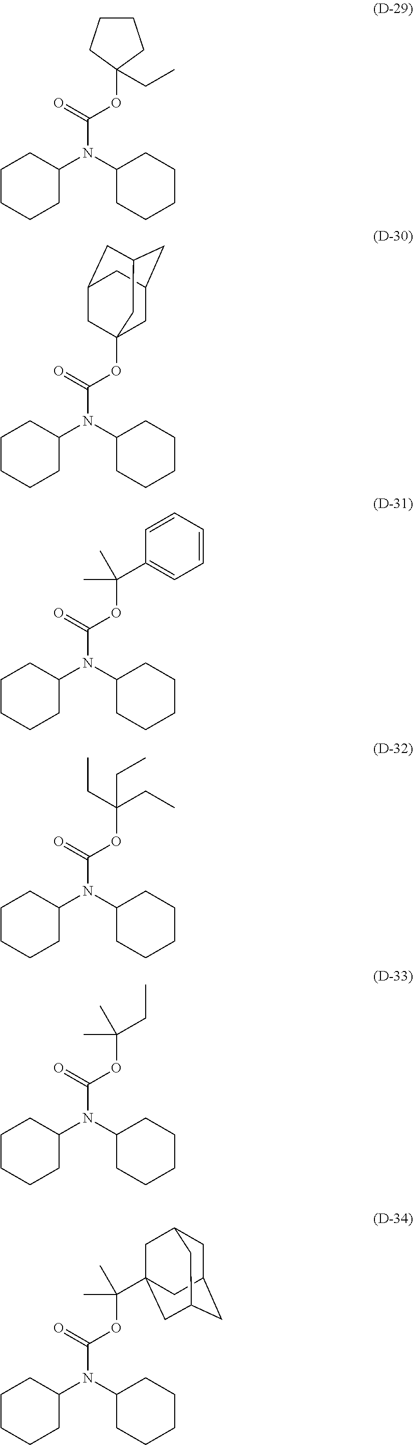

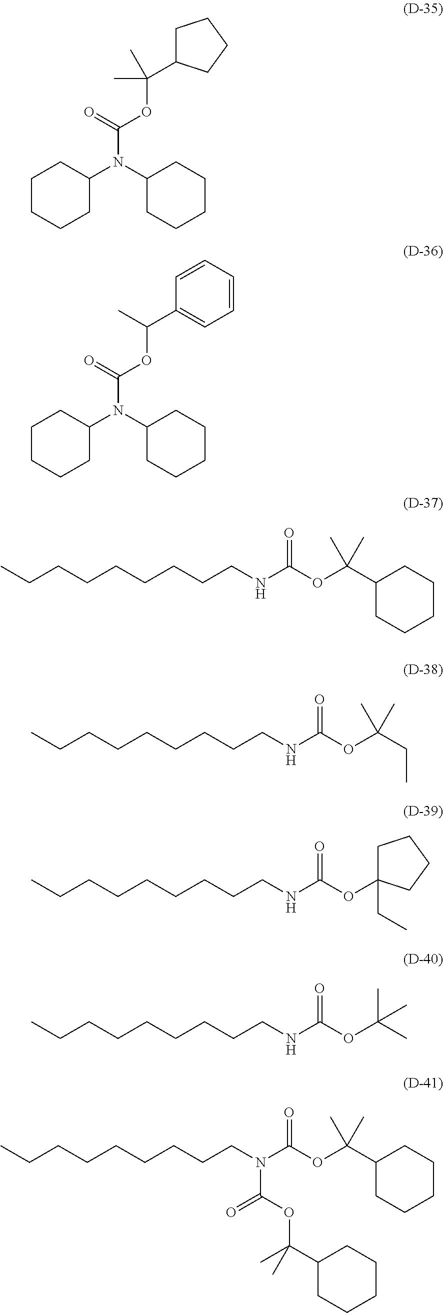

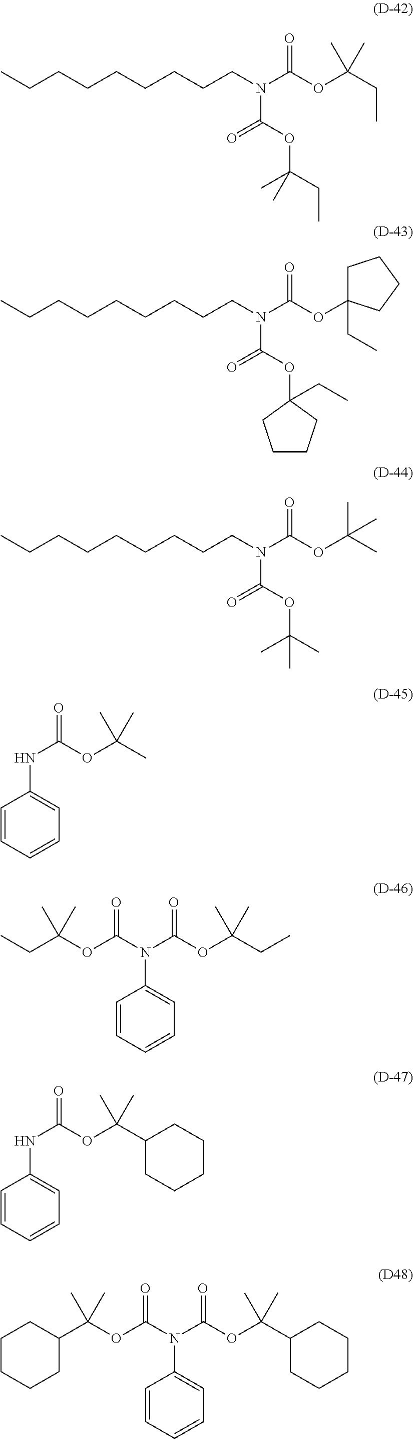

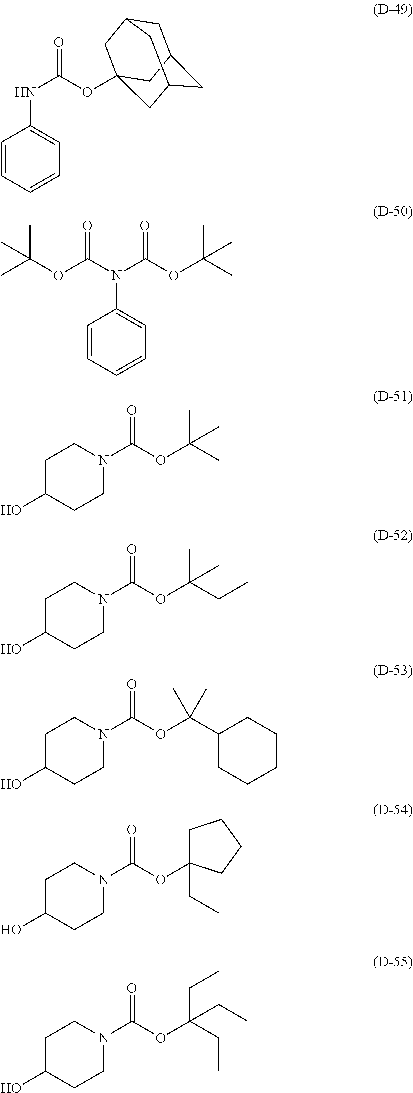

As the compound represented by the general formula (F), commercially available ones may be used. Alternatively, the compound may be synthesized from commercially available amines through a method disclosed in “Protective Groups in Organic Synthesis, 4^{th} edition” or the like. The compound can be synthesized based on the most common method, for example, the method disclosed in JP2009-199021A.

The molecular weight of the basic compound is preferably 250 to 2000, and even more preferably 400 to 1000. From the viewpoint of further reducing LWR and uniformity in local pattern dimension, the molecular weight of the basic compound is preferably 400 or more, more preferably 500 or more, and even more preferably 600 or more.

These basic compounds (C′) may be used alone or in combination with the above-described basic compound (C) or in combination of two or more kinds thereof.

The actinic ray-sensitive or radiation-sensitive resin composition of the present invention may or may not contain a basic compound. When a basic compound is contained, an amount of the basic compound used is generally 0.001 to 10% by mass, and preferably 0.01% to 5% by mass, based on the solid content of the actinic ray-sensitive or radiation-sensitive resin composition.

The ratio between the acid-generating agent and the basic compound used in the composition is preferably an acid-generating agent/a basic compound (molar ratio)=2.5 to 300. That is, in respect of the sensitivity and resolution of the resist film, the molar ratio is preferably 2.5 or higher, and in respect of inhibiting the reduction in resolution resulting from thickening of a resist pattern caused with elapse of time during baking treatment after exposing, the molar ratio is preferably 300 or lower. The acid-generating agent/basic compound (molar ratio) is more preferably 5.0 to 200, and more preferably 7.0 to 150.

[4] Solvent (D)

Examples of the solvent which may be used for preparing the actinic ray-sensitive or radiation-sensitive resin composition of the present invention include organic solvents such as alkylene glycol monoalkyl ether carboxylate, alkylene glycol monoalkyl ether, alkyl lactate ester, alkyl alkoxy propionate, cyclic lactone (preferably having 4 to 10 carbon atoms), a monoketone compound (preferably having 4 to 10 carbon atoms) which may have a ring, alkylene carbonate, alkyl alkoxy acetate and alkyl pyruvate.

Specific examples of these solvents include the solvents disclosed in Paragraphs 0441 to 0455 in the specification of US2008/0187860A.

In the present invention, as an organic solvent, a mixed solvent which is a mixture of a solvent containing a hydroxyl group in the structure and a solvent not containing a hydroxyl group may be used.

The solvent containing a hydroxyl group and the solvent not containing a hydroxyl group can be appropriately selected from the example compounds described above. The solvent containing a hydroxyl group is preferably alkylene glycol monoalkyl ether, alkyl lactate or the like, and more preferably propylene glycol monomethyl ether (PGME, having another name of 1-methoxy-2-propanol) or ethyl lactate. The solvent not containing a hydroxyl group is preferably alkylene glycol monoalkyl ether acetate, alkyl alkoxy propionate, a monoketone compound that may contain a ring, cyclic lactone, alkyl acetate or the like. Among these, propylene glycol monomethyl ether acetate (PGMEA, having another name of 1-methoxy-2-acetoxypropane), ethyl ethoxy propionate, 2-heptanone, γ-butyrolactone, cyclohexanone and butyl acetate are particularly preferable, and propylene glycol monomethyl ether acetate, ethyl ethoxy propionate and 2-heptanone are most preferable.

The mixing ratio (mass) between the solvent containing a hydroxyl group and the solvent not containing a hydroxyl group is 1/99 to 99/1, preferably 10/90 to 90/10, and more preferably 20/80 to 60/40. A mixed solvent which contains 50% by mass or more of the solvent not containing a hydroxyl group is particularly preferable in respect of coating uniformity.

The solvent preferably contains propylene glycol monomethyl ether acetate. In addition, the solvent is preferably a single solvent of propylene glycol monomethyl ether acetate or a mixed solvent of two or more kinds of solvents containing propylene glycol monomethyl ether acetate.

[5] Hydrophobic Resin (E)

When the actinic ray-sensitive or radiation-sensitive resin composition of the present invention is applied particularly to the liquid immersion exposure, this composition may contain a hydrophobic resin (hereinafter, also referred to as a “hydrophobic resin (E)” or simply as a “resin (E)”) which contains at least one of fluorine atoms and silicon atoms. In this manner, the hydrophobic resin (E) is localized on the surface layer of a film, and the static and dynamic contact angle of the resist film surface with respect to water (a liquid immersion medium) is improved accordingly, whereby followability of the resist film with respect to the liquid for liquid immersion is improved.

It is preferable to design such that the hydrophobic resin (E) is localized in the interface as described above. However, contrary to a surfactant, the hydrophobic resin does not necessarily have a hydrophilic group in a molecule and may not help a polar substance and a non-polar substance to be evenly mixed.

The hydrophobic resin (E) typically contains a fluorine atoms and/or a silicon atoms. The fluorine atoms and/or the silicon atoms in the hydrophobic resin (E) may be contained in either the main chain or the side chain of the resin.

When the hydrophobic resin (E) contains fluorine atoms, the resin is preferably a resin including, as a partial structure containing fluorine atoms, an alkyl group having fluorine atoms, a cycloalkyl group having fluorine atoms or an aryl group having a fluorine atom.

The alkyl group (preferably having 1 to 10 carbon atoms, and more preferably having 1 to 4 carbon atoms) having a fluorine atom is a linear or branched alkyl group in which at least one hydrogen atom is substituted with a fluorine atom, and may further have a substituent other than a fluorine atom.

The cycloalkyl group having a fluorine atom is a monocyclic or polycyclic cycloalkyl group in which at least one hydrogen atom is substituted with a fluorine atom, and may further have a substituent other than a fluorine atom.

Examples of the aryl group having a fluorine atom include aryl groups such as a phenyl group and naphthyl group in which at least one hydrogen atom is substituted with a fluorine atom. The aryl group may further have a substituent other than a fluorine atom.

Examples of the alkyl group having a fluorine atom, the cycloalkyl group having a fluorine atom, and the aryl group having a fluorine atom preferably include groups represented by the following general formulae (F2) to (F4), but the present invention is not limited thereto.

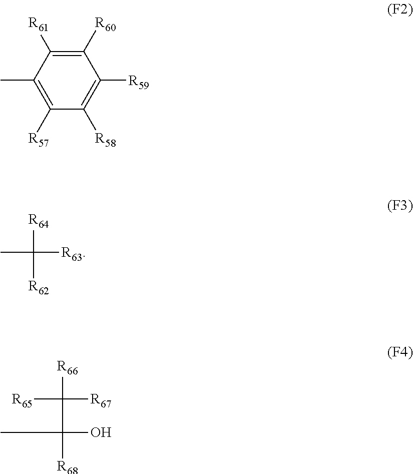

In the general formulae (F2) to (F4),
each of R₅₇ to R₆₈ independently represents a hydrogen atom, a fluorine atom, or a (linear or branched) alkyl group. Here, at least one of R₅₇ to R₆₁, at least one of R₆₂ to R₆₄ and at least one of R₆₅ to R₆₈ independently represent a fluorine atom or an alkyl group (preferably having 1 to 4 carbon atoms) in which at least one hydrogen atom has been substituted with a fluorine atom.

All of R₅₇ to R₆₁ and R₆₅ to R₆₇ are preferably fluorine atoms. R₆₂, R₆₃, and R₆₈ are preferably alkyl groups (preferably having 1 to 4 carbon atoms) in which at least one hydrogen atom has been substituted with a fluorine atom, and more preferably perfluoroalkyl groups having 1 to 4 carbon atoms. R₆₂ and R₆₃ may form a ring by being bonded to each other.

Specific examples of the group represented by the general formula (F2) include a p-fluorophenyl group, a pentafluorophenyl group, a 3,5-di(trifluoromethyl)phenyl group, and the like.

Specific examples of the group represented by the general formula (F3) include a trifluoromethyl group, a pentafluoropropyl group, a pentafluoroethyl group, a heptafluorobutyl group, a hexafluoroisopropyl group, a heptafluoroisopropyl group, a hexafluoro(2-methyl)isopropyl group, a nonafluorobutyl group, an octafluoroisobutyl group, a nonafluorohexyl group, a nonafluoro-t-butyl group, a perfluoroisopentyl group, a perfluorooctyl group, a perfluoro(trimethyl)hexyl group, a 2,2,3,3-tetrafluorocyclobutyl group, a perfluorocyclohexyl group, and the like. Among these, a hexafluoroisopropyl group, a heptafluoroisopropyl group, a hexafluoro(2-methyl)isopropyl group, an octafluoroisobutyl group, a nonafluoro-t-butyl group, and a perfluoroisopentyl group are preferable, and a hexafluoroisopropyl group and a heptafluoroisopropyl group are more preferable.

Specific examples of the group represented by the general formula (F4) include —C(CF₃)₂OH, —C(C₂F₅)₂OH, —C(CF₃)(CH₃)OH, —CH(CF₃)OH and the like, and —C(CF₃)₂OH is preferable.

The partial structure having a fluorine atom may directly bond to the main chain, or may bond to the main chain through a group selected from a group consisting of an alkylene group, a phenylene group, an ether bond, a thioether bond, a carbonyl group, an ester bond, an amide bond, a urethane bond and a ureylene bond, or through a group including a combination of two or more kinds of the above ones.

Examples of suitable repeating units having a fluorine atom include repeating units shown below.

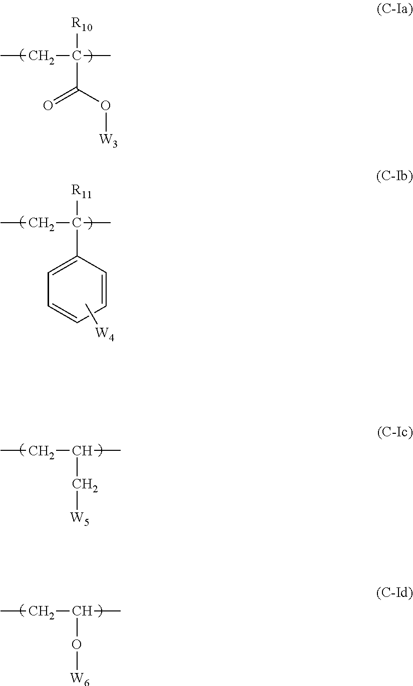

In the formulae, each of R₁₀ and R₁₁ independently represents a hydrogen atom, a fluorine atom, or an alkyl group. The alkyl group is preferably a linear or branched alkyl group having 1 to 4 carbon atoms and may have a substituent. Examples of the alkyl group having a substituent particularly include a fluorinated alkyl group.

Each of W₃ to W₆ independently represents an organic group containing at least one or more fluorine atom, and specific examples thereof include atomic groups of (F2) to (F4) described above.

In addition to the above repeating units, the hydrophobic resin (E) may include units shown below as the repeating unit having a fluorine atom.

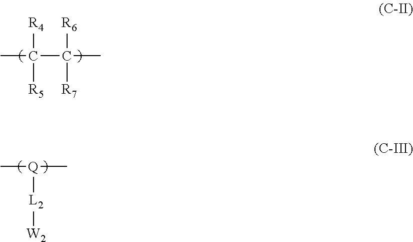

In the formulae, each of R₄ to R₇ independently represents a hydrogen atom, a fluorine atom, or an alkyl group. The alkyl group is preferably a linear or branched alkyl group having 1 to 4 carbon atoms, and may have a substituent. Examples of the alkyl group having a substituent particularly include a fluorinated alkyl group.

Here, at least one of R₄ to R₇ represents a fluorine atom. R₄ and R₅ or R₆ and R₇ may form a ring.

W₂ represents an organic group containing at least one fluorine atom, and specific examples thereof include atomic groups of (F2) to (F4) described above.

L₂ represents a single bond or a divalent linking group. Examples of the divalent linking group include a substituted or unsubstituted arylene group, a substituted or unsubstituted alkylene group, a substituted or unsubstituted cycloalkylene group, —O—, —SO₂—, —CO—, —N(R)— (wherein R represents a hydrogen atom or alkyl), —NHSO₂— or a divalent linking group including a combination of a plurality thereof.

Q represents an alicyclic structure. The alicyclic structure may have a substituent, and may be monocyclic or polycyclic. If the structure is polycyclic, the structure may be a bridged structure. The monocyclic structure is preferably a cycloalkyl group having 3 to 8 carbon atoms, and examples thereof include a cyclopentyl group, a cyclohexyl group, a cyclobutyl group, a cyclooctyl group and the like. Examples of the polycyclic structure include groups having a bicyclo, tricyclo, or tetracyclo structure having 5 or more carbon atoms, and a cycloalkyl group having 6 to 20 carbon atoms is preferable. Examples thereof include an adamantyl group, a norbornyl group, a dicyclopentyl group, a tricyclodecanyl group, a tetracyclododecyl group, and the like. A portion of the carbon atoms in the cycloalkyl group may be substituted with hetero atoms such as oxygen atoms. Particularly preferable examples of Q include a norbornyl group, a tricyclodecanyl group, a tetracyclododecyl group, and the like.

Specific examples of the repeating unit having a fluorine atom is shown below, but the present invention is not limited thereto.

In the specific examples, X₁ represents a hydrogen atom, —CH₃, —F or —CF₃, and X₂ represents —F or —CF₃.

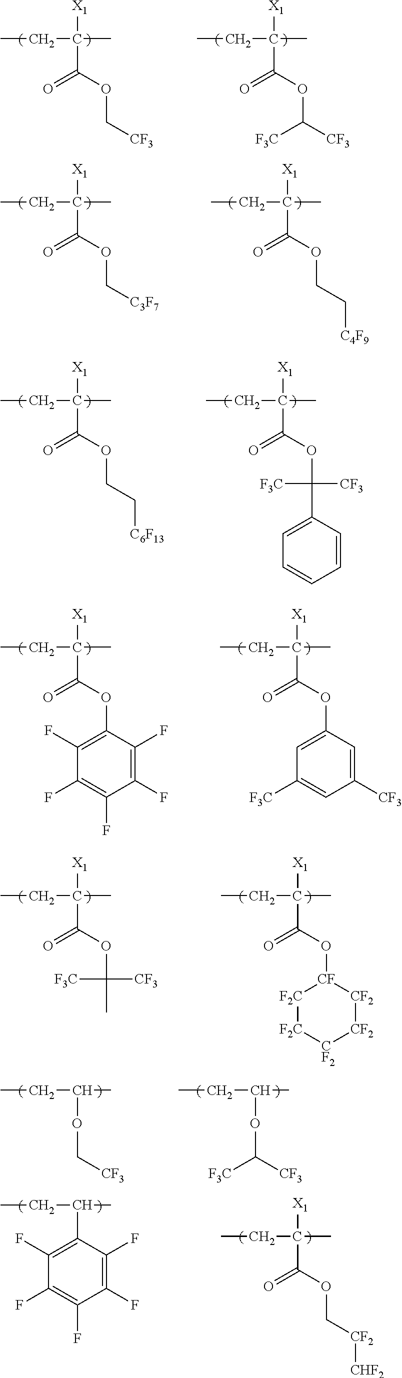

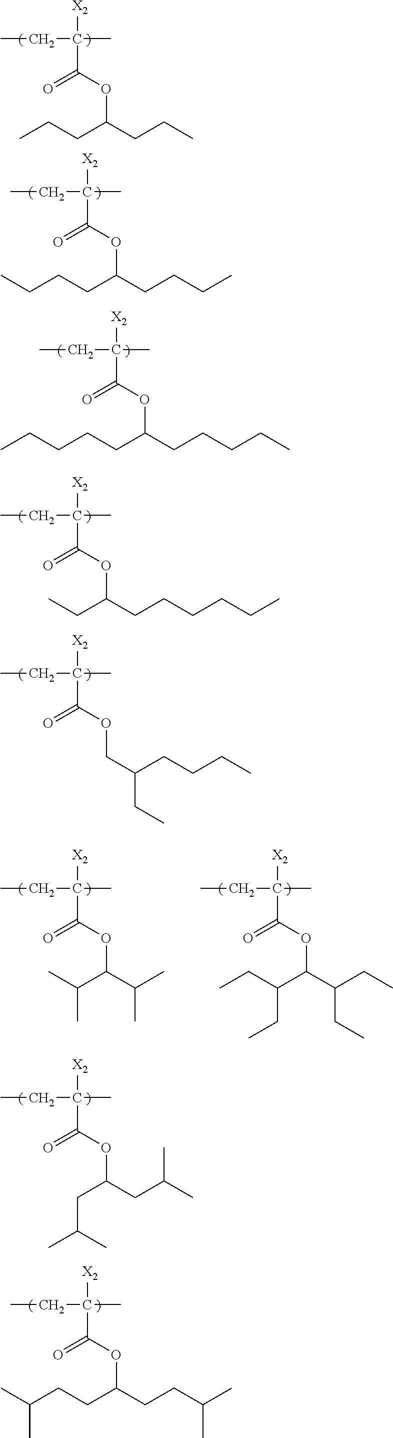

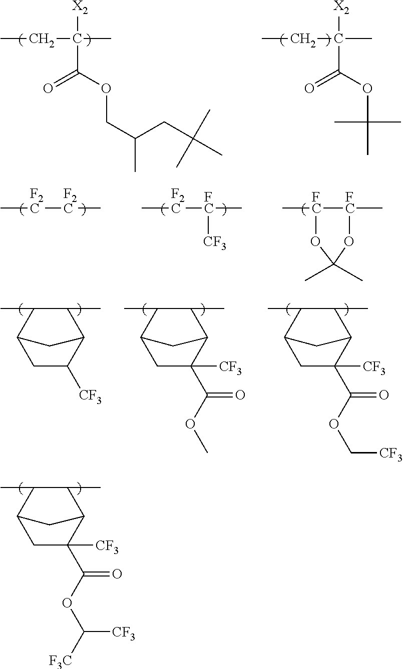

The hydrophobic resin (E) may contain silicon atoms. The hydrophobic resin (E) preferably has an alkylsilyl structure (preferably a trialkylsilyl group) or a cyclic siloxane structure as a partial structure having silicon atoms.

Specific examples of the alkylsilyl structure or the cyclic siloxane structure include groups represented by the following general formulae (CS-1) to (CS-3).

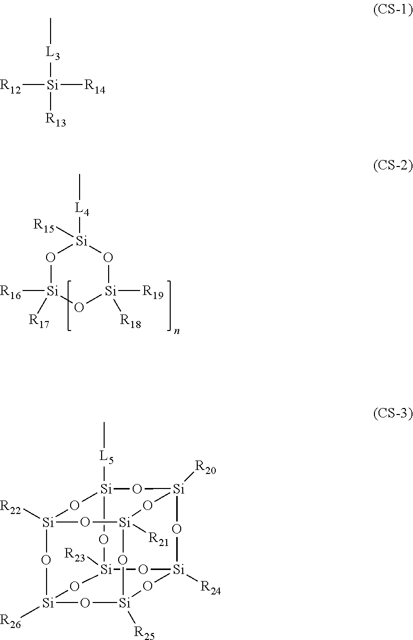

In the general formulae (CS-1) to (CS-3),
each of R₁₂ to R₂₆ independently represents a linear or branched alkyl group (preferably having 1 to 20 carbon atoms) or a cycloalkyl group (preferably having 3 to 20 carbon atoms),
L₃ to L₅ represent a single bond or a divalent linking group, examples of the divalent linking group include a single group or a combination of two or more kinds of groups (preferably having 12 or less carbon atoms in total) selected from a group consisting of an alkylene group, a phenylene group, an ether bond, a thioether bond, a carbonyl group, an ester bond, an amide bond, a urethane bond and a urea bond, and
n represents an integer of 1 to 5, and is preferably an integer of 2 to 4.

Specific examples of the repeating unit having the group represented by the general formulae (CS-1) to (CS-3) are shown below, but the present invention is not limited thereto. In the specific examples, X₁ represents a hydrogen atom, —CH₃, —F or —CF₃.

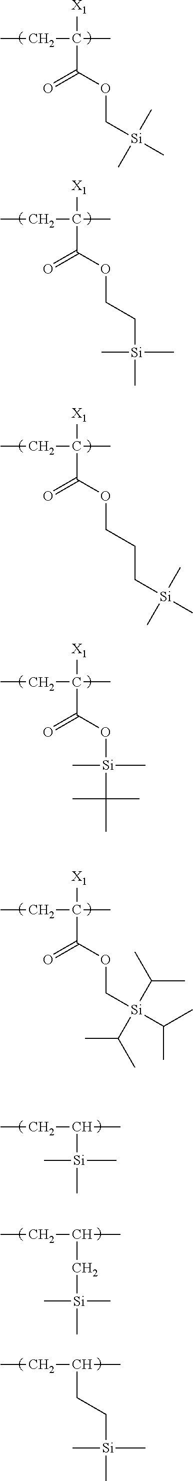

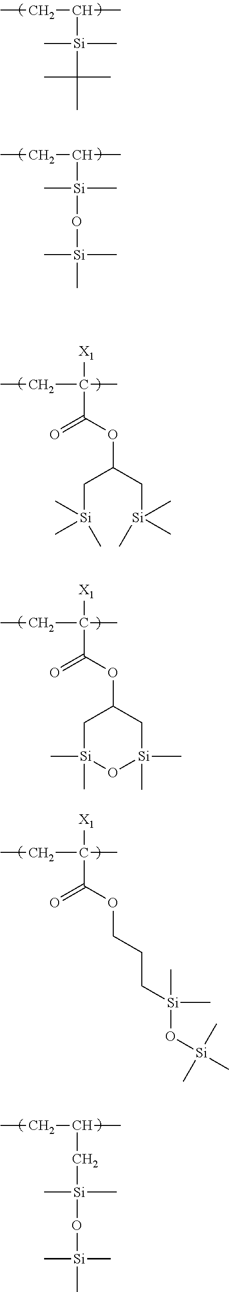

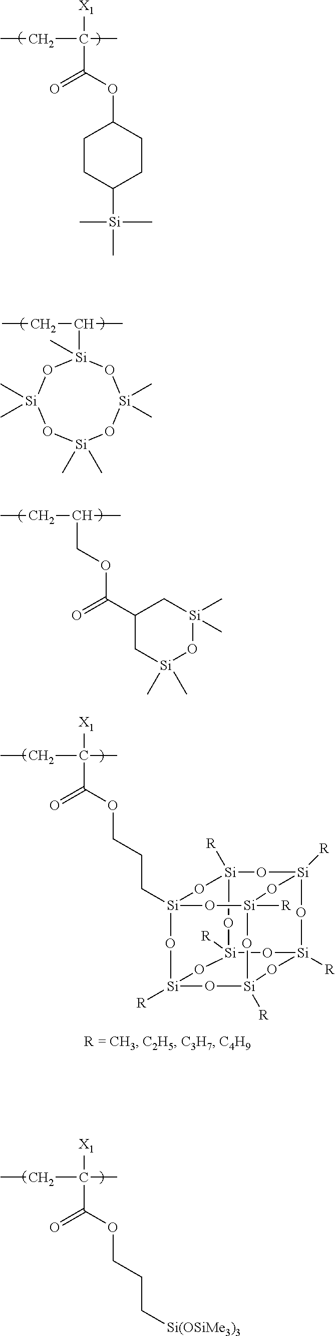

The hydrophobic resin (E) may further contain at least one group selected from a group consisting of (x) to (z) shown below.
(x) an acid group
(y) a group having a lactone structure, an acid anhydride group or an acid imide group
(z) a group decomposes by an action of an acid

Examples of the acid group (x) include a phenolic hydroxyl group, a carboxylic group, a fluorinated alcohol group, a sulfonic acid group, a sulfonamide group, a sulfonylimide group, an (alkylsulfonyl)(alkylcarbonyl)methylene group, an (alkylsulfonyl)(alkylcarbonyl)imide group, a bis(alkylcarbonyl)methylene group, a bis(alkylcarbonyl)imide group, a bis(alkylsulfonyl)methylene group, a bis(alkylsulfonyl)imide group, a tris(alkylcarbonyl)methylene group, a tris(alkylsulfonyl)methylene group, and the like.

Examples of the preferable acid group include a fluorinated alcohol group (preferably a hexafluoroisopropanol), a sulfonamide group, and a bis(alkylcarbonyl)methylene group.

Examples of a repeating unit having the acid group (x) include a repeating unit in which the acid group directly bonds to the main chain of a resin, such as a repeating unit of acrylic acid or methacrylic acid, a repeating unit in which the acid group bonds to the main chain of a resin through a linking group, and the like. In addition, a polymerization initiator and a chain transfer agent having an acid group may be introduced to the terminal of a polymer chain in polymerization, and any of these cases is preferable. The repeating unit having the acid group (x) may contain at least any one of a fluorine atom and a silicon atom.

The content of the repeating unit having the acid group (x) is preferably 1 mol % to 50 mol %, more preferably 3 mol % to 35 mol %, and even more preferably 5 mol % to 20 mol %, based on all repeating units in the hydrophobic resin (E).

Specific examples of the repeating unit having the acid group (x) are shown below, but the present invention is not limited thereto. In the formula, Rx represents a hydrogen atom, CH₃, CF₃, or CH₂OH.

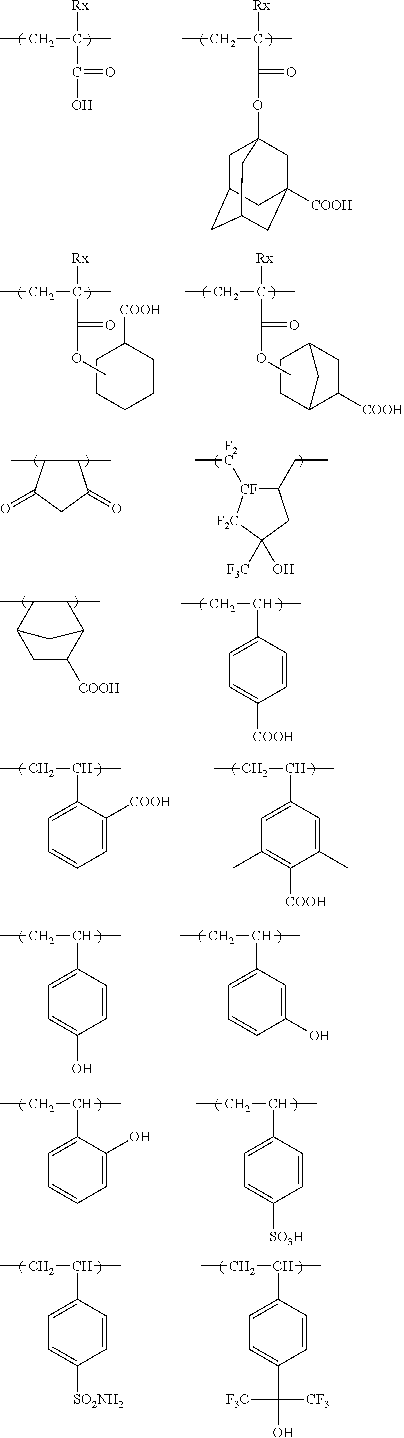

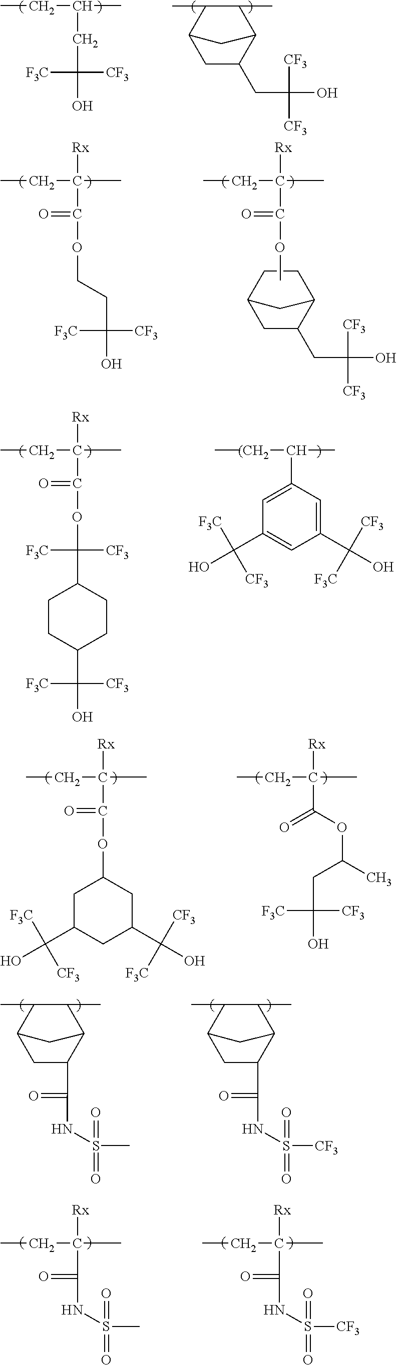

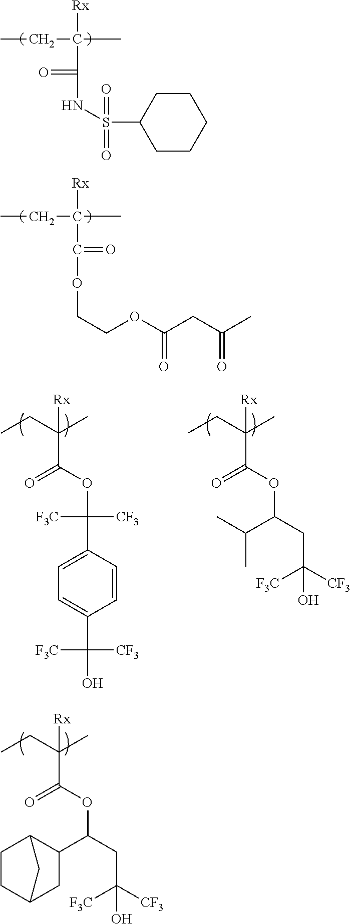

As “(y) the group having a lactone structure, the acid anhydride group or the acid imide group”, the group having a lactone structure is particularly preferable.

A repeating unit having the group (y) is a repeating unit in which the group (y) is directly bonded to the main chain of the resin, such as a repeating unit of acrylic acid ester or methacrylic acid ester. Alternatively, the repeating unit may be a repeating unit in which the group (y) is bonded to the main chain of the resin through a linking group. As another option, the repeating unit may be introduced to the terminal of the resin by using a polymerization initiator or a chain transfer agent containing these groups during polymerization.

Examples of the repeating unit containing the group having a lactone structure include the same ones as those of the repeating unit having a lactone structure described above for the acid-decomposable resin (P).

The content of the repeating unit containing the group having a lactone structure, the acid anhydride group or the acid imide group is preferably 1 mol % to 100 mol %, more preferably 3 mol % to 98 mol %, and even more preferably 5 mol % to 95 mol %, based on all repeating units in the hydrophobic resin.

Examples of (z) the repeating unit containing the group decomposed by the action of an acid in the hydrophobic resin (E) include the same ones as those of the repeating unit containing an acid-decomposable group exemplified for the resin (P). The repeating unit containing the group (z) decomposed by the action of an acid may include at least any one of fluorine atoms and silicon atoms. The content of the repeating unit containing the group (z) decomposed by the action of an acid in the hydrophobic resin (E) is preferably 1 mol % to 80 mol %, more preferably 10 mol % to 80 mol %, and even more preferably 20 mol % to 60 mol %, based on all repeating units in the resin (E).

The hydrophobic resin (E) may further contain a repeating unit represented by the following general formula (CIII).

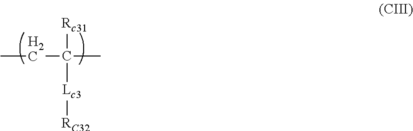

In the general formula (CIII),
R_{c31} represents a hydrogen atom, an alkyl group (which may be substituted with a fluorine atom or the like), a cyano group or a —CH₂—O-Rac₂ group. In the formula, Rac₂ represents a hydrogen atom, an alkyl group or an acyl group. R_{c31} is preferably a hydrogen atom, a methyl group, a hydroxymethyl group, or a trifluoromethyl group, and particularly preferably a hydrogen atom or a methyl group,
R_{c32} represents a group having an alkyl group, a cycloalkyl group, an alkenyl group, a cycloalkenyl group, or an aryl group, these groups may be substituted with a group containing a fluorine atom or a silicon atom, and
L_{c3} represents a single bond or a divalent linking group.

The alkyl group of R_{c32} in the general formula (CIII) is preferably a linear or branched alkyl group having 3 to 20 carbon atoms.

The cycloalkyl group is preferably a cycloalkyl group having 3 to 20 carbon atoms.

The alkenyl group is preferably an alkenyl group having 3 to 20 carbon atoms.

The cycloalkenyl group is preferably a cycloalkenyl group having 3 to 20 carbon atoms.

The aryl group is preferably an aryl group having 6 to 20 carbon atoms, and more preferably a phenyl group or a naphthyl group and may have a substituent.

R_{c32} is an unsubstituted alkyl group or an alkyl group substituted with a fluorine atom.

The divalent linking group of L_{c3} is preferably an alkylene group (preferably having 1 to 5 carbon atoms), an ether bond, a phenylene group, or an ester bond (a group represented by —COO—).

The content of the repeating unit represented by the general formula (CIII) is preferably 1 to 100 mol %, more preferably 10 to 90 mol %, and even more preferably 30 to 70 mol %, based on all repeating units in the hydrophobic resin.

The hydrophobic resin (E) preferably further contains the repeating unit represented by the following general formula (CII-AB).

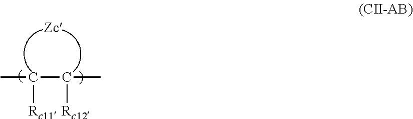

In the formula (CII-AB),
each of R_{c11}′ and R_{c12}′ independently represents a hydrogen atom, a cyano group, a halogen atom, or an alkyl group, and
Zc′ contains two carbon atoms (C—C) binding to each other, and represents an atomic group necessary for forming an alicyclic structure.

The content of the repeating unit represented by General Formula (CII-AB) is preferably 1 mol % to 100 mol %, more preferably 10 mol % to 90 mol %, and even more preferably 30 mol % to 70 mol %, based on all repeating units in the hydrophobic resin.

Specific examples of the repeating units represented by General Formulae (III) and (CII-AB) is shown below, but the present invention is not limited thereto. In the formulae, Ra represents H, CH₃, CH₂OH, CF₃, or CN.

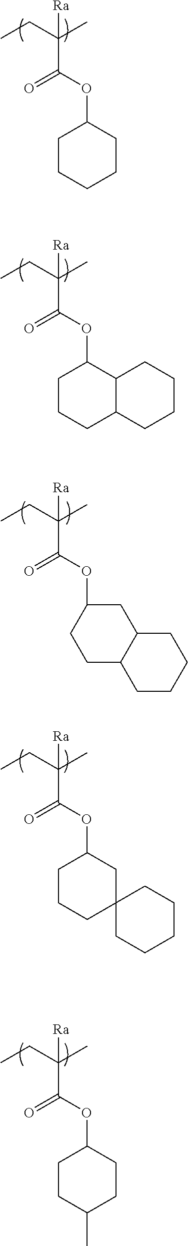

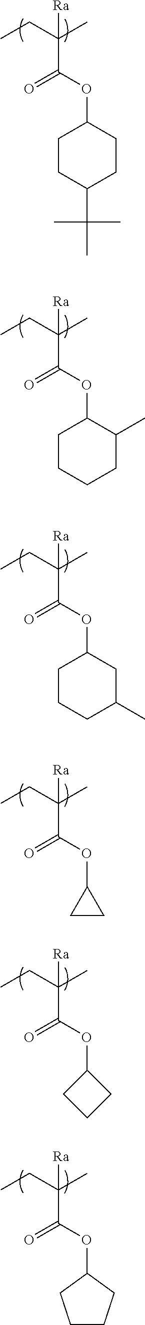

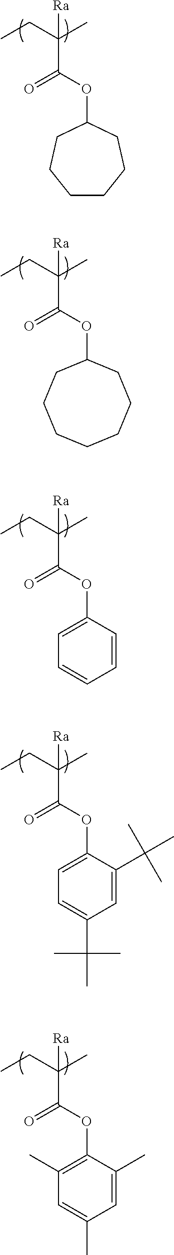

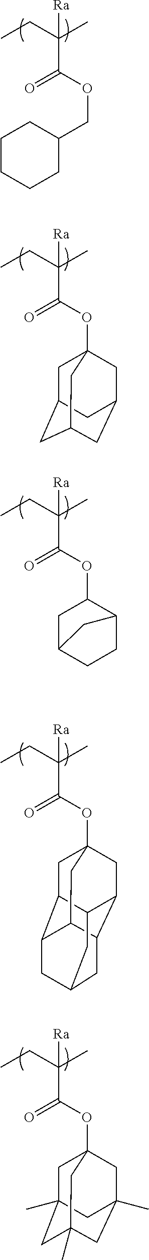

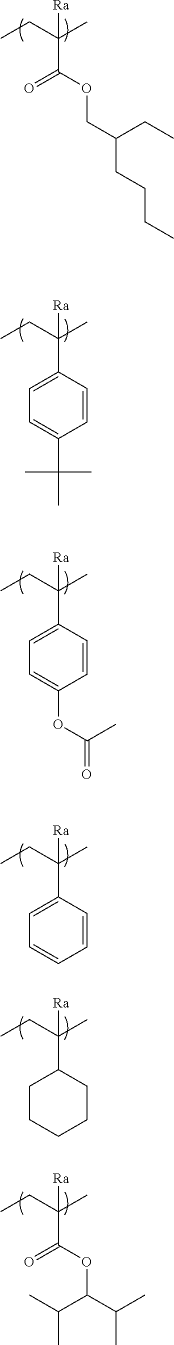

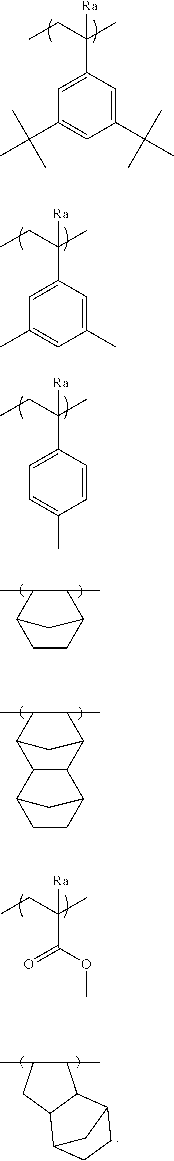

When the hydrophobic resin (E) contains fluorine atoms, the content of the fluorine atoms is preferably 5% to 80% by mass, and more preferably 10% to 80% by mass, based on the weight average molecular weight of the hydrophobic resin (E). In addition, the content of the repeating unit containing a fluorine atom is preferably 10 to 100 mol %, and more preferably 30 to 100 mol %, based on all repeating units contained in the hydrophobic resin (E).

When the hydrophobic resin (E) contains a silicon atom, the content of the silicon atoms is preferably 2 to 50% by mass, and more preferably 2 to 30% by mass, based on the weight average molecular weight of the hydrophobic resin (E). In addition, the content of the repeating unit containing a silicon atom is preferably 10 to 100 mol %, and more preferably 20 to 100 mol %, based on all repeating units contained in the hydrophobic resin (E).

The weight average molecular weight of the hydrophobic resin (E) calculated in terms of standard polystyrene is preferably 1,000 to 100,000, more preferably 1,000 to 50,000, and even more preferably 2,000 to 15,000.

The hydrophobic resin (E) may be used alone, or a plurality of hydrophobic resins (E) may be used concurrently.

The content of the hydrophobic resin (E) in the composition is preferably 0.01 to 10% by mass, more preferably 0.05 to 8% by mass, and even more preferably 0.1 to 5% by mass, based on the total solid content in the composition of the present invention.

It is natural that the hydrophobic resin (E) contains a small amount of impurities such as metals, similarly to the resin (P), and the amount of residual monomers and oligomer components is preferably 0.01 to 5% by mass, more preferably 0.01 to 3% by mass, and even more preferably 0.05% to 1% by mass. In this amount, an actinic ray-sensitive or radiation-sensitive resin composition is obtained which does not have foreign matter in a liquid and does not show the change in sensitivity or the like over time. The molecular weight distribution (Mw/Mn, which is also referred to as degree of dispersion) is preferably in a range of from 1 to 5, more preferably in a range of from 1 to 3, and even more preferably in a range of from 1 to 2, in respect of resolution, the resist shape, side walls of the resist pattern, roughness, and the like.

As the hydrophobic resin (E), various commercially available products can be used, and the hydrophobic resin can also be synthesized by a common method (for example, a radical polymerization). Examples of the general synthesis method include batch polymerization in which polymerization is performed by dissolving monomer materials and initiators in a solvent and heating the resultant, and dropping polymerization in which a solution including monomer materials and initiators is added dropwise to a heated solvent for 1 to 10 hours. A preferable method is the dropping polymerization.

The reaction solvent, polymerization initiator, reaction conditions (temperature, concentration, and the like), and a method of purification after the reaction are the same as those that were described for the resin (P). However, for synthesizing the hydrophobic resin (E), the reaction concentration is preferably 30% to 50% by mass.

Specific examples of the hydrophobic resin (E) is shown below. In addition, the molar ratio (corresponding to the respective repeating units from left in order), weight average molecular weight, degree of dispersion of repeating units in the respective resins are shown in the following Table 1 and Table 2.

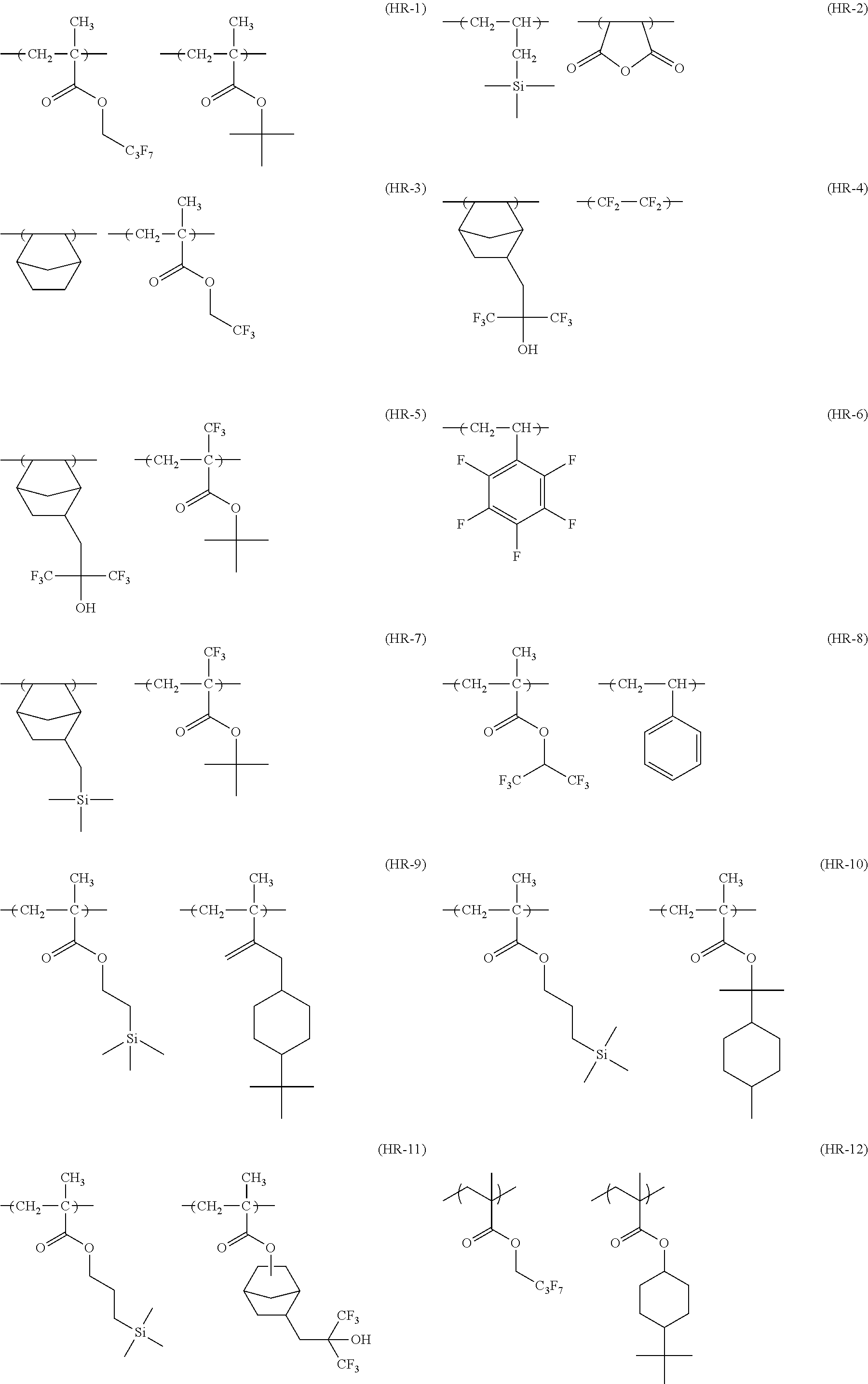

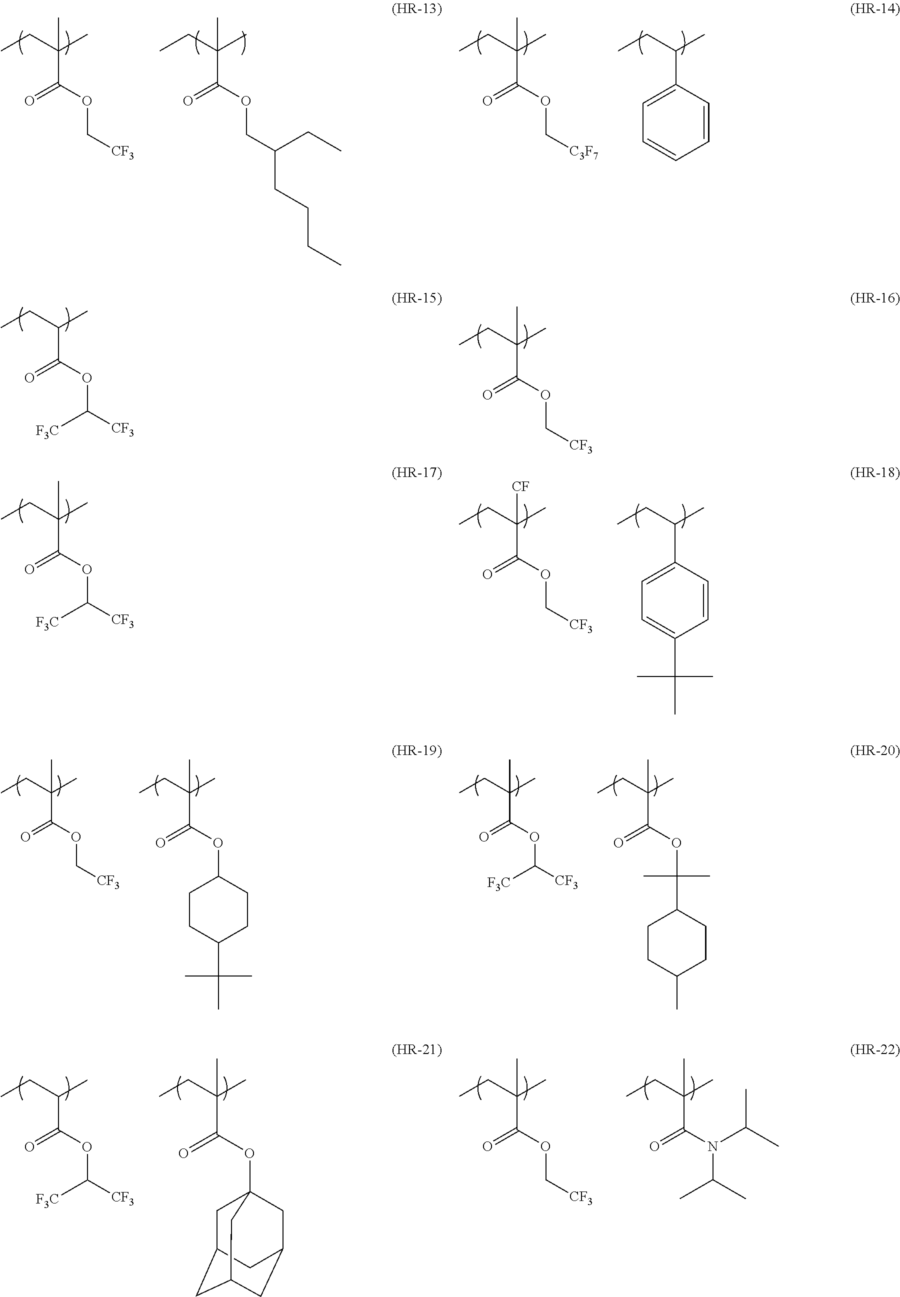

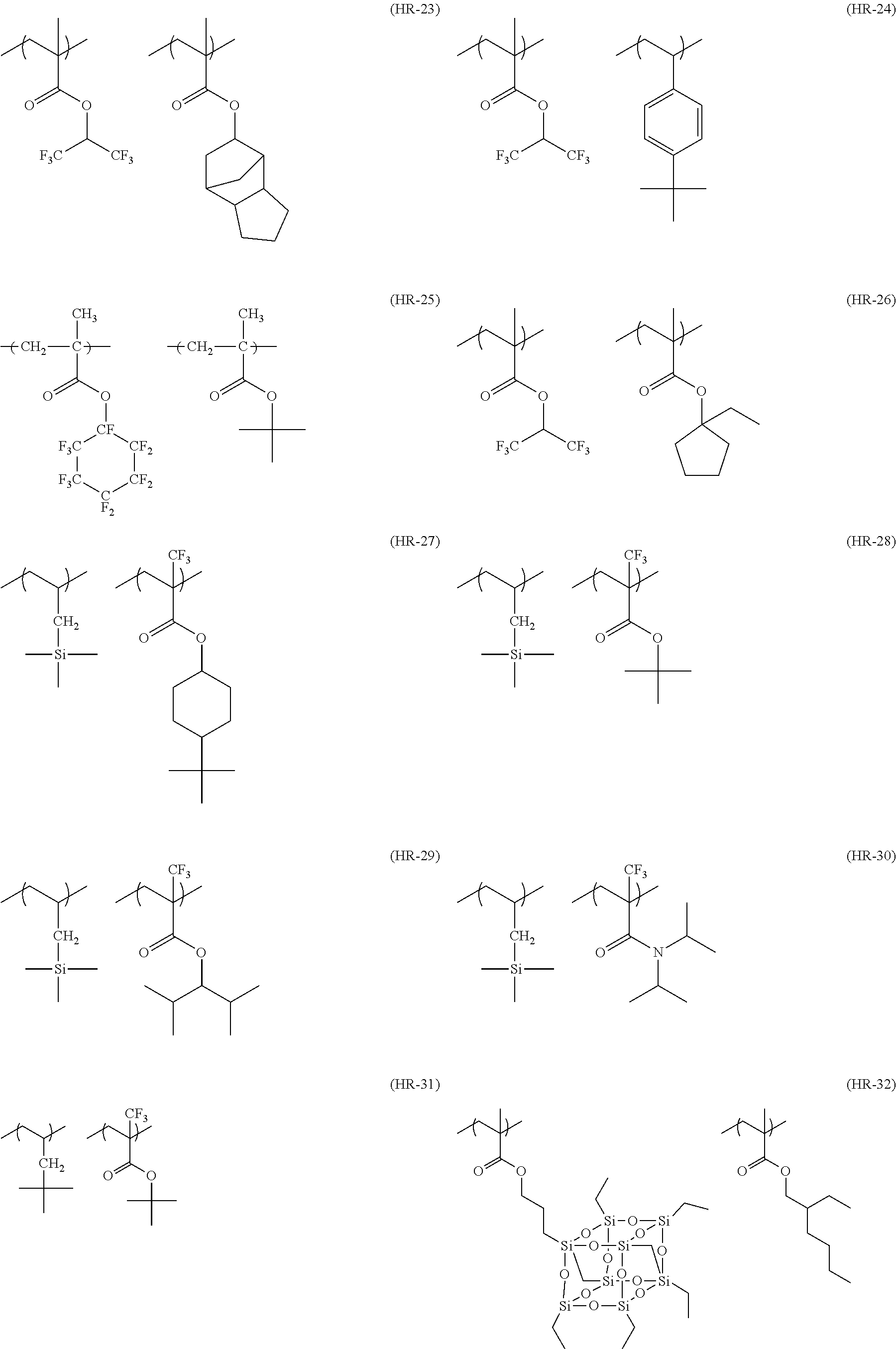

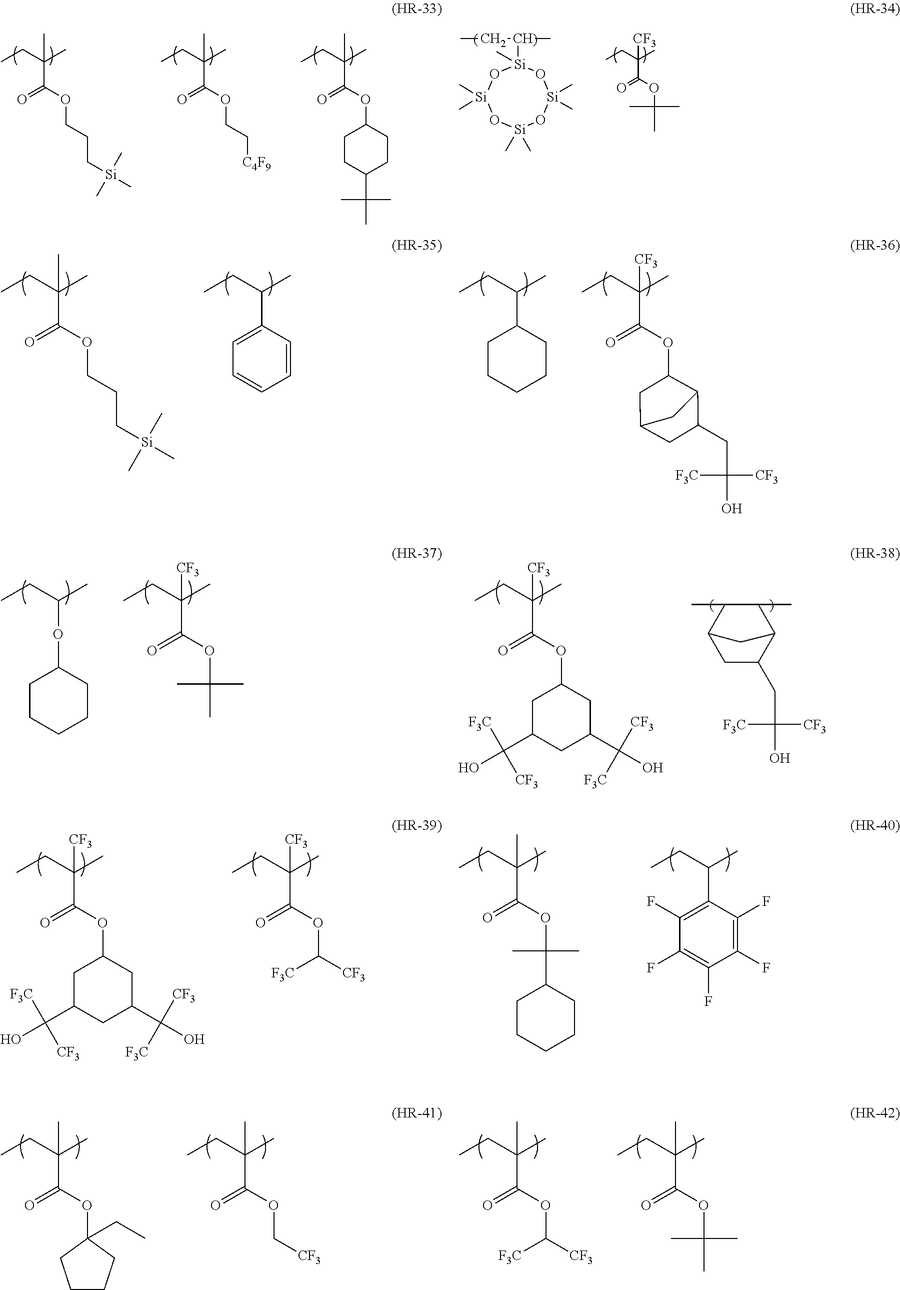

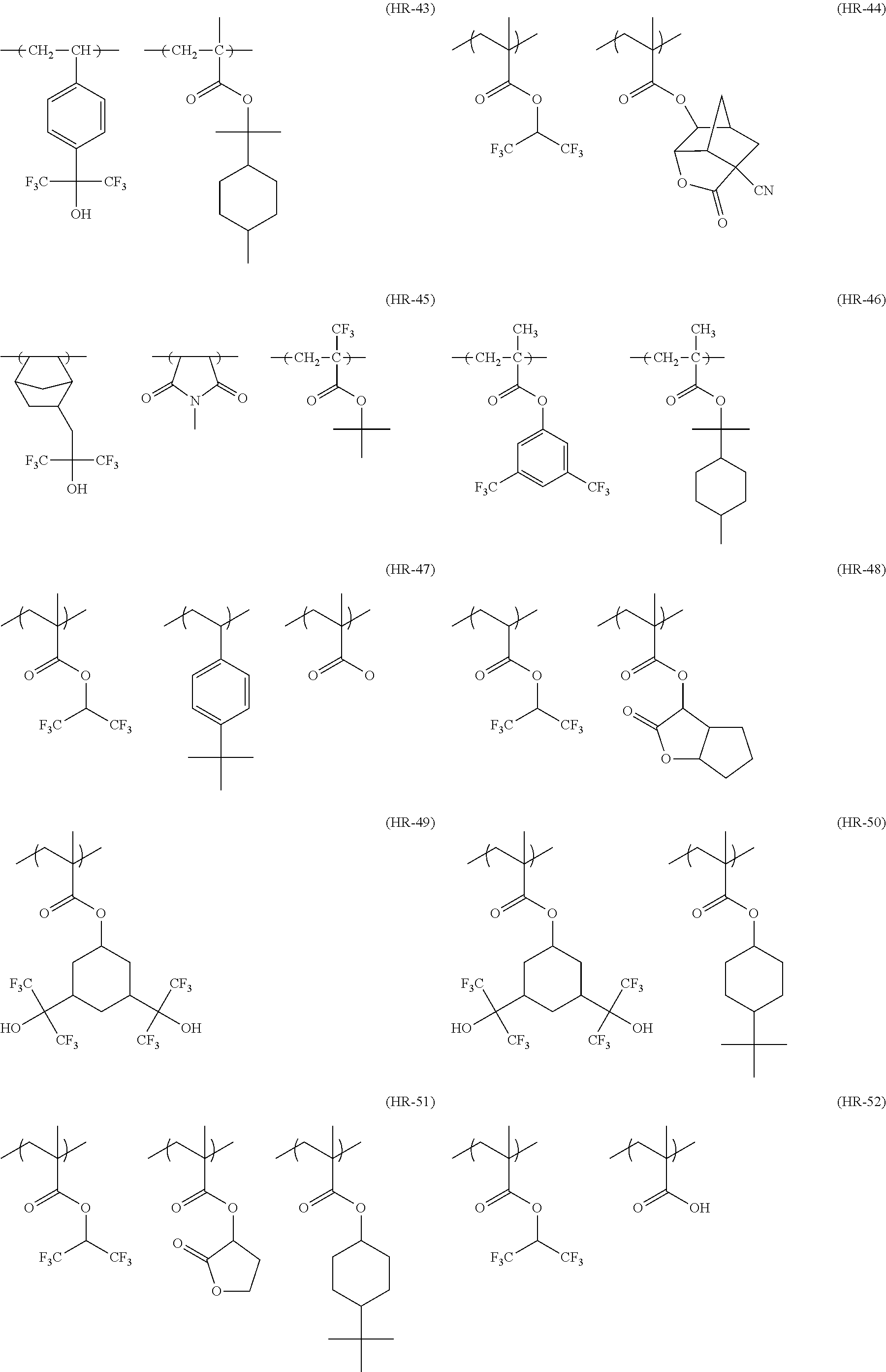

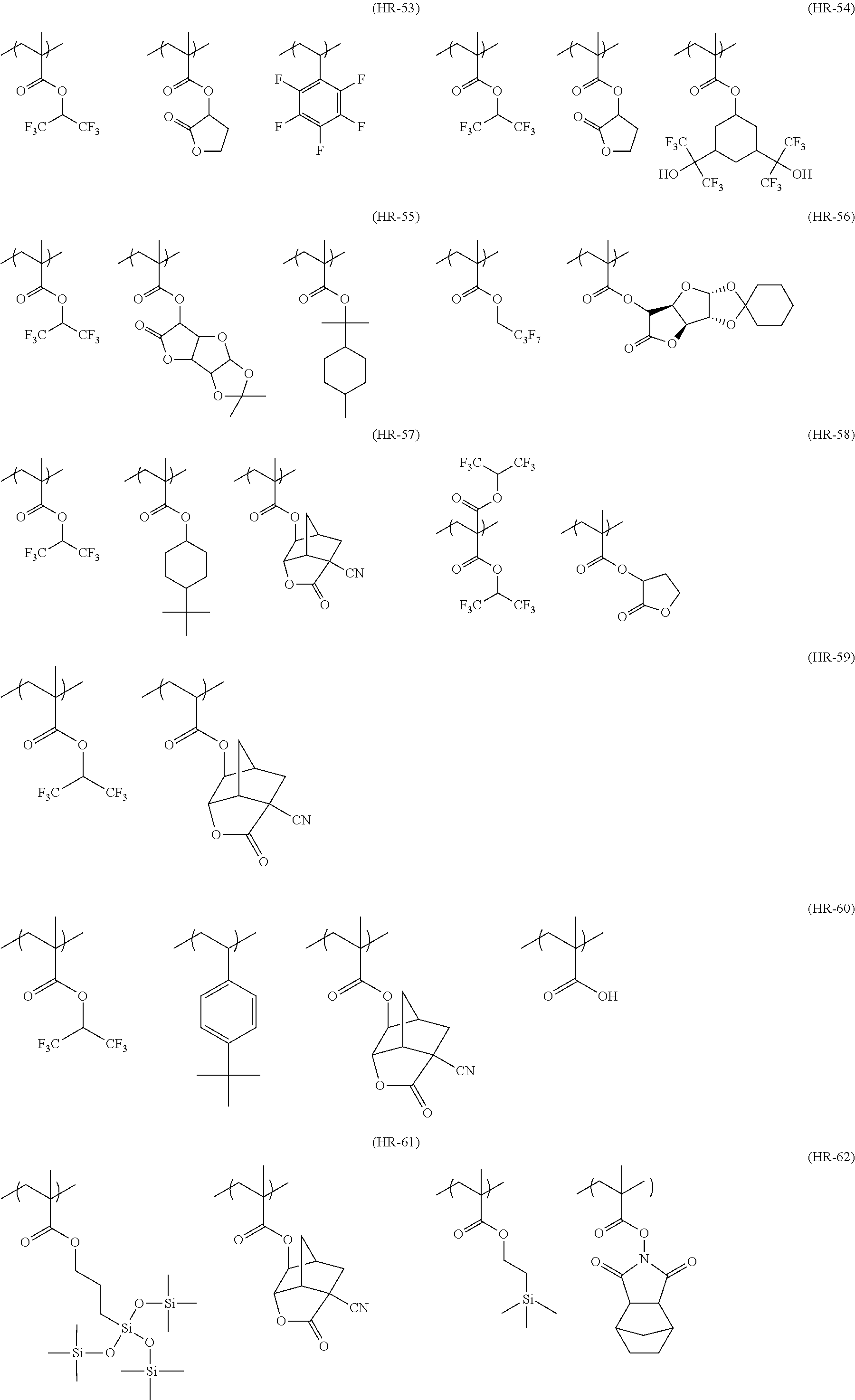

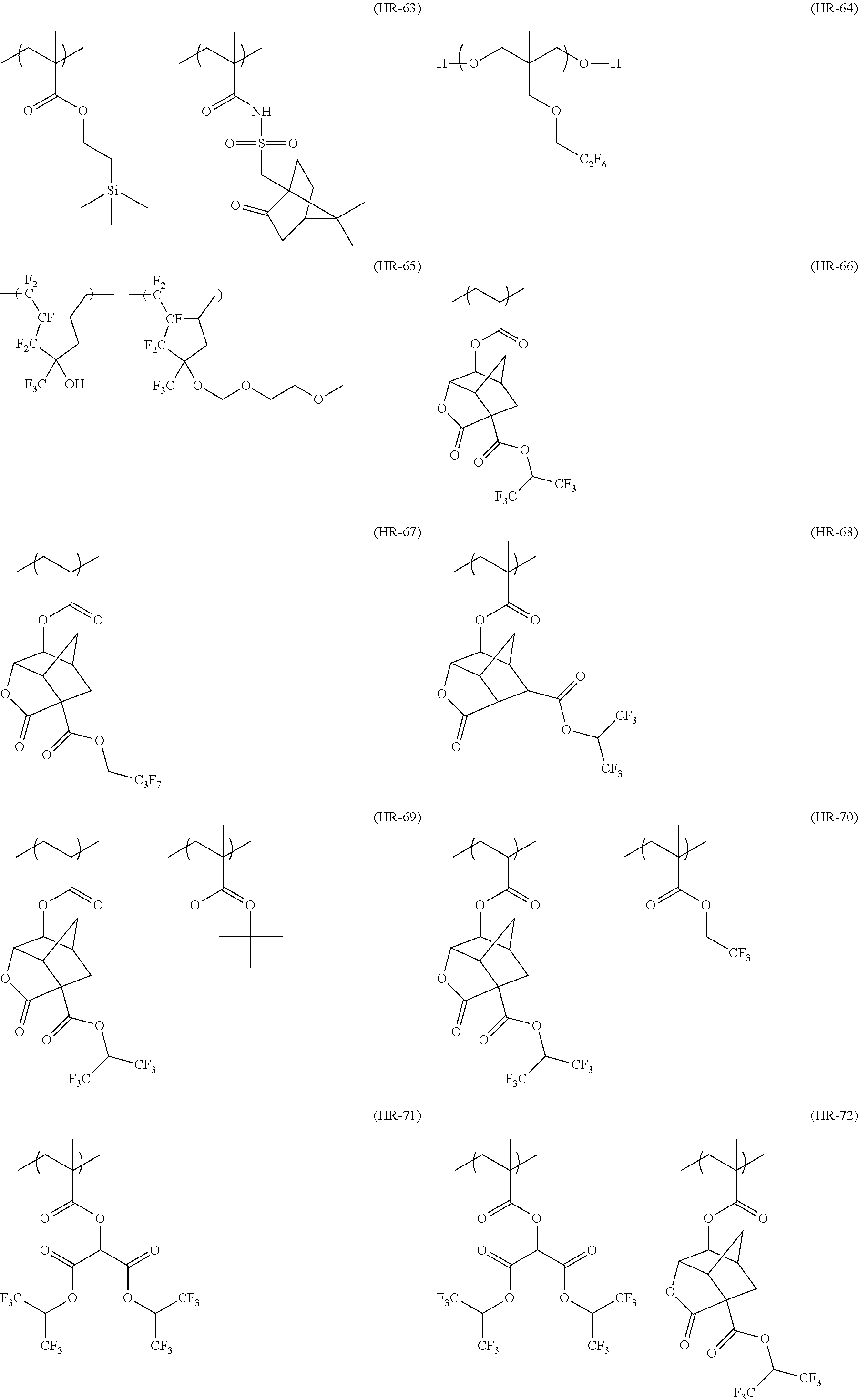

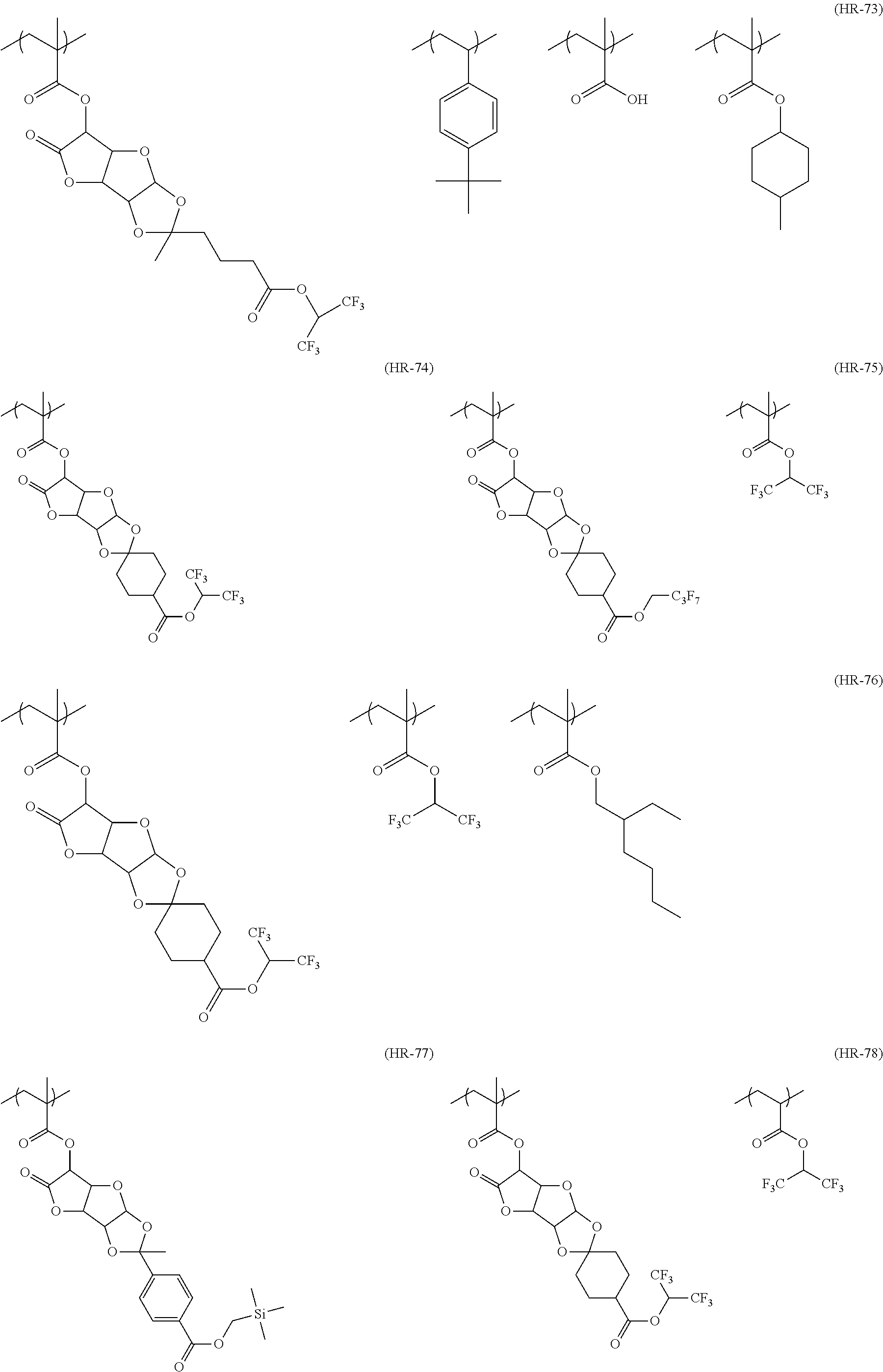

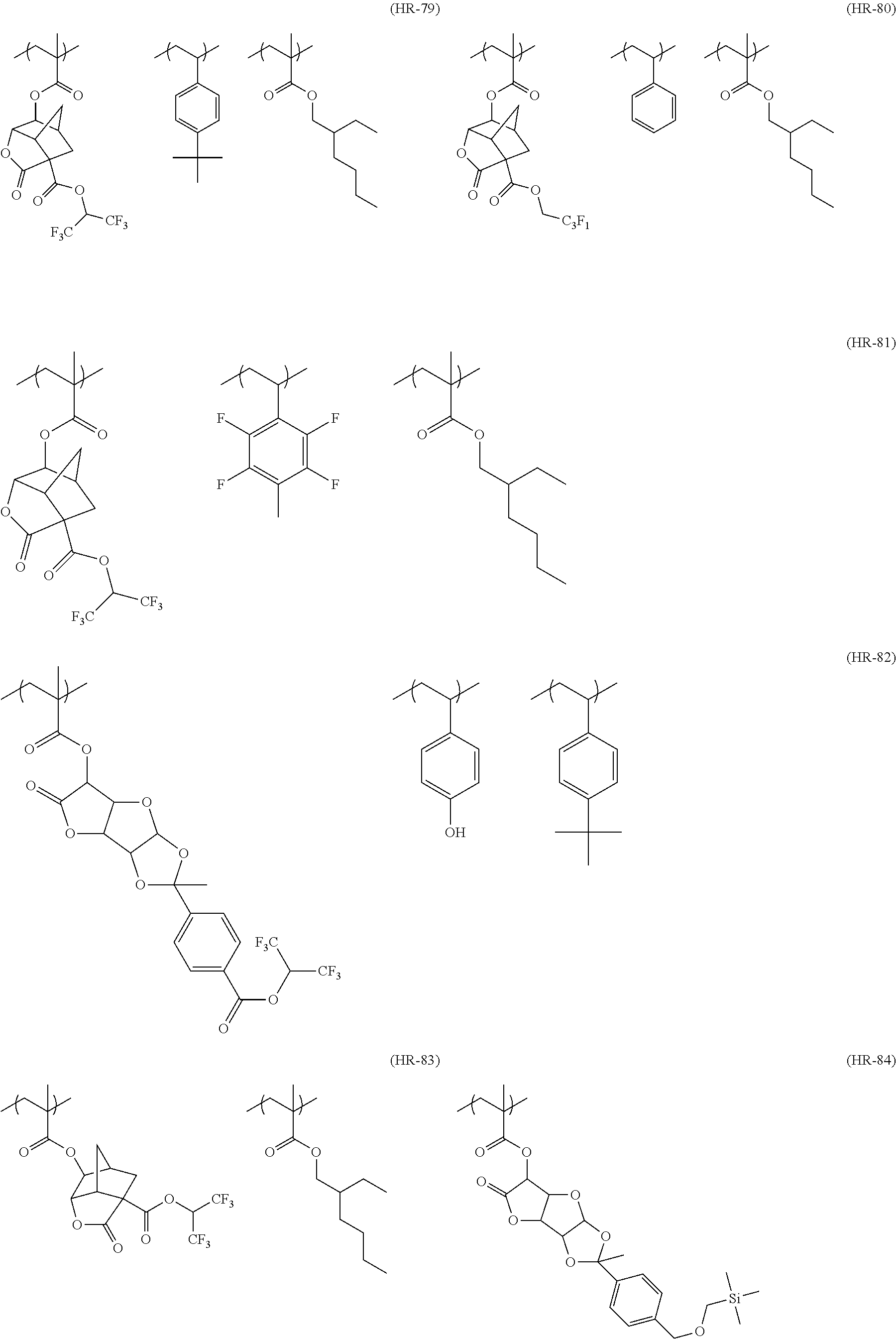

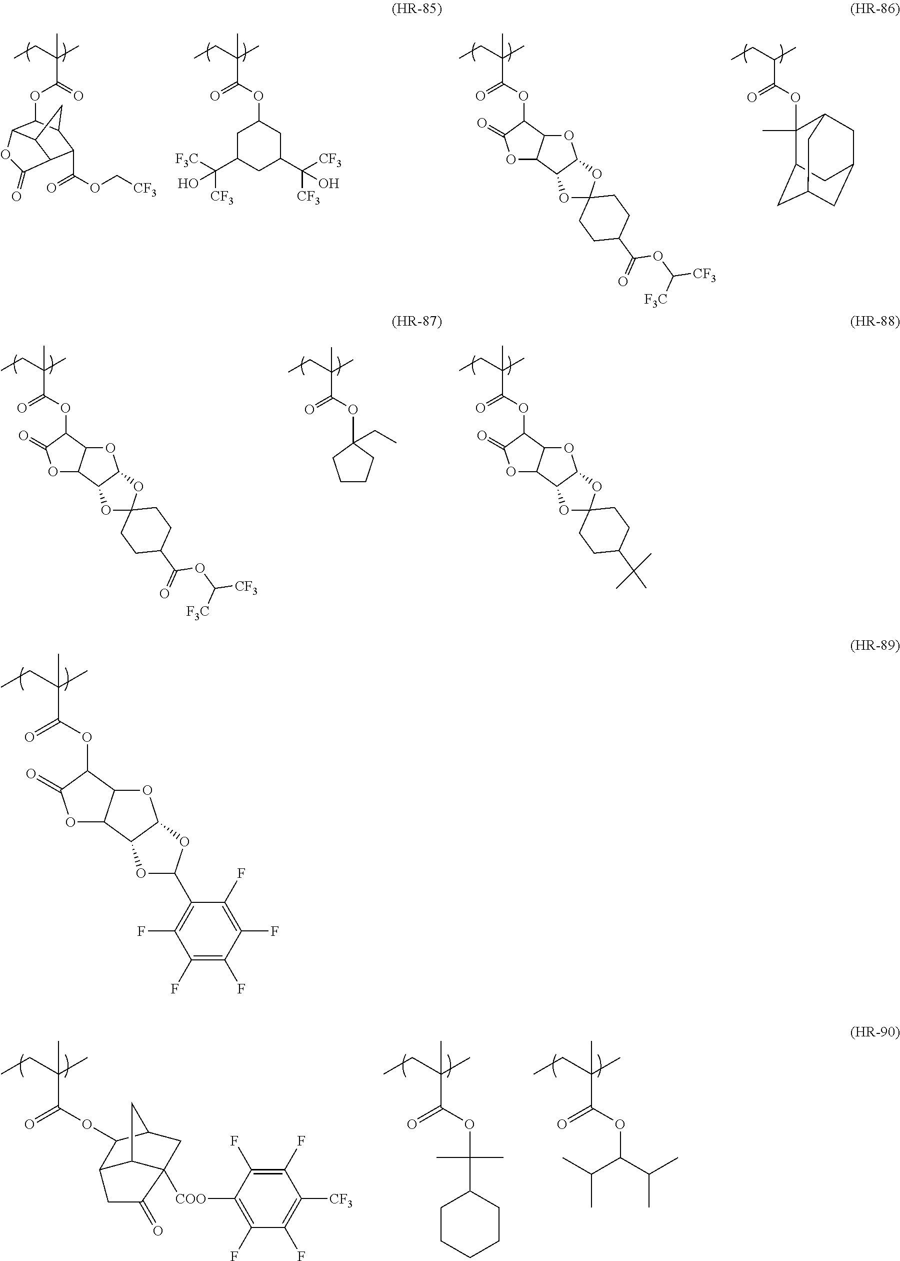

TABLE 1

| Resin | Composition | Mw | Mw/Mn |
|---|---|---|---|
| HR-1 | 50/50 | 4900 | 1.4 |
| HR-2 | 50/50 | 5100 | 1.6 |
| HR-3 | 50/50 | 4800 | 1.5 |
| HR-4 | 50/50 | 5300 | 1.6 |
| HR-5 | 50/50 | 4500 | 1.4 |
| HR-6 | 100 | 5500 | 1.6 |
| HR-7 | 50/50 | 5800 | 1.9 |
| HR-8 | 50/50 | 4200 | 1.3 |
| HR-9 | 50/50 | 5500 | 1.8 |
| HR-10 | 40/60 | 7500 | 1.6 |
| HR-11 | 70/30 | 6600 | 1.8 |
| HR-12 | 40/60 | 3900 | 1.3 |
| HR-13 | 50/50 | 9500 | 1.8 |
| HR-14 | 50/50 | 5300 | 1.6 |
| HR-15 | 100 | 6200 | 1.2 |
| HR-16 | 100 | 5600 | 1.6 |
| HR-17 | 100 | 4400 | 1.3 |
| HR-18 | 50/50 | 4300 | 1.3 |
| HR-19 | 50/50 | 6500 | 1.6 |
| HR-20 | 30/70 | 6500 | 1.5 |
| HR-21 | 50/50 | 6000 | 1.6 |
| HR-22 | 50/50 | 3000 | 1.2 |
| HR-23 | 50/50 | 5000 | 1.5 |
| HR-24 | 50/50 | 4500 | 1.4 |
| HR-25 | 30/70 | 5000 | 1.4 |
| HR-26 | 50/50 | 5500 | 1.6 |
| HR-27 | 50/50 | 3500 | 1.3 |
| HR-28 | 50/50 | 6200 | 1.4 |
| HR-29 | 50/50 | 6500 | 1.6 |
| HR-30 | 50/50 | 6500 | 1.6 |
| HR-31 | 50/50 | 4500 | 1.4 |
| HR-32 | 30/70 | 5000 | 1.6 |
| HR-33 | 30/30/40 | 6500 | 1.8 |
| HR-34 | 50/50 | 4000 | 1.3 |
| HR-35 | 50/50 | 6500 | 1.7 |
| HR-36 | 50/50 | 6000 | 1.5 |
| HR-37 | 50/50 | 5000 | 1.6 |
| HR-38 | 50/50 | 4000 | 1.4 |
| HR-39 | 20/80 | 6000 | 1.4 |
| HR-40 | 50/50 | 7000 | 1.4 |
| HR-41 | 50/50 | 6500 | 1.6 |
| HR-42 | 50/50 | 5200 | 1.6 |
| HR-43 | 50/50 | 6000 | 1.4 |
| HR-44 | 70/30 | 5500 | 1.6 |
| HR-45 | 50/20/30 | 4200 | 1.4 |
| HR-46 | 30/70 | 7500 | 1.6 |
| HR-47 | 40/58/2 | 4300 | 1.4 |
| HR-48 | 50/50 | 6800 | 1.6 |
| HR-49 | 100 | 6500 | 1.5 |
| HR-50 | 50/50 | 6600 | 1.6 |
| HR-51 | 30/20/50 | 6800 | 1.7 |
| HR-52 | 95/5 | 5900 | 1.6 |
| HR-53 | 40/30/30 | 4500 | 1.3 |
| HR-54 | 50/30/20 | 6500 | 1.8 |
| HR-55 | 30/40/30 | 7000 | 1.5 |
| HR-56 | 60/40 | 5500 | 1.7 |
| HR-57 | 40/40/20 | 4000 | 1.3 |
| HR-58 | 60/40 | 3800 | 1.4 |
| HR-59 | 80/20 | 7400 | 1.6 |
| HR-60 | 40/40/15/5 | 4800 | 1.5 |
| HR-61 | 60/40 | 5600 | 1.5 |
| HR-62 | 50/50 | 5900 | 2.1 |
| HR-63 | 80/20 | 7000 | 1.7 |
| HR-64 | 100 | 5500 | 1.8 |
| HR-65 | 50/50 | 9500 | 1.9 |

TABLE 2

| Resin | Composition | Mw | Mw/Mn |
|---|---|---|---|
| HR-66 | 100 | 6000 | 1.5 |
| HR-67 | 100 | 6000 | 1.4 |
| HR-68 | 100 | 9000 | 1.5 |
| HR-69 | 60/40 | 8000 | 1.3 |
| HR-70 | 80/20 | 5000 | 1.4 |
| HR-71 | 100 | 9500 | 1.5 |
| HR-72 | 40/60 | 8000 | 1.4 |
| HR-73 | 55/30/5/10 | 8000 | 1.3 |
| HR-74 | 100 | 13000 | 1.4 |
| HR-75 | 70/30 | 8000 | 1.3 |
| HR-76 | 50/40/10 | 9500 | 1.5 |
| HR-77 | 100 | 9000 | 1.6 |
| HR-78 | 80/20 | 3500 | 1.4 |
| HR-79 | 90/8/2 | 13000 | 1.5 |
| HR-80 | 85/10/5 | 5000 | 1.5 |
| HR-81 | 80/18/2 | 6000 | 1.5 |
| HR-82 | 50/20/30 | 5000 | 1.3 |
| HR-83 | 90/10 | 8000 | 1.4 |
| HR-84 | 100 | 9000 | 1.6 |
| HR-85 | 80/20 | 15000 | 1.6 |
| HR-86 | 70/30 | 4000 | 1.42 |
| HR-87 | 60/40 | 8000 | 1.32 |
| HR-88 | 100 | 3800 | 1.29 |
| HR-89 | 100 | 6300 | 1.35 |
| HR-90 | 50/40/10 | 8500 | 1.51 |

[6] Surfactant (F)

The actinic ray-sensitive or radiation-sensitive resin composition of the present invention may or may not further contain a surfactant. When the actinic ray-sensitive or radiation-sensitive resin composition contains a surfactant, the composition preferably contains any one of a fluorine-based surfactant and/or a silicon-based surfactant (a fluorine-based surfactant, a silicon-based surfactant, and a surfactant including both fluorine atoms and silicon atoms) or two or more kinds of these surfactants.

If the actinic ray-sensitive or radiation-sensitive resin composition of the present invention contains the surfactant, a resist pattern having few adhesion and development defects can be provided with excellent sensitivity and resolution, when an exposure light source of 250 nm or less, particularly, an exposure light source of 220 nm or less is used.

Examples of the fluorine-based surfactant and/or silicon-based surfactant include surfactants disclosed in Paragraph 0276 of the specification of US2008/0248425A, which are, for example, EFTop EF301 and EF303 (manufactured by Shin-Akita Kasei K.K.); Fluorad FC430, 431 and 4430 (manufactured by Sumitomo 3M Inc); Magaface F171, F173, F176, F189, F113, F110, F177, F120 and R08 (manufactured by DIC CORPORATION); Surflon S-382, SC101, 102, 103, 104, 105, 106 and KH-20 (manufactured by ASAHI GLASS CO., LTD.); Troysol S-366 (manufactured by Troy Chemical); GF-300 and GF-150 (manufactured by TOAGOSEI, CO., LTD.); Surflon S-393 (manufactured by SEIMI CHEMICAL CO., LTD.); EFtop EF121, EF122A, EF122B, RF122C, EF125M, EF135M, EF351, EF352, EF801, EF802 and EF601 (manufactured by JEMCO Inc.); PF636, PF656, PF6320 and PF6520 (manufactured by OMNOVA solutions Inc.); and FTX-204G, 208G, 218G, 230G, 204D, 208D, 212D, 218D and 222D (manufactured by NEOS Co., Ltd.). In addition, a polysiloxane polymer KP-341 (manufactured by Shin-Etsu Chemical Co., Ltd.) can also be used as the silicon-based surfactant.

As the surfactant, surfactants that use a polymer having a fluoroaliphatic group derived from fluoroaliphatic compounds which are produced by a telomerization method (which is also called a telomer method) or an oligomerization method (which is also called an oligomer method) can also be used, in addition to the well-known surfactants described above. The fluoroaliphatic compound can be synthesized by the method disclosed in JP2002-90991A.

Examples of the surfactants corresponding to those described above include Megaface F178, F-470, F-473, F-475, F-476, and F-472 (manufactured by DIC CORPORATION), a copolymer of acrylate (or methacrylate) having a C₆F₁₃ group and (poly(oxyalkylene))acrylate (or methacrylate), a copolymer of acrylate (or methacrylate) having a C₃F₇ group, (poly(oxyethylene))acrylate (or methacrylate), and (poly(oxypropylene))acrylate (or methacrylate), and the like.

In the present invention, surfactants other than the fluorine-based surfactant and/or silicon-based surfactant, which are described in Paragraph 0280 of the specification of US2008/0248425A, can also be used.

These surfactants may be used alone or in combination of several surfactants.

When the actinic ray-sensitive or radiation-sensitive resin composition contains the surfactant, the amount of the surfactant used is preferably 0.0001 to 2% by mass, and more preferably 0.0005 to 1% by mass, based on the total amount (excluding a solvent) of the actinic ray-sensitive or radiation-sensitive resin composition.

Meanwhile, if the amount of the surfactant added is set to 10 ppm or less based on the total amount (excluding a solvent) of the actinic ray-sensitive or radiation-sensitive resin composition, the surface-localization property of the hydrophobic resin is more improved. As a result, the resist film surface can be more hydrophobic, whereby the water-traceability of the resist film in the liquid immersion exposure can be improved.

[7] Other Additives (G)

The actinic ray-sensitive or radiation-sensitive resin composition of the present invention may or may not contain a carboxylic acid onium salt. Examples of the carboxylic acid onium salt include those disclosed in Paragraphs 0605 to 0606 of the specification of US2008/0187860A.

These carboxylic acid onium salts can be synthesized by reacting sulfonium hydroxide, iodonium hydroxide or ammonium hydroxide with carboxylic acid and silver oxide in an appropriate solvent.

When the actinic ray-sensitive or radiation-sensitive resin composition contains the carboxylic acid onium salt, the content of the carboxylic acid onium salt is generally 0.1 to 20% by mass, preferably 0.5 to 10% by mass, and more preferably 1 to 7% by mass based on the total solid content of the composition.

The actinic ray-sensitive or radiation-sensitive resin composition of the present invention may optionally further contain a dye, a plasticizer, a photosensitizer, a light absorber, an alkali-soluble resin, a dissolution inhibitor, and a compound (for example, a phenol compound having a molecular weight of 1000 or less, or an alicyclic or aliphatic compound having a carboxyl group) promoting solubility with respect to a developer, and the like.

A person skilled in the art may easily synthesize the phenol compound having a molecular weight of 1000 or less with reference to methods disclosed in, for example, JP1992-122938A (JP-H04-122938A), JP1990-28531A (JP-H02-28531A), U.S. Pat. No. 4,916,210A, EP219294B and the like.

Specific examples of the alicyclic or aliphatic compound having a carboxyl group include carboxylic acid derivatives having a steroid structure such as cholic acid, deoxycholic acid and lithocholic acid, adamantane carboxylic acid derivatives, adamantane dicarboxylic acid, cyclohexane carboxylic acid, cyclohexane dicarboxylic acid and the like, but the present invention is not limited thereto.

The actinic ray-sensitive or radiation-sensitive resin composition of the present invention is preferably used in a film thickness of 30 to 250 nm, and more preferably used in a film thickness of 30 to 200 nm, from the viewpoint of improving resolution. The solid content concentration in the composition is set within an appropriate range so as to make the composition have an appropriate viscosity and to improve coatability and film formability, and the above film thickness may be formed in this manner.

The solid content concentration of the actinic ray-sensitive or radiation-sensitive resin composition of the present invention is generally 1.0 to 10% by mass, preferably 2.0 to 5.7% by mass, and more preferably 2.0 to 5.3% by mass. By setting the solid content concentration within the above range, a resist solution can be evenly coated onto a substrate, and a resist pattern that is excellent in the line edge roughness can be formed. Though unclear, the reason is assumed to be that, by setting the solid content concentration to 10% by mass or less, preferably 5.7% by mass or less, the aggregation of a material, particularly, the photoacid-generating agent in the resist solution is inhibited, and consequently, a uniform resist film can be formed.

The solid content concentration is percent by weight of the weight of resist components excluding a solvent, based on the total weight of the actinic ray-sensitive or radiation-sensitive resin composition.

To use the actinic ray-sensitive or radiation-sensitive resin composition of the present invention, the above-described components are dissolved in a predetermined organic solvent, preferably the mixed solvent followed by filtering through a filter, and coated on a predetermined support. The pore size of the filter used for filtration is 0.1 μm or less, more preferably 0.05 μm or less, and even more preferably 0.03 μm or less, and the filter is preferably made of polytetrafluoroethylene, polyethylene or nylon. In the filtering using a filter, circulative filtering may be performed as described in JP2002-62667A, or filtering may be performed by a plurality of types of filters connected in series or in parallel. In addition, the composition may be filtered a plurality of times. Moreover, the composition may be subjected to deaeration treatment before and after the filtering.

Above is a detailed description of each components of the actinic ray-sensitive or radiation-sensitive resin composition. The following show preferable embodiments of actinic ray-sensitive or radiation-sensitive resin composition of the present invention. The definition, the specific examples, the preferable examples of the each group in the following formulae (I-1), (I), (III) and (IV) are respectively the same as the ones explained in the formulae (I-1), (I), (III) and (IV).

### Embodiment (I)

An actinic ray-sensitive or radiation-sensitive resin composition including the resin (P) of which the polarity increases by the action of an acid and thereby the solubility in a developer containing an organic solvent decreases and a compound (B′) which generates an acid represented by the following general formula (I-1) by irradiation with actinic rays or radiation.

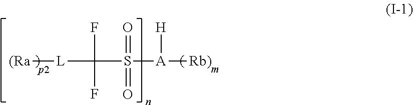

A represents a nitrogen atom or a carbon atom,
each Ra independently represents a hydrogen atom, an alkyl group, a cycloalkyl group or an aryl group, and Rb represents an electron-attracting group, an alkyl group or an aryl group,
when A is a nitrogen atom, n represents 1 or 2 and m represents (2-n),
when A is a carbon atom, n represents an integer of 1 to 3 and m represents (3-n),
p2 represents 1 or 2,

L represents a single bond or a (p2+1)-valent linking group. When L is a single bond, p2 represents 1,
when at least one of (i) p2 represents 2, and (ii) n represents 2 or 3, is satisfied, a plurality of Ra's may be the same as or different from each other and may be bonded to each other to form a ring, and
when A is a carbon atom and m represents 2, a plurality of Rb's may be the same as or different from each other.

### Embodiment (II)

An actinic ray-sensitive or radiation-sensitive resin composition including the resin (P′) which has a repeating unit (a1) is acid-decomposable and generates a carboxyl group and a compound (B) which generates an acid represented by the following general formula (I) by irradiation with actinic rays or radiation, wherein the content of the repeating unit (a1) is 50 mol % or more, based on all the repeating units in the resin (P′).

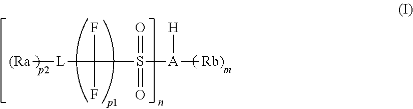

A represents a nitrogen atom or a carbon atom,
each Ra independently represents a hydrogen atom, an alkyl group, a cycloalkyl group or an aryl group, and Rb represents an electron-attracting group, an alkyl group or an aryl group,
when A is a nitrogen atom, n represents 1 or 2 and m represents (2-n),
when A is a carbon atom, n represents an integer of 1 to 3 and m represents (3-n),
p1 represents an integer of 1 to 4 and p2 represents 1 or 2,
L represents a single bond or a (p2+1)-valent linking group, when L is a single bond, p2 represents 1,
when at least one of (i) p2 represents 2, and (ii) n represents 2 or 3, is satisfied, a plurality of Ra's may be the same as or different from each other and may be bonded to each other to form a ring, and
when A is a carbon atom and m represents 2, a plurality of Rb's may be the same as or different from each other.

In the above embodiment (II), the repeating unit (a1) is preferably at least one of the repeating units represented by the following general formulae (III) and (IV).

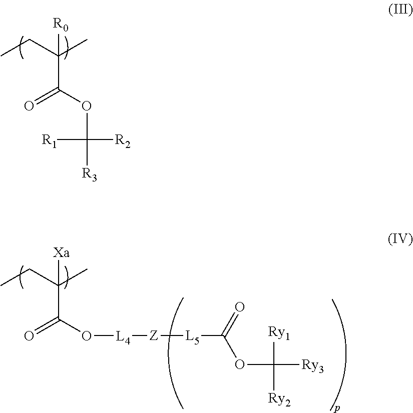

In the above general formula (III), R₀ represents a hydrogen atom, an alkyl group, a cyano group or a halogen atom, each of R₁ to R₃ independently represents a chain alkyl group, in the above general formula (IV), Xa represents a hydrogen atom, an alkyl group, cyano group or a halogen atom,
each of Ry₁ to Ry₃ independently represents an alkyl group, or a cycloalkyl group, two of Ry₁ to Ry₃ may bond to each other to form a ring,
Z represents a (p+1)-valent linking group having a polycyclic hydrocarbon structure which may have a hetero atom as a ring member,
each of L₄ and L₅ independently represents a single bond or a divalent linking group,
p represents an integer of 1 to 3, and
when p is 2 or 3, each of the plurality of L₅, the plurality of Ry₁, the plurality of Ry₁ and the plurality of Ry₃ may be the same as or different from each other.

### Embodiment (III)

An actinic ray-sensitive or radiation-sensitive resin composition including the resin (P) of which the polarity increases by the action of an acid and thereby the solubility in a developer containing an organic solvent decreases, a compound (B) which generates an acid represented by the following general formula (I) by irradiation with actinic rays or radiation, and the basic compound or an ammonium salt compound (C) in which basicity decreases by irradiation with actinic rays or radiation.

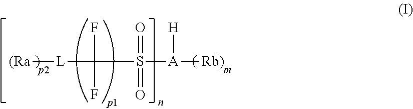

A represents a nitrogen atom or a carbon atom,
each Ra independently represents a hydrogen atom, an alkyl group, a cycloalkyl group or an aryl group, and Rb represents an electron-attracting group, an alkyl group or an aryl group,
when A is a nitrogen atom, n represents 1 or 2 and m represents (2-n),
when A is a carbon atom, n represents an integer of 1 to 3 and m represents (3-n),
p1 represents an integer of 1 to 4 and p2 represents 1 or 2,
L represents a single bond or a (p2+1)-valent linking group, when L is a single bond, p2 represents 1,
when at least one of (i) p2 represents 2, and (ii) n represents 2 or 3, is satisfied, a plurality of Ra's may be the same as or different from each other and may be bonded to each other to form a ring, and
when A is a carbon atom and m represents 2, a plurality of Rb's may be the same as or different from each other.

[8] Pattern Forming Method

A pattern forming method (negative pattern forming method) of the present invention includes at least
(1) forming a film (resist film) using an actinic ray-sensitive or radiation-sensitive resin composition,
(2) exposing the film, and
(3) developing with a developer that contains an organic solvent.

The exposing in the above (2) may be liquid immersion exposure.

The pattern forming method of the present invention preferably includes (4) baking after (2) exposing.

The pattern forming method of the present invention may further include (5) developing with an alkaline developer.

In the pattern forming method of the present invention, (2) exposing may be performed a plurality of times.

In the pattern forming method of the present invention, (5) baking may be performed a plurality of times.

The resist film is formed of the above-described actinic ray-sensitive or radiation-sensitive resin composition of the present invention. More specifically, the resist film is preferably formed on a substrate. In the pattern forming method of the present invention, forming the film using an actinic ray-sensitive or radiation-sensitive resin composition on a substrate, exposing the film, and developing may be performed by a generally known method.

After forming the film but before exposing the film, prebaking (PB) is preferably included in the pattern forming method.

In addition, after the exposing and before the developing, post exposure baking (PEB) is preferably included in the pattern forming method.

In both the PB and PEB, the baking temperature is preferably 70 to 130° C., and more preferably 80 to 120° C.

The baking time is preferably 30 to 300 seconds, more preferably 30 to 180 seconds, and even more preferably 30 to 90 seconds.

The baking can be performed using a means provided to a general exposing and developing machine, and a hot plate or the like may also be used.

By the baking, the reaction of the exposed portion is promoted, and the sensitivity and pattern profile are improved.

A light source wavelength used in an exposure apparatus in the present invention is not limited, but examples thereof include infrared rays, visible light rays, ultraviolet rays, far-ultraviolet rays, extreme-ultraviolet rays, X-rays, an electron beam and the like, and is preferably far-ultraviolet rays of a wavelength of 250 nm or less, more preferably a wavelength of 220 nm or less, and particularly preferably a wavelength of 1 to 200 nm. Specific examples thereof include KrF excimer laser (248 nm), ArF excimer laser (193 nm), F₂ excimer laser (157 nm), X-rays, EUV (13 nm), an electron beam and the like. KrF excimer laser, ArF excimer laser, EUV and an electron beam are preferable and ArF excimer laser is more preferable.

Liquid immersion exposure may be applied to the exposing of the present invention.

The liquid immersion exposure is a technique for improving resolving power, where a liquid having a high refractive index (also referred to as a “liquid for liquid immersion” hereinafter) is filled between a projection lens and a sample so as to perform exposure.

As described above, provided that λ₀ is a wavelength of exposure light in the air, n is a refractive index of a liquid for liquid immersion with respect to the air, and that θ is a beam convergence half angle which is NA₀=sin θ, when the liquid immersion is performed, the “effect of liquid immersion” can be indicated by calculating the resolving power and depth of focus from the following formulae. Herein, k₁ and k₂ are coefficients relating to the process.

(Resolving power)=k₁*(λ₀/n)/NA₀

(Depth of focus)=±k₂*(λ₀/n)/NA₀²

That is, the effect of liquid immersion is equivalent to the effect obtained when an exposure wavelength of 1/n is used. In other words, in a case of a projection optical system of the same NA, the depth of focus can be increased n-fold by the liquid immersion. The liquid immersion is effective for various pattern shapes and can be combined with super resolution techniques such as a phase shift method and a modified illumination method that are being examined currently.

When the liquid immersion exposure is performed, (1) before the film is exposed after being formed on a substrate and/or (2) before the film is baked after being exposed through the liquid for liquid immersion, the film surface may be washed with an aqueous chemical liquid.

The liquid for liquid immersion is preferably a liquid which is transparent to the exposure wavelength and has as small a temperature coefficient of a refractive index as possible so as to minimize the distortion of an optical image projected onto the film. Particularly, when the exposure light source is an ArF excimer laser (wavelength: 193 nm), it is preferable to use water in respect that water is easily obtained and handled, in addition to the above-described viewpoints.

When water is used, an additive (liquid) which decreases the surface tension of water and increases surfactant potency may be added in a slight proportion. As the additive, a material which does not dissolve the resist film on a wafer and negligibly affects an optical coat of the lower surface of a lens element is preferable.

As the additive, for example, an aliphatic alcohol that has almost the same refractive index as that of water is preferable, and specific examples thereof include methyl alcohol, ethyl alcohol, isopropyl alcohol, and the like. By adding the alcohol having almost the same refractive index as that of water, an advantage is obtained that even if the concentration of the alcohol contained in the water changes due to evaporation of the alcohol component, change in the refractive index caused in an overall liquid can be minimized.

When a substance that is opaque to light of 193 nm and impurities that have a refractive index greatly differing from that of water are mixed in, distortion of the optical image projected onto the resist is caused, therefore distilled water is preferable as water to be used. In addition, pure water filtered through an ion exchange filter or the like may be used.

The electrical resistance of the water used as the liquid for liquid immersion is preferably 18.3 MΩcm or more and the TOC (total organic matter concentration) is preferably 20 ppb or less. Also, the water is preferably subjected to a deaeration treatment.

Furthermore, by increasing the refractive index of the liquid for liquid immersion, it is possible to enhance a lithography performance. From such viewpoints, an additive capable of increasing a refractive index may be added to the water, or heavy water (D₂O) may be used in place of the water.

When the film formed using the composition of the present invention is exposed through a liquid immersion medium, the above-described hydrophobic resin (E) may be optionally further added. The addition of the hydrophobic resin (E) improves backward contact angle of the film surface. The backward contact angle of the film is preferably 60° to 90°, and more preferably 70° or more.

In the liquid immersion exposure, the liquid for liquid immersion needs to move on the wafer so as to follow the movement of forming an exposure pattern by an exposure head scanning on a wafer at a high speed. Accordingly, the contact angle of the liquid for liquid immersion with respect to the resist film that is in a dynamic state is important, and the resist is required to have a performance that can follow the high-speed scanning of the exposure head without causing droplets to remain.

In order not to cause the film to directly contact the liquid for liquid immersion, a film (hereinafter, also referred to as a “topcoat”) that is poorly soluble in a liquid for liquid immersion may be provided between the film formed using the composition of the present invention and the liquid for liquid immersion. As properties required for the topcoat, coating suitability to the upper layer portion of the resist, transparency to radiation, particularly to radiation with a wavelength of 193 nm, and poor solubility in the liquid for liquid immersion can be exemplified. It is preferable that the topcoat can be evenly coated onto the upper layer of the resist without being mixed with the resist.

The topcoat is preferably a polymer not containing an aromatic group, from the viewpoint of the transparency to 193 nm.

Specific examples of such a polymer include a hydrocarbon polymer, an acrylic acid ester polymer, polymethacrylic acid, polyacrylic acid, polyvinyl ether, a silicon-containing polymer and a fluorine-containing polymer. The hydrophobic resin (E) described above is also suitable as the topcoat. If impurities are eluted from the topcoat to the liquid for liquid immersion, the optical lens is contaminated. Accordingly, residual monomer components of the polymer contained in the topcoat is preferably small.

For removing the topcoat, a developer may be used, or another remover may be used. As the remover, a solvent that rarely penetrates the film is preferable. From the viewpoint that the removing can be performed simultaneously with developing treatment, it is preferable that the topcoat be removable by an alkaline developer. From the viewpoint of removing the topcoat with an alkaline developer, the topcoat is preferably acidic. However, from the viewpoint of a non-intermixing property with respect to the film, the topcoat may be neutral or alkaline.

It is preferable that there be no difference or a small difference in the refractive index between the topcoat and the liquid for liquid immersion. In this case, the resolving power can be improved. When the exposure light source is an ArF excimer laser (wavelength: 193 nm), it is preferable to use water as the liquid for liquid immersion. Consequently, the topcoat for ArF liquid immersion exposure preferably has a refractive index close to the refractive index (1.44) of water. In addition, from the viewpoint of transparency and refractive index, the topcoat is preferably a thin film.

It is preferable that the topcoat be not mixed with the film and the liquid for liquid immersion. From such a viewpoint, when the liquid for liquid immersion is water, the solvent used for the topcoat is preferably poorly soluble in the solvent used for the composition of the present invention and is a water-insoluble medium. Moreover, when the liquid for liquid immersion is an organic solvent, the topcoat may be water-soluble or water-insoluble.

In the present invention, the substrate for forming a film is not particularly limited, and an inorganic substrate such as silicon, SiN, SiO₂, and SiN, a coated inorganic substrate such as SOG and the like which are generally used in a production process of a semiconductor such as IC, a production process of a circuit board of a liquid crystal, a thermal head or the like, and other lithography processes of photofabrication can be used. In addition, an organic antireflection film may be optionally formed between the film and the substrate.

When the pattern forming method of the present invention further includes developing with an alkaline developer, as the alkaline developer, for example, an aqueous alkaline solution of inorganic alkalis such as sodium hydroxide, potassium hydroxide, sodium carbonate, sodium silicate, sodium metasilicate, and aqueous ammonia; primary amines such as ethylamine and n-propylamine; secondary amines such as diethylamine, and di-n-butylamine; tertiary amines such as triethylamine and methyl diethylamine; alcoholamines such as dimethylethanolamine and triethanolamine; quaternary ammonium salts such as tetramethyl ammonium hydroxide and tetraethyl ammonium hydroxide; and cyclic amines such as pyrrole and piperidine may be used.

In addition, to the above aqueous alkaline solution, alcohols and a surfactant can be added in an appropriate amount for use.

An alkali concentration of the alkaline developer is generally 0.1% by mass to 20% by mass.

pH of the alkaline developer is generally 10.0 to 15.0.

Particularly, a 2.38% by mass aqueous tetramethylammonium hydroxide solution is desirable.

As a rinsing liquid used in rinsing treatment performed after alkali development, pure water is used, and a surfactant may be added thereto in an appropriate amount for use.

In addition, after the development treatment or rinsing treatment, treatment for removing the developer or rinsing liquid attached onto the pattern by using supercritical fluid can be performed.

As the developer (hereinafter, also referred to as an organic developer) used in the forming process of a negative pattern by developing with a developer which contains an organic solvent, a polar solvent such as a ketone-based solvent, an ester-based solvent, an alcohol-based solvent, an amide-based solvent, or an ether-based solvent and a hydrocarbon-based solvent may be used.

Examples of the ketone-based solvent include 1-octanone, 2-octanone, 1-nonanone, 2-nonanone, acetone, 2-heptanone(methyl amyl ketone), 4-heptanone, 1-hexanone, 2-hexanone, diisobutyl ketone, cyclohexanone, methyl cyclohexanone, phenyl acetone, methyl ethyl ketone, methyl isobutyl ketone, acetyl acetone, acetonyl acetone, ionone, diacetonyl alcohol, acetyl carbinol, acetophenone, methyl naphthyl ketone, isophorone, propylene carbonate and the like.

Examples of the ester-based solvent include methyl acetate, butyl acetate, ethyl acetate, isopropyl acetate, pentyl acetate, isopentyl acetate, amyl acetate, propylene glycol monomethyl ether acetate, ethylene glycol monoethyl ether acetate, diethylene glycol monobutyl ether acetate, diethylene glycol monoethyl ether acetate, ethyl-3-ethoxy propionate, 3-methoxybutyl acetate, 3-methyl-3-methoxybutyl acetate, methyl formate, ethyl formate, butyl formate, propyl formate, ethyl lactate, butyl lactate, propyl lactate and the like.

Examples of the alcohol-based solvent include alcohols such as methyl alcohol, ethyl alcohol, n-propyl alcohol, isopropyl alcohol, n-butyl alcohol, sec-butyl alcohol, tert-butyl alcohol, isobutyl alcohol, n-hexyl alcohol, n-heptyl alcohol, n-octyl alcohol, or n-decanol; glycol-based solvents such as ethylene glycol, diethylene glycol, or triethylene glycol; a glycol ether-based solvent such as ethylene glycol monomethyl ether, propylene glycol monomethyl ether, ethylene glycol monoethyl ether, propylene glycol monoethyl ether, diethylene glycol monomethyl ether, triethylene glycol monoethyl ether, or methoxymethyl butanol; and the like.

Examples of the ether-based solvent include dioxane, tetrahydrofuran and the like in addition to the above-described glycol ether-based solvents.

As the amide-based solvent, for example, N-methyl-2-pyrrolidone, N,N-dimethylacetamide, N,N-dimethylformamide, hexamethyl phosphoric triamide, 1,3-dimethyl-2-imidazolidinone and the like may be used.

Examples of the hydrocarbon-based solvent include an aromatic hydrocarbon-based solvent such as toluene or xylene and an aliphatic hydrocarbon-based solvent such as pentane, hexane, octane or decane.

The above solvent may be used as a mixture of plural kinds thereof or used by being mixed with a solvent other than the above solvents and with water. Here, in order to sufficiently bring about the effects of the present invention, the moisture content in the whole developer is preferably less than 10% by mass, and it is more preferable that the developer substantially do not contain moisture.

That is, the amount of the organic solvent used in the organic developer is preferably 90% by mass to 100% by mass, and more preferably 95% by mass to 100% by mass, based on the total amount of the developer.

Particularly, the organic developer preferably is a developer containing at least one kind of organic solvent selected from a group consisting of a ketone-based solvent, an ester-based solvent, an alcohol-based solvent, an amide-based solvent, and an ether-based solvent.

The vapor pressure of the organic developer is preferably 5 kPa or lower, more preferably 3 kPa or lower, and particularly preferably 2 kPa or lower at 20° C. By the vapor pressure of the organic developer being set to be 5 kPa or lower, the developer is inhibited from being vaporized on the substrate or in a development cup, and the temperature uniformity in a wafer surface is improved. As a result, dimensional uniformity in the wafer surface is improved.

Specific examples of the organic developer having a vapor pressure of 5 kPa or lower include a ketone-based solvent such as 1-octanone, 2-octanone, 1-nonanone, 2-nonanone, 2-heptanone(methyl amyl ketone), 4-heptanone, 2-hexanone, diisobutyl ketone, cyclohexanone, methyl cyclohexanone, phenyl acetone and methyl isobutyl ketone; an ester-based solvent such as butyl acetate, pentyl acetate, isopentyl acetate, amyl acetate, propylene glycol monomethyl ether acetate, ethylene glycol monoethyl ether acetate, diethylene glycol monobutyl ether acetate, diethylene glycol monoethyl ether acetate, ethyl-3-ethoxy propionate, 3-methoxybutyl acetate, 3-methyl-3-methoxybutyl acetate, butyl formate, propyl formate, ethyl lactate, butyl lactate and propyl lactate; an alcohol-based solvent such as n-propyl alcohol, isopropyl alcohol, n-butyl alcohol, sec-butyl alcohol, tert-butyl alcohol, isobutyl alcohol, n-hexyl alcohol, n-heptyl alcohol, n-octyl alcohol and n-decanol; a glycol-based solvent such as ethylene glycol, diethylene glycol and triethylene glycol; a glycol ether-based solvent such as ethylene glycol monomethyl ether, propylene glycol monomethyl ether, ethylene glycol monoethyl ether, propylene glycol monoethyl ether, diethylene glycol monomethyl ether, triethylene glycol monoethyl ether and methoxymethyl butanol; an ether-based solvent such as tetrahydrofuran; an amide-based solvent such as N-methyl-2-pyrrolidone, N,N-dimethylacetamide and N,N-dimethylformamide; an aromatic hydrocarbon-based solvent such as toluene and xylene; and an aliphatic hydrocarbon-based solvent such as octane and decane.

Specific examples of the organic developer having a vapor pressure of 2 kPa or lower which is a particularly preferable range include a ketone-based solvent such as 1-octanone, 2-octanone, 1-nonanone, 2-nonanone, 4-heptanone, 2-hexanone, diisobutyl ketone, cyclohexanone, methyl cyclohexanone and phenyl acetone; an ester-based solvent such as butyl acetate, amyl acetate, propylene glycol monomethyl ether acetate, ethylene glycol monoethyl ether acetate, diethylene glycol monobutyl ether acetate, diethylene glycol monoethyl ether acetate, ethyl-3-ethoxy propionate, 3-methoxybutyl acetate, 3-methyl-3-methoxybutyl acetate, ethyl lactate, butyl lactate, or propyl lactate; ah alcohol-based solvent such as n-butyl alcohol, sec-butyl alcohol, tert-butyl alcohol, isobutyl alcohol, n-hexyl alcohol, n-heptyl alcohol, n-octyl alcohol and n-decanol; a glycol-based solvent such as ethylene glycol, diethylene glycol and triethylene glycol; a glycol ether-based solvent such as ethylene glycol monomethyl ether, propylene glycol monomethyl ether, ethylene glycol monoethyl ether, propylene glycol monoethyl ether, diethylene glycol monomethyl ether, triethylene glycol monoethyl ether and methoxymethyl butanol; an amide-based solvent such as N-methyl-2-pyrrolidone, N,N-dimethylacetamide and N,N-dimethylformamide; an aromatic hydrocarbon-based solvent such as xylene; and an aliphatic hydrocarbon-based solvent such as octane and decane.

A surfactant can be optionally added to the organic developer in an appropriate amount.

The surfactant is not particularly limited, and for example, ionic or nonionic fluorine-based surfactants and/or silicon-based surfactants can be used. Examples of these fluorine-based surfactants and/or silicon-based surfactants include surfactants disclosed in JP1987-36663A (JP-S62-36663A), JP1986-226746A (JP-S61-226746A), JP1986-226745A (JP-S61-226745A), JP1987-170950A (JP-S62-170950A), JP1988-34540A (JP-S63-34540A), JP1995-230165A (JP-H07-230165A), JP1996-62834A (JP-H08-62834A), JP1997-54432A (JP-H09-54432A), JP1997-5988A (JP-H09-5988A), U.S. Pat. No. 5,405,720A, U.S. Pat. No. 5,360,692A, U.S. Pat. No. 5,529,881A, U.S. Pat. No. 5,296,330A, U.S. Pat. No. 5,436,098A, U.S. Pat. No. 5,576,143A, U.S. Pat. No. 5,294,511A, and U.S. Pat. No. 5,824,451A, and among these, nonionic surfactants are preferable. The nonionic surfactant is not particularly limited, but it is more preferable to use fluorine-based surfactants or silicon-based surfactants.

The amount of the surfactant used is generally 0.001 to 5% by mass, preferably 0.005 to 2% by mass, and even more preferably 0.01 to 0.5% by mass, based on the total amount of the developer.

As the developing method, for example, a method (dipping) of dipping a substrate in a tank filled with a developer for a certain time, a method (paddling) in which a developer is heaped on the substrate surface by surface tension and left to stand as it is for a certain time to perform developing, a method (spraying) of spraying a developer to the substrate surface, a method (dynamic dispense method) in which a developer is continuously discharged onto a substrate which rotates at a constant speed while a developer-discharging nozzle is scanned at a constant speed, and the like can be applied.

When the above various developing methods include discharging of developer to the resist film from a developing nozzle of a developing apparatus, the discharge pressure (flow rate of the discharged developer per unit area) of the discharged developer is preferably 2 mL/sec/mm² or less, more preferably 1.5 mL/sec/mm² or less, and even more preferably 1 mL/sec/mm² or less. The lower limit of the flow rate is not particularly limited, but in consideration of throughput, the lower limit is preferably 0.2 mL/sec/mm² or higher.

By setting the discharge pressure of the discharged developer to be in the above range, pattern defectiveness caused by resist residue remaining after developing may be markedly reduced.

The detail of the mechanism is unclear, but it is considered that, presumably, if the discharge pressure is set within the above range, the pressure that the developer applies to the resist film is reduced, whereby a phenomenon in which the resist film or the resist pattern is accidently scraped and collapsed is inhibited.

The discharge pressure (mL/sec/mm²) of the developer is a value of pressure in the outlet of the developing nozzle of the developing apparatus.

Examples of methods of adjusting the discharge pressure of the developer include a method of adjusting the discharge pressure by using a pump, a method of changing the discharge pressure by adjusting the pressure by means of providing pressure from a pressurizing tank, and the like.

In addition, after the developing with a developer that contains an organic solvent, the developing may be stopped while the organic solvent is substituted with another solvent.

After the developing with a developer which contains an organic solvent, it is preferable to wash the resist film with a rinsing liquid.

The rinsing liquid used in rinsing which is performed after the developing with a developer which contains an organic solvent is not particularly limited so long as the rinsing liquid does not dissolve the resist pattern, and a solution containing a general organic solvent can be used as the rinsing liquid. As the rinsing liquid, it is preferable to use a rinsing liquid containing at least one kind of organic solvent selected from a group consisting of a hydrocarbon-based solvent, a ketone-based solvent, an ester-based solvent, an alcohol-based solvent, an amide-based solvent and an ether-based solvent.

Specific examples of the hydrocarbon-based solvent, ketone-based solvent, ester-based solvent, alcohol-based solvent, amide-based solvent and ether-based solvent include the same ones as those described for the developer containing an organic solvent.

After the developing with a developer that contains an organic solvent, rinsing is performed more preferably using a rinsing liquid containing at least one kind of organic solvent selected from a group consisting of a ketone-based solvent, an ester-based solvent, an alcohol-based solvent and an amide-based solvent, even more preferably using a rinsing liquid containing an alcohol-based solvent or an ester-based solvent, particularly preferably using a rinsing liquid containing a monohydric alcohol, and most preferably using a rinsing liquid containing a monohydric alcohol having 5 or more carbon atoms.

Examples of the monohydric alcohol used in the rinsing include linear, branched, or cyclic monohydric alcohols, and specifically, 1-butanol, 2-butanol, 3-methyl-1-butanol, tert-butyl alcohol, 1-pentanol, 2-pentanol, 1-hexanol, 4-methyl-2-pentanol, 1-heptanol, 1-octanol, 2-hexanol, cyclopentanol, 2-heptanol, 2-octanol, 3-hexanol, 3-heptanol, 3-octanol, 4-octanol and the like may be used. As particularly preferable monohydric alcohols having 5 or more carbon atoms, 1-hexanol, 2-hexanol, 4-methyl-2-pentanol, 1-pentanol, 3-methyl-1-butanol and the like may be used.

The respective components described above may be used as a mixture of plural kinds thereof, or may be used by being mixed with organic solvents other than the above ones.

The moisture content in the rinsing liquid is preferably 10% by mass or less, more preferably 5% by mass or less, and particularly preferably 3% by mass or less. If the moisture content is 10% by mass or less, excellent development properties can be obtained.

The vapor pressure of the rinsing liquid used after the developing with a developer that contains an organic solvent is preferably 0.05 to 5 kPa, more preferably 0.1 to 5 kPa, and most preferably 0.12 to 3 kPa at 20° C. If the vapor pressure of the rinsing liquid is 0.05 to 5 kPa, the temperature uniformity in the wafer surface is improved, and swelling caused by the permeation of the rinsing liquid is inhibited, whereby the dimensional uniformity in the wafer surface is improved.

The rinsing liquid to which a surfactant has been added in an appropriate amount can also be used.

In the rinsing, the wafer having undergone the developing with a developer that contains an organic solvent is washed with the rinsing liquid containing the above organic solvent. There is no particular limitation of the washing method, and for example, a method (rotation coating) of continuously discharging the rinsing liquid onto a substrate rotating at a constant speed, a method (dipping) of dipping the substrate in a tank filled with the rinsing liquid for a certain time, a method (spraying) of spraying the rinsing liquid to the substrate surface, and the like can be applied. Among these, it is preferable to wash the wafer by the rotation coating and rotate the washed substrate at a frequency of rotation of 2000 rpm to 4000 rpm so as to remove the rinsing liquid from the substrate. In addition, it is preferable to include post baking after the rinsing. By the baking, the developer and rinsing liquid remaining between or in the patterns are removed. The baking after rinsing is generally performed at 40 to 160° C., preferably at 70 to 95° C. generally for 10 seconds to 3 minutes, and preferably for 30 seconds to 90 seconds.

In addition, the present invention relates to a production method of an electronic device, including the pattern forming method of the present invention as described above, and an electronic device produced by the production method.

The electronic device of the present invention may be suitably mounted on an electric/electronic device (domestic appliances, OA media-related devices, optical devices, communication devices and the like).

### EXAMPLES

The present invention will be explained below in more detail with reference to Examples, but the contents of the present invention are not limited thereto.

### Synthesis Examples

### Synthesis of Acid-Generating Agent PAG1

An acid-generating agent PAG1 was synthesized according to the following reaction scheme.

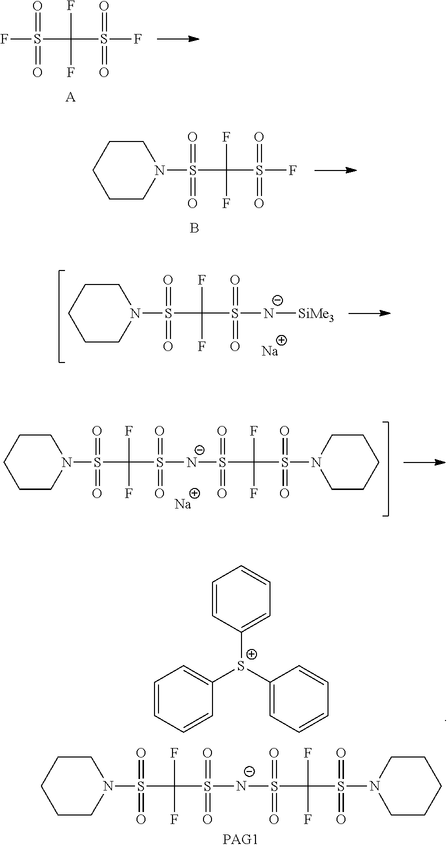

That is, a compound A (10 g), and 100 ml of tetrahydrofuran (THF) were added to a 300 ml recovery flask, piperidine (7.88 g) was added dropwise thereto while being cooled with ice, and the mixture was stirred for 2 hours at room temperature. Thereafter, the reaction solution is added to 200 ml of 1N of hydrochloric acid, extraction was performed twice using ethyl acetate (100 ml×2), the obtained organic layer was collected, washed with 200 ml of water and concentrated, and then 10.6 g of a compound B was obtained as a crude product.

The obtained compound B (5 g) was added into a 100 ml three-necked flask, 10 ml of diethylene glycol dimethyl ether was added thereto, and THF solution of sodium hexamethyldisilazide (38%, 9.3 ml) were added dropwise while being cooled with ice. After the mixture was stirred for 2 hours at room temperature, the compound B (5 g) was added thereto and the mixture was stirred for 15 hours at 130° C. Thereafter, water (50 ml) was added to the reaction solution, triphenylsulfonium bromide (8 g) vas added and extraction was performed twice using methylene chloride (100 ml×2). The obtained organic layer was collected, washed by water (100 ml×5) for 5 times and concentrated. Cyclopentylmethyl ether (20 ml) was added to the obtained oil-like crude product, the mixture was stirred at room temperature, and an acid-generating agent PAG1 (9.6 g, 66%) was obtained by filtering generated crystals.

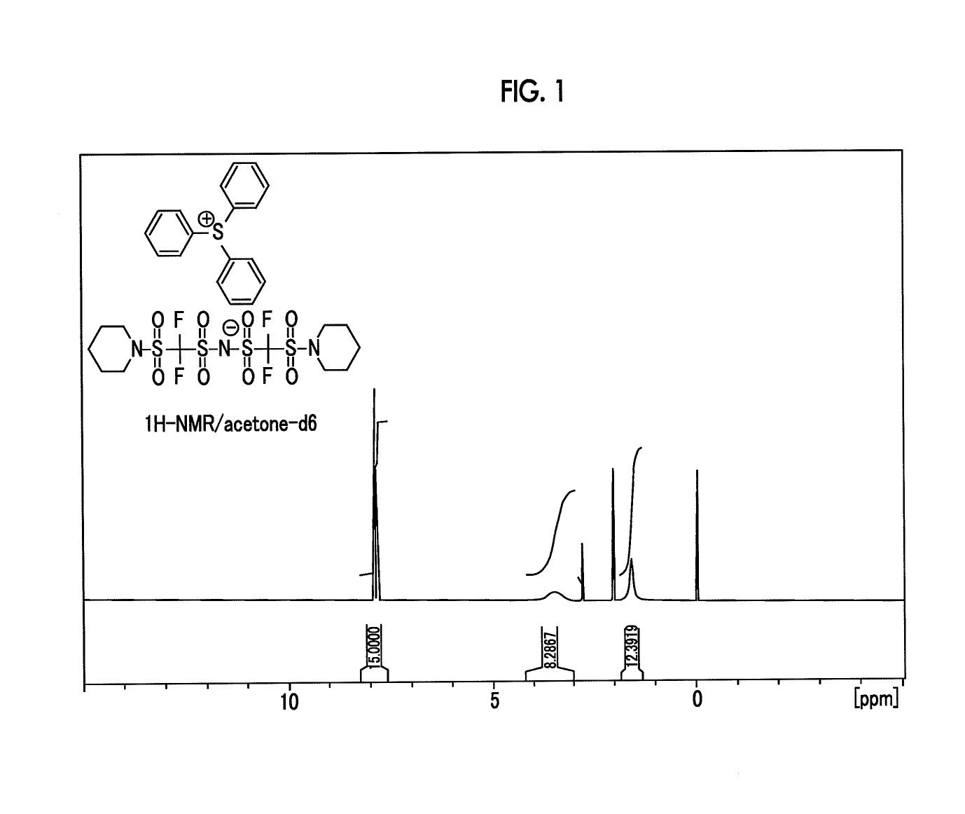

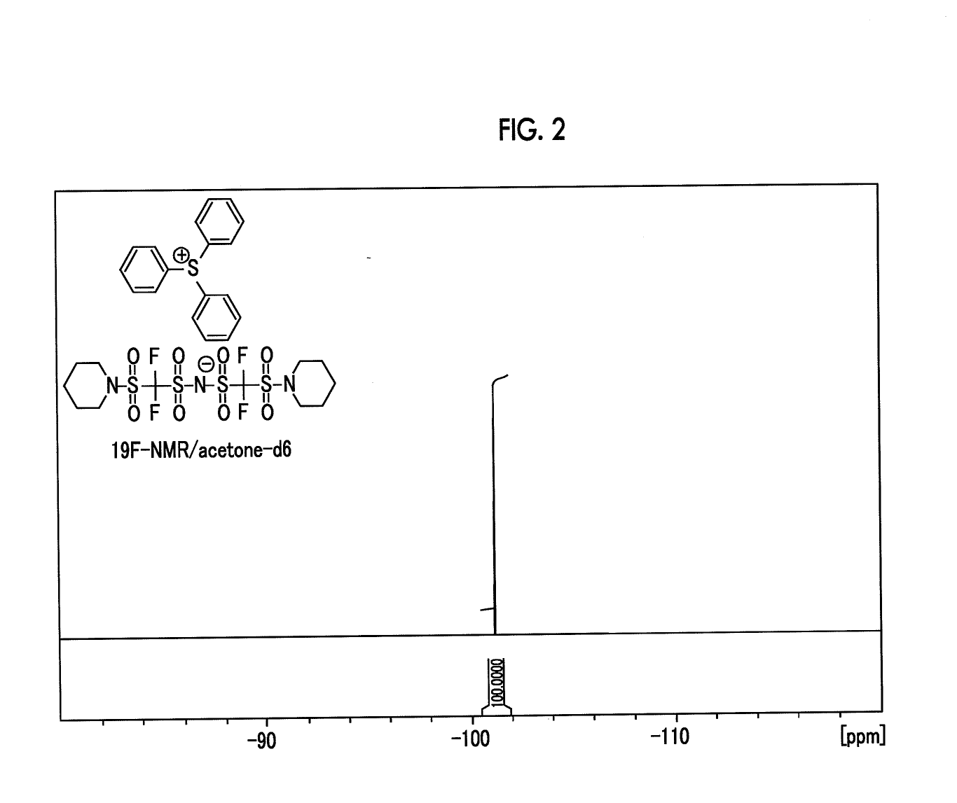

A ¹H-NMR chart and a ¹⁹F-NMR chart of the obtained acid-generating agent PAG1 are respectively shown in the FIG. 1 and the FIG. 2.

The acid-generating agents PAG2 to PAG13 shown below were synthesized according to the same method as the method synthesizing the above-mentioned acid-generating agent PAG1.

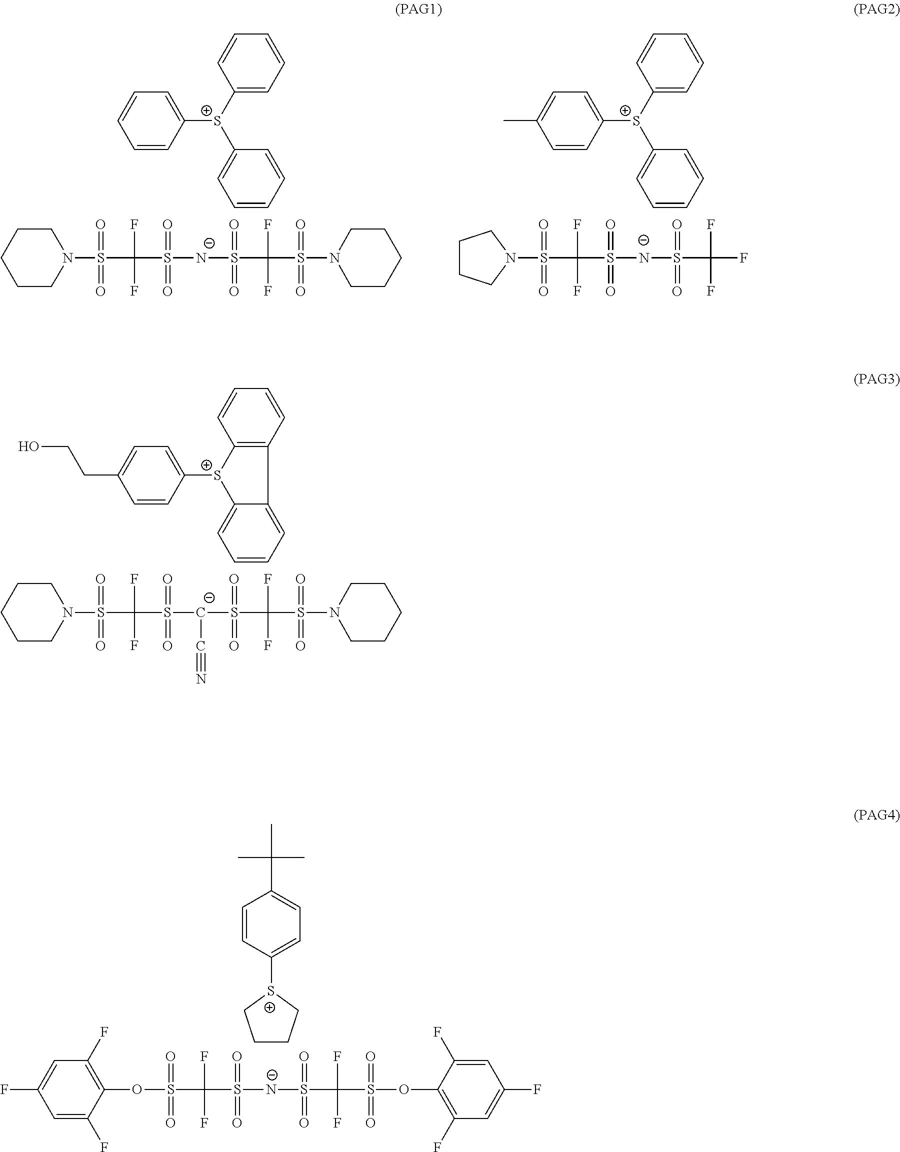

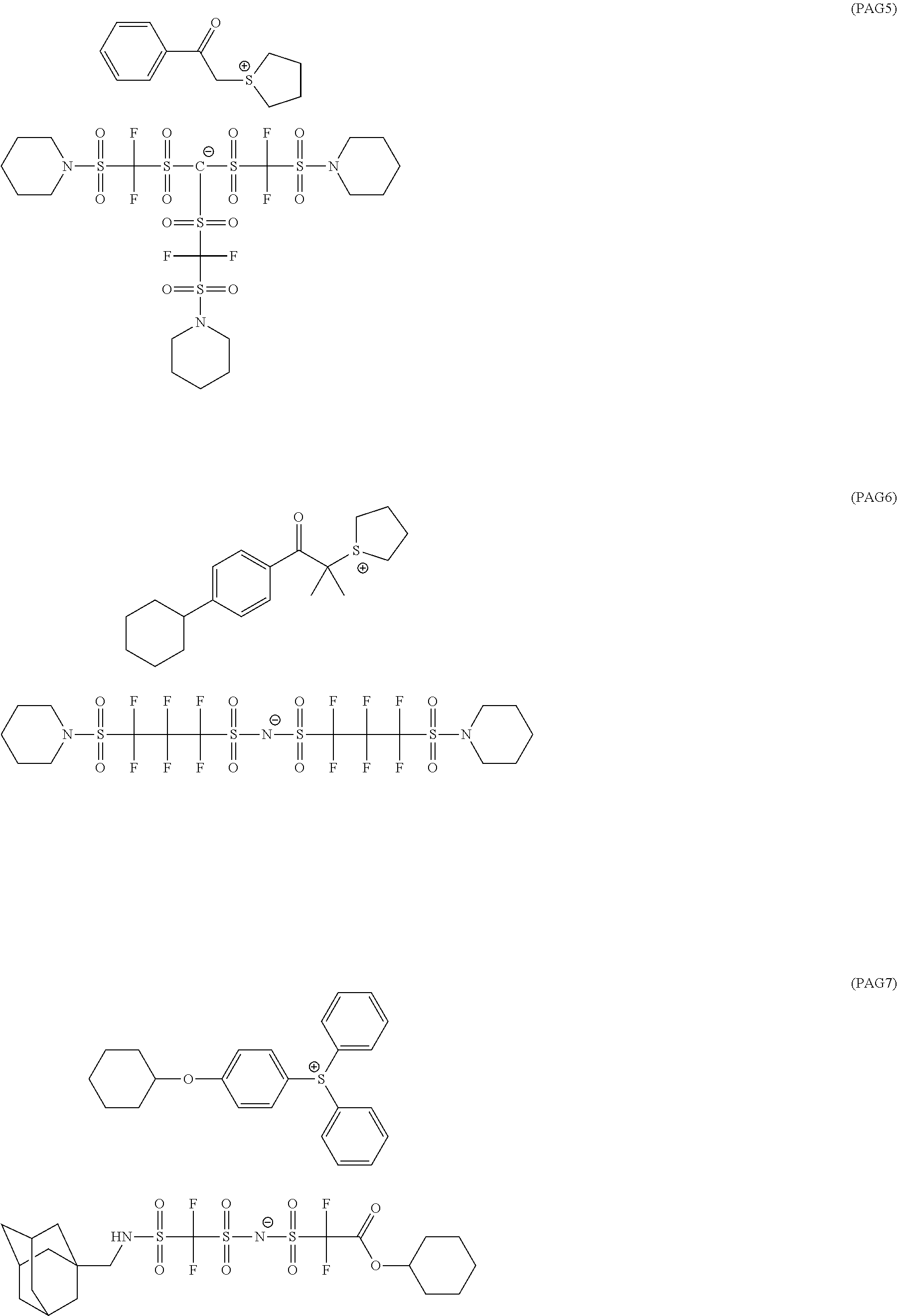 [SMILES: O=C(C[S+]1CCCC1)c1ccccc1 ; O=S(=O)([C-](S(=O)(=O)C(F)(F)S(=O)(=O)N1CCCCC1)S(=O)(=O)C(F)(F)S(=O)(=O)N1CCCCC1)C(F)(F)S(=O)(=O)N1CCCCC1 ; CC(C)(C(=O)c1ccc(C2CCCCC2)cc1)[S+]1CCCC1 ; O=S(=O)([N-]S(=O)(=O)C(F)(F)C(F)(F)C(F)(F)S(=O)(=O)N1CCCCC1)C(F)(F)C(F)(F)C(F)(F)S(=O)(=O)N1CCCCC1 ; c1ccc([S+](c2ccccc2)c2ccc(OC3CCCCC3)cc2)cc1 ; O=C(OC1CCCCC1)C(F)(F)S(=O)(=O)[N-]S(=O)(=O)C(F)(F)S(=O)(=O)NCC12CC3CC(CC(C3)C1)C2]

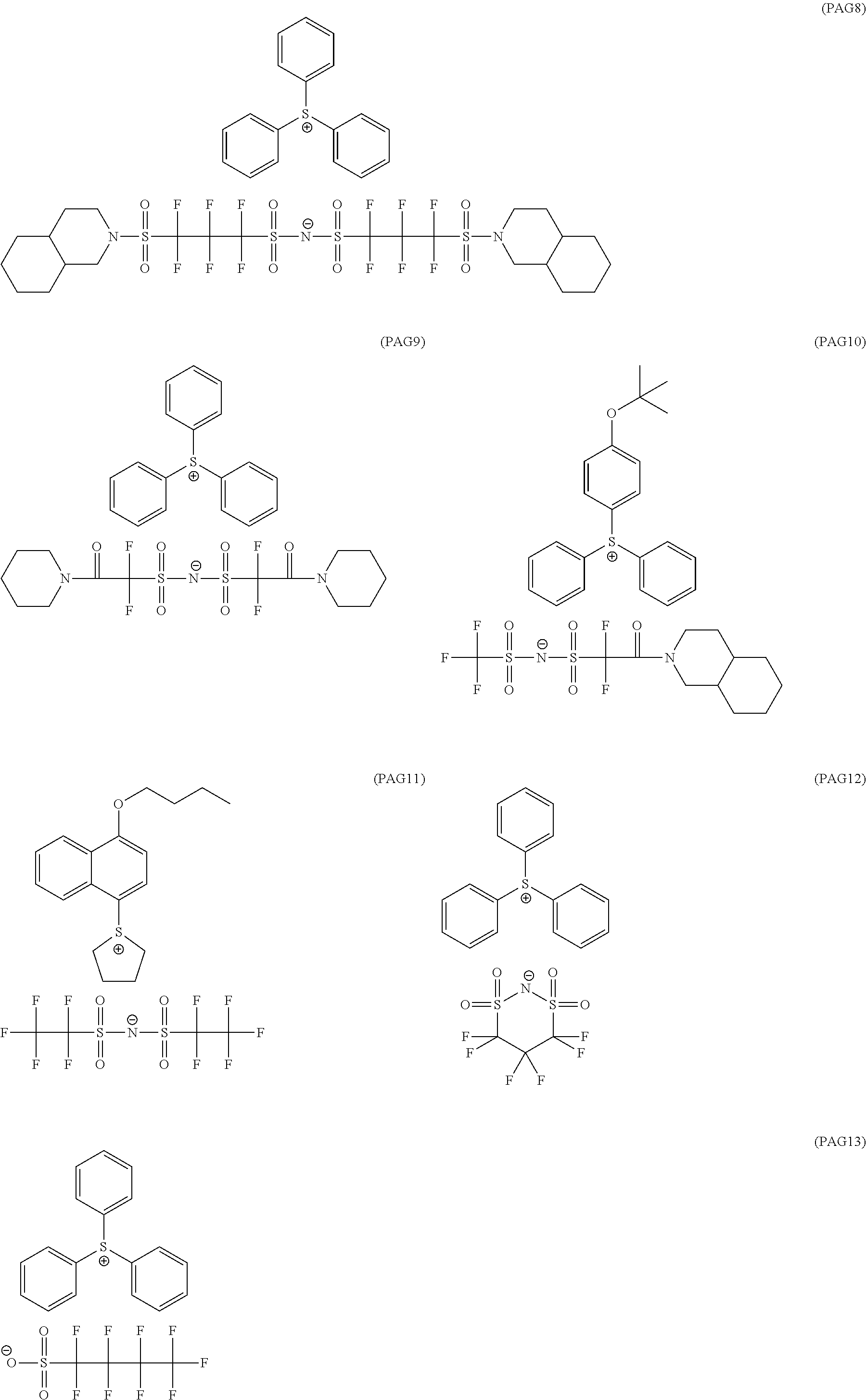

### Synthesis Examples

### Synthesis of Acid-Generating Agent PAG14

An acid-generating agent PAG14 was synthesized according to the following reaction scheme.

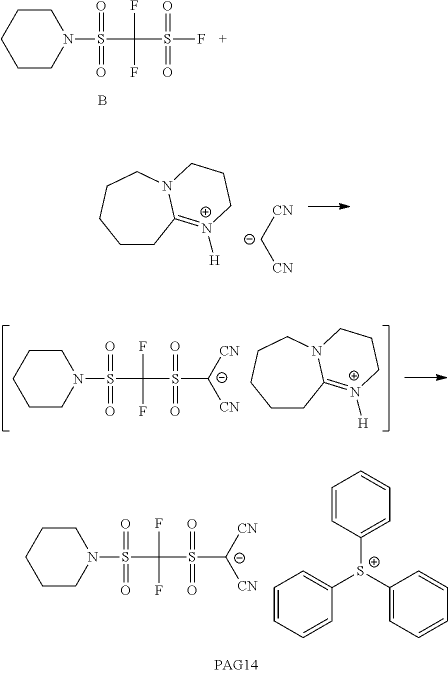

After devolving malononitril (2.35 g) in THF (50 ml) in a 300 ml recovery flask, the mixture was cooled at 0° C., DBU (5.41 g) was added and stirred for 30 minutes. Then the compound B (5 g) was added dropwise thereto and the mixture was stirred at 0° C. for 30 minutes and further stirred at 25° C. for 1 hour.

Water (100 ml), triphenylsulfoniumbromide (6.1 g) and methylene chloride (100 ml) were added to the obtained reaction solution and the mixture was stirred at 25° C. for 1 hour.

The organic layer of the reaction solution was separated and washed once with 1N of hydrochloric acid (100 ml) and for 3 times with destilled water (100 ml), then concentrated under reduced pressure, and a brown liquid with viscosity was obtained.

T-butylmethlether (150 ml) was added to the liquid with viscosity, the mixture was stirred at room temperature for 1 hour, and PAG14 (7.9 g, yield rate 75%) was obtained as a yellow solid.

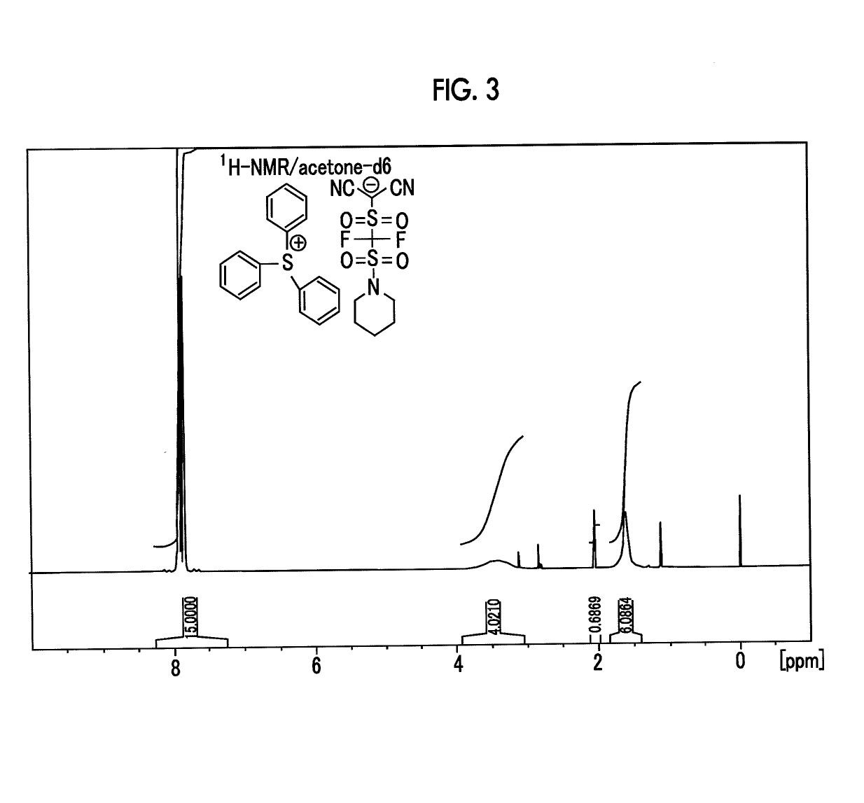

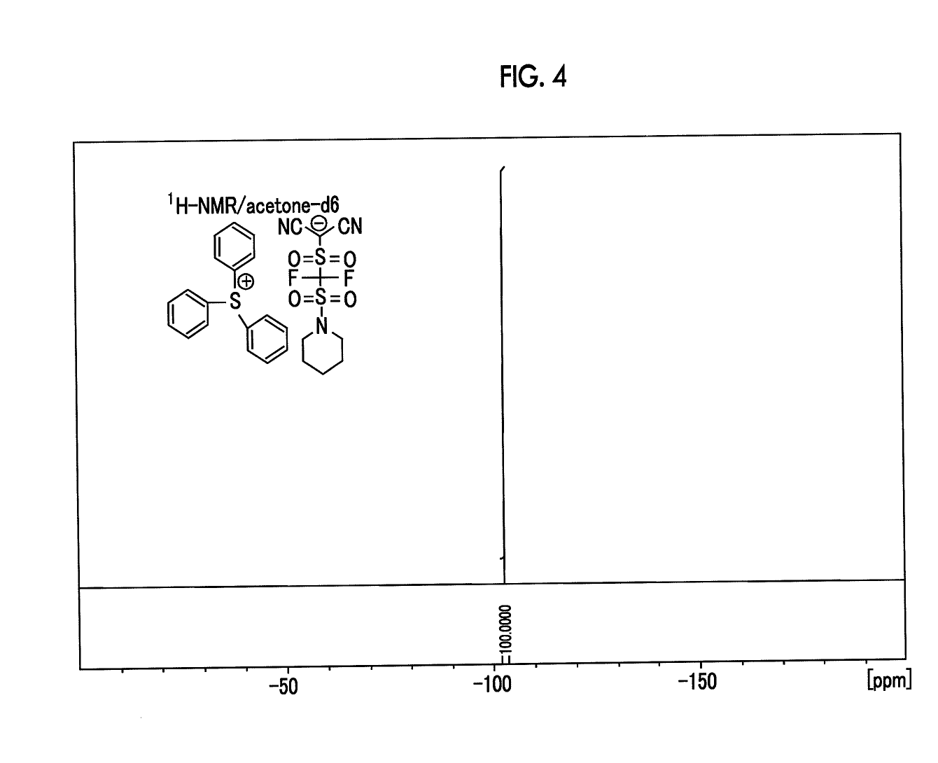

The FIGS. 3 and 4 respectively show a ¹H-NMR chart and ¹⁹F-NMR chart of the obtained PAG14.

An acid-generating agent PAG15 shown below was synthesized according to the same method as the acid-generating agent PAG14.

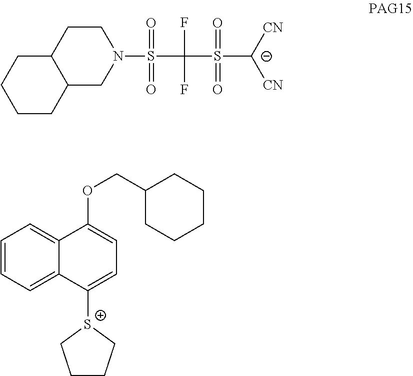 [SMILES: N#C[C-](C#N)S(=O)(=O)C(F)(F)S(=O)(=O)N1CCC2CCCCC2C1 ; c1ccc2c([S+]3CCCC3)ccc(OCC3CCCCC3)c2c1]

(Synthesis of Resin P-1)

Under a nitrogen air flow, 23.4 g of cyclohexanone was put into a three-neck flask, and heated at 80° C. Next, the following monomer 1 (24.7 g) and the following monomer 2(t-butyl methacrylate) (14.2 g) were dissolved in cyclohexanone (93.5 g) to prepare a monomer solution. Further, 0.92 g of a polymerization initiator, V-601 (manufactured by Wako Pure Chemical Industries, Ltd.) (2.0 mol % based on the total amount of the monomers) was added and dissolved therein. The prepared solution was added dropwise to the above-mentioned flask over 6 hours. After completion of dropwise addition, the solution was further subjected to a reaction at 80° C. for 2 hours. The reaction liquid was left to be cooled and then added dropwise to a mixed solvent of 1635 g of heptane/181.7 g of water. The precipitate thus formed was collected by filtration and dried to obtain 31.8 g of a resin (P-1). The weight average molecular weight of the obtained resin (P-1) was 20200, the dispersity (Mw/Mn) thereof was 1.57, and the compositional ratio (molar ratio) measured by ¹³C-NMR was 50/50.

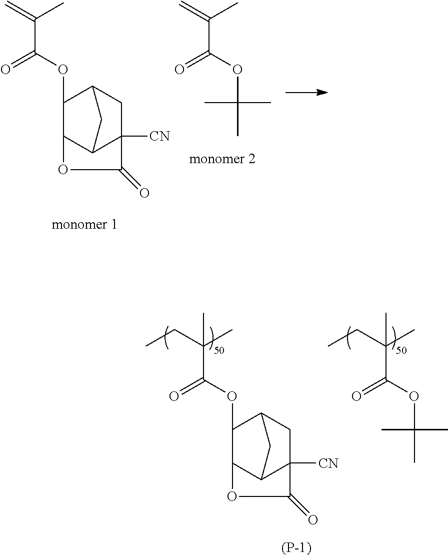

Resins (P-2) to (P-11) were synthesized in the same manner as the resin (P-1).

The structures, the compositional ratio (molar ratio) of the repeating units, the weight average molecular weight and the degree of dispersion of these synthesized resins are as shown below.

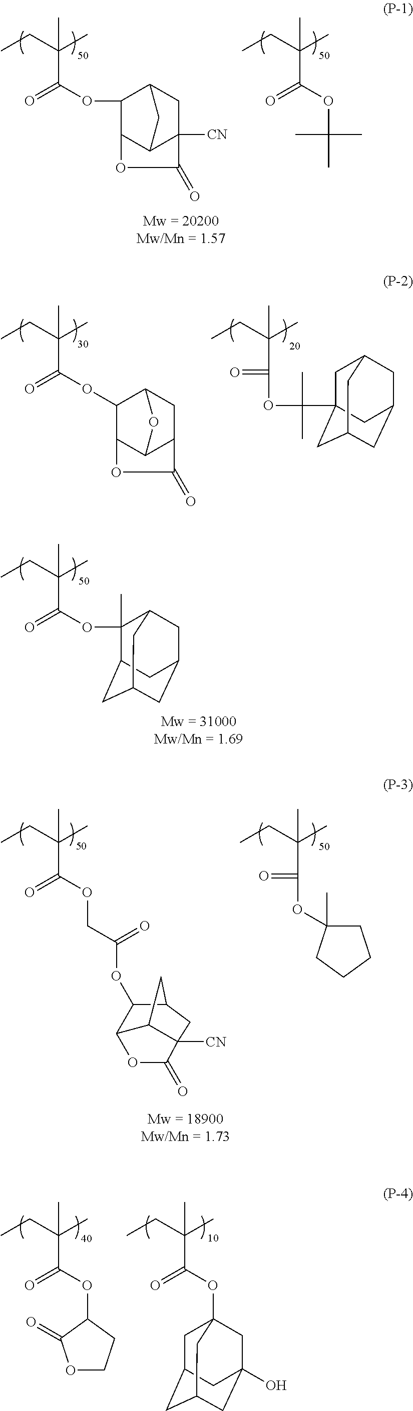

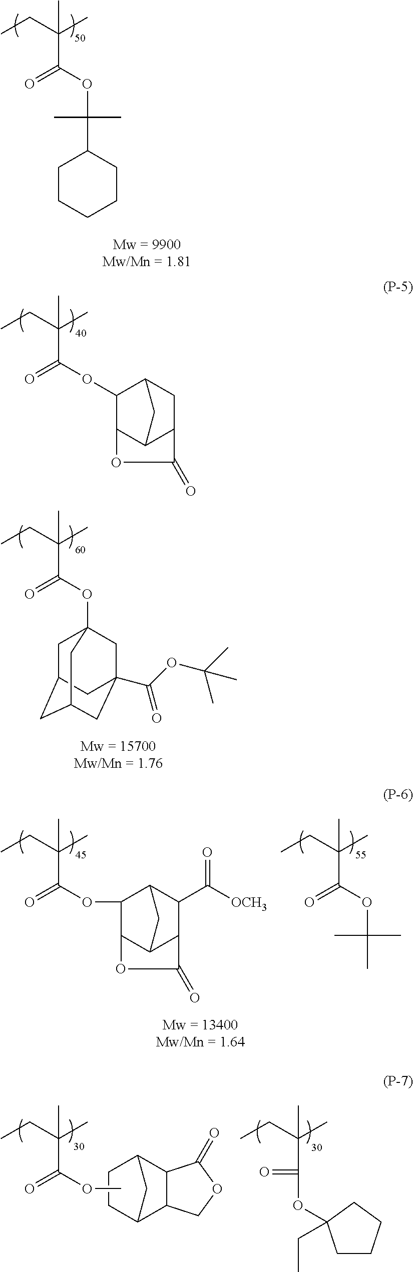

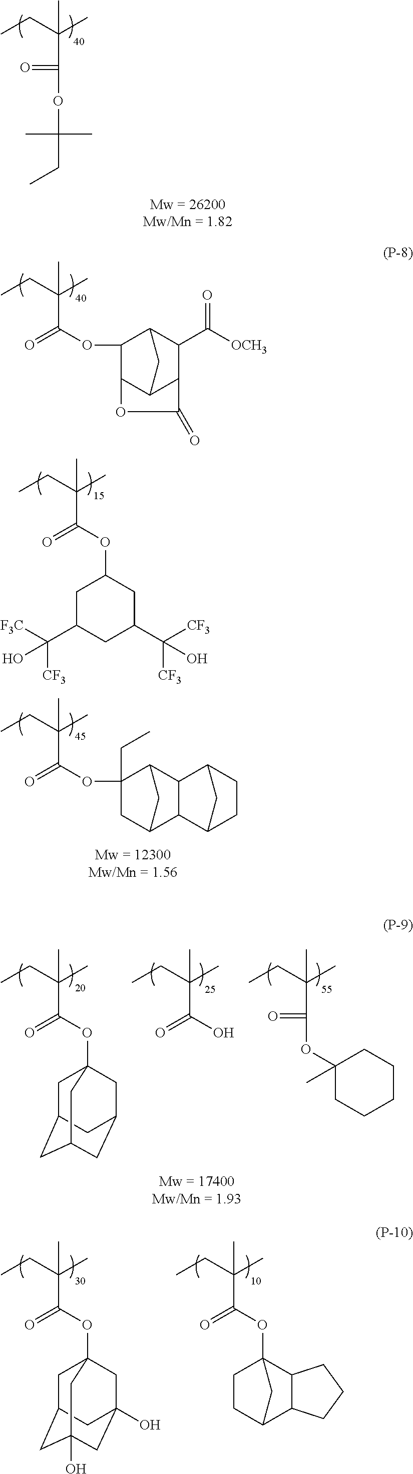

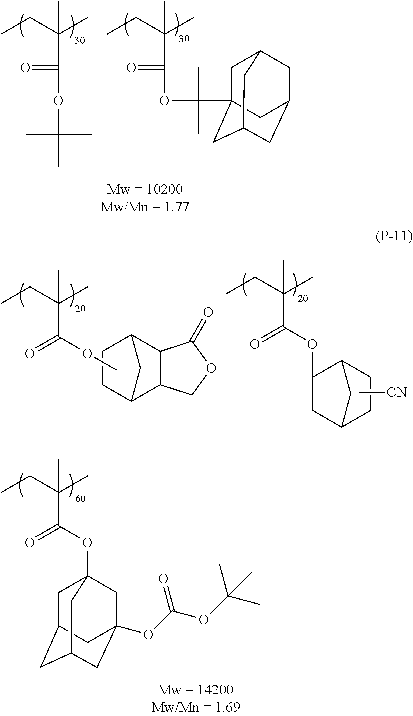

Basic Compound (C) in which basicity decreases by irradiation with actinic rays or radiation and Basic Compound (C′)>

As a basic compound in which basicity decreases by irradiation with actinic rays or radiation and a basic compound, the following compounds were used.

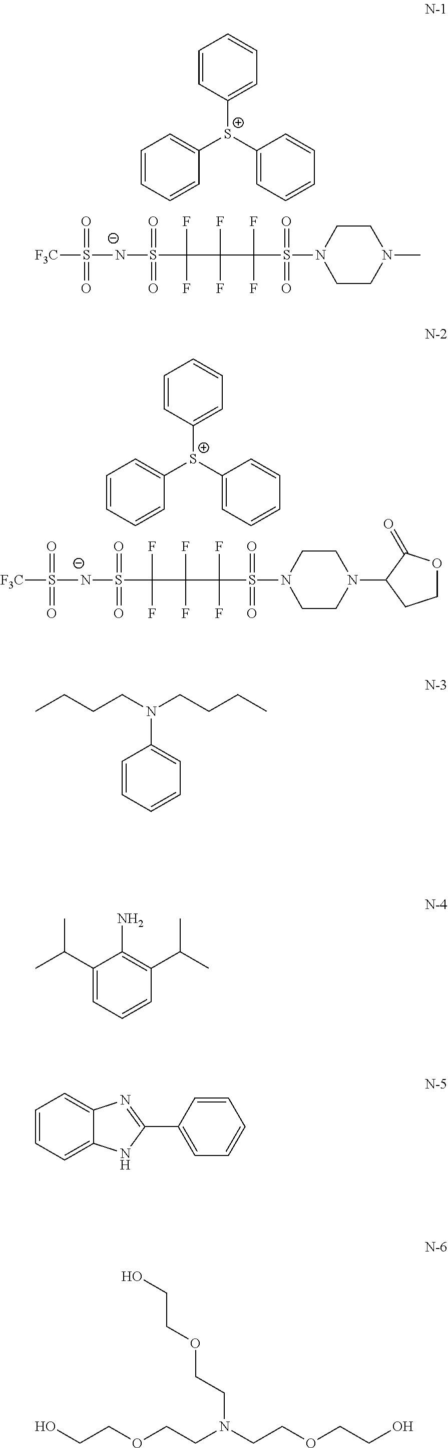

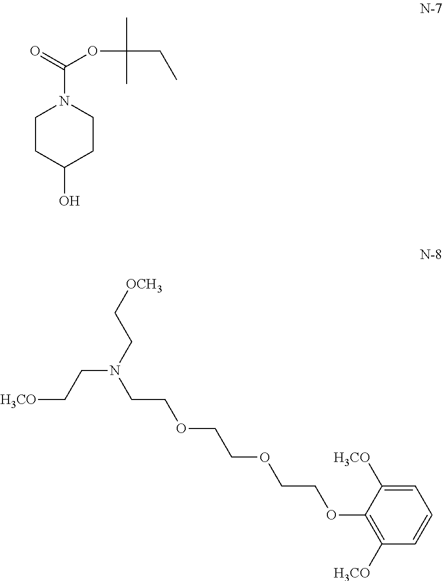 [SMILES: CCC(C)(C)OC(=O)N1CCC(O)CC1 ; COCCN(CCOC)CCOCCOCCOc1c(OC)cccc1OC]

<Hydrophobic Resin>

The hydrophobic resin was used by being appropriately selected from the above-exemplified resins (HR-1) to (FIR-90).

The hydrophobic resin (HR-79) was synthesized based on the disclosures of US2010/0152400A, WO2010/067,905A, WO2010/067898A and the like.

<Surfactant>

As surfactants, the following were used.
W-1: Megaface F176 (manufactured by DIC CORPORATION; a fluorine-based surfactant)
W-2: Megaface R08 (manufactured by DIC CORPORATION; a fluorine and silicon-based surfactant)
W-3: polysiloxane polymer KP-341 (manufactured by Shin-Etsu Chemical Co., Ltd; a silicon-based surfactant)
W-4: Troysol S-366 (manufactured by Troy Chemical)
W-5: KH-20 (manufactured by ASAHI GLASS CO., LTD)
W-6: PolyFox PF-6320 (manufactured by OMNOVA solution Inc.; a fluorine-based surfactant)

<Solvent>

As solvents, the following were used.
(group a)
SL-1: propylene glycol monomethyl ether acetate (PGMEA)
SL-2: propylene glycol monomethyl ether propionate
SL-3: 2-heptanone
(group b)
SL-4: ethyl lactate
SL-5: propylene glycol monomethyl ether (PGME)
SL-6: cyclohexanone
(group c)
SL-7: γ-butyrolactone
SL-8: propylene carbonate

<Developer>

As developers, the following were used.
SG-1: butyl acetate
SG-2: methyl amyl ketone
SG-3: ethyl-3-ethoxy propionate
SG-4: pentyl acetate
SG-5: isopentyl acetate
SG-6: propylene glycol monomethyl ether acetate (PGMEA)
SG-7: cyclohexanone

<Rinsing Liquid>

As rinsing liquids, the following were used.
SR-1: 4-methyl-2-pentanol
SR-2: 1-hexanol
SR-3: butyl acetate
SR-4: methyl amyl ketone
SR-5: ethyl-3-ethoxy propionate

<ArF Dry Exposure>

(Preparation of Resist)

The components shown in the following Tables 3 and 4 were dissolved in the solvents shown in the same table at 3.8% by mass in terms of a solid content, and the respective solutions were filtered through a polyethylene filter having a pore size of 0.1 μm, thereby preparing actinic ray-sensitive or radiation-sensitive resin compositions (resist compositions). ARC29SR (manufactured by NISSAN CHEMICAL INDUSTRIES, LTD.) for forming an organic antireflection film was coated onto a silicon wafer, followed by baking at 205° C. for 60 seconds, thereby forming an antireflection film having a film thickness of 86 nm. The actinic ray-sensitive or radiation-sensitive resin composition was coated onto the antireflection followed by baking (PB: Prebake) at 100° C. for 60 seconds, thereby forming a resist film having a film thickness of 100 nm.

The obtained resist film was subjected to pattern exposure by using an ArF excimer laser scanner (manufactured by ASML; PAS5500/1100, NA 0.75, Dipole, outer sigma 0.89, inner sigma 0.65). Here, as reticle, a 6% halftone mask where a line size=75 nm and line:space=1:1 was used. Thereafter, the wafer was baked (PEB: Post Exposure Bake) at 105° C. for 60 seconds. Next, developing was performed by paddling the developer shown in the Tables 3 and 4 for 30 seconds, the wafer was rinsed by paddling the rinsing liquid shown in the Tables 3 and 4 for 30 seconds. Subsequently, the wafer was rotated at a frequency of rotation of 4000 rpm for 30 seconds. In this manner, a resist pattern with a line and space (1:1) having a line width of 75 nm was obtained.

[Exposure Latitude (EL, %)]

An exposure amount that reproduces a mask pattern of a line and space having a line width of 75 nm (line:space=1:1) was taken as an optimal exposure amount Eₒₚₜ. Next, an exposure amount range that allows the pattern size to be 75 nm±10% (in other words, 67.5 nm and 82.5 nm), which is the objective value was determined. Then exposure latitude (EL) defined by the following formula was calculated. The larger the value of EL, the smaller the change in performance caused by a change in the exposure amount.

[EL(%)]={[(an exposure amount when a line width is 82.5 nm)−(an exposure amount when a line width is 67.5 nm)]/Eₒₚₜ}×100

[Line Width Roughness (LWR, nm)]

A line and space of 75 nm (1:1) resolved with the optimal exposure amount in the exposure latitude evaluation was observed from the top of the pattern by a length measurement scanning electron microscope (SEM (manufactured by Hitachi, Ltd., S-9380II)). At this time, the line width at an arbitrary 50 points was observed and evaluated under measuring variation of 3φ. The smaller the value, the better the performance.

[Developing Time Dependency]

With the optimal exposure amount at the exposure latitude evaluation, exposure was performed in the same way as above (resist preparation), a difference between a developed line width after a developer was paddled for 30 second and a developed line width after a developer was paddled for 60 seconds is divided by 30, and the obtained value was taken as developing time dependency. The smaller the value, the better the performance.

[developing time dependency (nm/sec)]=[(line width at 60 second development (nm))−(line width at 30 second development (nm))]/30 (sec)

The results of the above evaluations are shown in the following Tables 3 and 4.

TABLE 3

| | | | Compound | | Compound | | Basic | | | Mass | | |
|---|---|---|---|---|---|---|---|---|---|---|---|---|
| Examples | Resin | (g) | (B) | (g) | (C) | (g) | Compound | (g) | Solvent | Ratio | Surfactant | (g) |
| Example 1 | P-1 | 10 | PAG1 | 1.18 | N-2 | 0.44 | | | SL-1/ | 70/30 | W-3 | 0.003 |
| | | | | | | | | | SL-8 | | | |
| Example 2 | P-2 | 10 | PAG2 | 1.24 | | | N-5 | 0.14 | SL-1/ | 60/40 | W-5 | 0.003 |
| | | | | | | | | | SL-5 | | | |
| Example 3 | P-3 | 10 | PAG3 | 1.14 | | | N-5 | 0.14 | SL-1/ | 60/40 | W-1 | 0.003 |
| | | | | | | | | | SL-5 | | | |
| Example 4 | P-4 | 10 | PAG4 | 1.26 | N-1 | 0.64 | | | SL-1/ | 80/20 | N/A | N/A |
| | | | | | | | | | SL-3 | | | |
| Example 5 | P-5 | 10 | PAG5 | 2.22 | N-1 | 0.54 | | | SL-1/ | 60/40 | W-6 | 0.003 |
| | | | | | | | | | SL-5 | | | |
| Example 6 | P-6 | 10 | PAG6 | 1.32 | | | N-5 | 0.12 | SL-1/ | 90/10 | W-1 | 0.003 |
| | | | | | | | | | SL-4 | | | |
| Example 7 | P-7 | 10 | PAG7 | 1.50 | N-2 | 0.76 | N-8 | 0.12 | SL-1/ | 60/40 | W-1 | 0.003 |
| | | | | | | | | | SL-5 | | | |
| Example 8 | P-8 | 10 | PAG8 | 1.04 | | | N-4/ | 0.04/ | SL-1/ | 60/40 | W-4 | 0.003 |
| | | | | | | | N-7 | 0.04 | SL-5 | | | |
| Example 9 | P-9 | 10 | PAG9 | 1.33 | N-1 | 0.58 | | | SL-1/ | 70/30 | W-1 | 0.003 |
| | | | | | | | | | SL-7 | | | |
| Example 10 | P-10 | 10 | PAG10 | 1.28 | | | N-3 | 0.14 | SL-1/ | 60/40 | W-1 | 0.003 |
| | | | | | | | | | SL-5 | | | |
| Example 11 | P-1/ | 5/5 | PAG4 | 1.14 | | | N-5 | 0.04 | SL-1/ | 60/40 | N/A | N/A |
| | P-10 | | | | | | | | SL-5 | | | |
| Example 12 | P-7 | 10 | PAG5/ | 1.00/ | | | N-5 | 0.08 | SL-1/ | 60/40 | W-1 | 0.001 |
| | | | PAG13 | 0.25 | | | | | SL-5 | | | |
| Example 13 | P-11 | 10 | PAG1 | 1.33 | | | N-6 | 0.14 | SL-1/ | 60/40 | W-3 | 0.003 |
| | | | | | | | | | SL-5 | | | |
| Comparative | P-1 | 10 | PAG11 | 1.50 | | | N-5 | 0.14 | SL-1/ | 60/40 | W-3 | 0.003 |
| Example 1 | | | | | | | | | SL-5 | | | |
| Comparative | P-2 | 10 | PAG12 | 1.44 | | | N-5 | 0.14 | SL-5/ | 30/70 | W-1 | 0.003 |
| Example 2 | | | | | | | | | SL-6 | | | |
| Comparative | P-3 | 10 | PAG13 | 1.48 | | | N-8 | 0.14 | SL-1/ | 90/10 | W-1 | 0.003 |
| Example 3 | | | | | | | | | SL-2 | | | |

| | | | | | | | Developing Time |
|---|---|---|---|---|---|---|---|
| | | Mass | Rinsing | Mass | EL | LWR | Dependency |
| Examples | Developer | Ratio | Liquid | Ratio | (%) | (nm) | [nm/sec] |
| Example 1 | SG-3 | 100 | SR-1 | 100 | 18.9 | 4.3 | 0.15 |
| Example 2 | SG-1 | 100 | SR-1 | 100 | 14.3 | 5.0 | 0.21 |
| Example 3 | SG-1/ | 50/50 | SR-1 | 100 | 17.3 | 4.8 | 0.19 |
| | SG-4 | | | | | | |
| Example 4 | SG-1 | 100 | SR-1 | 100 | 18.1 | 4.7 | 0.17 |
| Example 5 | SG-5 | 100 | SR-5 | 100 | 18.7 | 4.8 | 0.18 |
| Example 6 | SG-1 | 100 | SR-1 | 100 | 17.5 | 4.9 | 0.19 |
| Example 7 | SG-1 | 100 | SR-1/ | 90/ | 17.4 | 4.9 | 0.19 |
| | | | SR-3 | 10 | | | |
| Example 8 | SG-1 | 100 | SR-1 | 100 | 15.9 | 5.2 | 0.21 |
| Example 9 | SG-2 | 100 | SR-2 | 100 | 17.1 | 4.9 | 0.19 |
| Example 10 | SG-1 | 100 | SR-1 | 100 | 17.2 | 4.9 | 0.20 |
| Example 11 | SG-5 | 100 | SR-1 | 100 | 18.3 | 4.6 | 0.17 |
| Example 12 | SG-1 | 100 | SR-1 | 100 | 17.5 | 4.8 | 0.20 |
| Example 13 | SG-1 | 100 | SR-4 | 100 | 14.1 | 5.3 | 0.22 |
| Comparative | SG-1 | 100 | SR-1 | 100 | 8.7 | 9.3 | 0.29 |
| Example 1 | | | | | | | |
| Comparative | SG-1 | 100 | SR-1 | 100 | 9.6 | 8.4 | 0.32 |
| Example 2 | | | | | | | |
| Comparative | SG-7 | 100 | SR-1 | 100 | 9.3 | 7.8 | 0.35 |
| Example 3 | | | | | | | |

TABLE 4

| | | | Compound | | Compound | | Basic | | | Mass | | |
|---|---|---|---|---|---|---|---|---|---|---|---|---|
| Examples | Resin | (g) | (B) | (g) | (C) | (g) | Compound | (g) | Solvent | Ratio | Surfactant | (g) |
| Example 27 | P-1 | 10 | PAG14 | 1.25 | N-l | 0.64 | | | SL-1/ | 60/40 | W-3 | 0.003 |
| | | | | | | | | | SL-5 | | | |
| Example 28 | P-5 | 10 | PAG15 | 1.88 | | | N-5 | 0.14 | SL-1/ | 60/40 | W-3 | 0.003 |
| | | | | | | | | | SL-5 | | | |

| | | | | | | | Developing Time |
|---|---|---|---|---|---|---|---|
| | | Mass | Rinsing | Mass | EL | LWR | Dependency |
| Examples | Developer | Ratio | Liquid | Ratio | (%) | (nm) | [nm/sec] |
| Example 27 | SG-1 | 100 | SR-4 | 100 | 18.1 | 4.8 | 0.18 |
| Example 28 | SG-2 | 100 | SR-4 | 100 | 17.4 | 4.9 | 0.19 |

From the results shown in the Tables 3 and 4, it is clearly understood that the Comparative Examples 1 to 3 where the acid-generating agent in the present invention was not used had large line width roughness (LWR), small exposure latitude (EL) and large developing time dependency, which shows that the Comparative Examples 1 to 3 were poor in any the LWR, EL and developing time dependency.

On the other hand, it was concluded that Examples 1 to 13, 27 and 28 where the acid-generating agent in the present invention was used had small LWR, large EL and reduced developing time dependency, which shows that Examples 1 to 13, 27 and 28 were excellent in both the LWR, EL and developing time dependency.

<ArF Liquid Immersion Exposure>

(Preparation of Resist)

The components shown in the following Tables 5 and 6 were dissolved in the solvents shown in the same table at 3.8% by mass in terms of a total solid content, and the respective solutions were filtered through a polyethylene filter having a pore size of 0.03 μm, thereby preparing actinic ray-sensitive or radiation-sensitive resin compositions (resist compositions). ARC29SR (manufactured by NISSAN CHEMICAL INDUSTRIES, LTD.) for forming an organic antireflection film was coated onto a silicon wafer, followed by baking at 205° C. for 60 seconds, thereby forming an antireflection film having a film thickness of 95 nm. The actinic ray-sensitive or radiation-sensitive resin composition was coated onto the antireflection film, followed by baking (PB: Prebake) at 100° C. for 60 seconds, thereby forming a resist film having a film thickness of 100 nm.

The obtained wafer was subjected to pattern exposure through a halftone mask where a hole size is 60 nm, the pitch between holes is 90 nm, and the holes are arranged in a square array, by using an ArF excimer laser liquid immersion scanner (manufactured by ASML; XT 1700i, NA 1.20, C-Quad, outer sigma 0.900, inner sigma 0.812, XY deflection). As the liquid for liquid immersion, ultrapure water was used. Thereafter, the wafer was baked (PEB: Post Exposure Bake) at 105° C. for 60 seconds. Next, developing was performed by paddling the developer mentioned in the Tables 5 and 6 for 30 seconds, and the wafer was rinsed by paddling with the rinsing liquid shown in the Tables 5 and 6 for 30 seconds. Subsequently, the wafer was rotated at a frequency of rotation of 4000 rpm for 30 seconds. In this manner, a contact hole pattern of 45 nm was obtained.

[Exposure Latitude (EL) (%)]

By observing a hole size using a length measuring scanning electron microscope (SEM (manufactured by Hitachi, Ltd., S-9380II)), an optimal exposure amount when a contact hole pattern with a hole size of 45 nm was developed was taken as sensitivity Eₒₚₜ (mJ/cm²). Based on the obtained optimal exposure amount Eₒₚₜ, an exposure amount when a size of the contact hole becomes the objective value, which was 45 nm±10% (that is, 40.5 nm and 49.5 nm) was determined. Then exposure latitude (EL, %) defined by the following formula was calculated. The larger the value of EL, the smaller the change in performance caused by a change in the exposure amount.

[EL(%)]={[(an exposure amount when a pattern size is 40.5 nm)−(an exposure amount when a pattern size is 49.5 nm)]/Eₒₚₜ}×100

[Uniformity in Local Pattern Dimension (Local CDU, nm)]

In an area developed by one shot with the optimal exposure amount in the exposure latitude evaluation, the sizes of arbitrary 25 holes in each 20 areas of 1 μm square (500 holes in total) were measured. A standard deviation was calculated and 3φ was obtained. The smaller the value, the better the performance with smaller distribution of dimensions.

[Film Thickness in Pattern Portion (nm)]

A cross-sectional shape of each pattern of the optimal exposure amount was observed using a scanning electron microscope (manufactured by Hitachi, Ltd., S-4800). A height of a pattern in resist remaining portion of a hole pattern was measured. The larger the value, the better with lower film thinning.

The results of the above evaluations are shown in the following Tables 5 and 6.

TABLE 5

| | | | Compound | | Compound | | Basic | | Hydrophobic | | | Mass |
|---|---|---|---|---|---|---|---|---|---|---|---|---|
| Examples | Resin | (g) | (B) | (g) | (C) | (g) | Compound | (g) | Resin (E) | (g) | Solvent | Ratio |
| Example 14 | P-1 | 10 | PAG1 | 1.18 | N-2 | 0.44 | | | HR-24 | 0.06 | SL-1/ | 60/40 |
| | | | | | | | | | | | SL-5 | |
| Example 15 | P-2 | 10 | PAG2 | 1.24 | | | N-5 | 0.14 | HR-24 | 0.06 | SL-1/ | 70/30 |
| | | | | | | | | | | | SL-7 | |
| Example 16 | P-3 | 10 | PAG3 | 1.14 | | | N-5 | 0.14 | HR-3 | 0.06 | SL-1/ | 60/40 |
| | | | | | | | | | | | SL-5 | |
| Example 17 | P-4 | 10 | PAG4 | 1.26 | N-1 | 0.64 | | | HR-26 | 0.06 | SL-1/ | 90/10 |
| | | | | | | | | | | | SL-4 | |
| Example 18 | P-5 | 10 | PAG5 | 2.22 | N-1 | 0.54 | | | HR-47 | 0.06 | SL-1/ | 60/40 |
| | | | | | | | | | | | SL-5 | |
| Example 19 | P-6 | 10 | PAG6 | 1.32 | | | N-5 | 0.12 | HR-24 | 0.06 | SL-1/ | 60/40 |
| | | | | | | | | | | | SL-5 | |
| Example 20 | P-7 | 10 | PAG7 | 1.50 | N-2 | 0.76 | N-8 | 0.12 | HR-24/ | 0.04/ | SL-1 | 100 |
| | | | | | | | | | HR-79 | 0.02 | | |
| Example 21 | P-8 | 10 | PAG8 | 1.04 | | | N-4/ | 0.04/ | HR-24 | 0.06 | SL-1/ | 60/40 |
| | | | | | | | N-7 | 0.04 | | | SL-5 | |
| Example 22 | P-9 | 10 | PAG9 | 1.33 | N-1 | 0.58 | | | HR-24 | 0.06 | SL-1/ | 60/40 |
| | | | | | | | | | | | SL-5 | |
| Example 23 | P-10 | 10 | PAG10 | 1.28 | | | N-3 | 0.14 | HR-3 | 0.06 | SL-5/ | 30/70 |
| | | | | | | | | | | | SL-6 | |
| Example 24 | P-1/ | 5/5 | PAG4 | 1.14 | | | N-5 | 0.04 | HR-24 | 0.06 | SL-1/ | 80/20 |
| | P-10 | | | | | | | | | | SL-3 | |
| Example 25 | P-7 | 10 | PAG5/ | 1.00/ | | | N-5 | 0.08 | HR-47 | 0.06 | SL-1/ | 90/10 |
| | | | PAG13 | 0.25 | | | | | | | SL-2 | |
| Example 26 | P-11 | 10 | PAG1 | 1.33 | | | N-6 | 0.14 | HR-24 | 0.06 | SL-1/ | 60/40 |
| | | | | | | | | | | | SL-5 | |
| Comparative | P-1 | 10 | PAG11 | 1.50 | | | N-5 | 0.14 | HR-24 | 0.06 | SL-1/ | 60/40 |
| Example 4 | | | | | | | | | | | SL-5 | |
| Comparative | P-2 | 10 | PAG12 | 1.44 | | | N-5 | 0.14 | HR-24 | 0.06 | SL-5/ | 30/70 |
| Example 5 | | | | | | | | | | | SL-6 | |
| Comparative | P-3 | 10 | PAG13 | 1.48 | | | N-8 | 0.14 | HR-3 | 0.06 | SL-1/ | 90/10 |
| Example 6 | | | | | | | | | | | SL-2 | |

| | | | | | | | Local | | Film Thickness |
|---|---|---|---|---|---|---|---|---|---|
| | | | | Mass | Rinsing | Mass | CDU | EL | in Pattern |
| Examples | Surfactant | (g) | Developer | Ratio | Liquid | Ratio | (nm) | (%) | Portion (nm) |
| Example 14 | W-1 | 0.003 | SG-1 | 100 | SR-1 | 100 | 4.1 | 19.4 | 86 |
| Example 15 | W-2 | 0.003 | SG-1 | 100 | SR-1 | 100 | 5.2 | 15.4 | 80 |
| Example 16 | W-2 | 0.003 | SG-5 | 100 | SR-1 | 100 | 5.8 | 17.6 | 82 |
| Example 17 | W-1 | 0.003 | SG-1 | 100 | SR-1 | 100 | 4.4 | 18.2 | 84 |
| Example 18 | N/A | N/A | SG-6 | 100 | SR-1 | 100 | 4.3 | 19.3 | 83 |
| Example 19 | W-6 | 0.003 | SG-2 | 100 | SR-1 | 100 | 5.2 | 17.8 | 82 |
| Example 20 | W-1 | 0.003 | SG-1 | 100 | SR-1 | 100 | 5.2 | 17.1 | 82 |
| Example 21 | W-1 | 0.003 | SG-1 | 100 | SR-5 | 100 | 5.9 | 15.2 | 80 |
| Example 22 | W-4 | 0.003 | SG-1 | 100 | SR-1 | 100 | 4.6 | 17.4 | 81 |
| Example 23 | W-1 | 0.003 | SG-7 | 100 | SR-1/ | 90/10 | 4.7 | 17.5 | 81 |
| | | | | | SR-3 | | | | |
| Example 24 | W-3 | 0.003 | SG-1 | 100 | SR-1 | 100 | 4.3 | 18.3 | 84 |
| Example 25 | W-5 | 0.003 | SG-1 | 100 | SR-1 | 100 | 4.9 | 17.8 | 81 |
| Example 26 | W-3 | 0.003 | SG-1 | 100 | SR-4 | 100 | 6.1 | 15.5 | 80 |
| Comparative | W-3 | 0.003 | SG-1 | 100 | SR-1 | 100 | 10.2 | 9.6 | 68 |
| Example 4 | | | | | | | | | |
| Comparative | W-1 | 0.030 | SG-1 | 100 | SR-1 | 100 | 9.9 | 10.1 | 74 |
| Example 5 | | | | | | | | | |
| Comparative | W-l | 0.003 | SG-7 | 100 | SR-1 | 100 | 9.1 | 9.6 | 71 |
| Example 6 | | | | | | | | | |

TABLE 6

| | | | Compound | | Compound | | Basic | | Hydrophobic | | | Mass |
|---|---|---|---|---|---|---|---|---|---|---|---|---|
| Examples | Resin | (g) | (B) | (g) | (C) | (g) | Compound | (g) | Resin (E) | (g) | Solvent | Ratio |
| Example 29 | P-1 | 10 | PAG14 | 1.25 | N-1 | 0.64 | | | HR-24 | 0.06 | SL-1/ | 60/40 |
| | | | | | | | | | | | SL-5 | |
| Example 30 | P-5 | 10 | PAG15 | 1.88 | | | N-5 | 0.14 | HR-3 | 0.06 | SL-1/ | 60/40 |
| | | | | | | | | | | | SL-5 | |

| | | | | | | | Local | | Film Thickness |
|---|---|---|---|---|---|---|---|---|---|
| | | | | Mass | Rinsing | Mass | CDU | EL | in Pattern |
| Examples | Surfactant | (g) | Developer | Ratio | Liquid | Ratio | (nm) | (%) | Portion (nm) |
| Example 29 | W-3 | 0.003 | SG-2 | 100 | SR-4 | 100 | 4.6 | 18.2 | 83 |
| Example 30 | W-3 | 0.003 | SG-1 | 100 | SR-4 | 100 | 5.2 | 17.8 | 81 |

From the results shown in the Tables 5 and 6, it is clearly understood that the Comparative Examples 4 to 6 in which the acid-generating agent of the present invention was not used, had small exposure latitude (EL) and large local CDU, which shows that the film thickness in the pattern portion is small.

On the other hand, it is understood that Examples 14 to 26, 29 and 30 in which the acid-generating agent of the present invention was used, had large EL and small local CDU, which shows that Examples 14 to 26, 29 and 30 are excellent in both the EL and local CDU. In addition, it is understood that Examples 14 to 26, 29 and 30 had a large film thickness in a pattern portion.

This application claims priority under 35 U.S.C. §119 of Japanese Patent application JP 2011-166023, filed on Jul. 28, 2011 and Japanese Patent application JP 2012-135121, filed on Jun. 14, 2012, the entire contents of which are hereby incorporated by reference.

What is claimed is:

1. A pattern forming method comprising:
(1) forming a film by using an actinic ray-sensitive or radiation-sensitive resin composition containing a resin (P) of which the polarity increases by the action of an acid and thereby the solubility in a developer containing an organic solvent decreases and a compound (B) which generates an acid represented by the following general formula (I) by being irradiated with actinic rays or radiation;
(2) exposing the film; and
(3) forming a negative-type pattern by developing with a developer which contains an organic solvent, 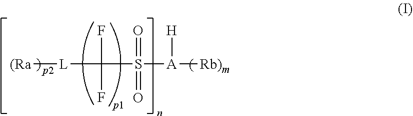
where A represents a nitrogen atom or a carbon atom,
each Ra independently represents a hydrogen atom, an alkyl group which does not have a fluorine atom as a substituent, a cycloalkyl group or an aryl group, and Rb represents an electron-attracting group, an alkyl group or an aryl group,
when A is a nitrogen atom, n represents 1 or 2 and m represents (2-n),
when A is a carbon atom, n represents an integer of 1 to 3 and m represents (3-n),
p1 represents an integer of 1 to 4 and p2 represents 1 or 2,
L represents a single bond or a (p2+1)-valent linking group and when L is a single bond, p2 represents 1,
when at least one of (i) p2 represents 2, and (ii) n represents 2 or 3, is satisfied, a plurality of Ra's may be the same as or different from each other and may be bonded to each other to form a ring, and
when A is a carbon atom and m represents 2, a plurality of Rb's may be the same as or different from each other.

2. The pattern forming method according to claim 1,
wherein the compound (B) is an ionic compound represented by the following general formula (II), 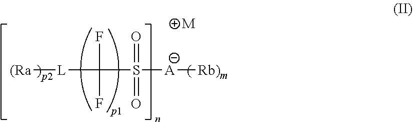
where in the general formula (II), A, Ra, Rb, L, m, n, p1 and p2 have the same definition as that of the respective A, Ra, Rb, L, m, n, p1 and p2 in the general formula (I) and
M⁺ represents an organic counterion.

3. The pattern forming method according to claim 2,
wherein M⁺ in the above general formula (II) is a sulfonium cation or an iodonium cation.

4. The pattern forming method according to claim 1,
wherein in each of n groups represented by [(Ra)ₚ₂-L-(CF₂)ₚ₁—SO₂]— in the above general formula (I),
(i) p2 represents 1 and L represents a single bond or a divalent group represented by any of the following formulae (L1) to (L6), or
(ii) p2 represents 2 and L represents trivalent formula represented by any of the following formulae (L7) to (L9), and 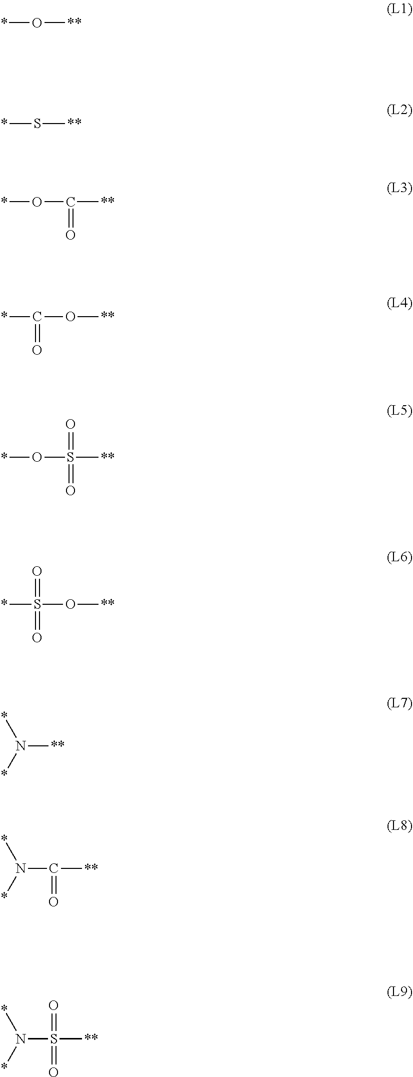
where in the above formulae, * represents a bond bonding to Ra in the general formula (I) and ** represents a bond bonding to —(CF₂)ₚ₁— in the general formula (I).

5. The pattern forming method according to claim 2,
wherein in each of n groups represented by [(Ra)ₚ₂-L-(CF₂)ₚ₁—SO₂]— in the above general formula (II),
(i) p2 represents 1 and L represents a single bond or a divalent group represented by any of the following formulae (L1) to (L6), or
(ii) p2 represents 2 and L represents trivalent formula represented by any of the following formulae (L7) to (L9), and 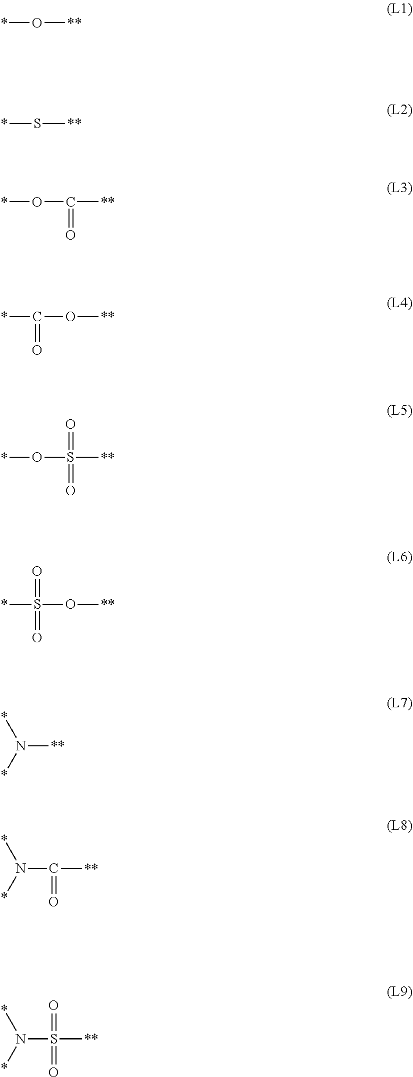
where in the above formulae, * represents a bond bonding to Ra in the general formula (II) and ** represents a bond bonding to —(CF₂)ₚ₁— in the general formula (II).

6. The pattern forming method according to claim 1,
wherein L does not have a fluorine atom and p1 represents 1 in the above general formula (I).

7. The pattern forming method according to claim 2,
wherein L does not have a fluorine atom and p1 represents 1 in the above general formula (II).

8. The pattern forming method according to claim 1,
wherein the resin (P) has a repeating unit (a1) which is acid-decomposable and thereby generates a carboxyl group.

9. The pattern forming method according to claim 8,
wherein the repeating unit (a1) which generates a carboxyl group is at least one of a repeating unit represented by the following general formula (III) and a repeating unit represented by the following general formula (IV), 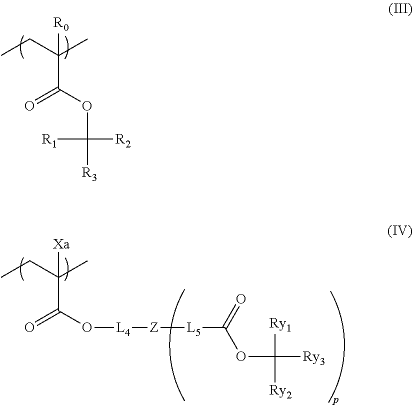
where in the above general formula (III), R₀ represents a hydrogen atom, an alkyl group, a cyano group or a halogen atom,
R₁ to R₃ each independently represent a chain alkyl group,
in the above general formula (IV), Xa represents a hydrogen atom, an alkyl group, a cyano group or a halogen atom,
Ry₁ to Ry₃ each independently represent an alkyl group or a cycloalkyl group. Two of Ry₁ to Ry₃ may be bonded to each other to form a ring,
Z represents a (p+1)-valent linking group which has a polycyclic hydrocarbon structure and may have a hetero atom as a ring member,
L₄ and L₅ each independently represent a single bond or a divalent linking group,
p represents an integer of 1 to 3,
when p is 2 or 3, a plurality of L₅, a plurality of Ry₁, a plurality of Ry₂ and a plurality of Ry₃ may be the same as or different from each other.

10. The pattern forming method according to claim 8,
wherein the content of the repeating unit (a1) is 50 mol % or more, based on all the repeating units in the resin (P).

11. The pattern forming method according to claim 10,
wherein the content of the repeating unit (a1) is 50 mol % or more and 65 mol % or less, based on all the repeating units in the resin (P).

12. The pattern forming method according to claim 1,
wherein the actinic ray-sensitive or radiation-sensitive resin composition further contains a basic compound or an ammonium salt compound (C), in which basicity decreases by irradiation with actinic rays or radiation.

13. The pattern forming method according to claim 1,
wherein the actinic ray-sensitive or radiation-sensitive resin composition further contains a hydrophobic resin which contains at least one of fluorine atoms and silicon atoms.

14. The pattern forming method according to claim 1,
wherein the developer contains at least one kind of organic solvent selected from a group consisting of a ketone-based solvent, an ester-based solvent, an alcohol-based solvent, an amide-based solvent, and an ether-based solvent.

15. The pattern forming method according to claim 1, further comprising:
(4) washing with a rinsing liquid containing an organic solvent.

16. The pattern forming method according to claim 1,
wherein the exposing in (2) is liquid immersion exposure.

17. An actinic ray-sensitive or radiation-sensitive resin composition comprising:
a resin (P) of which the polarity increases by the action of an acid and thereby the solubility in a developer containing an organic solvent decreases and
a compound (B′) which generates an acid represented by the following general formula (I-1) by being irradiated with actinic rays or radiation. 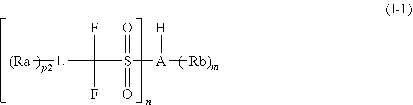
A represents a nitrogen atom or a carbon atom.
Each Ra independently represents a hydrogen atom, an alkyl group which does not have a fluorine atom as a substituent, a cycloalkyl group or an aryl group, and Rb represents an electron-attracting group, an alkyl group or an aryl group.
When A is a nitrogen atom, n represents 1 or 2 and m represents (2-n).
When A is a carbon atom, n represents an integer of 1 to 3 and m represents (3-n).
p2 represents 1 or 2.
L represents a single bond or a (p2+1)-valent linking group which does not have a fluorine atom. When L is a single bond, p2 represents 1.
When at least one of (i) p2 represents 2, and (ii) n represents 2 or 3, is satisfied, a plurality of Ra's may be the same as or different from each other and may be bonded to each other to form a ring.
When A is a carbon atom and m represents 2, a plurality of Rb's may be the same as or different from each other.

18. An actinic ray-sensitive or radiation-sensitive resin composition comprising:
a resin (P′) which has a repeating unit (a1) which is acid-decomposable and thereby generates a carboxyl group and
a compound (B) which generates an acid represented by the following general formula (I) by being irradiated with actinic rays or radiation,
wherein the content of the repeating unit (a1) is 50 mol % or more, based on all the repeating units in the resin (P′). 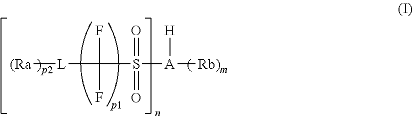
A represents a nitrogen atom or a carbon atom.
Each Ra independently represents a hydrogen atom, an alkyl group which does not have a fluorine atom as a substituent, a cycloalkyl group or an aryl group, and Rb represents an electron-attracting group, an alkyl group or an aryl group.
When A is a nitrogen atom, n represents 1 or 2 and m represents (2-n).
When A is a carbon atom, n represents an integer of 1 to 3 and m represents (3-n).
p1 represents an integer of 1 to 4 and p2 represents 1 or 2.
L represents a single bond or a (p2+1)-valent linking group. When L is a single bond, p2 represents 1.
When at least one of (i) p2 represents 2, and (ii) n represents 2 or 3, is satisfied, a plurality of Ra's may be the same as or different from each other and may be bonded to each other to form a ring.
When A is a carbon atom and m represents 2, a plurality of Rb's may be the same as or different from each other.

19. The actinic ray-sensitive or radiation-sensitive resin composition according to claim 18,
wherein the content of the repeating unit (a1) is 50 mol % or more and 65 mol % or less, based on all the repeating units in the resin (P′).

20. The actinic ray-sensitive or radiation-sensitive resin composition according to claim 18,
wherein the repeating unit (a1) is at least one of a repeating unit represented by the following general formula (III) and a repeating unit represented by the following general formula (IV). 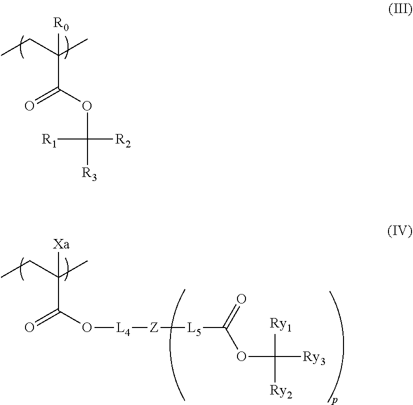
In the above general formula (III), R₀ represents a hydrogen atom, an alkyl group, a cyano group or a halogen atom.
R₁ to R₃ each independently represent a chain alkyl group.
In the above general formula (IV), Xa represents a hydrogen atom, an alkyl group, a cyano group or a halogen atom.
Ry₁ to Ry₃ each independently represent an alkyl group or a cycloalkyl group. Two of Ry₁ to Ry₃ may be bonded to each other to form a ring.
Z represents a (p+1)-valent linking group which has a polycyclic hydrocarbon structure and may have a hetero atom as a ring member.
L₄ and L₅ each independently represent a single bond or a divalent linking group.
p represents an integer of 1 to 3.
When p is 2 or 3, a plurality of L₅, a plurality of Ry₁, a plurality of Ry₂ and a plurality of Ry₃ may be the same as or different from each other.

21. An actinic ray-sensitive or radiation-sensitive resin composition comprising:
a resin (P) of which the polarity increases by the action of an acid and thereby the solubility in a developer containing an organic solvent decreases; a compound (B) which generates an acid represented by the following general formula (I) by being irradiated with actinic rays or radiation; and a basic compound or an ammonium salt compound (C), in which basicity decreases by irradiation with actinic rays or radiation. 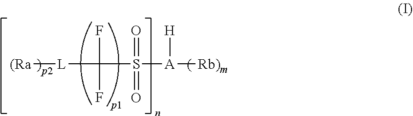
A represents a nitrogen atom or a carbon atom.
Each Ra independently represents a hydrogen atom, an alkyl group which does not have a fluorine atom as a substituent, a cycloalkyl group or an aryl group, and Rb represents an electron-attracting group, an alkyl group or an aryl group.
When A is a nitrogen atom, n represents 1 or 2 and m represents (2-n).
When A is a carbon atom, n represents an integer of 1 to 3 and m represents (3-n).
p1 represents an integer of 1 to 4 and p2 represents 1 or 2.
L represents a single bond or a (p2+1)-valent linking group. When L is a single bond, p2 represents 1.
When at least one of (i) p2 represents 2, and (ii) n represents 2 or 3, is satisfied, a plurality of Ra's may be the same as or different from each other and may be bonded to each other to form a ring.
When A is a carbon atom and m represents 2, a plurality of Rb's may be the same as or different from each other.

22. A resist film which is formed using the actinic ray-sensitive or radiation-sensitive resin composition according to claim 17.

23. A method for preparing an electronic device, comprising the pattern forming method according to claim 1.

24. An electronic device prepared by the method for preparing an electronic device according to claim 23.
